(19) United States
(12) Patent Application Publication
(10) Pub. No.: US 2023/0284528 A1
(43) Pub. Date: Sep. 7, 2023

(54) LIGHT EMITTING ELEMENT AND POLYCYCLIC COMPOUND FOR LIGHT EMITTING ELEMENT

(71) Applicant: Samsung Display Co., Ltd., Yongin-si (KR)

(72) Inventors: MUN-KI SIM, Seoul (KR); SUN YOUNG PAK, Suwon-si (KR); JUNHA PARK, Gwacheon-si (KR); Kyoung SUNWOO, Hwaseong-si (KR); CHANSEOK OH, Seoul (KR); MORAN HA, Asan-si (KR)

(73) Assignee: Samsung Display Co., Ltd., Yongin-si (KR)

(21) Appl. No.: 18/095,295

(22) Filed: Jan. 10, 2023

(30) Foreign Application Priority Data
Mar. 2, 2022 (KR) 10-2022-0027037

(51) Int. Cl. H10K 85/60; C07F 5/02; C09K 11/06

(52) U.S. Cl. CPC H10K 85/658; C07F 5/027; C09K 11/06; H10K 50/12

(57) ABSTRACT

Embodiments provide a light emitting element that includes a first electrode, a second electrode disposed on the first electrode, and an emission layer disposed between the first electrode and the second electrode. The emission layer includes a polycyclic compound represented by Formula 1, which includes a boron-containing core moiety, and a spiro-bifluorene substituent, thereby exhibiting high efficiency and long service life characteristics:

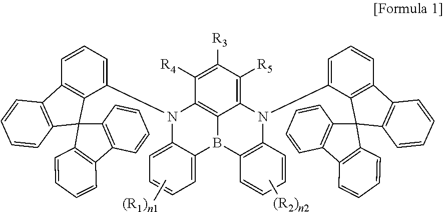

### CROSS-REFERENCE TO RELATED APPLICATION(S)

This application claims priority to and benefits of Korean Patent Application No. 10-2022-0027037 under 35 U.S.C. § 119, filed on Mar. 2, 2022 in the Korean Intellectual Property Office, the entire contents of which are incorporated herein by reference.

### BACKGROUND

### 1. Technical Field

The disclosure relates to a light emitting element including, in an emission layer, materials such as a novel polycyclic compound used as a luminescent material.

### 2. Description of the Related Art

Active development continues for an organic electroluminescence display device as an image display device. The organic electroluminescence display device includes a so-called self-luminescent light emitting element in which holes and electrons respectively injected from a first electrode and a second electrode recombine in an emission layer, so that a luminescent material of the emission layer emits light to achieve display.

In the application of a light emitting element to a display device, there is a demand for a light emitting element having low driving voltage, high luminous efficiency, and a long service life, and continuous development is required on materials for a light emitting element which are capable of stably achieving such characteristics.

In order to implement an organic electroluminescence device with high efficiency, technologies pertaining to phosphorescence emission which uses energy in a triplet state or to delayed fluorescence emission which uses the generation of singlet excitons by the collision of triplet excitons (triplet-triplet annihilation, TTA) are being developed, and development is currently directed to a material for thermally activated delayed fluorescence (TADF) using a delayed fluorescence mechanism.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element exhibiting high efficiency and long service life characteristics.

The disclosure also provides a polycyclic compound, which is a material for a light emitting element having high luminous efficiency and improved service life characteristics.

An embodiment of the disclosure provides a light emitting element which may include a first electrode, a second electrode disposed on the first electrode, and an emission layer disposed between the first electrode and the second electrode. The emission layer may include: a first compound represented by Formula 1; and at least one of a second compound represented by Formula HT-1, a third compound represented by Formula ET-1, or a fourth compound represented by Formula M-b:

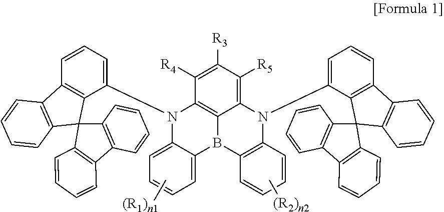

In Formula 1, R₁ and R₂ may each independently be a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; R₃ may be a substituted or unsubstituted amine group, a substituted or unsubstituted silyl group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; R₄ and R₅ may each independently be a hydrogen atom or a deuterium atom; and n1 and n2 may each independently be an integer from 0 to 4.

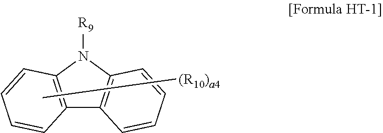

In Formula HT-1, a4 may be an integer from 0 to 8; and R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms.

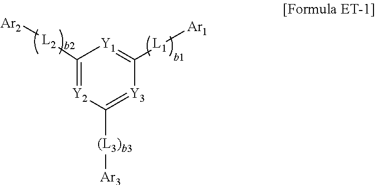

In Formula ET-1, at least one of Y₁ to Y₃ may each be N; the remainder of Y₁ to Y₃ may each independently be C(Rₐ); Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms; and Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

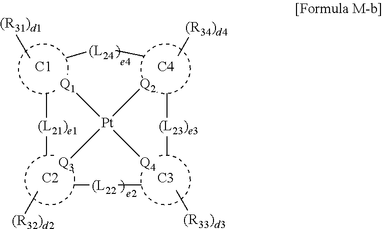

In Formula M-b, Q₁ to Q₄ may each independently be C or N; C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms; e1 to e4 may each independently be 0 or 1; L₂₁ to L₂₄ may each independently be a direct linkage,

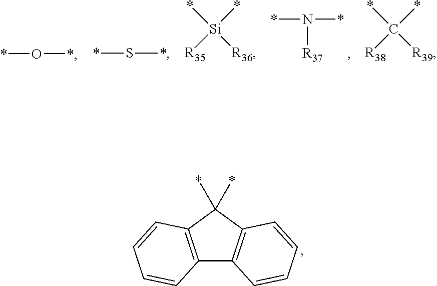

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; d1 to d4 may each independently be an integer from 0 to 4; and R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the first compound represented by Formula 1 may be represented by any one of Formula 1-1 to Formula 1-3:

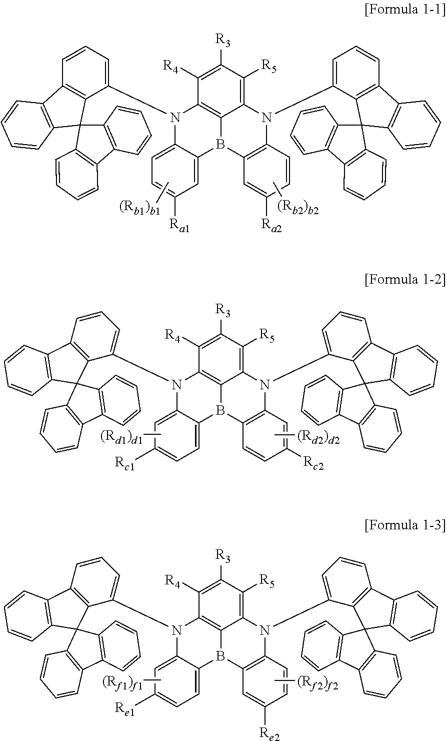

In Formula 1-1 to Formula 1-3, Rₐ₁, Rₐ₂, R_{c1}, R_{c2}, Rₑ₁, and Rₑ₂ may each independently be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a substituted or unsubstituted heterocycle; R_{b1}, R_{b2}, Rₐ₁, Rₐ₂, R_{f1}, and R_{f2} may each independently be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a substituted or unsubstituted heterocycle; b1, b2, d1, d2, f1, and f2 may each independently be an integer from 0 to 3; and R₃ to R₅ are each the same as defined in Formula 1.

In an embodiment, the first compound represented by Formula 1 may be represented by any one of Formula 2-1 to Formula 2-7:

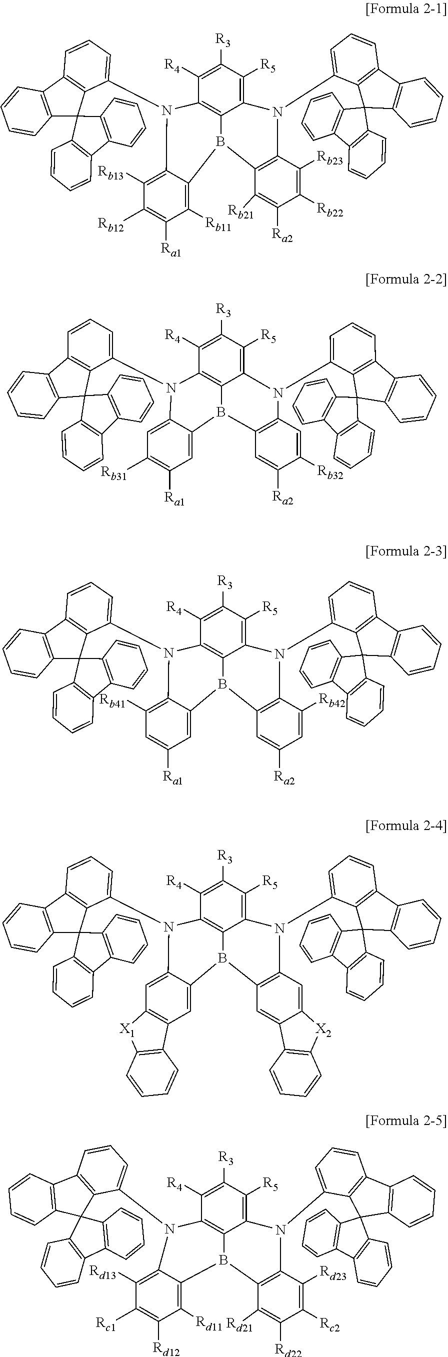

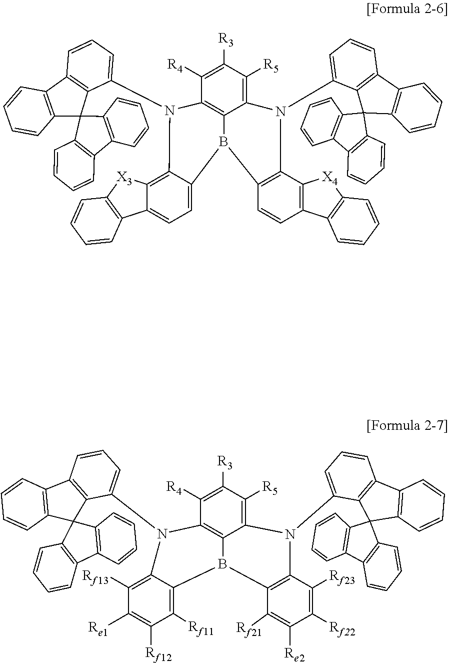

In Formula 2-1 to Formula 2-7, R_{b11} to R_{b13}, R_{b21} to R_{b23}, Rₐ₁₁ to Rₐ₁₃, Rₐ₂₁ to Rₐ₂₃, R_{f11} to R_{f13}, and R_{f21} to R_{f23} may each independently be a hydrogen atom or a deuterium atom; R_{b31}, R_{b32}, R_{b41}, and R_{b42} may each independently be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; X₁ to X₄ may each independently be O, S, or N(Rₓ₁); Rₓ₁ may be a substituted or unsubstituted aryl group having 6 to 20 ring-forming carbon atoms; and Rₐ₁, Rₐ₂, R_{c1}, R_{c2}, Rₑ₁, Rₑ₂, and R₃ to R₅ are each the same as defined in Formula 1 and Formula 1-1 to Formula 1-3.

In an embodiment, the first compound represented by Formula 1 may be represented by Formula 3:

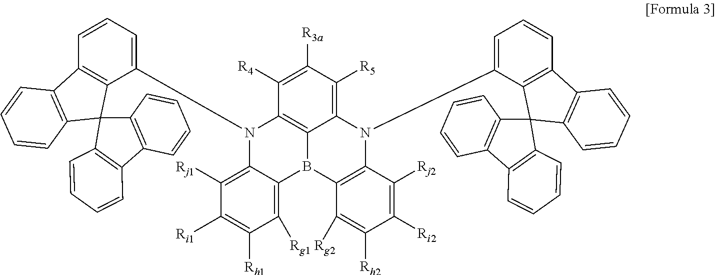

In Formula 3, R_{g1}, R_{g2}, Rₕ₁, Rₕ₂, Rᵢ₁, Rᵢ₂, Rⱼ₁, and Rⱼ₂ may each independently be a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, or may be bonded to an adjacent group to form a substituted or unsubstituted heterocycle; R₃ₐ may be a substituted or unsubstituted alkyl group having 1 to 10 carbon atoms, a substituted or unsubstituted carbazole group, a substituted or unsubstituted indolocarbazole group, a substituted or unsubstituted phenyl group, a substituted or unsubstituted fluorenyl group, a substituted or unsubstituted dibenzofuran group, a substituted or unsubstituted diphenylamine group, or a substituted or unsubstituted triphenylsilyl group; and R₄ and R₅ are each the same as defined in Formula 1.

In an embodiment, the first compound represented by Formula 3 may be represented by any one of Formula 3-1 to Formula 3-3:

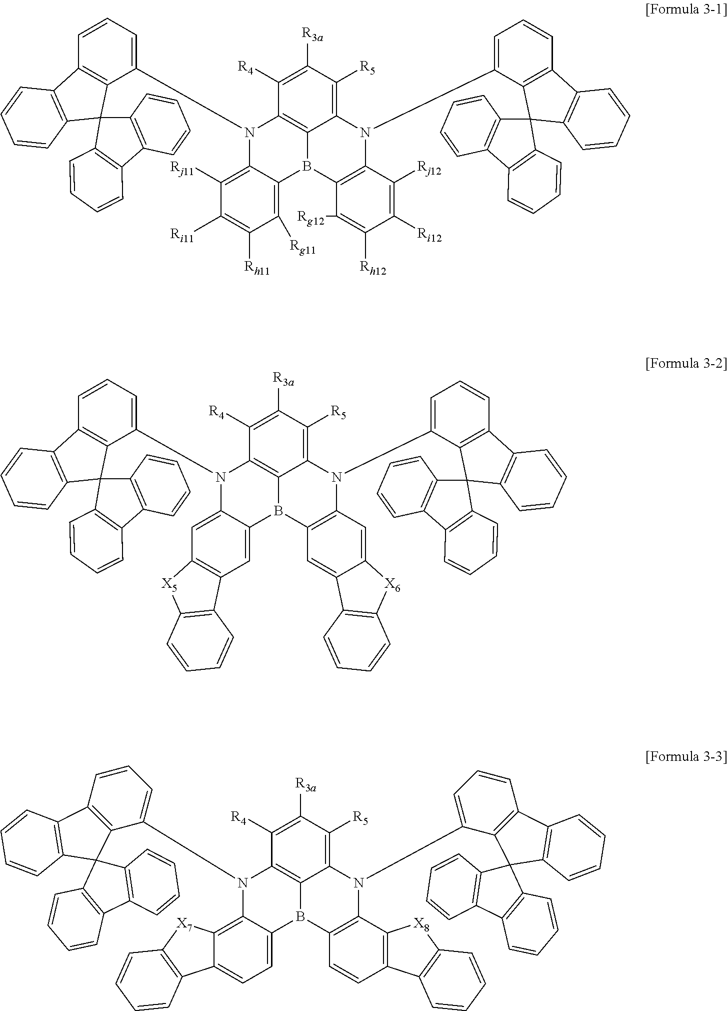

In Formula 3-1, R_{g11}, Rₕ₁₁, Rᵢ₁₁, Rⱼ₁₁, R_{g12}, Rₕ₁₂, Rᵢ₁₂, and Rⱼ₁₂ may each independently be a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms; and at least one of R_{g11}, Rₕ₁₁, Rᵢ₁₁, or Rⱼ₁₁ and at least one of R_{g12}, Rₕ₁₂, Rᵢ₁₂, or Rⱼ₁₂ may each independently be a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms. In Formula 3-2 and Formula 3-3, X₅ to X₈ may each independently be O, S, or N(Rₓ₂); and Rₓ₂ may be a substituted or unsubstituted aryl group having 6 to 20 ring-forming carbon atoms. In Formula 3-1 to Formula 3-3, R₃ₐ, R₄, and R₅ are each the same as defined in Formula 1 and Formula 3.

In an embodiment, R₃ may be a group represented by any one of R3-1 to R3-8:

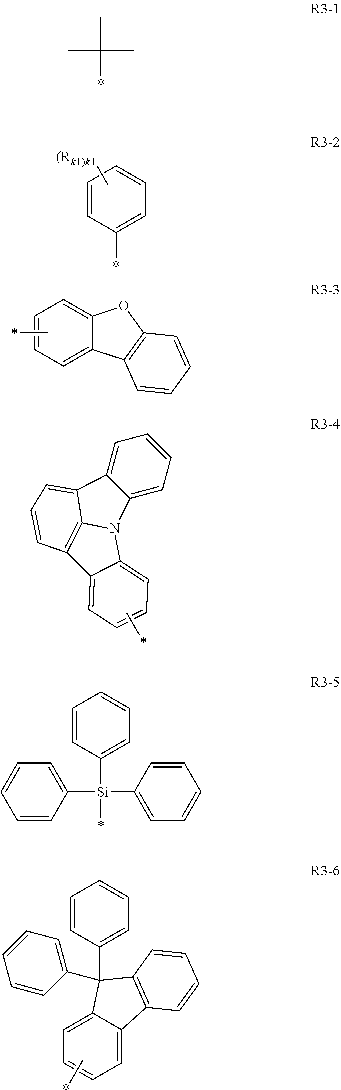

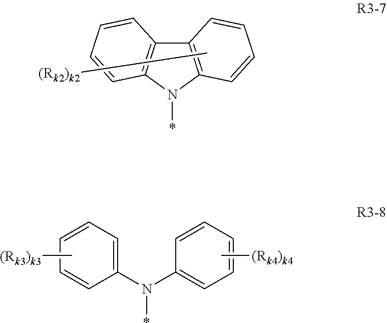

In R3-1 to R3-8, Rₖ₁, Rₖ₂, Rₖ₃, and Rₖ₄ may each independently be a hydrogen atom, a deuterium atom, a substituted or unsubstituted alkyl group having 1 to 10 carbon atoms, or a substituted or unsubstituted aryl group having 6 to 10 ring-forming carbon atoms; k1, k3, and k4 may each independently be an integer from 0 to 5; and k2 may be an integer from 0 to 8.

In an embodiment, the emission layer may include the first compound, the second compound, and the third compound.

In an embodiment, the emission layer may include the first compound, the second compound, the third compound, and the fourth compound.

In an embodiment, the emission layer may emit delayed fluorescence.

In an embodiment, the emission layer may emit light having a central wavelength in a range of about 430 nm to about 490 nm.

In an embodiment, a weight ratio of the second compound to the third compound may be in a range of about 3:7 to about 7:3.

In an embodiment, the light emitting element may further include a hole transport region disposed between the first electrode and the emission layer, wherein hole transport region may include a compound represented by Formula H-1:

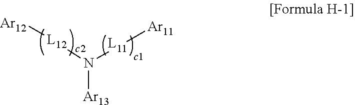

In Formula H-1, c1 and c2 may each independently be an integer from 0 to 10; L₁₁ and L₁₂ may each independently be a direct linkage, a substituted or unsubstituted arylene group having 6 to 30 ring-forming carbon atoms, or a substituted or unsubstituted heteroarylene group having 2 to 30 ring-forming carbon atoms; Ar₁₁ and Ar₁₂ may each independently be a substituted or unsubstituted aryl group having 6 to 30 ring-forming carbon atoms, or a substituted or unsubstituted heteroaryl group having 2 to 30 ring-forming carbon atoms; and Ar₁₃ may be a substituted or unsubstituted aryl group having 6 to 30 ring-forming carbon atoms.

In an embodiment, the first compound may be selected from Compound Group 1, which is explained below.

An embodiment of the disclosure provides a polycyclic compound which may be represented by Formula 1, which is explained herein.

In an embodiment, the polycyclic compound represented by Formula 1 may be represented by any one of Formula 1-1 to Formula 1-3, which are explained herein.

In an embodiment, the polycyclic compound represented by Formula 1 may be represented by any one of Formula 2-1 to Formula 2-7, which are explained herein.

In an embodiment, the polycyclic compound represented by Formula 1 may be represented by Formula 3, which is explained herein.

In an embodiment, the polycyclic compound represented by Formula 3 may be represented by any one of Formula 3-1 to Formula 3-3, which are explained herein.

In an embodiment, R₃ may be a group represented by any one of R3-1 to R3-8, which are explained herein.

In an embodiment, the polycyclic compound may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a plan view illustrating a display device according to an embodiment;

FIG. 2 is a schematic cross-sectional view illustrating a part taken along line I-I′ of FIG. 1;

FIG. 3 is a schematic cross-sectional view illustrating a light emitting element according to an embodiment;

FIG. 4 is a schematic cross-sectional view illustrating a light emitting element according to an embodiment;

FIG. 5 is a schematic cross-sectional view illustrating a light emitting element according to an embodiment;

FIG. 6 is a schematic cross-sectional view illustrating a light emitting element according to an embodiment;

FIG. 7 is a schematic cross-sectional view illustrating a display device according to an embodiment;

FIG. 8 is a schematic cross-sectional view illustrating a display device according to an embodiment;

FIG. 9 is a schematic cross-sectional view illustrating a display device according to an embodiment; and

FIG. 10 is a schematic cross-sectional view illustrating a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the description, an alkenyl group may be a hydrocarbon group including one or more carbon-carbon double bonds in the middle of or at a terminus of an alkyl group having two or more carbon atoms. An alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styrylvinyl group, etc., without limitation.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not specifically limited, but may be 2 to 30, 2 to 20, or 2 to 10. Examples of an alkynyl group may include an ethynyl group, a propynyl group, etc., without limitation.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. The aryl group may be monocyclic or polycyclic. The number of ring-forming carbon atoms in an aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorene group may be substituted, and two substituents may be bonded to each other to form a spiro structure. Examples of substituted fluorene groups are as follows. However, embodiments are not limited thereto.

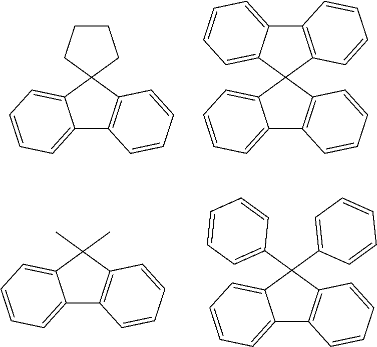

In the specification, a heterocyclic group herein may be any functional group or substituent derived from a ring that includes at least one of B, O, N, P, Si, S, or Se as a heteroatom. The heterocyclic group may be an aliphatic heterocyclic group or an aromatic heterocyclic group. An aromatic heterocyclic group may be a heteroaryl group. An aliphatic heterocycle or an aromatic heterocycle may each independently be monocyclic or polycyclic.

In the specification, a heterocyclic group may include at least one of B, O, N, P, Si, S, or Se as a heteroatom. If a heterocyclic group contains two or more heteroatoms, the two or more heteroatoms may be the same as or different from each other. In the specification, a heterocyclic group may be monocyclic or polycyclic, and a heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, S, or Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, or Se as a heteroatom. If a heteroaryl group contains two or more heteroatoms, the two or more heteroatoms may be the same as or different from each other. A heteroaryl group may be monocyclic or polycyclic. The ring-forming carbon number in a heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of the aryl group may be applied to an arylene group, except that the arylene group is a divalent group. In the specification, the above description of the heteroaryl group may be applied to a heteroarylene group, except that the heteroarylene group is a divalent group.

In the specification, a boron group may be a boron atom is bonded to an alkyl group or an aryl group as defined herein. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, a silyl group may be an alkyl silyl group or an aryl silyl group. Examples of a silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, embodiments are not limited thereto.

In the specification, the number of ring-forming carbon atoms in a carbonyl group is not specifically limited, but may be 1 to 40, 1 to 30, or 1 to 20. For example, a carbonyl group may have one of the following structures, but embodiments are not limited thereto:

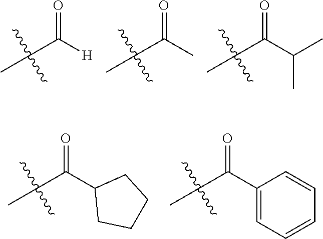

In the specification, the number of carbon atoms in a sulfinyl group or a sulfonyl group is not particularly limited, but may each be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined herein. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined herein. An oxy group may be an alkoxy group or an aryl oxy group. An alkoxy group may be linear, branched, or cyclic. The number of carbon atoms in an alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments are not limited thereto.

In the specification, the number of carbon atoms in an amine group is not specifically limited, but may be 1 to 30. The amine group may be an alkyl amine group or an aryl amine group. Examples of the amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of the alkyl group as described above.

In the specification, an aryl group in an aryloxy group, an arylthio group, an arylsulfoxy group, an arylamino group, an arylboron group, an arylsilyl group, or an arylamine group may be the same as an example of the aryl group as described above.

In the specification, a direct linkage may be a single bond.

In the specification, the symbols

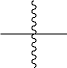

or [symbol] each represent a binding site to a neighboring atom.

Hereinafter, embodiments will be described with reference to the drawings.

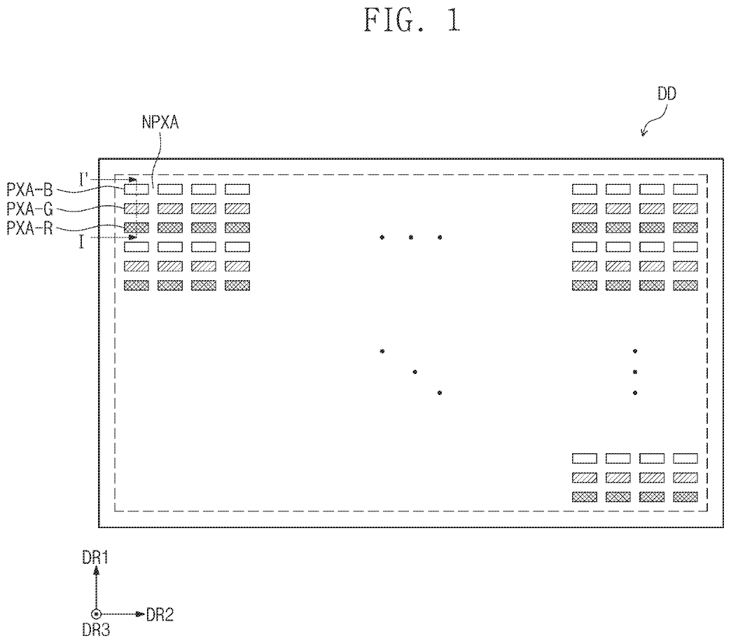

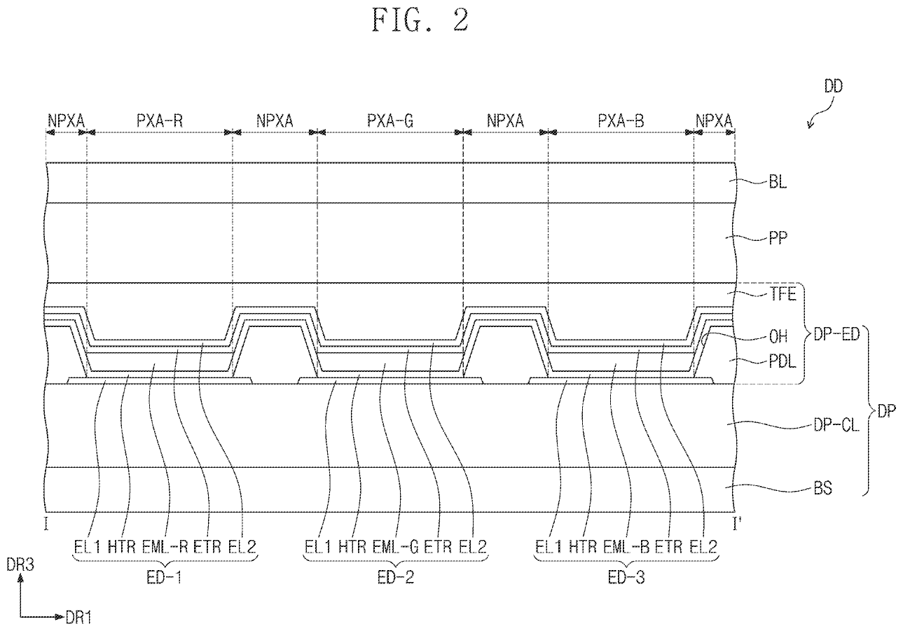

FIG. 1 is a plan view illustrating an embodiment of a display device DD. FIG. 2 is a schematic cross-sectional view of the display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP may include light emitting elements ED-1, ED-2, and ED-3. The display device DD may include multiples of each of the light emitting elements ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and a display element layer DP-ED. The display element layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting elements ED-1, ED-2, and ED-3 of the display element layer DP-ED.

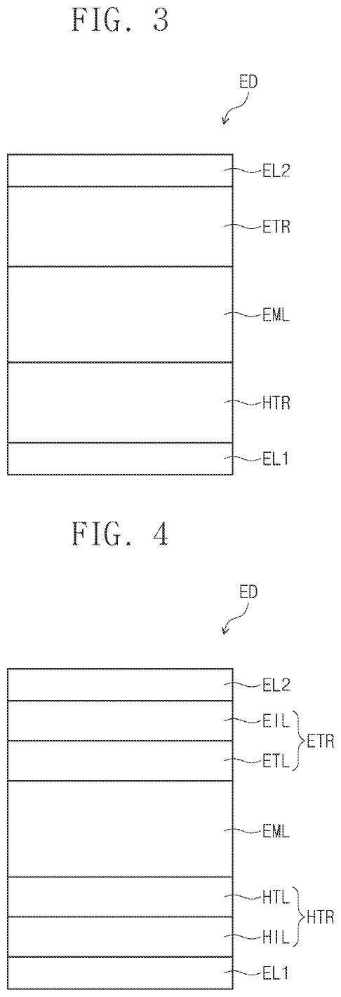

Each of the light emitting elements ED-1, ED-2, and ED-3 may have a structure of a light emitting element ED of an embodiment according to one of FIGS. 3 to 6, which will be described later. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, embodiments are not limited thereto.

Although not illustrated in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned by an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display element layer DP-ED from moisture and/or oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may each be a region in which light respectively generated by the light emitting elements ED-1, ED-2, and ED-3 is emitted. The light emitting regions PXA-R, PXA-G, and PXA-B may be spaced apart from each other in a plan view.

Each of the light emitting regions PXA-R, PXA-G, and PXA-B may be a region separated by the pixel defining film PDL. The non-light emitting regions NPXA may be regions between the adjacent light emitting regions PXA-R, PXA-G, and PXA-B, which correspond to portions of the pixel defining film PDL. For example, in an embodiment, the light emitting regions PXA-R, PXA-G, and PXA-B may each respectively correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which emit red light, green light, and blue light, respectively, are illustrated as an example. For example, the display device DD according to an embodiment may include the red light emitting region PXA-R, the green light emitting region PXA-G, and the blue light emitting region PXA-B which are separated from each other.

In the display device DD according to an embodiment, the light emitting elements ED-1, ED-2, and ED-3 may emit light having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments are not limited thereto, and the first to third light emitting elements ED-1, ED-2, and ED-3 may emit light in a same wavelength range, or at least one light emitting element may emit light in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may each be arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have a similar area, but embodiments are not limited thereto. Thus, the light emitting regions PXA-R, PXA-G, and PXA-B may have different areas from each other according to a wavelength range of the emitted light. For example, the areas of the light emitting regions PXA-R, PXA-G, and PXA-B may be areas in a plan view that are defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required in the display device DD. For example, the light emitting regions PXA-R, PXA-G, and PXA-B may be arranged in a pentile configuration (for example, in a PENTILE™ configuration) or in a diamond configuration (for example, in a Diamond Pixel™ configuration).

In an embodiment, the areas of the light emitting regions PXA-R, PXA-G, and PXA-B may be different from each other. For example, in an embodiment, an area of the green light emitting region PXA-G may be smaller than an area of the blue light emitting region PXA-B, but embodiments are not limited thereto.

In the display device DD according to an embodiment illustrated in FIG. 2, at least one among the first to third light emitting elements ED-1, ED-2, and ED-3 may include a polycyclic compound according to an embodiment which will be described below.

Hereinafter, FIGS. 3 to 6 are each a schematic cross-sectional view illustrating a light emitting element according to an embodiment. The light emitting elements ED according to embodiments may each include a first electrode EL1, a second electrode EL2 disposed on the first electrode EL1, and at least one functional layer disposed between the first electrode EL1 and the second electrode EL2. Each of the light emitting elements ED according to embodiments may include a polycyclic compound according to an embodiment, which will be described below, in at least one functional layer. In the specification, the polycyclic compound according to an embodiment may be referred to as a first compound.

Each of the light emitting elements ED may include, as the at least one functional layer, a hole transport region HTR, an emission layer EML, and an electron transport region ETR, which may be stacked in that order. As shown in FIG. 3, the light emitting element ED according to an embodiment may include a first electrode EL1, a hole transport region HTR, an emission layer EML, an electron transport region ETR, and a second electrode EL2, which are stacked in that order. In The light emitting element ED according to an embodiment may include the polycyclic compound according to an embodiment, which will be described below, in the emission layer EML.

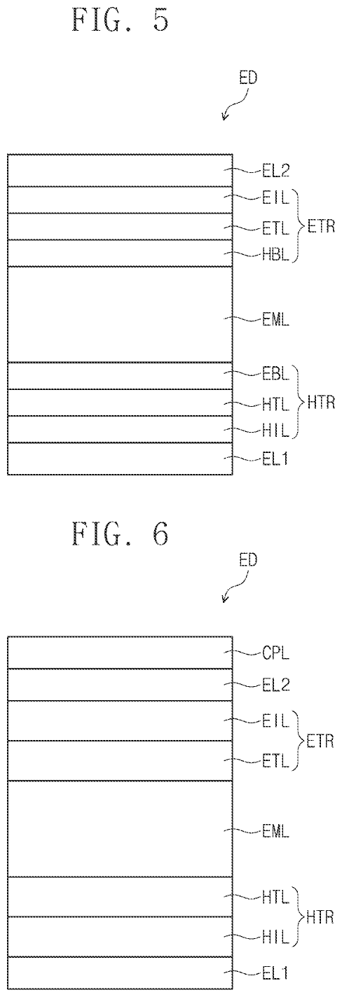

In comparison to FIG. 3, FIG. 4 illustrates a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting element ED according to an embodiment including a capping layer CPL disposed on a second electrode EL2.

In an embodiment, the emission layer EML may include a first compound including a core moiety containing a boron atom and nitrogen atoms as ring-forming atoms and a fluorene substituent substituted at the core moiety. In the first compound according to an embodiment, the fluorene substituent may be 9,9′-spirobifluorene.

In an embodiment, the emission layer EML may further include at least one of a second compound, a third compound, or a fourth compound. The second compound may include a substituted or unsubstituted carbazole moiety. The third compound may include a hexagonal ring containing at least one nitrogen atom as a ring-forming atom. The fourth compound may be an organometallic complex compound. The fourth compound may be an organometallic complex compound containing platinum (Pt) as a central metal.

In the light emitting element ED according to an embodiment, the first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective layer or a transflective layer formed of the above-described materials, and a transparent conductive layer formed of ITO, IZO, ZnO, ITZO, etc. For example, the first electrode EL1 may have a three-layer structure of ITO/Ag/ITO, but embodiments are not limited thereto. The electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may be a layer formed of a single material, a layer formed of different materials, or a structure including multiple layers formed of different materials.

The hole transport region HTR may include at least one of a hole injection layer HIL, a hole transport layer HTL, a buffer layer (not shown), an emission-auxiliary layer (not shown), or an electron blocking layer EBL. Although not illustrated in the drawings, in an embodiment, the hole transport region HTR may include a stack of multiple hole transport layers.

In embodiments, the hole transport region HTR may have a single layer structure of the hole injection layer HIL or the hole transport layer HTL, or may have a single layer structure formed of a hole injection material and a hole transport material. In other embodiments, the hole transport region HTR may have a single layer structure formed of different materials, or a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

A thickness of the hole transport region HTR may be, for example, in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

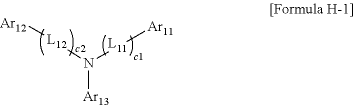

In Formula H-1, L₁₁ and L₁₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, c1 and c2 may each independently be an integer from 0 to 10. When c1 or c2 is 2 or more, multiple L₁₁ groups or multiple L₁₂ groups may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁₁ and Ar₁₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₁₃ may be a substituted or unsubstituted aryl group having 6 to 30 ring-forming carbon atoms.

In an embodiment, the compound represented by Formula H-1 may be a monoamine compound. In another embodiment, the compound represented by Formula H-1 may be a diamine compound in which at least one of Ar₁₁ to Ar₁₃ includes an amine group as a substituent. In still another embodiment, the compound represented by Formula H-1 may be a carbazole-based compound in which at least one of Ar₁₁ or Ar₁₂ includes a substituted or unsubstituted carbazole group, or a fluorene-based compound in which at least one of Ar₁₁ or Ar₁₂ includes a substituted or unsubstituted fluorene group.

The compound represented by Formula H-1 may be any one selected from Compound Group H. However, the compounds listed in Compound Group H are only examples, and the compounds represented by Formula H-1 are not limited to Compound Group H:

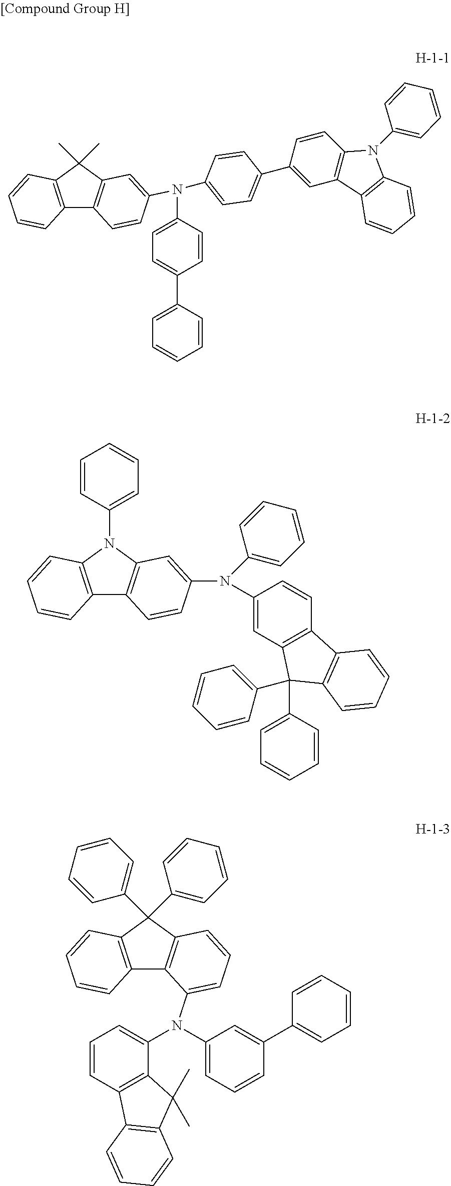 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

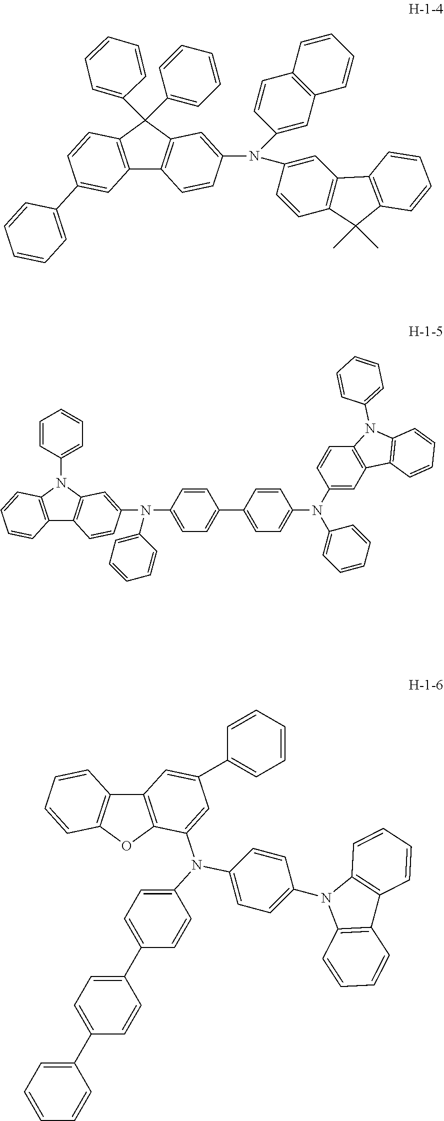 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

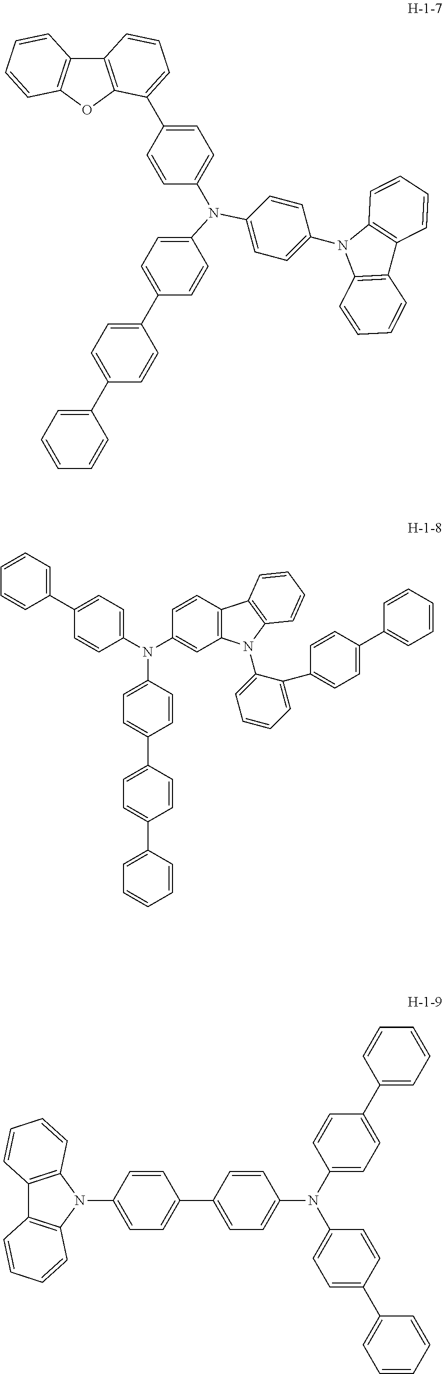 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

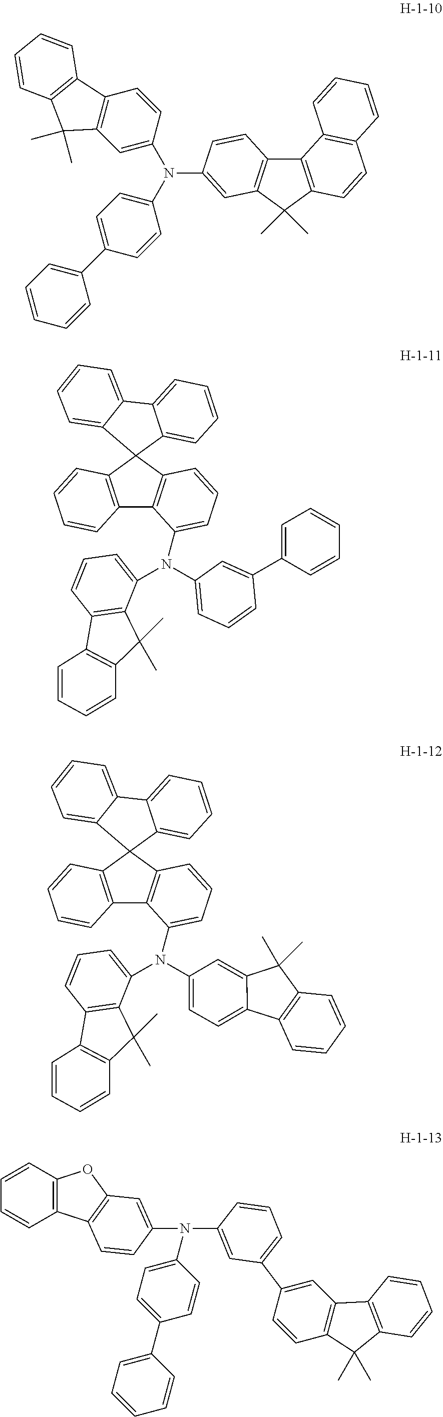

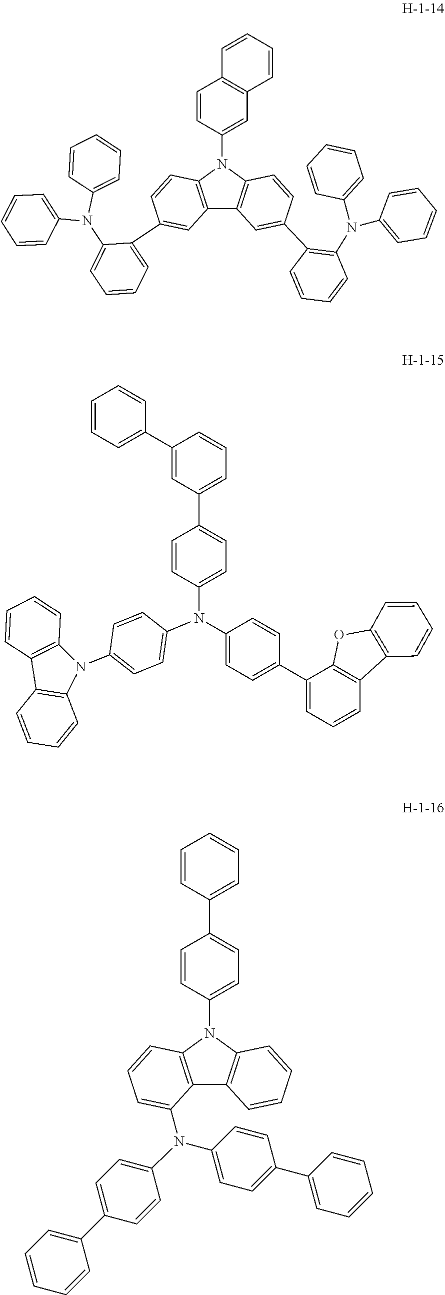 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

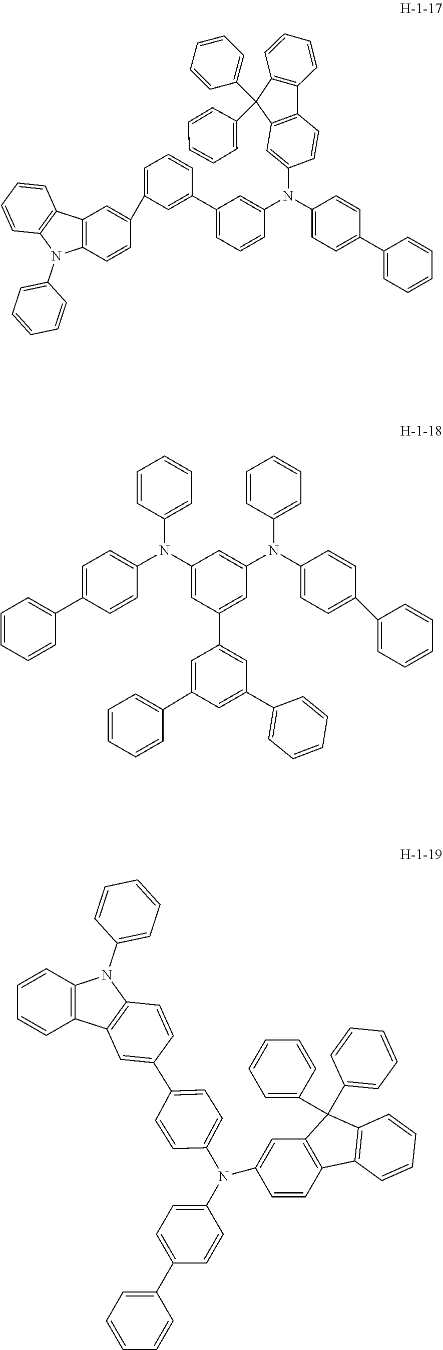 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a plithalocyanine compound such as copper phthalocyanine; N¹,N¹′-([1,1′-biphenyl]-4,4′-diyl)bis(N¹-phenyl-N⁴N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N-(1-naphthyl)-N-phenylamino]-triphenylamine (1-TNATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB or NPD of α-NPD), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenyl amine-based derivative such as 4,4′,4″-tris(N-carbazolyl)triphenylamine (TCTA), or N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. For example, when the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be used as a material to be contained in the buffer layer (not shown).

The electron blocking layer EBL may prevent the injection of electrons from the electron transport region ETR to the hole transport region HTR. The emission-auxiliary layer (not shown) may improve charge balance between holes and electrons. When the hole transport region HTR includes an electron blocking layer EBL, the electron blocking layer EBL may serve as an emission-auxiliary layer.

The emission layer EML is provided on the hole transport region HTR. The emission layer EML may have a thickness, for example, in a range of about 100 Å to about 1,000 Å. For example, the emission layer EML may have a thickness in a range of about 100 Å to about 300 Å. The emission layer EML may be a layer formed of a single material, a layer formed of different materials, or a structure having multiple layers formed of different materials.

In the light emitting element ED according to an embodiment, the emission layer EML may include multiple luminescent materials. In an embodiment, the emission layer EML may include the first compound, and at least one of a second compound, a third compound, or a fourth compound. In the light emitting element ED according to an embodiment, the emission layer EML may include at least one host and at least one dopant. For example, the emission layer EML of an embodiment may include a first dopant, and the emission layer EML may include a first host and a second host that are different from each other.

In an embodiment, the emission layer EML may include the first compound, represented by Formula 1. The first compound corresponds to the polycyclic compound according to an embodiment.

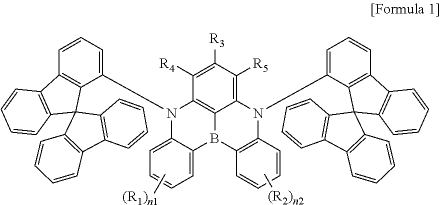

In Formula 1, R₁ and R₂ may each independently be a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, R₁ and R₂ may each independently be a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, or may be bonded to an adjacent group to form a substituted or unsubstituted heterocycle. For example, R₁ and R₂ may each independently be a substituted or unsubstituted t-butyl group, a substituted or unsubstituted carbazole group, a substituted or unsubstituted indolocarbazole group, a substituted or unsubstituted phenyl group, a substituted or unsubstituted fluorenyl group, or a substituted or unsubstituted dibenzofuran group. In an embodiment, adjacent R₁ groups may be bonded to each other or adjacent R₂ groups may be bonded to each other to form a substituted or unsubstituted heterocycle of indoline or benzofuran.

In Formula 1, n1 and n2 may each independently be an integer from 0 to 4. When n1 is 2 or greater, multiple R₁ groups may all be the same or at least one may be different from the rest. When n2 is 2 or greater, multiple R₂ groups may all be the same or at least one may be different from the rest. A case where n1 is 0 may be the same as a case where n1 is 4 and each R₁ group is a hydrogen atom. It may be understood that when n1 is 0, R₁ is not substituted at the polycyclic compound represented by Formula 1. A case where n2 is 0 may be the same as a case where n2 is 4 and each R₂ groups is a hydrogen atom. It may be understood that when n2 is 0, R₂ is not substituted at the polycyclic compound represented by Formula 1.

In Formula 1, R₃ may be a substituted or unsubstituted amine group, a substituted or unsubstituted silyl group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. In Formula 1, R₄ and R₅ may each independently be a hydrogen atom or a deuterium atom. For example, R₄ and R₅ may both be hydrogen atoms or may both be deuterium atoms.

In an embodiment, R₃ may be a substituted or unsubstituted alkyl group having 1 to 10 carbon atoms, a substituted or unsubstituted carbazole group, a substituted or unsubstituted indolocarbazole group, a substituted or unsubstituted phenyl group, a substituted or unsubstituted fluorenyl group, a substituted or unsubstituted dibenzofuran group, a substituted or unsubstituted diphenylamine group, or a substituted or unsubstituted triphenylsilyl group. For example, in an embodiment, R₃ may be a group represented by any one of R3-1 to R3-8:

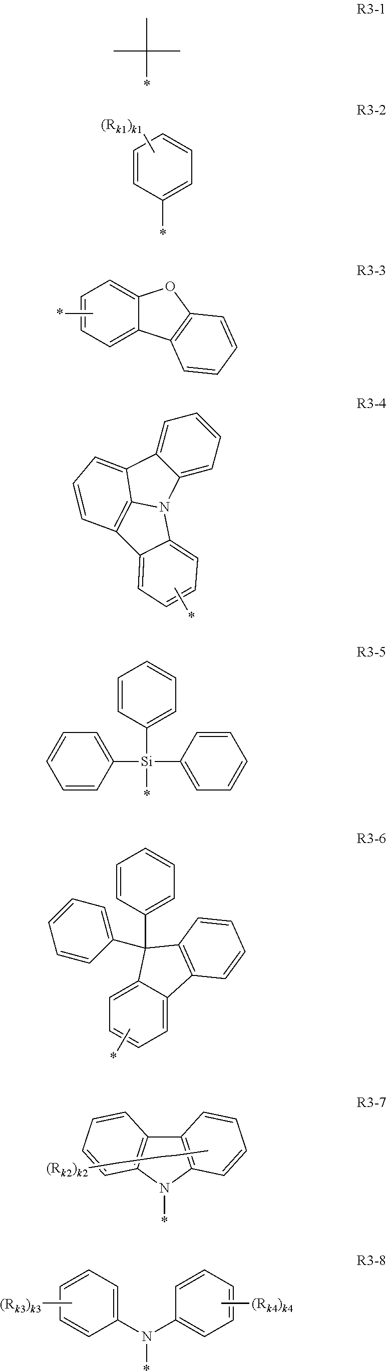

In R3-1 to R3-8, Rₖ₁, Rₖ₂, Rₖ₃, and Rₖ₄ may each independently be a hydrogen atom, a deuterium atom, a substituted or unsubstituted alkyl group having 1 to 10 carbon atoms, or a substituted or unsubstituted aryl group having 6 to 10 ring-forming carbon atoms. In an embodiment, Rₖ₁, Rₖ₂, RU, and Rₖ₄ may each independently be a hydrogen atom, a deuterium atom, a t-butyl group, or a substituted or unsubstituted phenyl group.

In R3-1 to R3-8, k1, k3, and k4 may each independently be an integer from 0 to 5. In R3-1 to R3-8, k2 may be an integer from 0 to 8. When each of k1, k3, and k4 is 2 or greater, multiple groups of each of Rₖ₁, RU, and Rₖ₄ may each be the same or at least one may be different from the rest. When k2 is 2 or greater, multiple Rₖ₂ groups may all be the same or at least one may be different from the rest. A case where k1 is 0 may be the same as a case where k1 is 5 and each Rₖ₁ group is a hydrogen atom. It may be understood that when k1 is 0, Rₖ₁ is not substituted at R₃ represented by R3-2. Such a description may also be equally applied to a case where k3 and k4 are each 0 when R₃ is represented by R3-8. A case where k2 is 0 may be the same as a case where k2 is 8 and each Rₖ₂ group is a hydrogen atom. It may be understood that when k2 is 0, Rₖ₂ is not substituted at R₃ represented by R3-7.

The polycyclic compound according to an embodiment may include at least one deuterium atom as a substituent. For example, in an embodiment, at least one of R₁ to R₅ in Formula 1 may include a deuterium atom, or a substituent containing a deuterium atom.

The polycyclic compound according to an embodiment includes a core moiety of a fused ring that includes a boron atom (B) and two nitrogen atoms (N) as ring-forming atoms, and an aryl substituent having a high steric hindrance is bonded to the core moiety, so that a p-orbital of the boron atom in the polycyclic compound may be protected, and interactions between bonds in the polycyclic compound may be reduced. The aryl substituent having a high steric hindrance such as spiro-bifluorene has a folded structure, so that orbitals are not distributed and electron density is trapped in the fused ring core moiety, and thereby the core moiety may facilitate multiple resonance due to high electron density.

In the polycyclic compound represented by Formula 1 according to embodiment, the spiro-bifluorene substituents having a high steric hindrance are respectively bonded to two nitrogen atoms of the core moiety, and thus may protect the core moiety. Referring to Reference Formula 1, in the polycyclic compound according to embodiments, the first position of spiro-bifluorene may be bonded to the nitrogen atom of the core moiety. The polycyclic compound according to embodiments may protect the p-orbital of the boron atom, and may effectively reduce Dexter energy transfer of the fused ring core moiety and peripheral molecules.

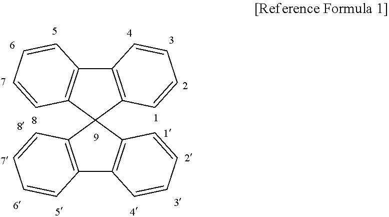 [SMILES: c1ccc2c(c1)-c1ccccc1C21c2ccccc2-c2ccccc21]

For example, the polycyclic compound according to embodiments to which the spiro-bifluorene substituent is bonded has structural characteristics in that the ninth position of spiro-bifluorene is a sp³-carbon and difficult to rotate. The polycyclic compound according to embodiments has a structure in which the core moiety and two spiro-bifluorene substituents overlap on a same plane, and thus may exhibit an effect of additionally suppressing rotation, and have a significant effect of shielding the p-orbital of the boron atom. Accordingly, the polycyclic compound according to embodiments has a reduced structural degree of freedom, and thus may prevent the deterioration of optical characteristics (Stokes shift, FWHM, etc.), and may contribute to the improvement of luminous efficiency and service life.

In an embodiment, the polycyclic compound represented by Formula 1 may be represented by one of Formula 1-1 to Formula 1-3. Formula 1-1 to Formula 1-3 each correspond to a case where R₁ and R₂ in Formula 1 are specified. Formula 1-1 corresponds to a case where the remaining substituents other than a hydrogen atom or a deuterium atom among substituents of R₁ and R₂ described in Formula 1 are bonded at para-positions to a nitrogen atoms of the core moiety. Formula 1-2 corresponds to a case where the remaining substituents other than a hydrogen atom or a deuterium atom among substituents of R₁ and R₂ described in Formula 1 are bonded at para-positions to the boron atom of the core moiety. Formula 1-3 corresponds to case where the remaining substituent other than a hydrogen atom or a deuterium atom among substituents of R₁ described in Formula 1 are bonded at a para-position to the boron atom of the core moiety, and the remaining substituent other than a hydrogen atom or a deuterium atom among substituents of R₂ described in Formula 1 are bonded at a para-position to a nitrogen atom of the core moiety. In Formula 1-1 to Formula 1-3, R₃ to R₅ are each the same as described in Formula 1.

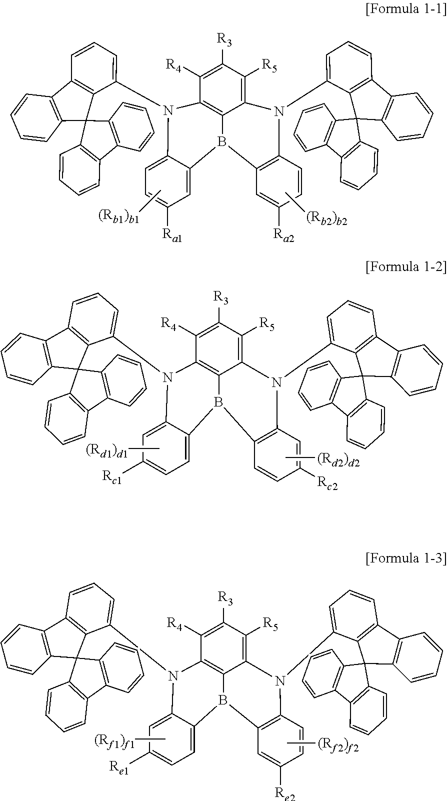

In Formula 1-1 to Formula 1-3, Rₐ₁, Rₐ₂, R_{c1}, R_{c2}, Rₑ₁, and Rₑ₂ may each independently be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a substituted or unsubstituted heterocycle.

In Formula 1-1 to Formula 1-3, R_{b1}, R_{b2}, Rₐ₁, Rₐ₂, R_{f1}, and R_{f2} may each independently be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a substituted or unsubstituted heterocycle.

In Formula 1-1 to Formula 1-3, b1, b2, d1, d2, f1, and f2 may each independently be an integer from 0 to 3. If each of b1, b2, d1, d2, f1, and f2 is 0, the polycyclic compound of an embodiment may not be substituted with each of R_{b1}, R_{b2}, R_{d1}, R_{d2}, R_{f1}, and R_{f2}. If each of b1, b2, d1, d2, f1, and f2 is 2 or greater, multiple groups of each of R_{b1}, R_{b2}, Rₐ₁, Rₐ₂, R_{f1}, and R_{f2} may each be the same or at least one thereof may be different from the others.

In an embodiment, the polycyclic compound represented by Formula 1 may be represented by any one of Formula 2-1 to Formula 2-7. Formula 2-1 to Formula 2-7 each represent a case where R₁ and R₂ in Formula 1 are specified. Formula 2-1 to Formula 2-7 each correspond to a case where Rₐ₁, Rₐ₂, R_{c1}, R_{c2}, R_{b1}, R_{b2}, R_{d1}, R_{d2}, Rₑ₁, Rₑ₂, R_{f1}, and R_{f2} in Formula 1-1 to Formula 1-3 are specified. In Formula 2-1 to Formula 2-7, Rₐ₁, Rₐ₂, R_{c1}, R_{c2}, Rₑ₁, Rₑ₂, and R₃ to R₅ are each the same as defined in Formula 1 and Formula 1-1 to Formula 1-3.

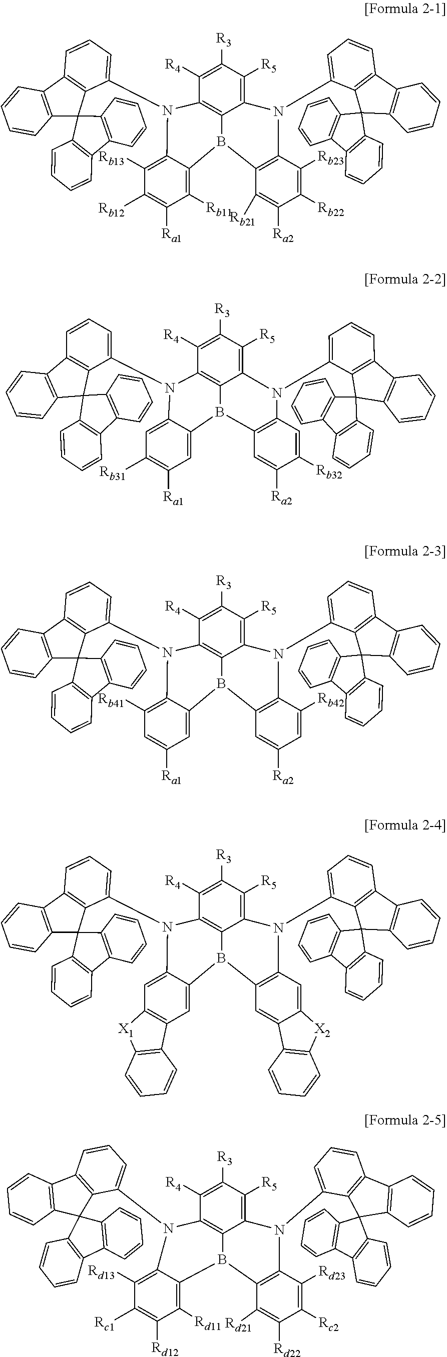

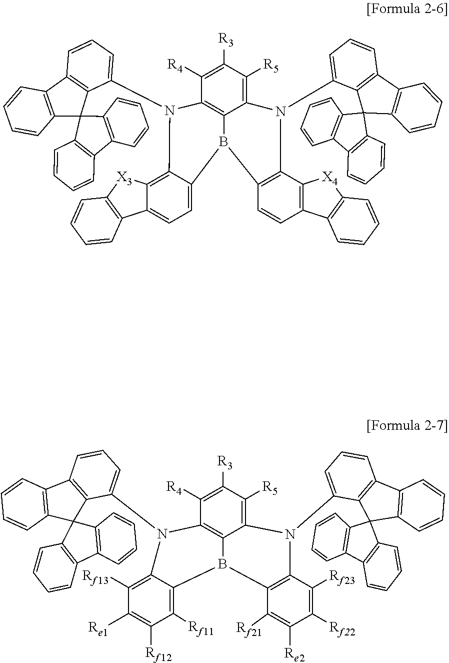

In Formula 2-1 to Formula 2-7, R_{b11} to R_{b13}, R_{b21} to R_{b23}, R_{d11} to R_{d13}, R_{d21} to R_{d23}, R_{f11} to R_{f13}, and R_{f21} to R_{f23} may each independently be a hydrogen atom or a deuterium atom. R_{b31}, R_{b32}, R_{b41}, and R_{b42} may each independently be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In Formula 2-4 and Formula 2-6, X₁ to X₄ may each independently be O, S, or N(Rₓ₁); and Rₓ₁ may be a substituted or unsubstituted aryl group having 6 to 20 ring-forming carbon atoms. For example, Rₓ₁ may be a substituted or unsubstituted phenyl group.

In an embodiment, the polycyclic compound represented by Formula 1 may be represented by Formula 3. Formula 3 corresponds to a case where R₁ to R₃ are specified in Formula 1. In Formula 3, R₄ and R₅ are each the same as defined in Formula 1.

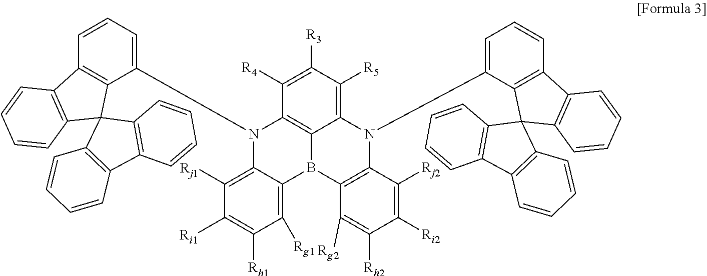

In Formula 3, R_{g1}, R_{g2}, Rₕ₁, Rₕ₂, Rᵢ₁, Rᵢ₂, Rⱼ₁, and Rⱼ₂ may each independently be a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, or may be bonded to an adjacent group to form a substituted or unsubstituted heterocycle.

In Formula 3, R₃ₐ may be a substituted or unsubstituted alkyl group having 1 to 10 carbon atoms, a substituted or unsubstituted carbazole group, a substituted or unsubstituted indolocarbazole group, a substituted or unsubstituted phenyl group, a substituted or unsubstituted fluorenyl group, a substituted or unsubstituted dibenzofuran group, a substituted or unsubstituted diphenylamine group, or a substituted or unsubstituted triphenylsilyl group. In an embodiment, in Formula 3, when R₃ₐ is an alkyl group, a carbazole group, an indolocarbazole group, a phenyl group, a fluorenyl group, a dibenzofuran group, a diphenylamine group, or a triphenylsilyl group, they may each independently be substituted with a deuterium atom, a t-butyl group, or a phenyl group.

In an embodiment, the polycyclic compound represented by Formula 3 may be represented by any one of Formula 3-1 to Formula 3-3. Formula 3-1 to Formula 3-3 each correspond to a case where R_{g1}, R_{g2}, Rₕ₁, Rₕ₂, Rᵢ₁, Rᵢ₂, Rⱼ₁, and Rⱼ₂ as described in Formula 3 are specified. Formula 3-1 to Formula 3-3 each also correspond to a case where R₁ to R₃ as described in Formula 1 are specified.

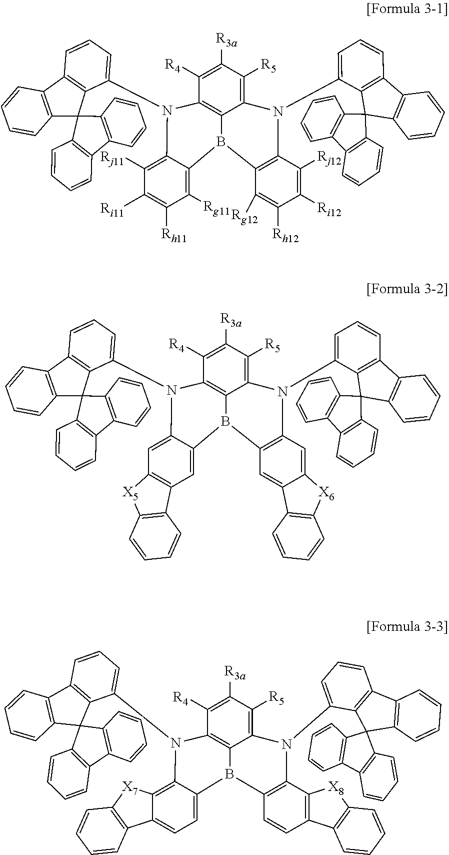

In Formula 3-1, R_{g11}, Rₕ₁₁, Rᵢ₁₁, Rⱼ₁₁, R_{g12}, Rₕ₁₂, Rᵢ₁₂, and Rⱼ₁₂ may each independently be a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms. For example, R_{g11}, Rₕ₁₁, Rᵢ₁₁, Rⱼ₁₁, R_{g12}, Rₕ₁₂, Rᵢ₁₂, and Rⱼ₁₂ may be each independently a hydrogen atom, a deuterium atom, a substituted or unsubstituted t-butyl group, a substituted or unsubstituted carbazole group, a substituted or unsubstituted fluorenyl group, a substituted or unsubstituted phenyl group, or a substituted or unsubstituted dibenzofuran group. However, embodiments are not limited thereto.

In an embodiment, in Formula 3-1, at least one of R_{g11}, Rₕ₁₁, Rᵢ₁₁, or Rⱼ₁₁ and at least one of R_{g12}, Rₕ₁₂, Rᵢ₁₂, or Rⱼ₁₂ may each independently be a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, and the remainder of R_{g11}, Rₕ₁₁, Rᵢ₁₁, Rⱼ₁₁, R_{g12}, Rₕ₁₂, Rᵢ₁₂, and Rⱼ₁₂ may each independently be a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms.

In Formula 3-2 and Formula 3-3, X₅ to X₈ may each independently be O, S, or N(Rₓ₂); and Rₓ₂ may be a substituted or unsubstituted aryl group having 6 to 20 ring-forming carbon atoms. For example, Rₓ₂ may be a substituted or unsubstituted phenyl group.

In Formula 3-1 to Formula 3-3, R₃ₐ, R₄, and R₅ are each the same as defined in Formula 1 and Formula 3.

The polycyclic compound according to an embodiment may be any one selected from Compound Group 1. An emission layer EML of the light emitting element ED according to an embodiment may include at least one compound selected from Compound Group 1 as the first compound.

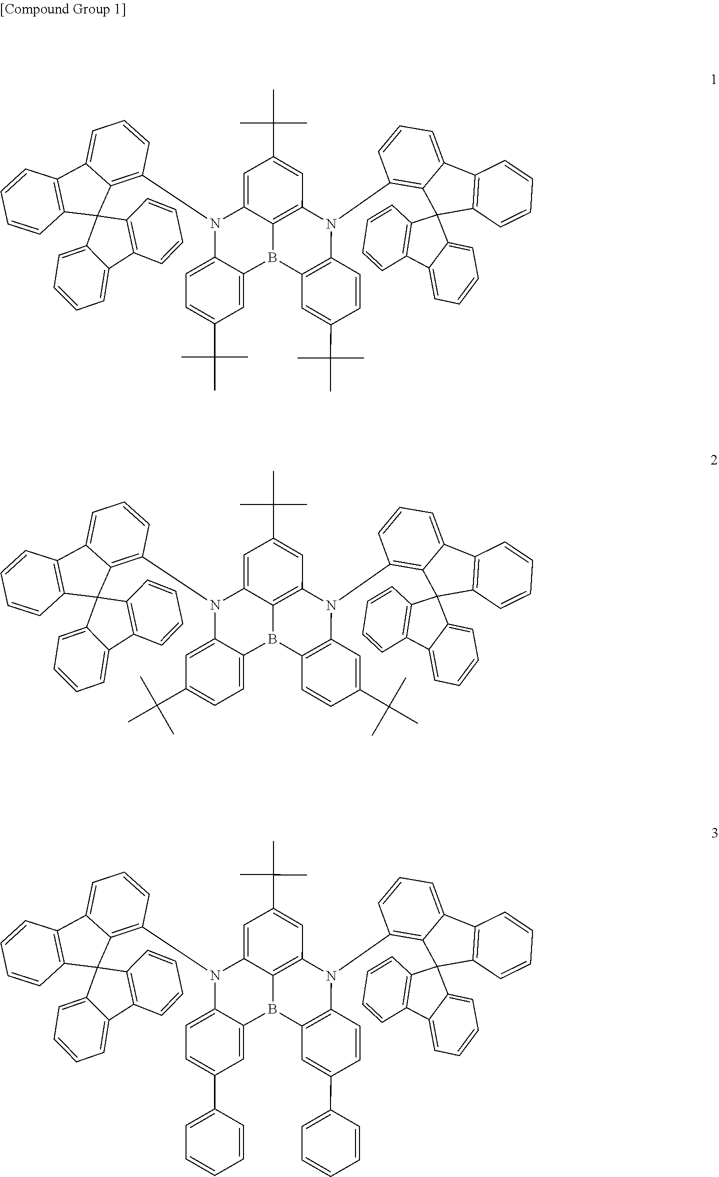 [SMILES: CC(C)(C)c1ccc2c(c1)B1c3cc(C(C)(C)C)ccc3N(c3cccc4c3C3(c5ccccc5-c5ccccc53)c3ccccc3-4)c3cc(C(C)(C)C)cc(c31)N2c1cccc2c1C1(c3ccccc3-c3ccccc31)c1ccccc1-2 ; CC(C)(C)c1ccc2c(c1)N(c1cccc3c1C1(c4ccccc4-c4ccccc41)c1ccccc1-3)c1cc(C(C)(C)C)cc3c1B2c1ccc(C(C)(C)C)cc1N3c1cccc2c1C1(c3ccccc3-c3ccccc31)c1ccccc1-2 ; CC(C)(C)c1cc2c3c(c1)N(c1cccc4c1C1(c5ccccc5-c5ccccc51)c1ccccc1-4)c1ccc(-c4ccccc4)cc1B3c1cc(-c3ccccc3)ccc1N2c1cccc2c1C1(c3ccccc3-c3ccccc31)c1ccccc1-2]

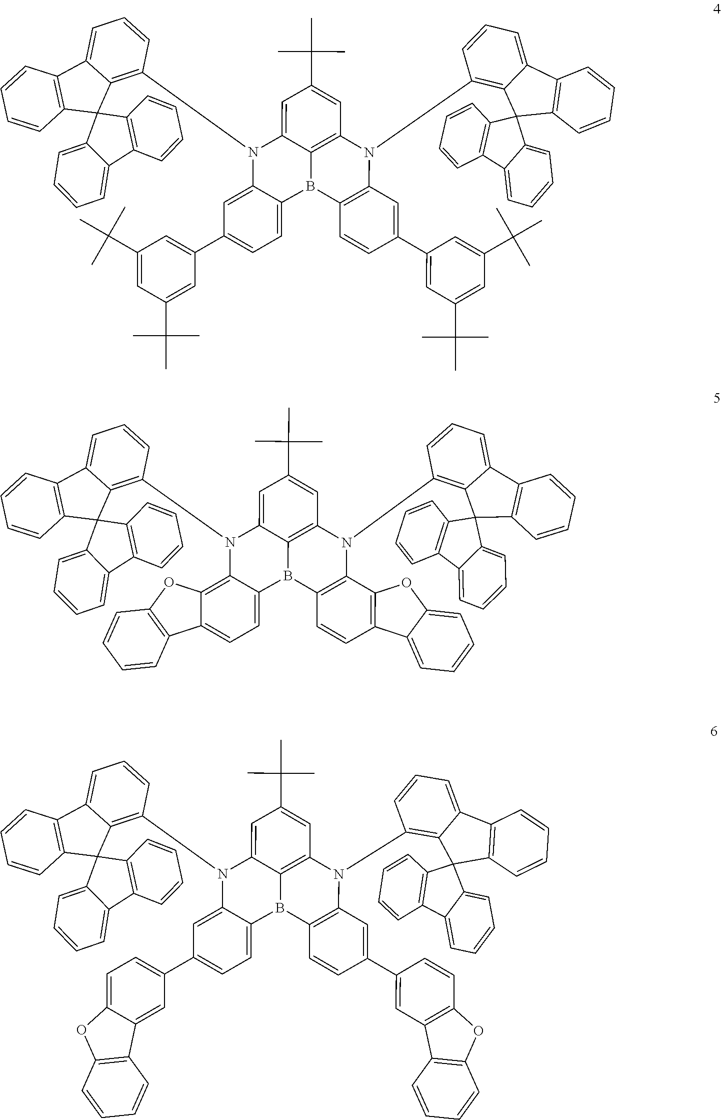

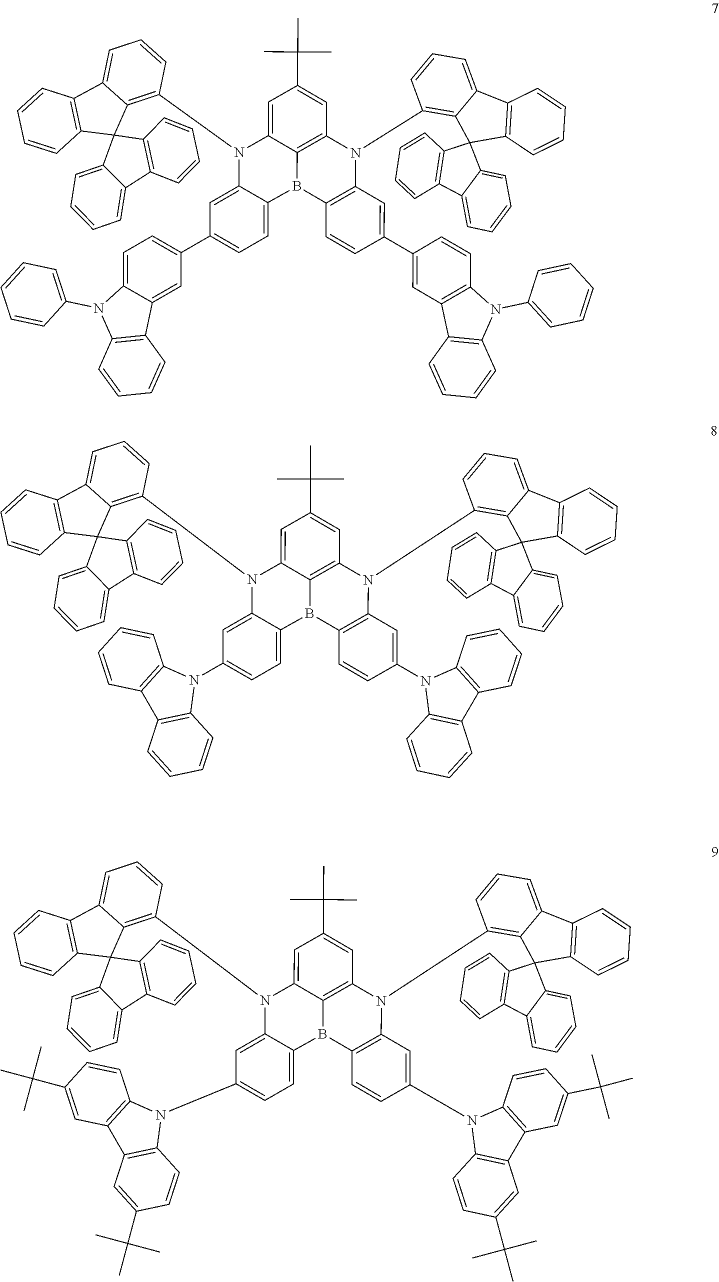

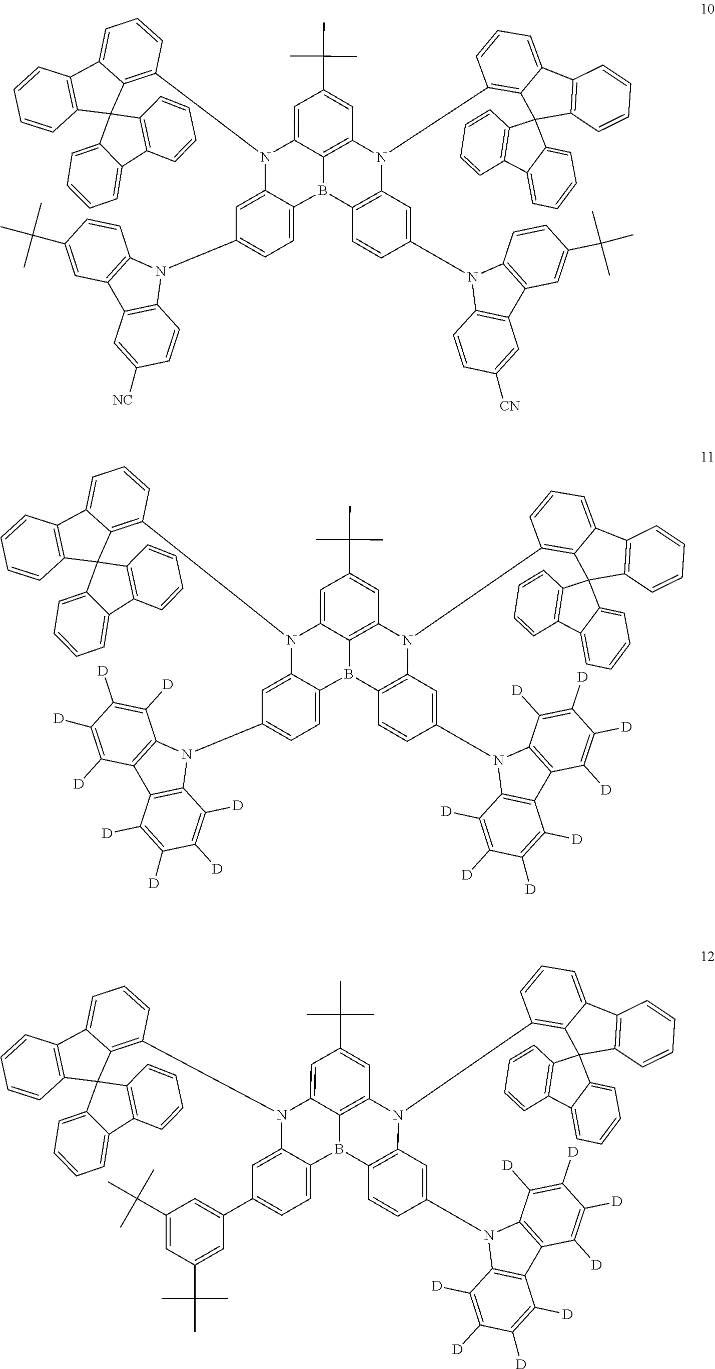

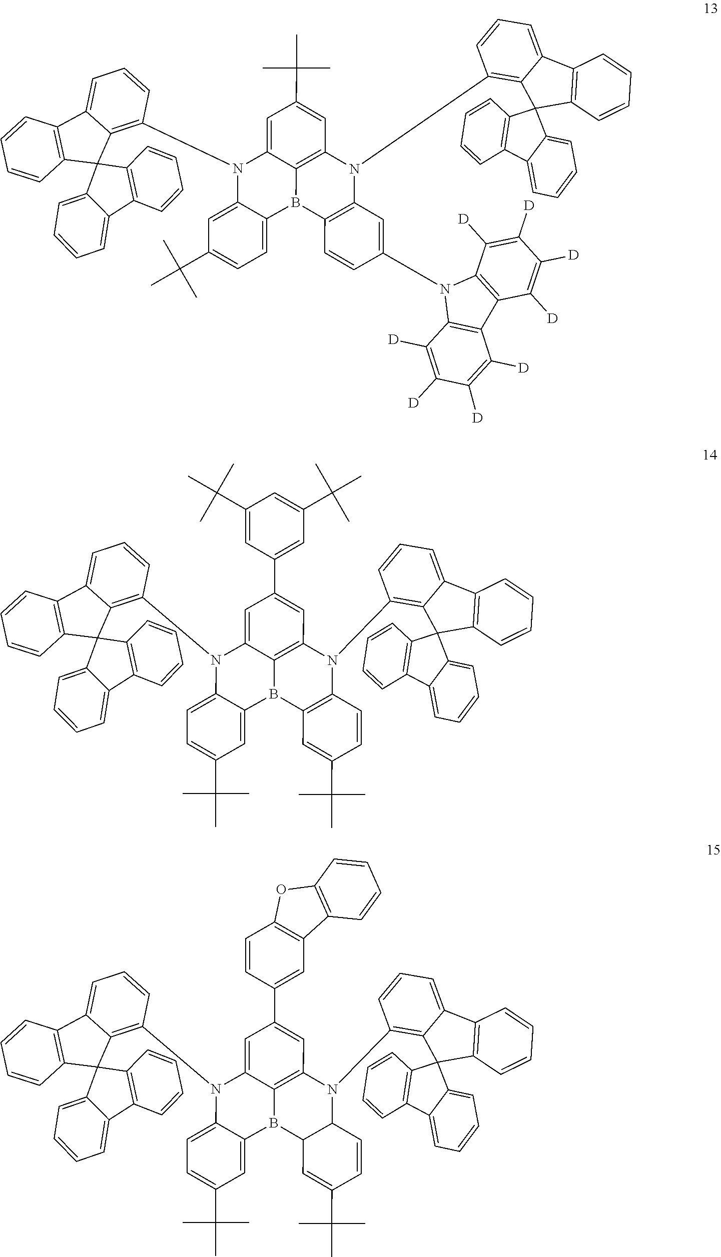

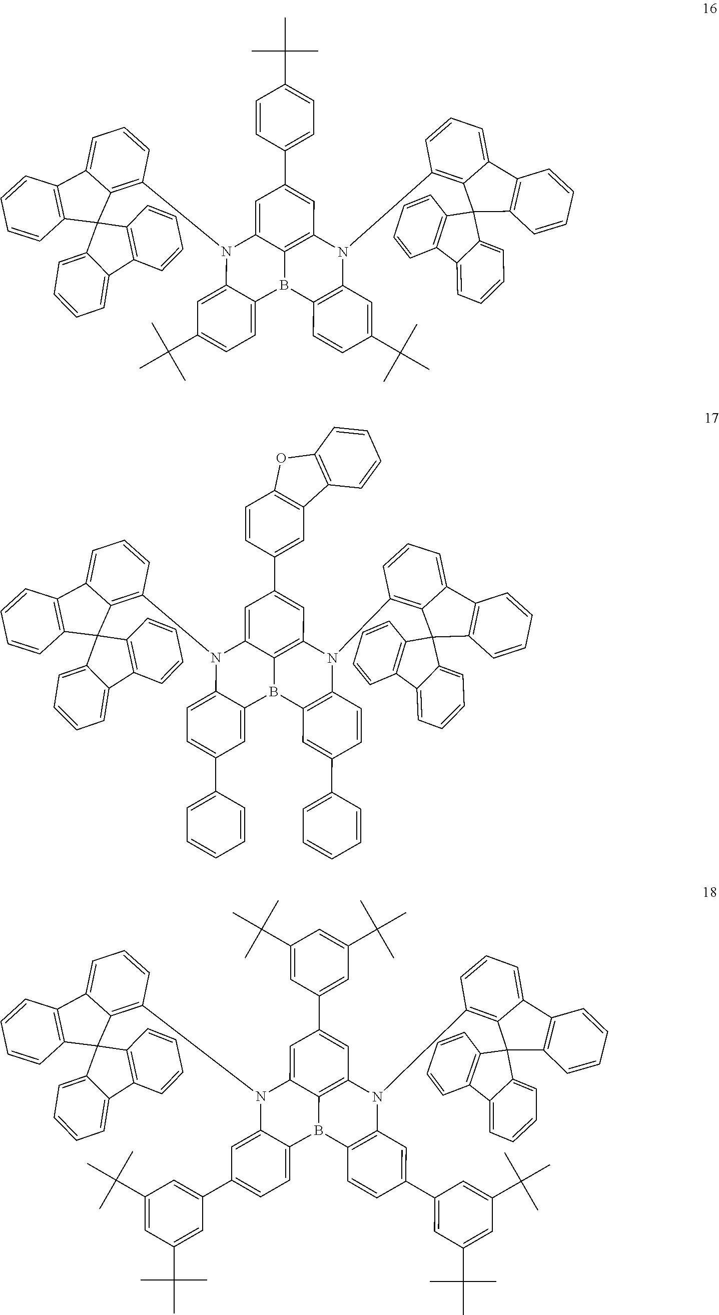

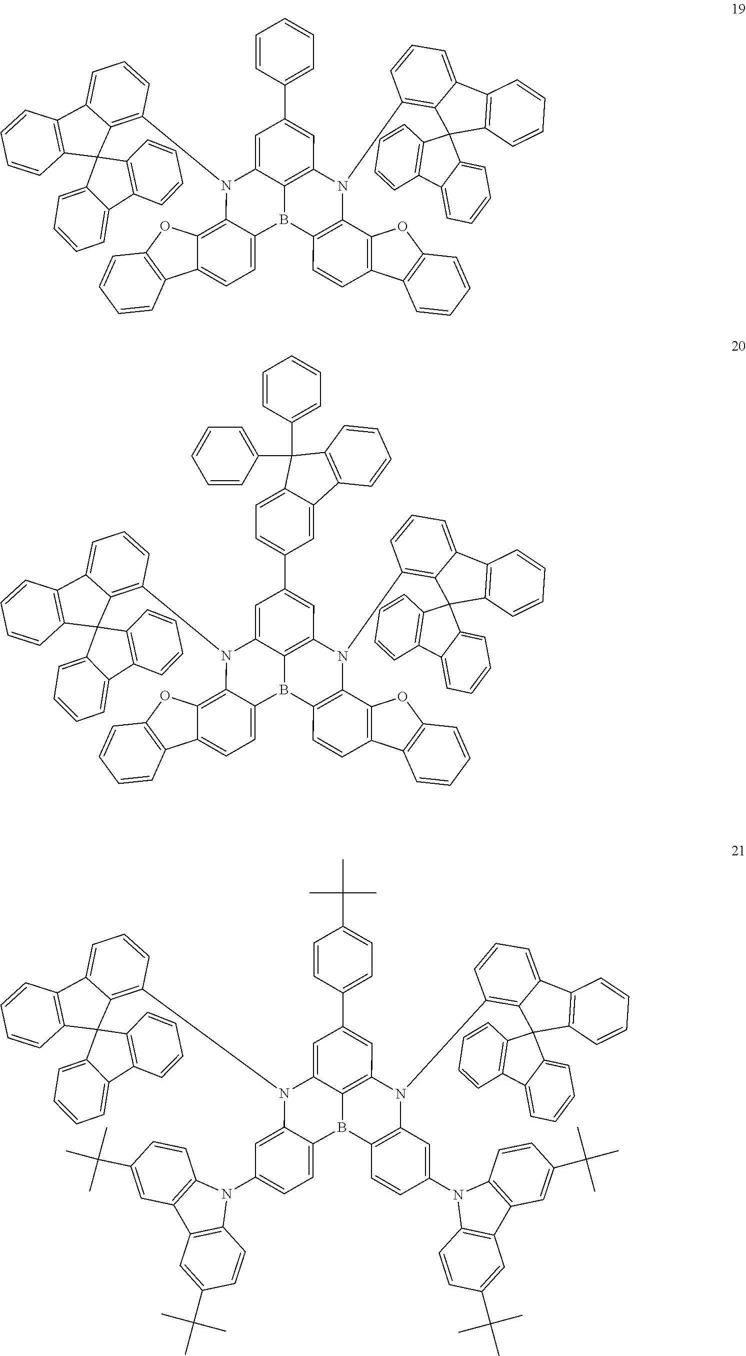

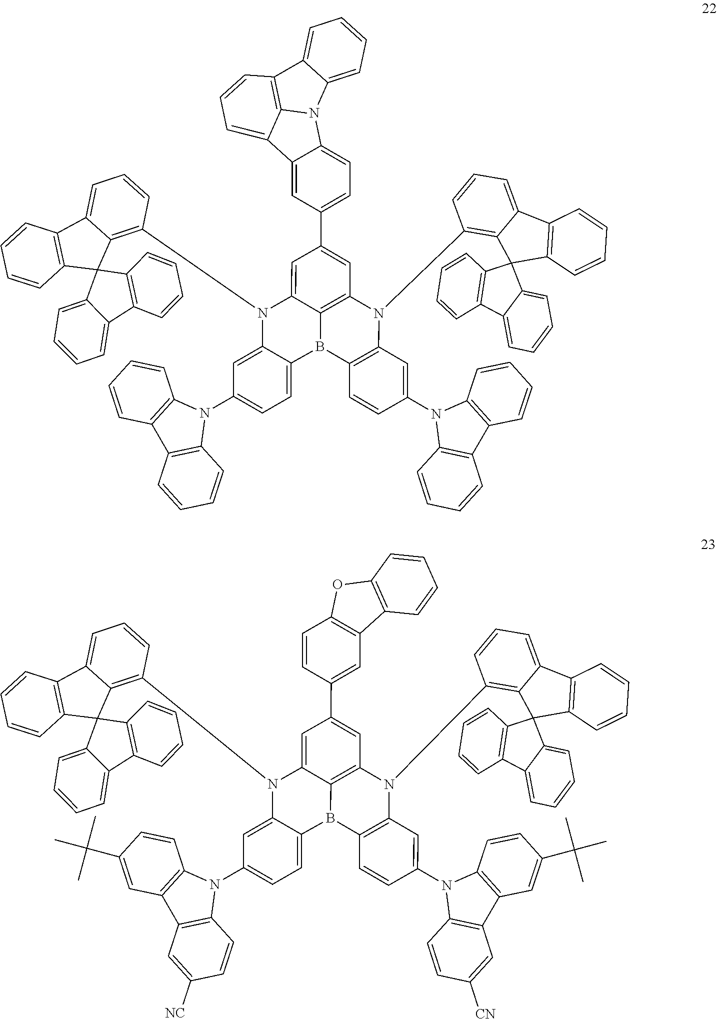 [SMILES: c1ccc2c(c1)-c1ccccc1C21c2ccccc2-c2cccc(N3c4cc(-n5c6ccccc6c6ccccc65)ccc4B4c5ccc(-n6c7ccccc7c7ccccc76)cc5N(c5cccc6c5C5(c7ccccc7-c7ccccc75)c5ccccc5-6)c5cc(-c6ccc7c(c6)c6cccc8c9ccccc9n7c86)cc3c54)c21 ; CC(C)(C)c1ccc2c(c1)c1cc(C#N)ccc1n2-c1ccc2c(c1)N(c1cccc3c1C1(c4ccccc4-c4ccccc41)c1ccccc1-3)c1cc(-c3ccc4oc5ccccc5c4c3)cc3c1B2c1ccc(-n2c4ccc(C#N)cc4c4cc(C(C)(C)C)ccc42)cc1N3c1cccc2c1C1(c3ccccc3-c3ccccc31)c1ccccc1-2]

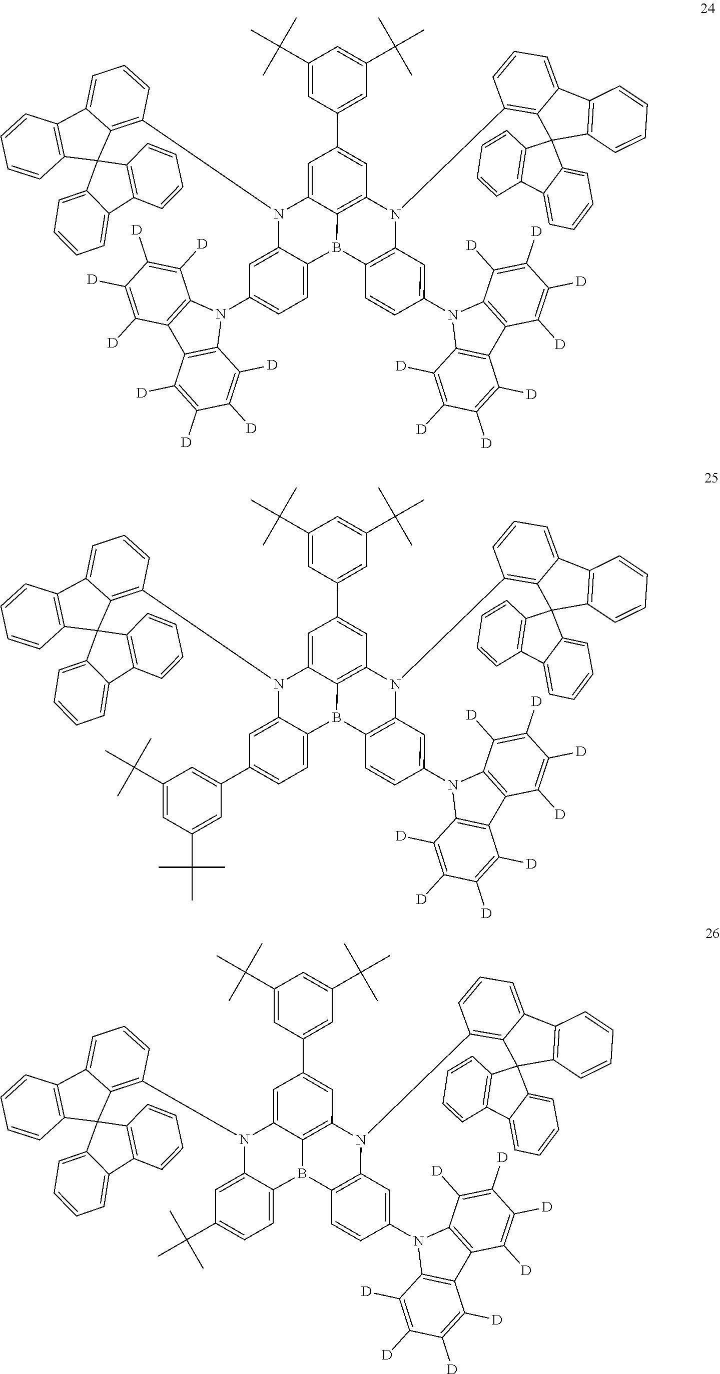

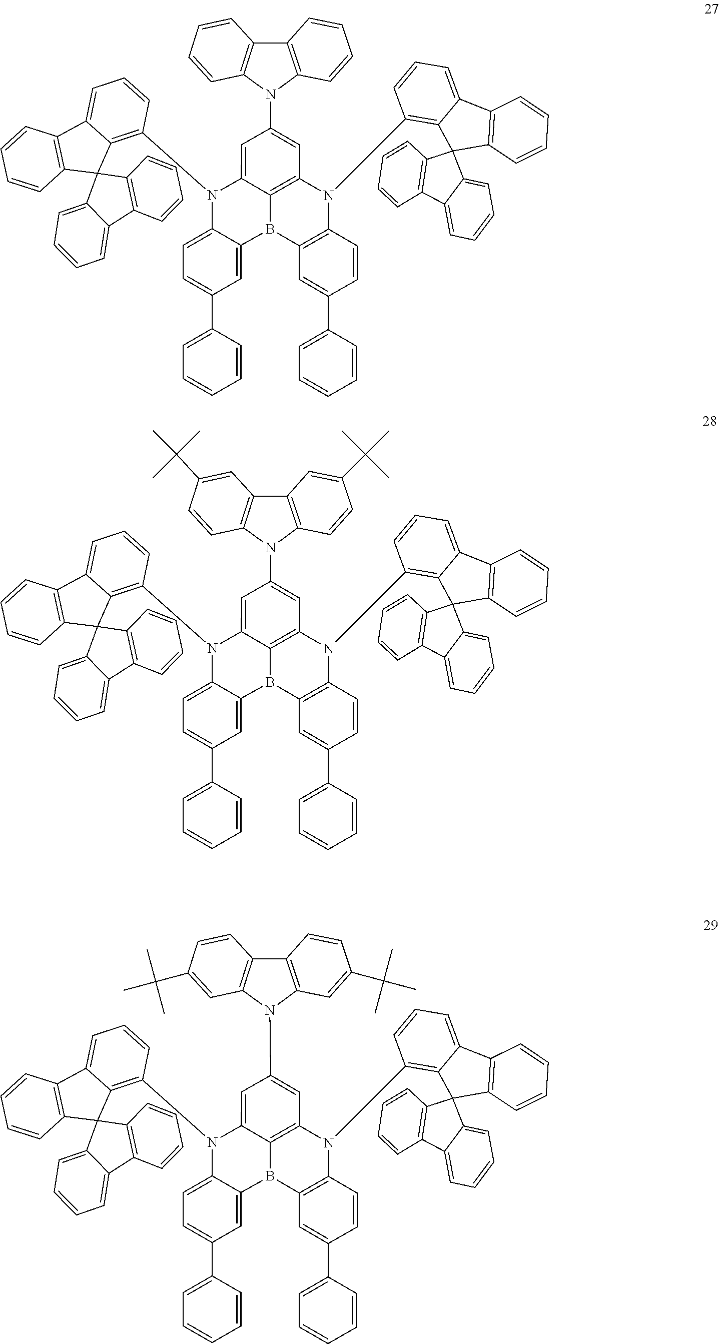

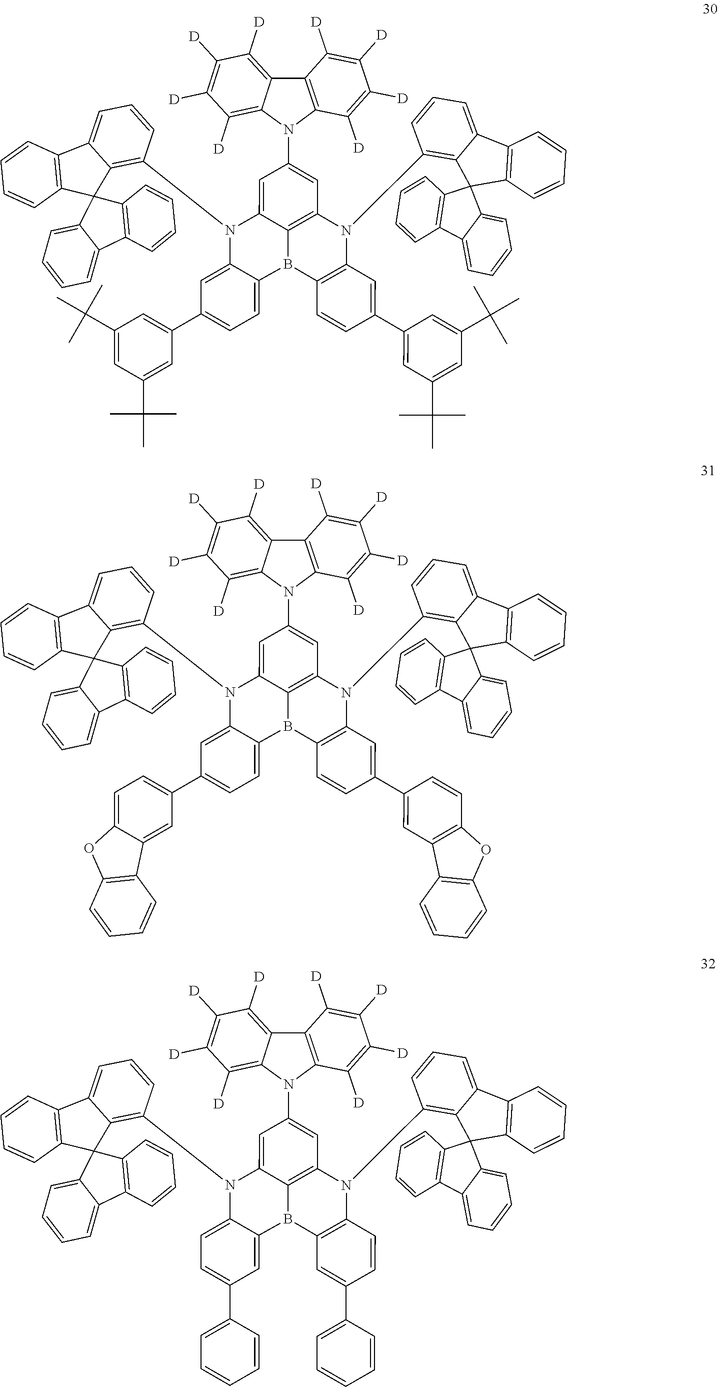

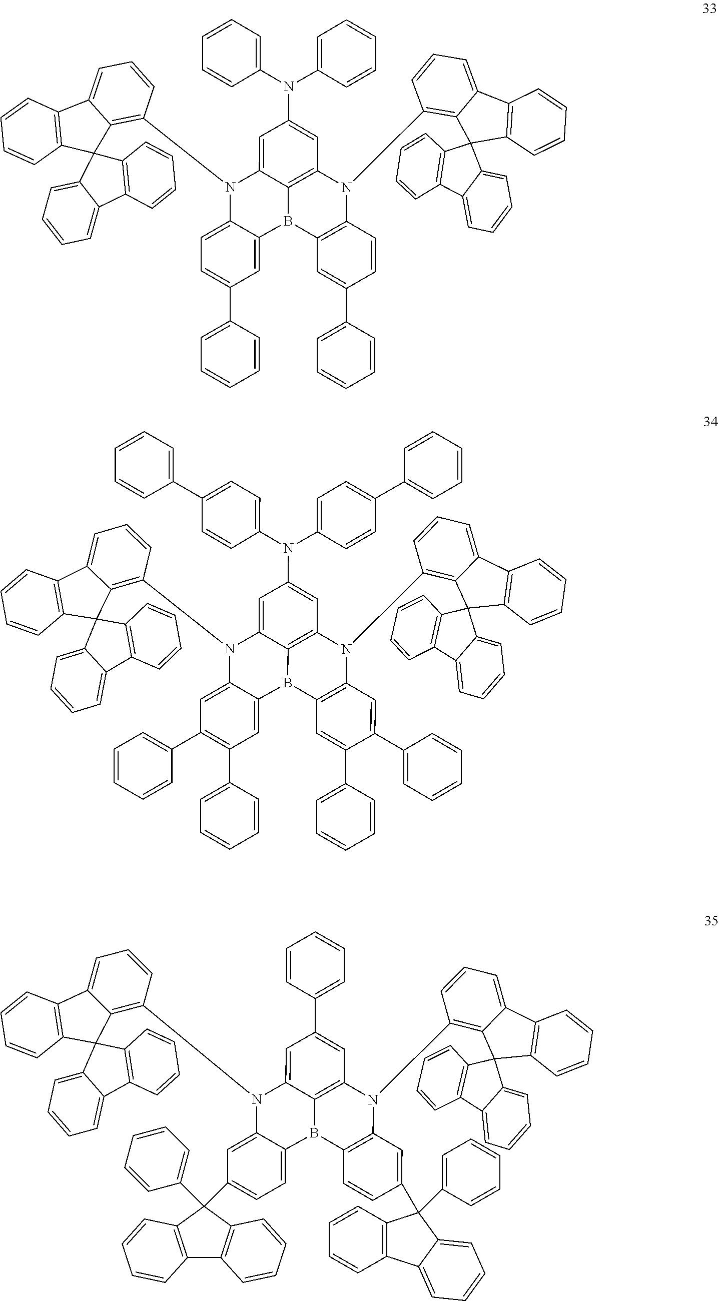

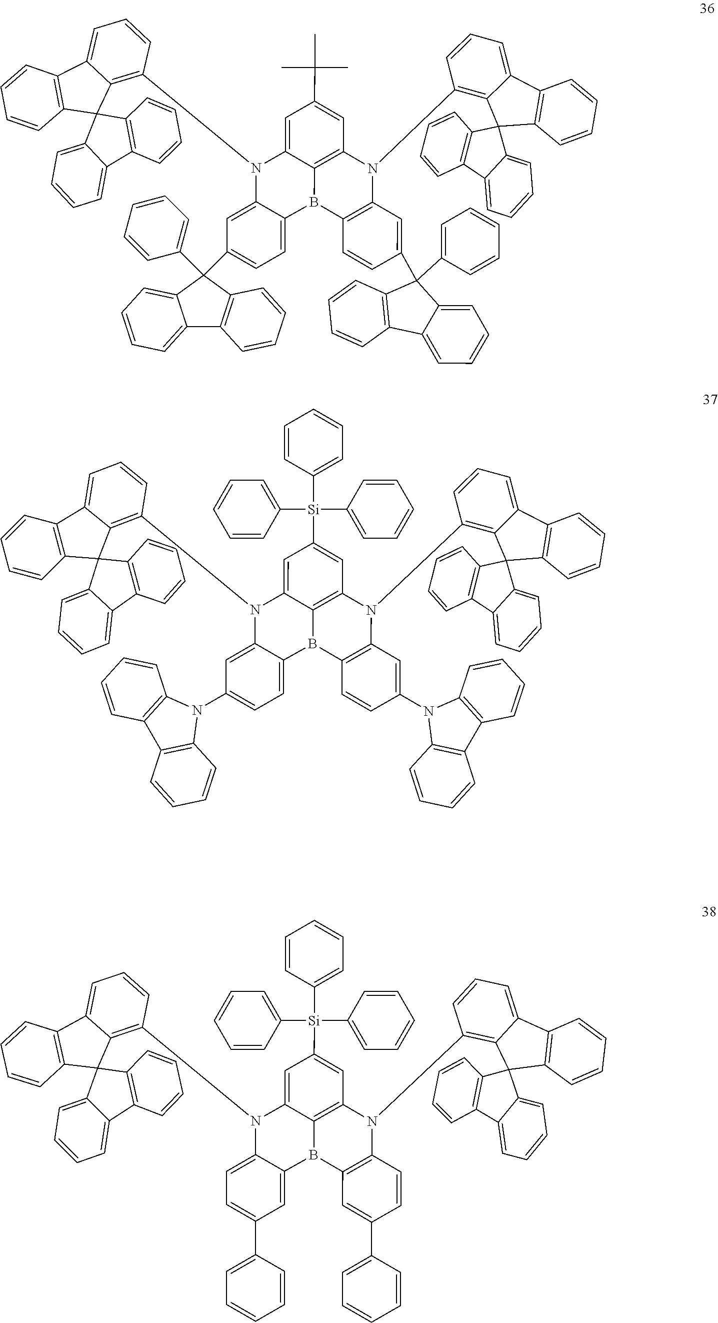

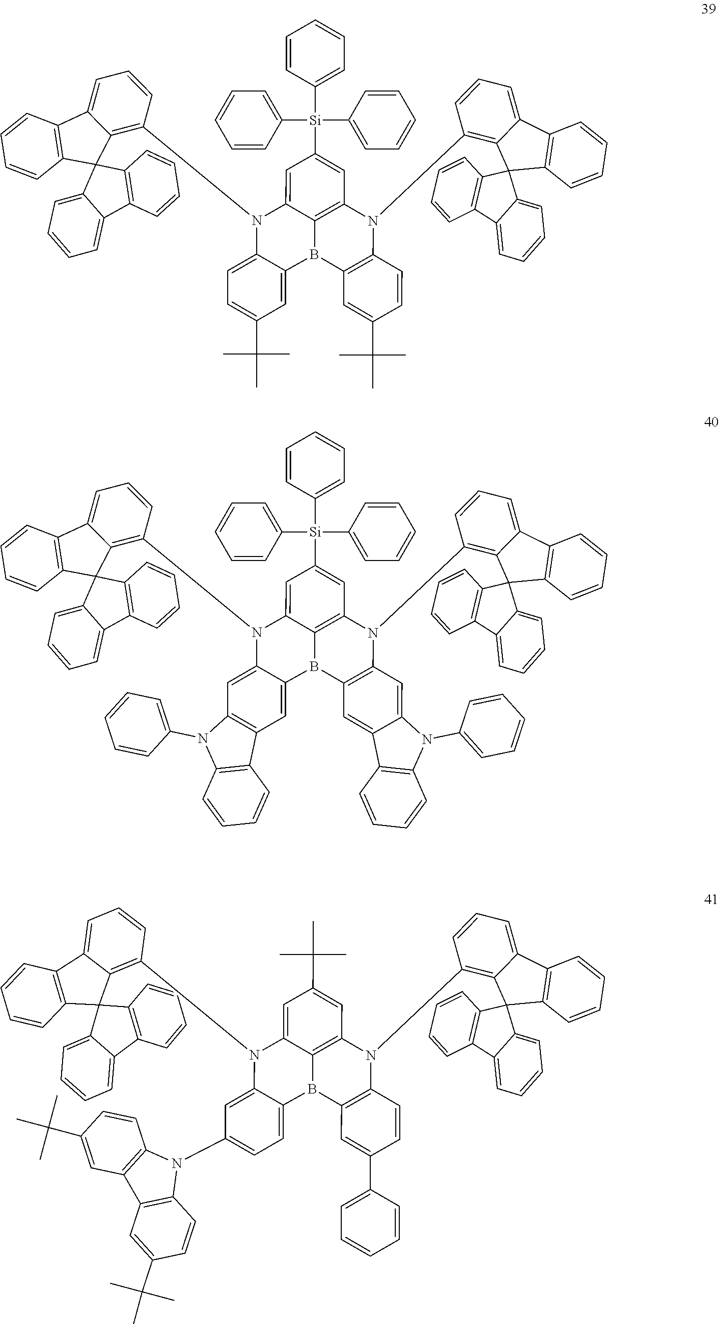

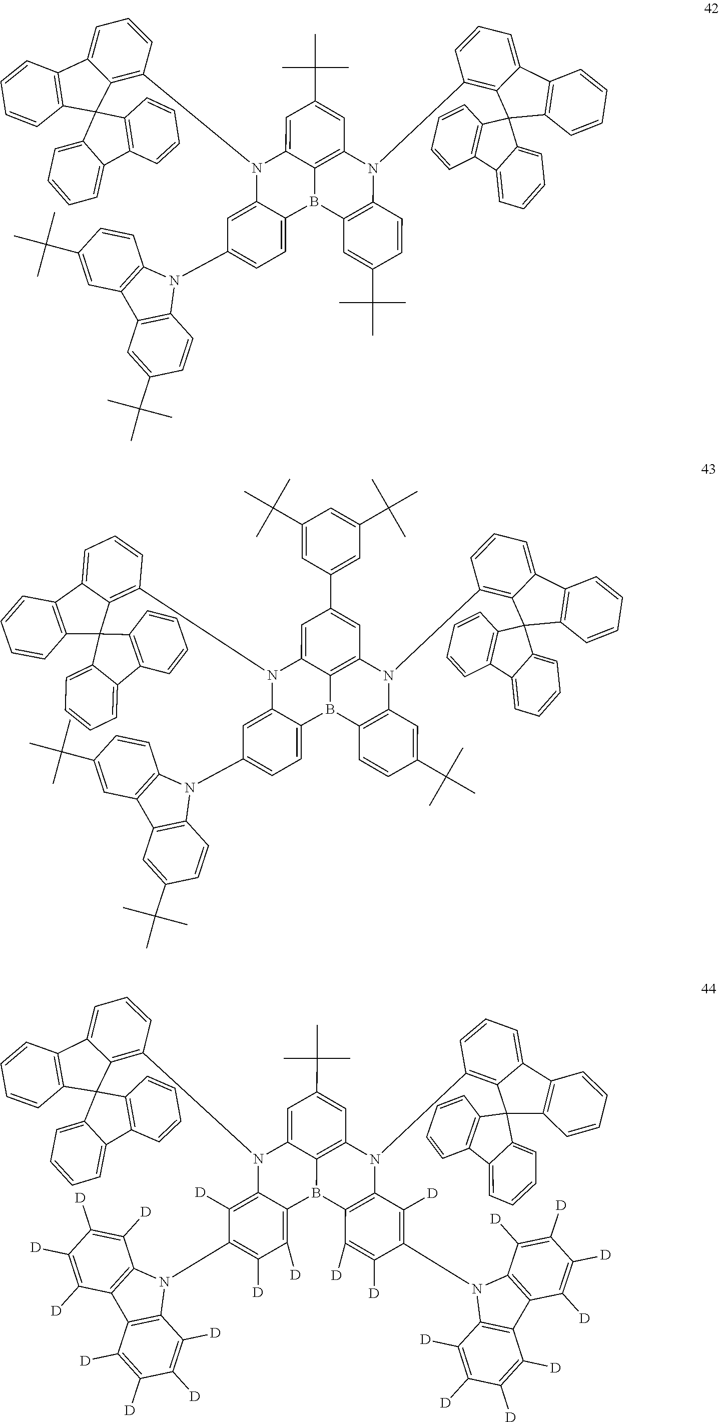

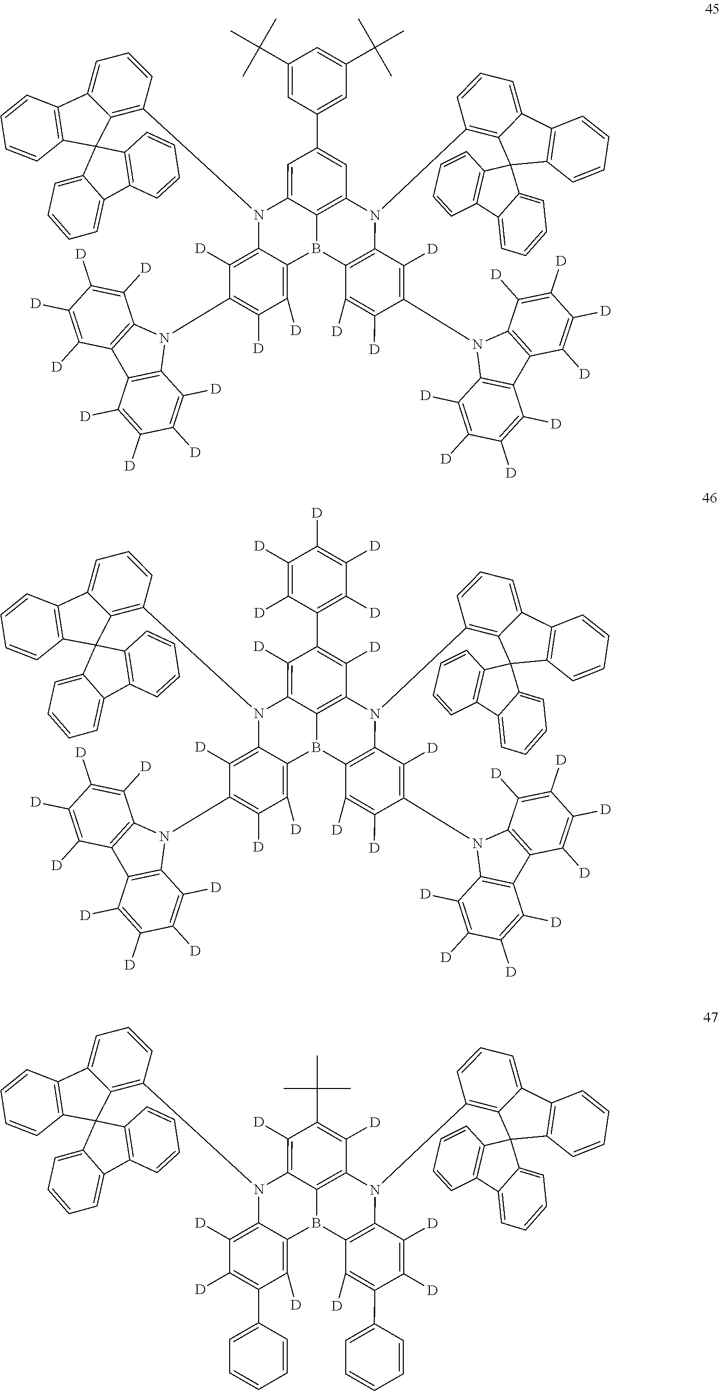

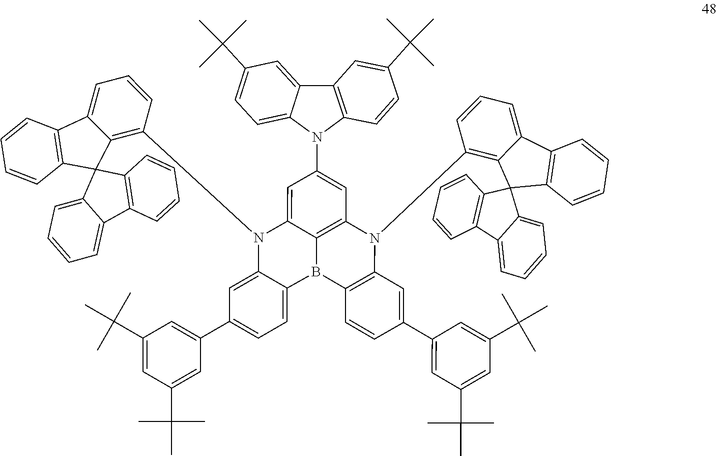 [SMILES: CC(C)(C)c1cc(-c2ccc3c(c2)N(c2cccc4c2C2(c5ccccc5-c5ccccc52)c2ccccc2-4)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2cccc3c2C2(c4ccccc4-c4ccccc42)c2ccccc2-3)cc(C(C)(C)C)c1]

In Compound Group 1, D represents a deuterium atom.

The polycyclic compound according to an embodiment includes a fused ring core moiety that includes a boron atom and two nitrogen atoms as ring-forming atoms and a spiro-bifluorene substituent bonded to each of the nitrogen atoms of the core moiety, thus having a reduced structural degree of freedom between bonds in the molecule, and thereby exhibiting high stability. With the inclusion of the spiro-bifluorene substituents bonded to the nitrogen atoms of the core moiety, the polycyclic compound according to an embodiment may prevent the deterioration of optical characteristics such as the difference between excited light and fluorescence peak wavelength (Stokes shift), and a full width of half maximum (FWHM), and may protect the p-orbital of the boron atom of the core moiety, and thus may further facilitate multiple resonance effects. Therefore, the polycyclic compound according to an embodiment may be used as a material for a light emitting element, thereby contributing to improvement in luminous efficiency and service life characteristics of the light emitting element.

The polycyclic compound represented by Formula 1 according to an embodiment may be a luminescent material for an emission layer EML, and when an emission layer EML includes the polycyclic compound according to embodiments, it may emit light having a central wavelength in a range of about 430 nm to about 490 nm. For example, the polycyclic compound represented by Formula 1 according to an embodiment may be a blue thermally activated delayed fluorescence (TADF) dopant. For example, in the light emitting element ED according to an embodiment, the emission layer EML may include, as a thermally activated delayed fluorescence dopant, at least one polycyclic compound selected from Compound Group 1 as described herein. However, embodiments are not limited thereto, and when the polycyclic compound according to an embodiment is used as a luminescent material, the polycyclic compound may be used as a dopant material emitting light in various wavelength regions, such as a red emitting dopant or a green emitting dopant.

The emission layer EML in the light emitting element ED according to an embodiment may emit delayed fluorescence. For example, the emission layer EML may emit thermally activated delayed fluorescence (TADF).

The emission layer EML of the light emitting element ED may emit blue light. For example, the emission layer EML of the light emitting element ED according to an embodiment may emit blue light having a wavelength equal to or less than about 490 nm. However, embodiments are not limited thereto, and the emission layer EML may emit green light or red light.

The emission layer EML in the light emitting element ED according to an embodiment may include a host. The host may transfer energy to a dopant without emitting light in the light emitting element ED. The emission layer EML may include at least one kind of host. For example, the emission layer EML may include two kinds of different hosts. When the emission layer EML includes two kinds of hosts, the two kinds of hosts may include a hole transporting host and an electron transporting host. However, embodiments are not limited thereto, and the emission layer EML may include one kind of host, or a mixture of two kinds of different hosts.

In an embodiment, the emission layer EML may include two different hosts. The host may include a second compound, and a third compound that is different from the second compound. The host may include the second compound having a hole transporting moiety and the third compound having an electron transporting moiety. In the light emitting element ED according to an embodiment, for the host, the second compound and the third compound may form an exciplex. For example, a triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, an absolute value of the triplet energy (T1) of the exciplex formed by the hole transporting host and the electron transporting host may be in a range of about 2.4 eV to about 3.0 eV. The triplet energy of the exciplex may have a value that is smaller than an energy gap of each host material. The exciplex may have a triplet energy equal to or less than about 3.0 eV that is an energy gap between the hole transporting host and the electron transporting host.

In an embodiment, the emission layer EML may include the first compound represented by Formula 1, and at least one of a second compound represented by Formula HT-1, a third compound represented by Formula ET-1, or a fourth compound represented by Formula M-b:

For example, the second compound according to an embodiment may be used as a hole transport host material of the emission layer EML.

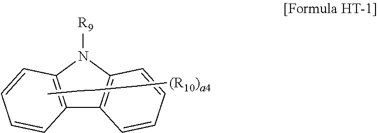

In Formula HT-1, a4 may be an integer from 0 to 8. When a4 is 2 or more, multiple R₁₀ groups may be the same as each other or at least one thereof may be different from the others. In Formula HT-1, R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, R₉ may be a substituted phenyl group, an unsubstituted dibenzofuran group, or a substituted fluorenyl group. For example, R₁₀ may be a substituted or unsubstituted carbazole group.

The second compound may be any compound selected from Compound Group 2. The light emitting element ED according to an embodiment may include any compound selected from Compound Group 2. In Compound Group 2, D represents a deuterium atom, and Ph represents a phenyl group:

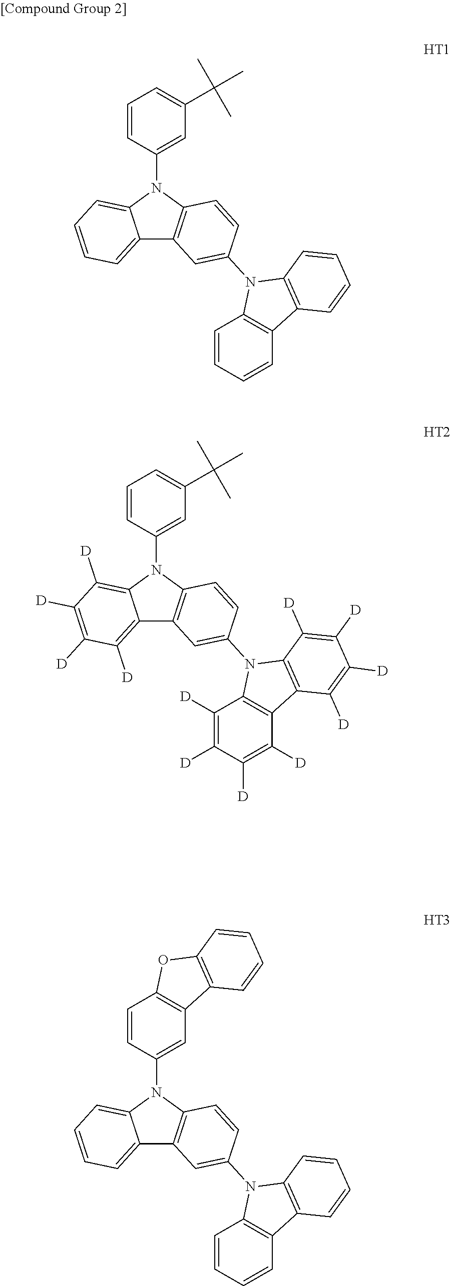 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

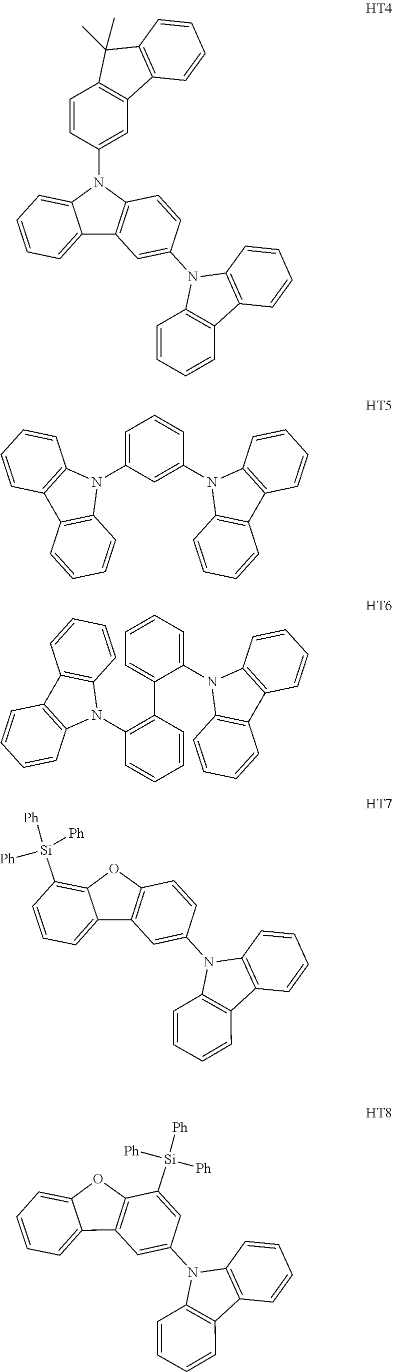

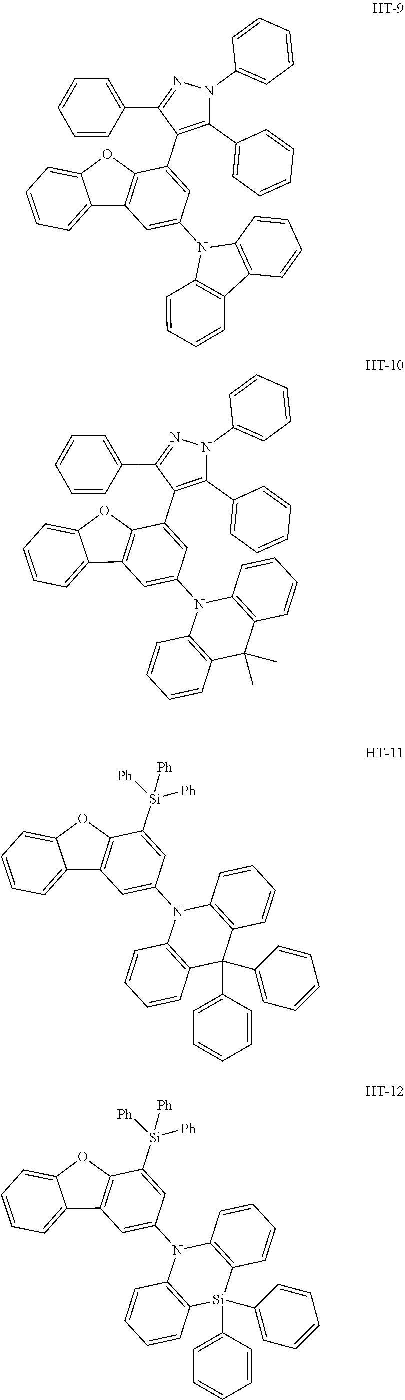 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

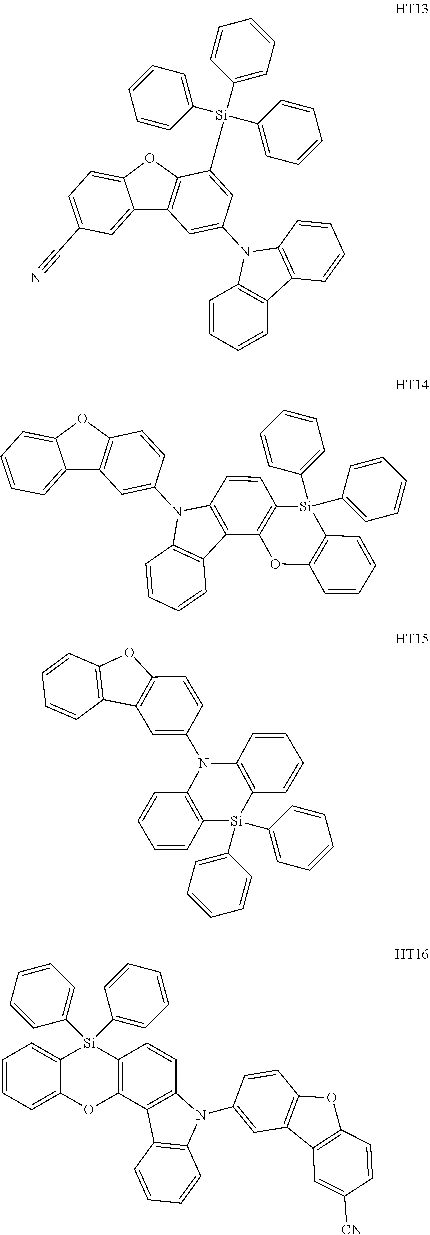 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

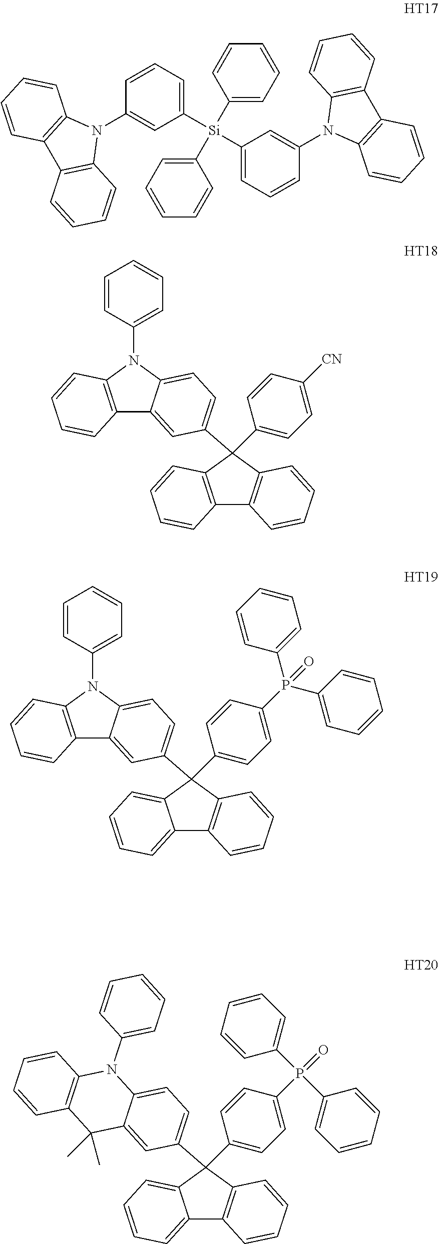 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

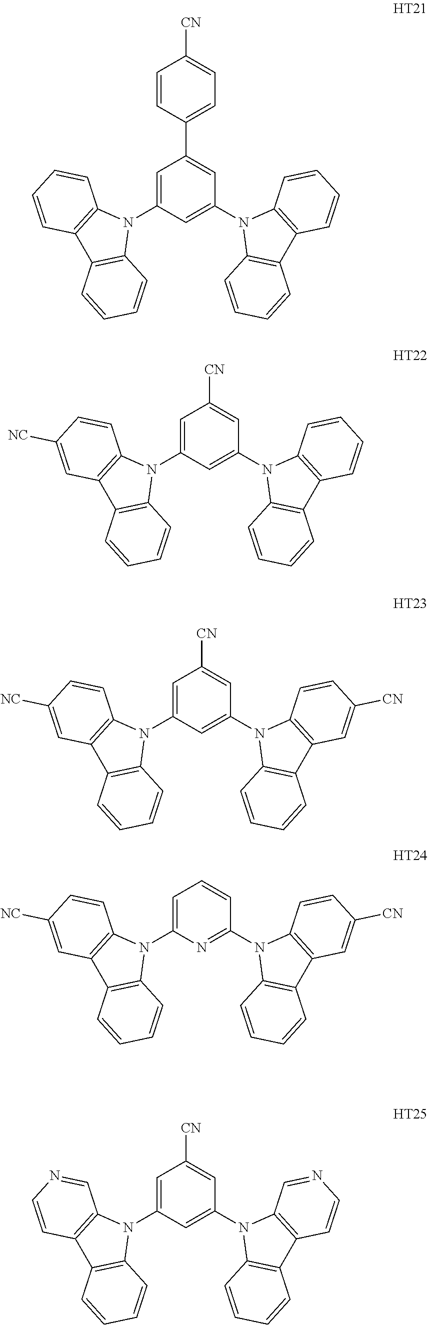 [SMILES: N#Cc1ccc(-c2cc(-n3c4ccccc4c4ccccc43)cc(-n3c4ccccc4c4ccccc43)c2)cc1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

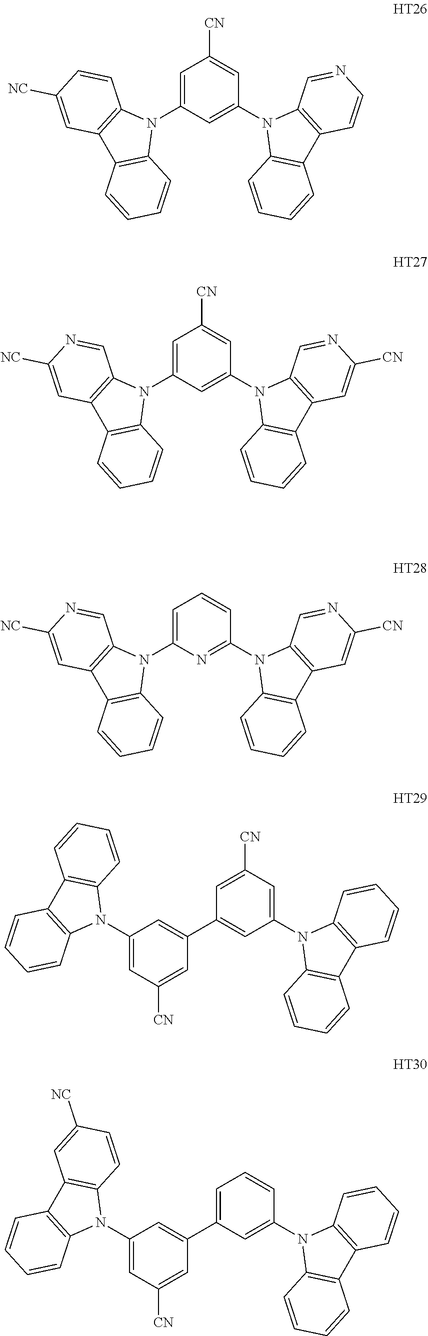 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

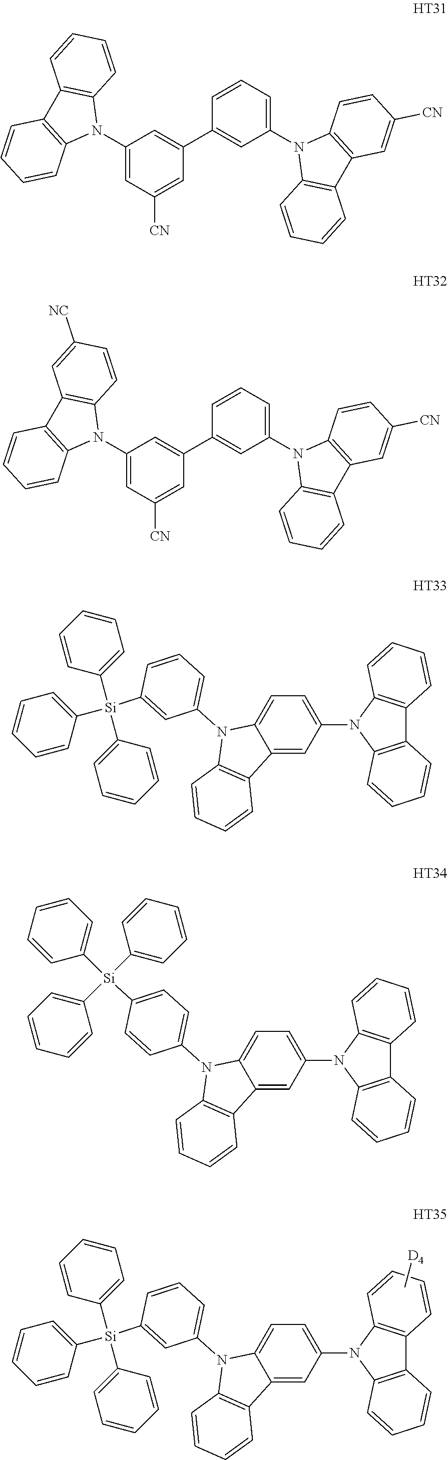

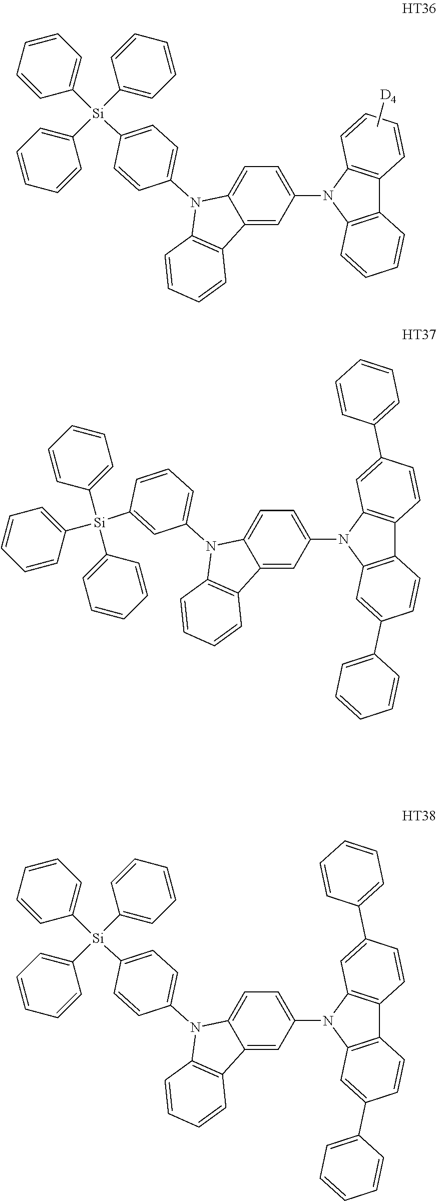

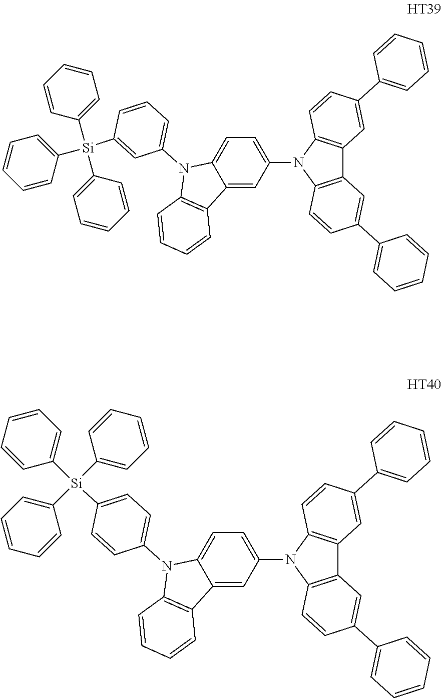 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

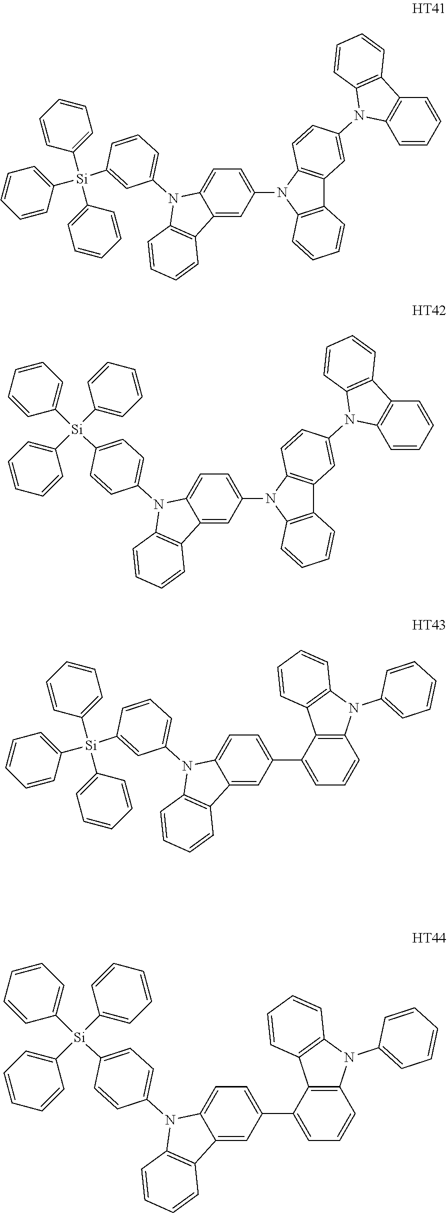 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

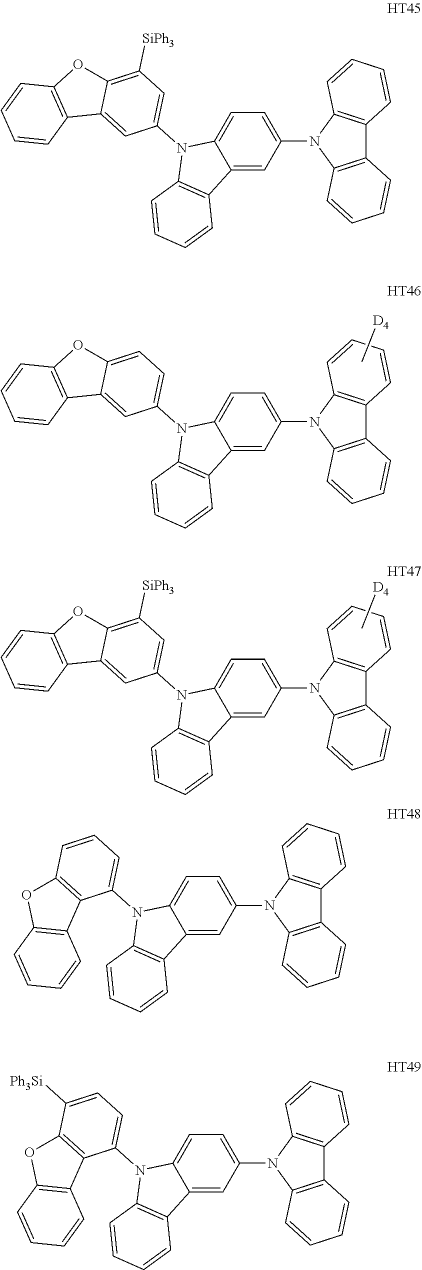

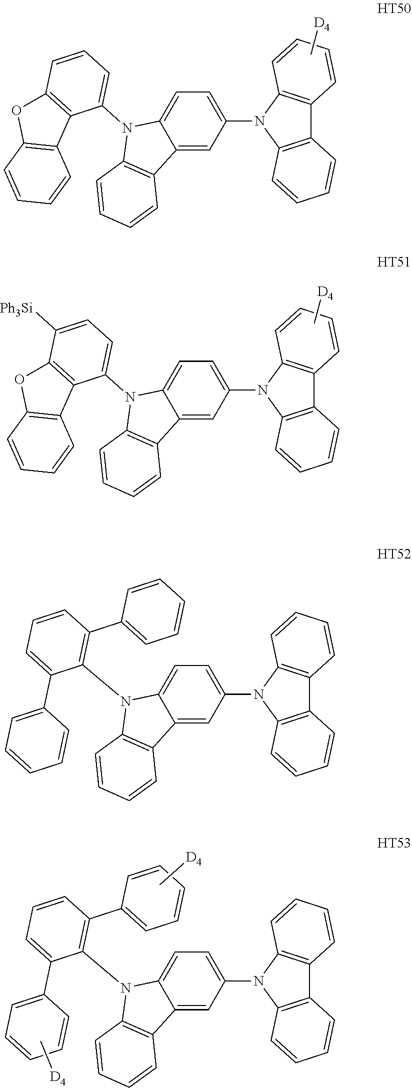

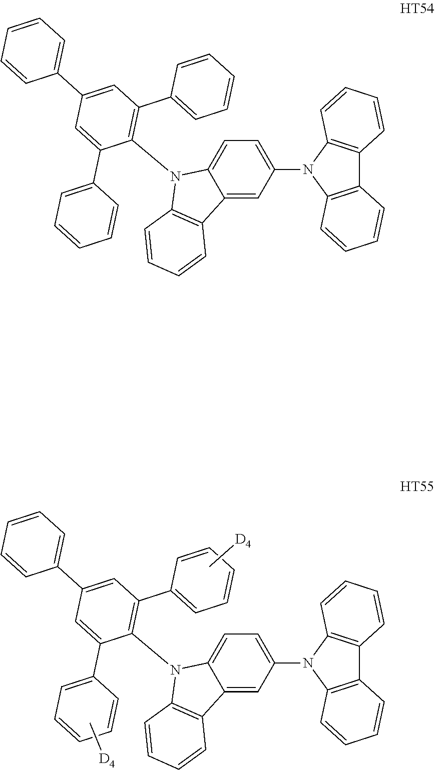

In an embodiment, the emission layer EML may include a third compound represented by Formula ET-1. For example, the third compound may be used as an electron transport host material of the emission layer EML.

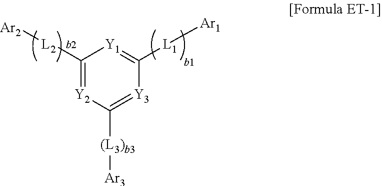

In Formula ET-1, at least one of Y₁ to Y₃ may each be N; the remainder of Y₁ to Y₃ may each independently be C(Rₐ); and Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10; and L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group, or a substituted or unsubstituted carbazole group.

The third compound may be any compound selected from Compound Group 3. The light emitting element ED according to an embodiment may include any compound selected from Compound Group 3: In Compound Group 3, D represents a deuterium atom.

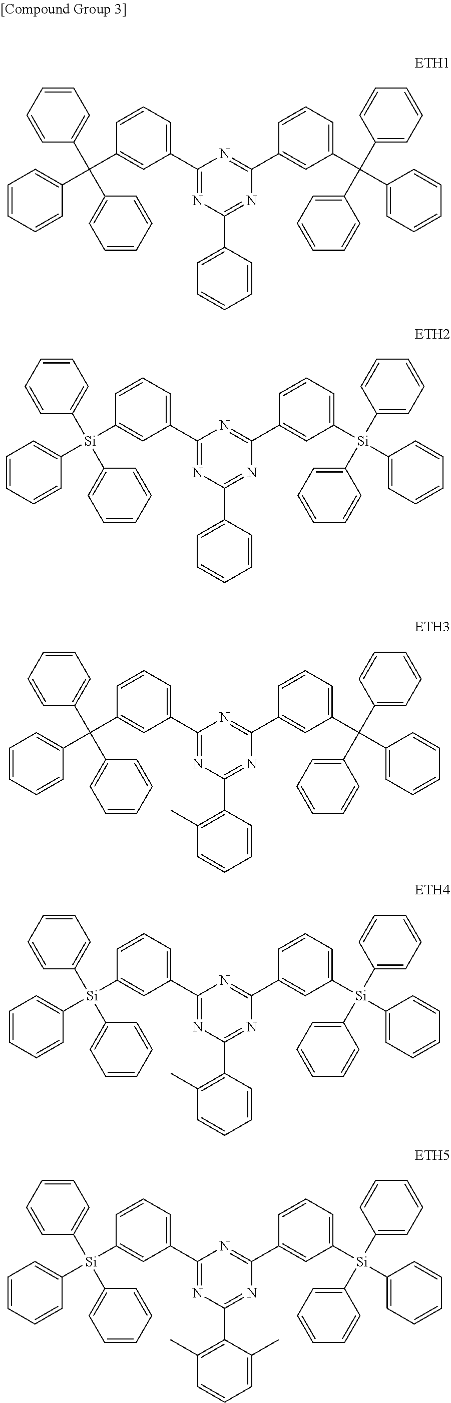

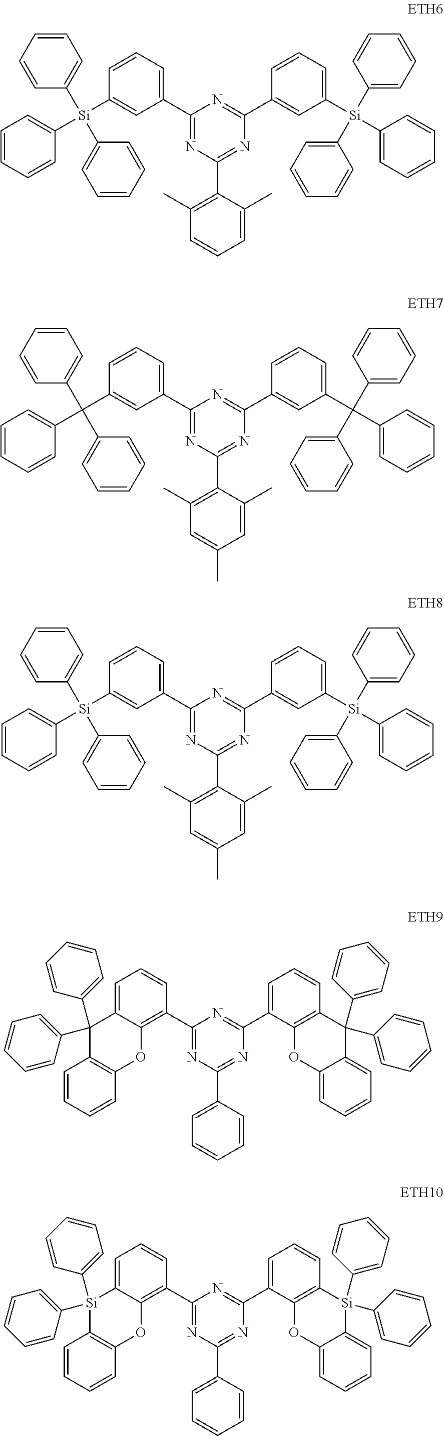

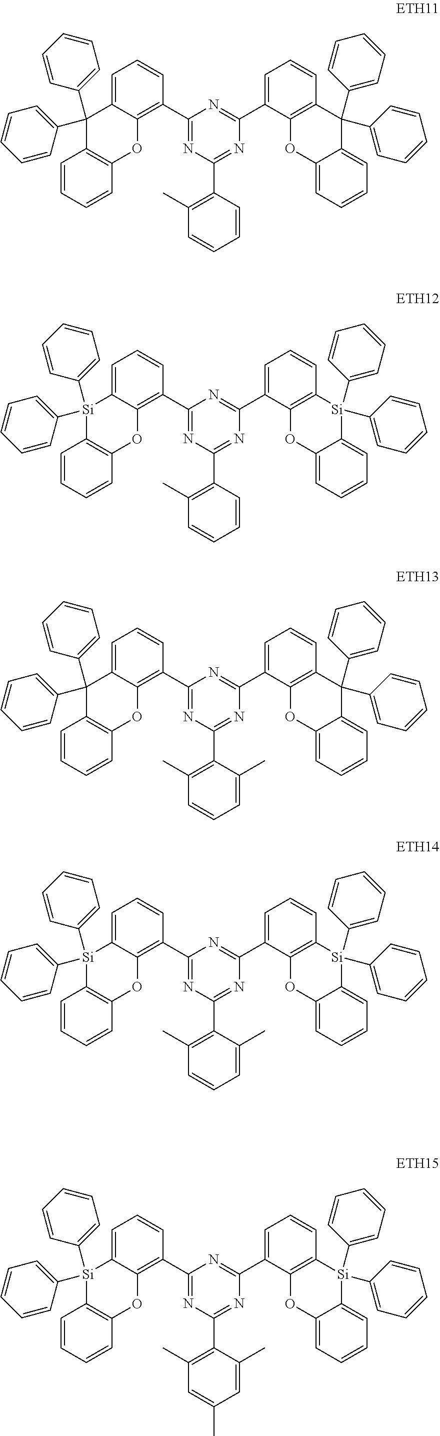

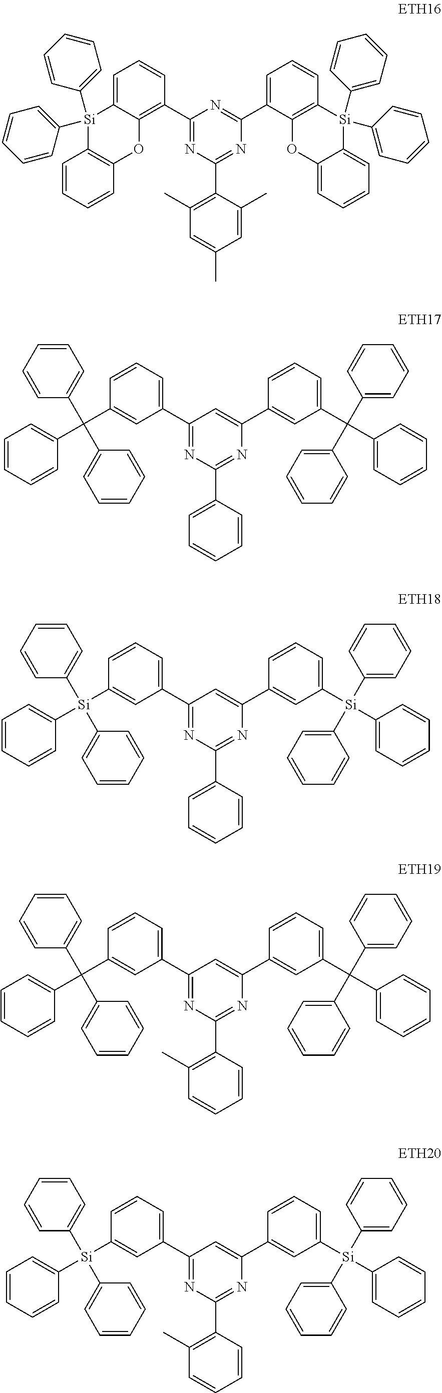

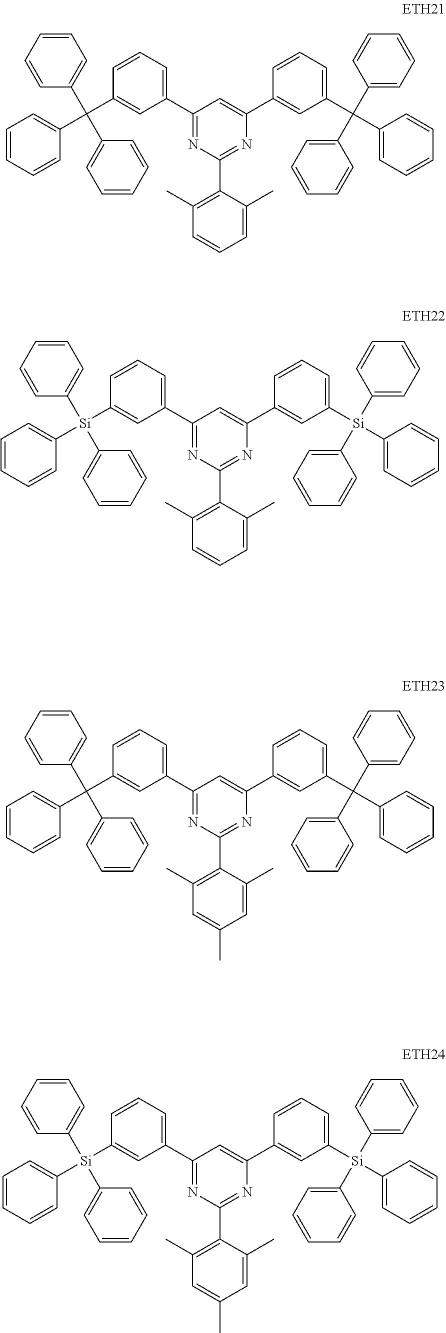 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

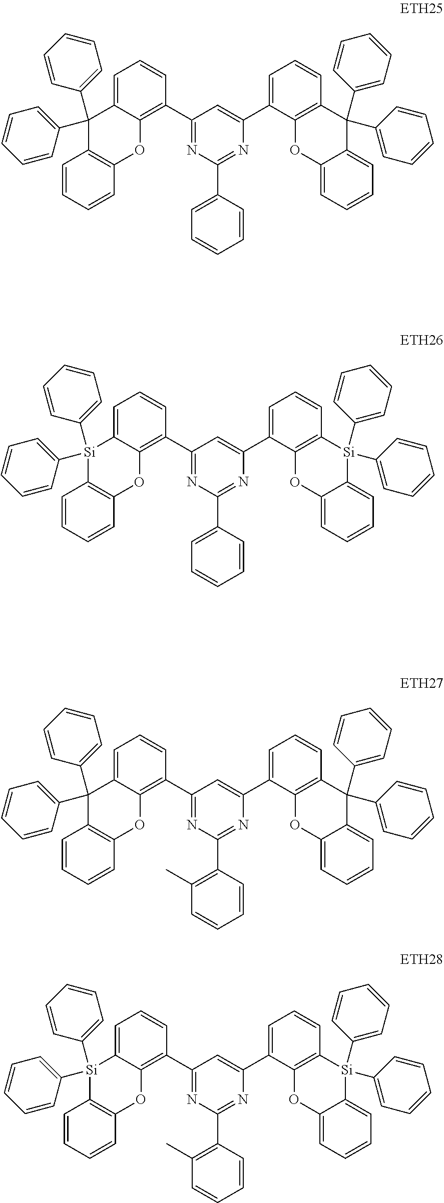 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

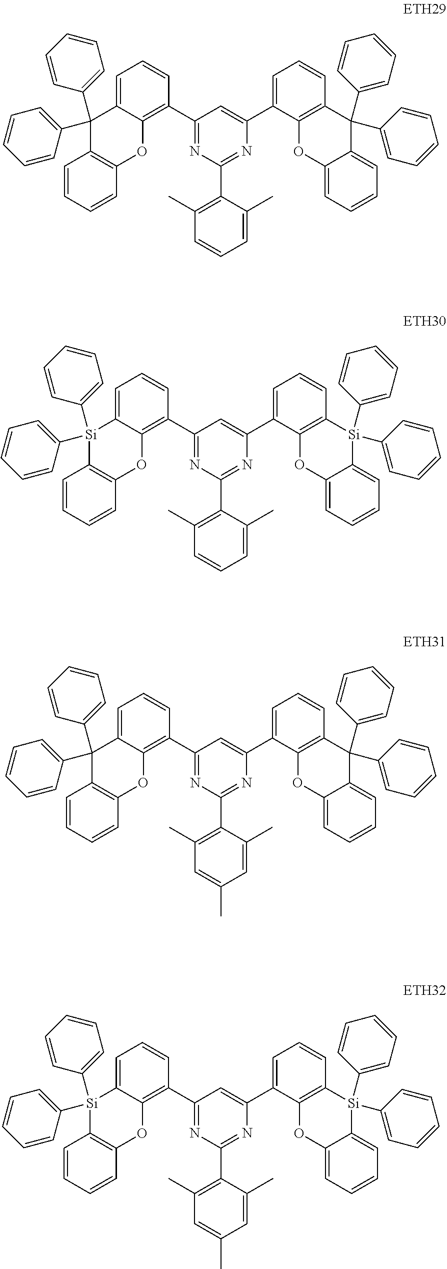 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

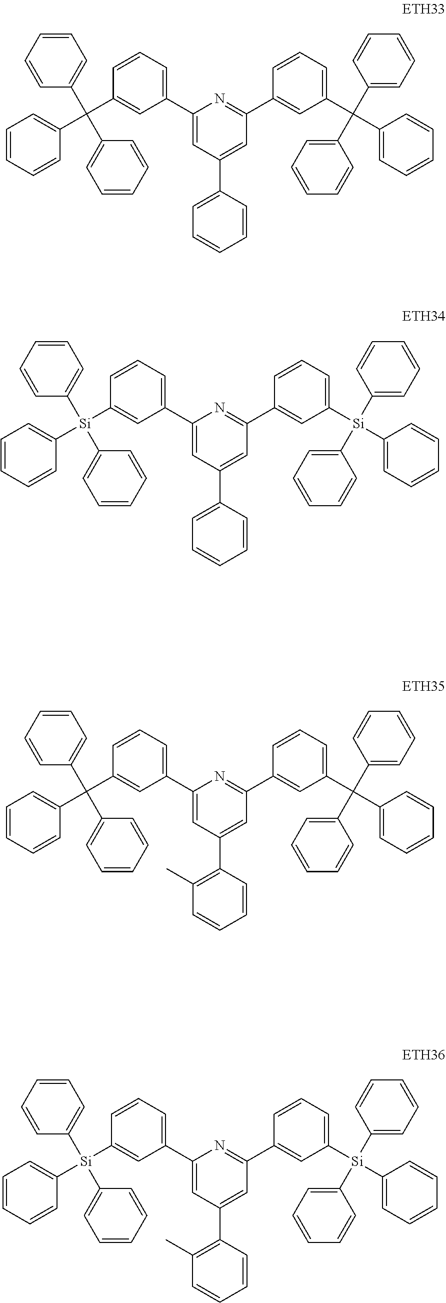 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

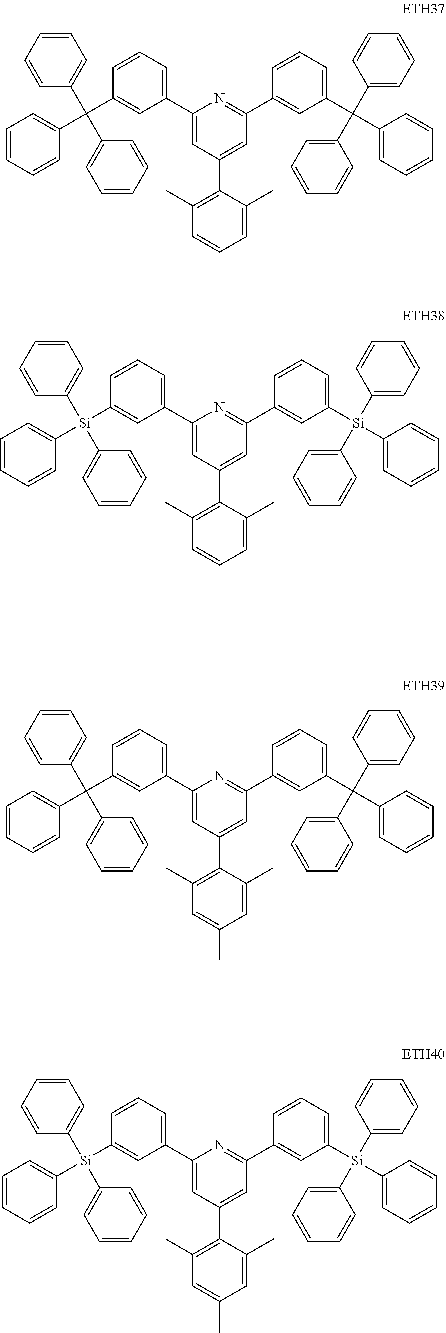 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

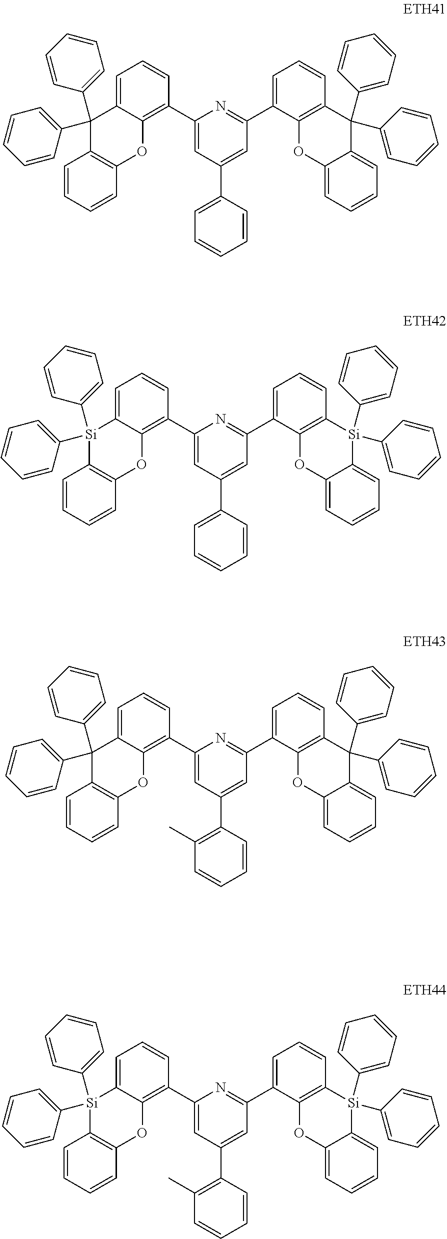 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

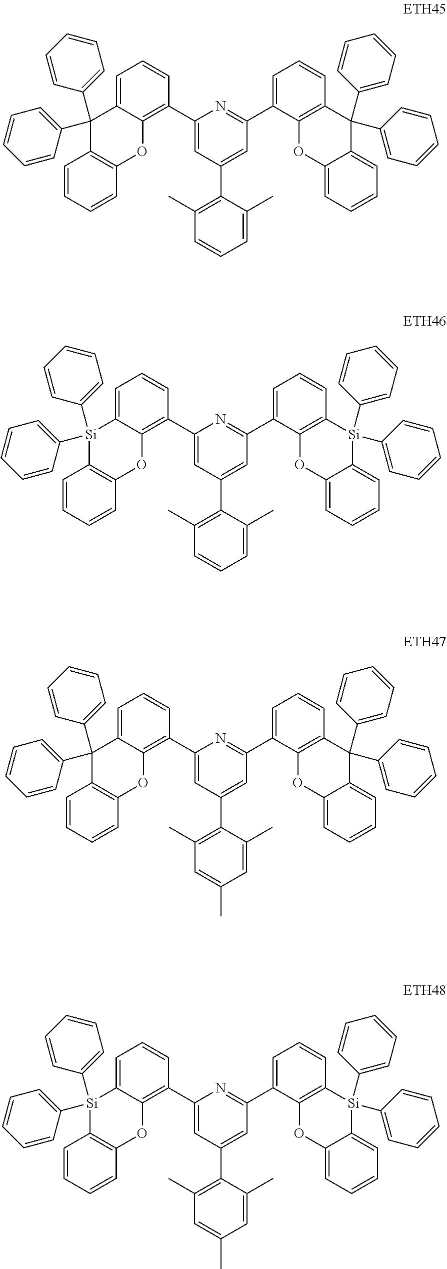 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

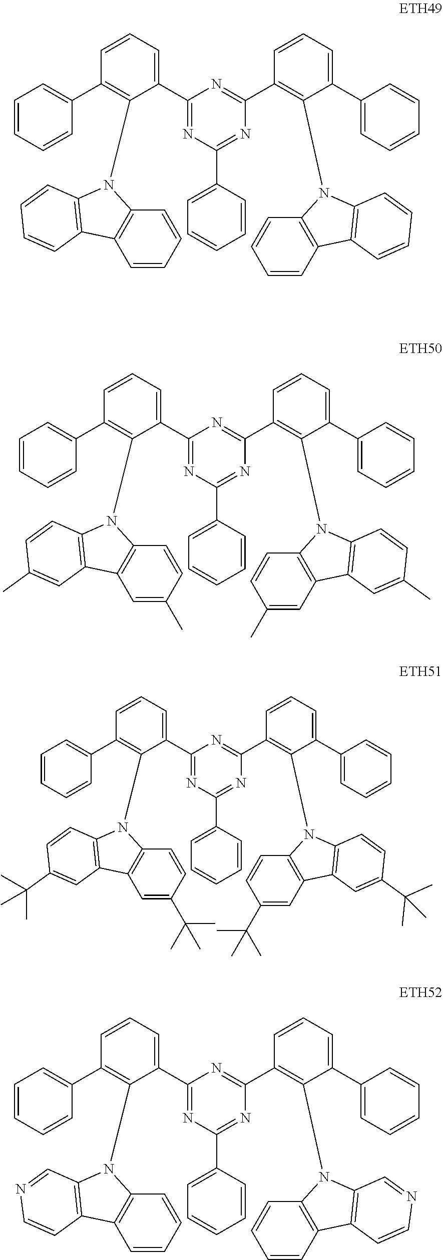

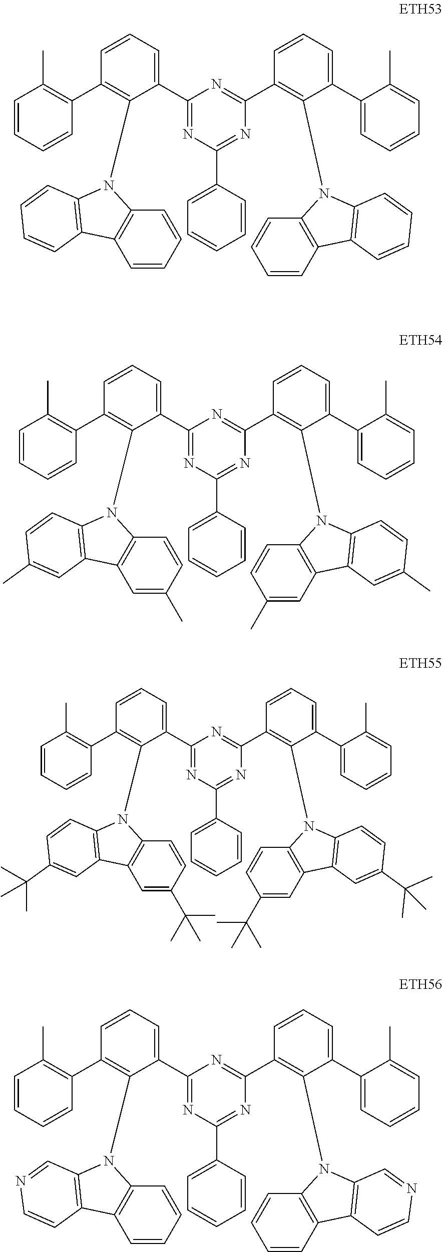

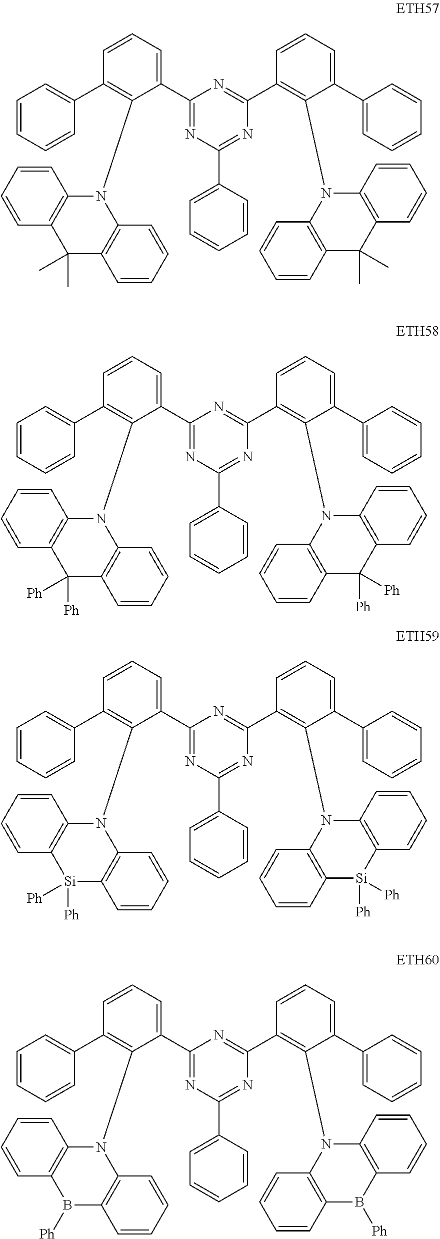

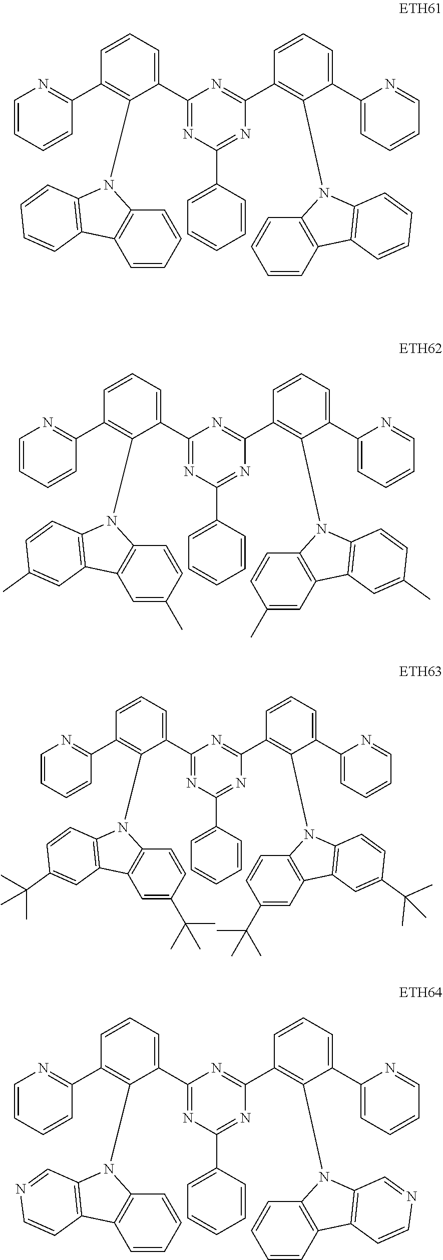

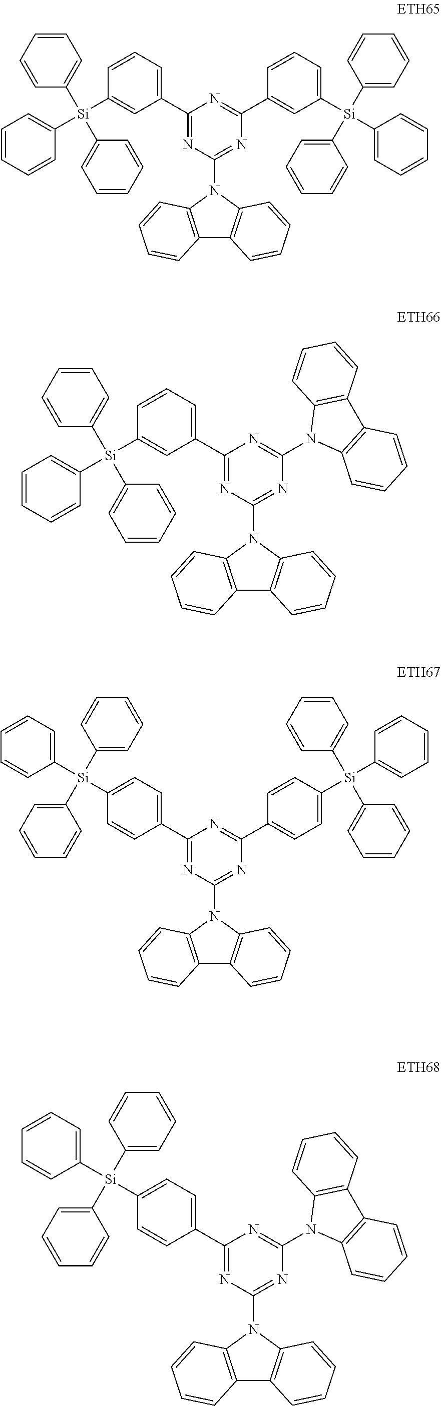 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

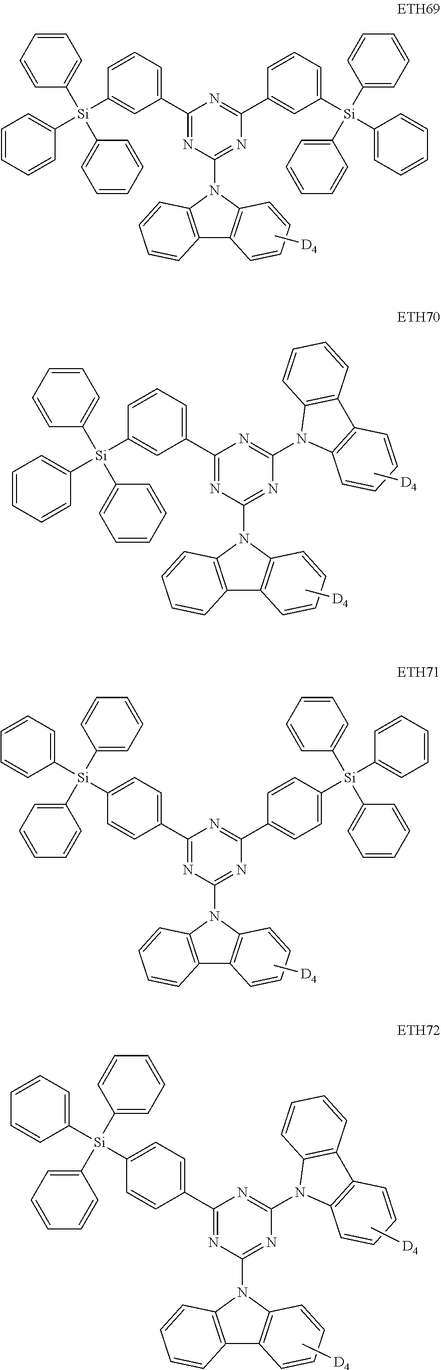

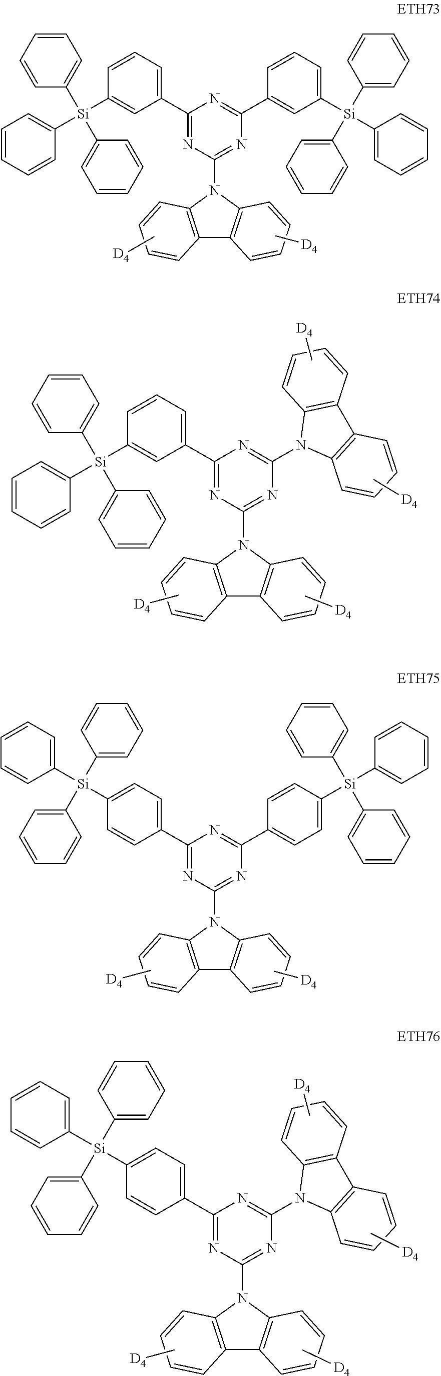

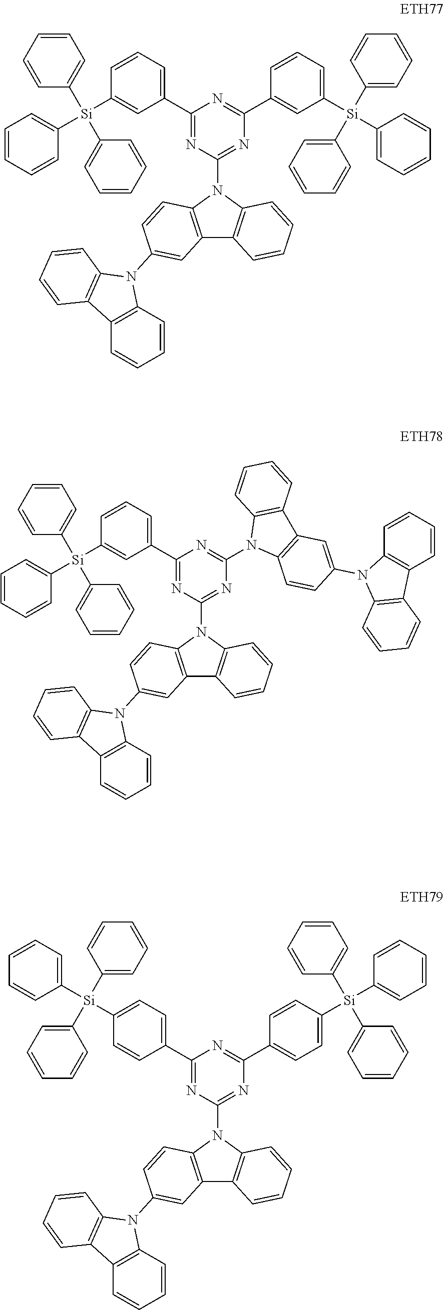 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

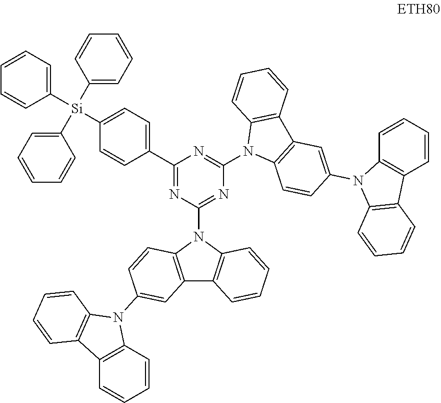 [SMILES: c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

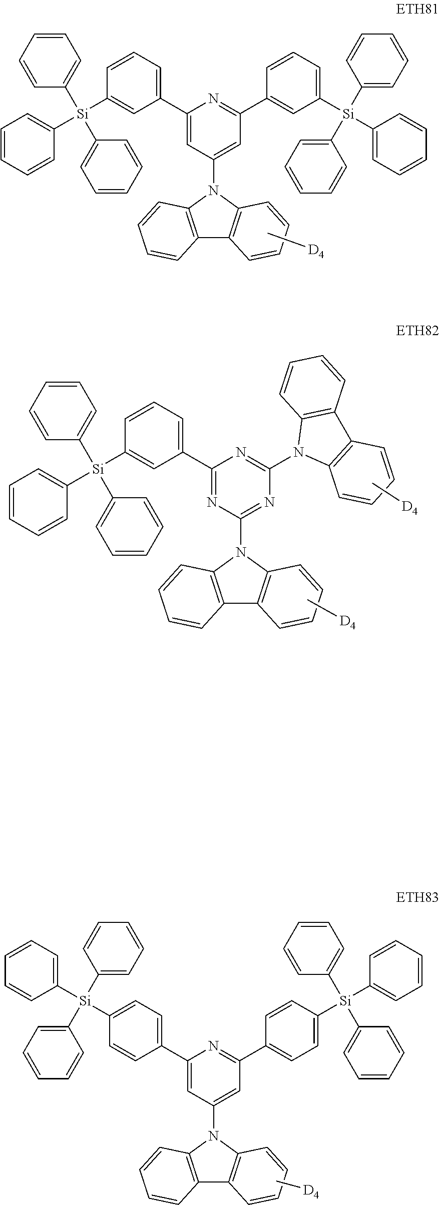

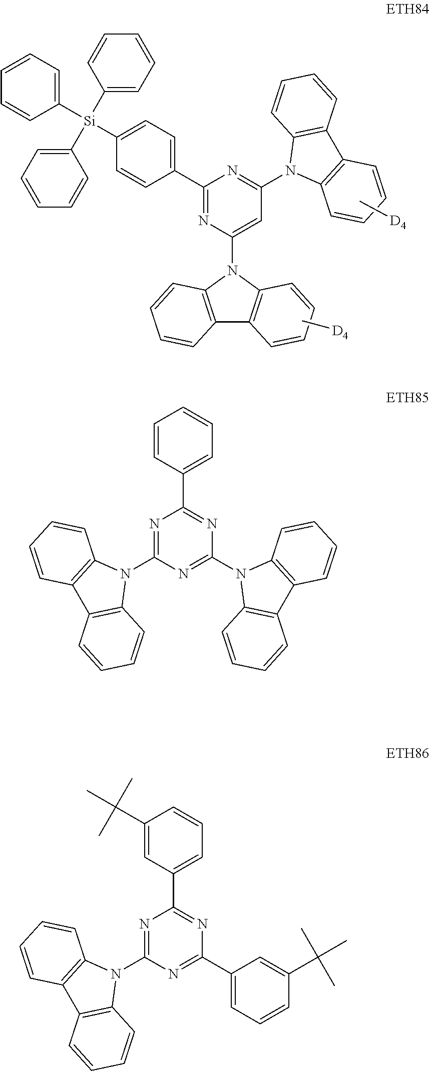

In an embodiment, the emission layer EML may include a fourth compound represented by Formula M-b. For example, the fourth compound may be used as a phosphorescent sensitizer in the emission layer EML. In the emission layer EML, energy may be transferred from the fourth compound to the first compound, thereby emitting light.

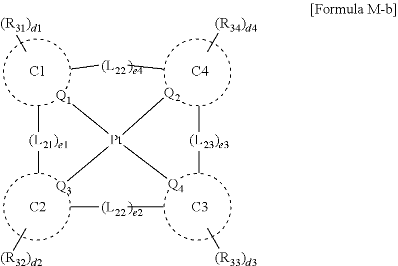

In Formula M-b, Q₁ to Q₄ may each independently be C or N; and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

In Formula M-b, e1 to e4 may each independently be 0 or 1; and L₂₁ to L₂₄ may each independently be a direct linkage,

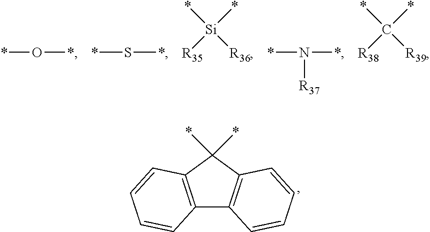

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula M-b, d1 to d4 may each independently be an integer from 0 to 4. When d1 is 2 or more, multiple R₃₁ groups may be the same as each other or at least one may be different from the others. When d2 is 2 or more, multiple R₃₂ groups may be the same as each other or at least one may be different from the others. When d3 is 2 or more, multiple R₃₃ groups may be the same as each other or at least one may be different from the others. When d4 is 2 or more, multiple R₃₄ groups may be the same as each other or at least one may be different from the others.

In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

The fourth compound may be any compound selected from Compound Group 4. The light emitting element ED according to an embodiment may include any compound selected from Compound Group 4:

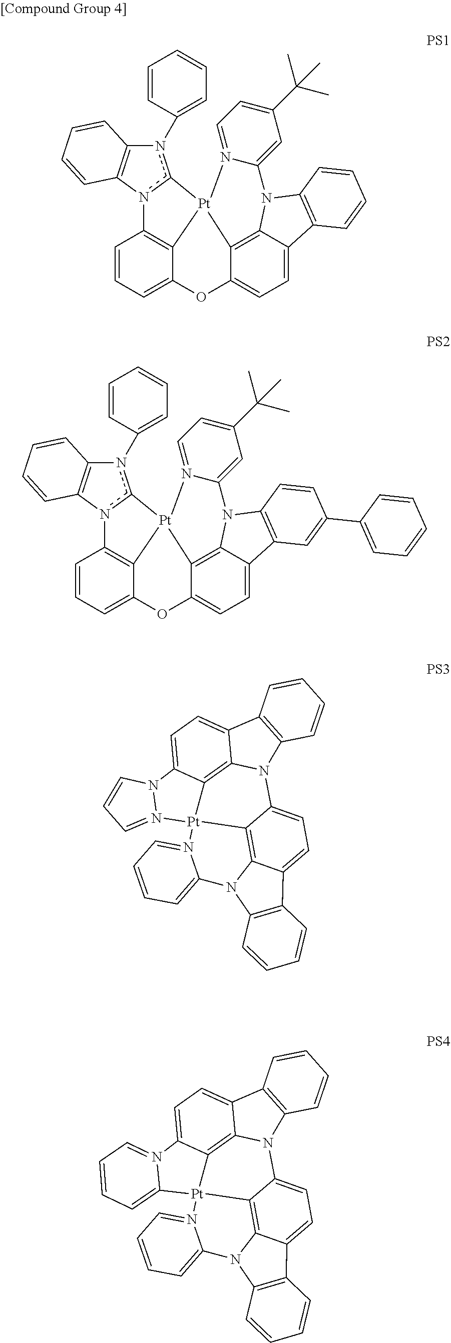

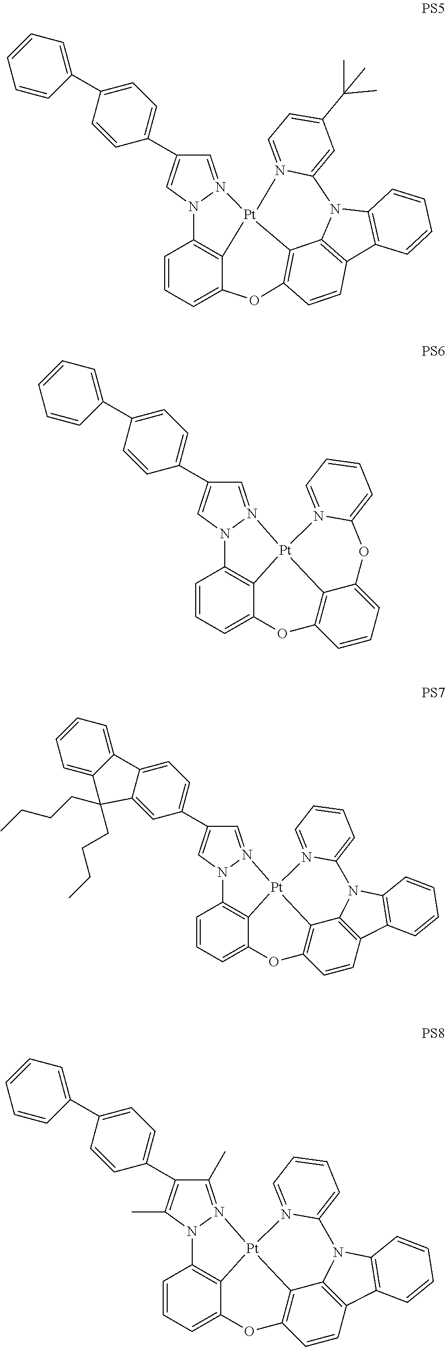

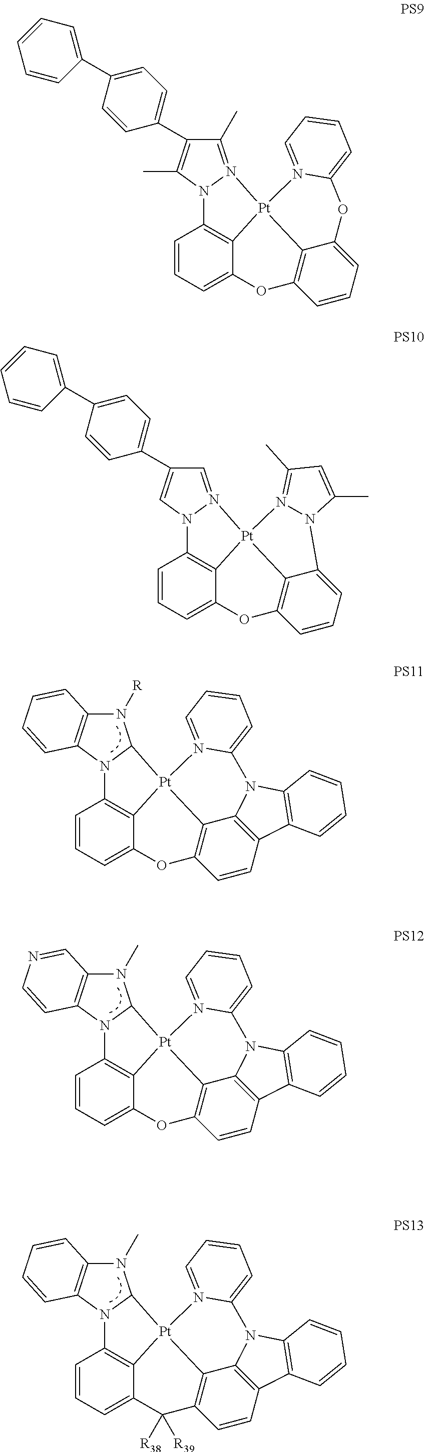

In Compound Group 4, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML according to an embodiment may include the first compound, and at least one of the second to fourth compounds. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. The fourth compound may be referred to as a phosphorescent sensitizer. The fourth compound may emit phosphorescence or may transfer energy to the first compound as an auxiliary dopant. However, the functions of the fourth compound are described herein only as an example, and embodiments are not limited thereto.

The fourth compound may transfer energy from the host to the first compound, which is a light emitting dopant. For example, the fourth compound, which may serve as an auxiliary dopant, accelerates energy transfer to the first compound, which is a light emitting dopant, thereby increasing the emission ratio of the first compound. Therefore, the emission layer EML according to an embodiment may have improved luminous efficiency. When energy transfer to the first compound is increased, an exciton formed in the emission layer EML may not accumulate inside the emission layer EML and may emit light rapidly, and thus deterioration of the light emitting element may be reduced. Therefore, the service life of the light emitting element ED according to an embodiment may increase.

When the emission layer EML in the light emitting element ED according to an embodiment includes the first compound, the second compound, the third compound, and the fourth compound, an amount of the first compound may be in a range about 1 wt % to about 5 wt %, and an amount of the fourth compound may be in a range of about 10 wt % to about 15 wt %, based on a total weight of the first compound, the second compound, the third compound, and the fourth compound.

When an amount of the first compound and an amount of the fourth compound each satisfy the above-described ranges, the fourth compound may efficiently transfer energy to the first compound, so that luminous efficiency and device service life may increase.

A total amount of the second compound and the third compound in the emission layer EML may be the remainder of the total weight of the first compound, the second compound, the third compound, and the fourth compound, apart from the total amount of the first compound and the fourth compound described herein. For example, a total amount of the second compound and the third compound in the emission layer EML may be in a range of about 80 wt % to about 89 wt %, based on a total weight of the first compound, the second compound, the third compound, and the fourth compound. Within the total amount of the second compound and the third compound in the emission layer EML, a weight ratio of the second compound to the third compound may be in a range of about 3:7 to about 7:3. For example, within the total amount of the second compound and the third compound in the emission layer EML, a weight ratio of the second compound to the third compound may be about 5:5.

When the amounts of the second compound and the third compound satisfy the above-described ranges and ratios, a charge balance characteristic in the emission layer EML may be improved, and thus the luminous efficiency and device service life may increase. When the amounts of the second compound and the third compound deviate from the above-described ranges and ratios, a charge balance in the emission layer EML may not be achieved, and thus the luminous efficiency may be reduced, and the device may deteriorate more readily.

When each of the first compound, the second compound, the third compound, and the fourth compound included in the emission layer EML satisfies the above-described ranges and ratios, excellent luminous efficiency and long service life may be achieved.

The emission layer EML may further include an emission layer material of the related art, besides the first to fourth compounds as described herein. In the light emitting element ED according to an embodiment, the emission layer EML may further include an anthracene derivative, a pyrene derivative, a fluoranthene derivative, a chrysene derivative, a dihydrobenzanthracene derivative, a triphenylene derivative, or the like. For example, the emission layer EML may further include an anthracene derivative or a pyrene derivative.

In each light emitting element ED according to embodiments illustrated in FIGS. 3 to 6, the emission layer EML may include a compound represented by Formula E-1. The compound represented by Formula E-1 may be used as a fluorescent host material.

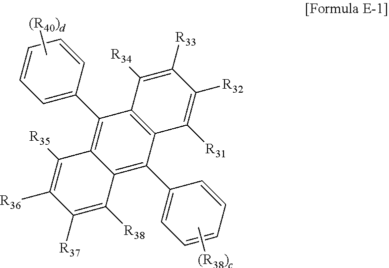

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

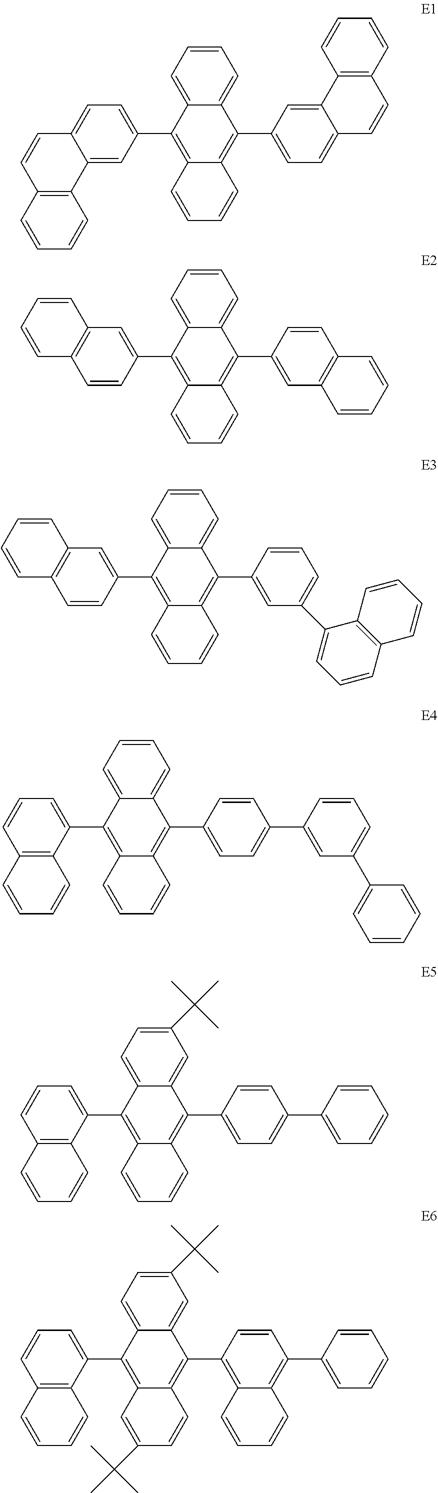

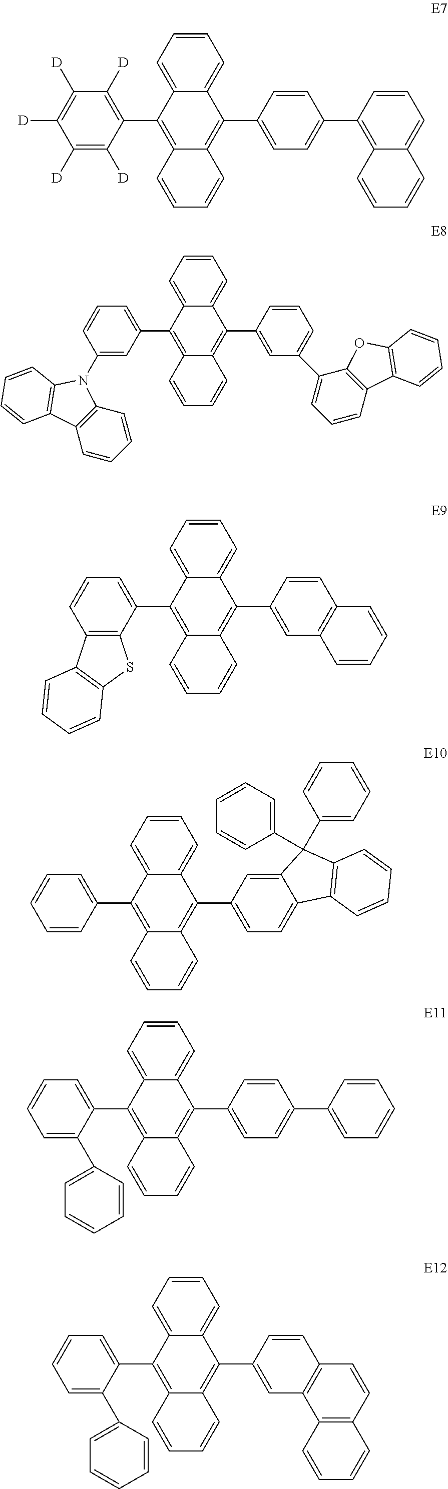

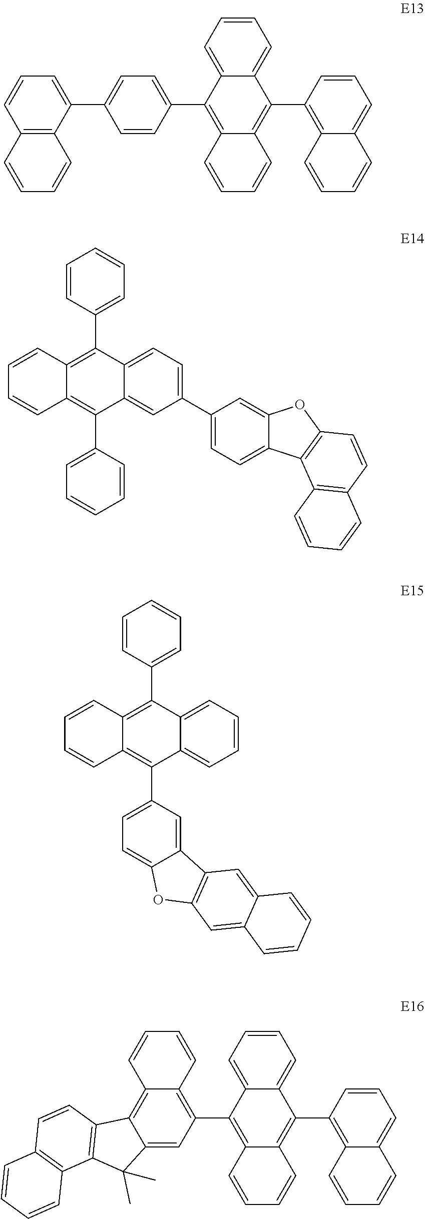

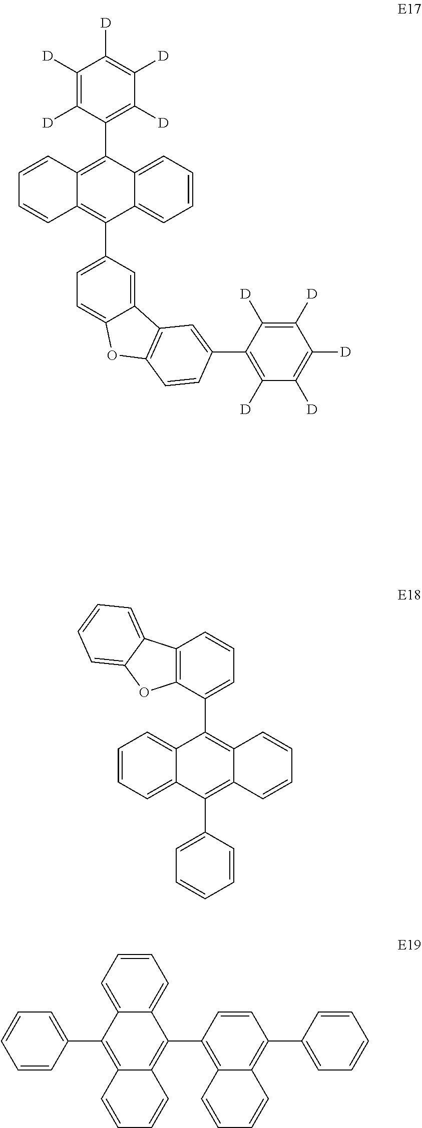

In an embodiment, the emission layer EML may include a compound represented by Formula E-2a or Formula E-2b. The compound represented by Formula E-2a or Formula E-2b may be used as a phosphorescent host material.

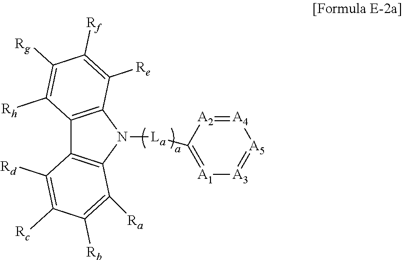

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or more, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc. as a ring-forming atom.

In Formula E-2a, two or three of A₁ to A₅ may each be N, and the remainder of A₁ to A₅ may each independently be C(Rᵢ).

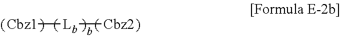

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

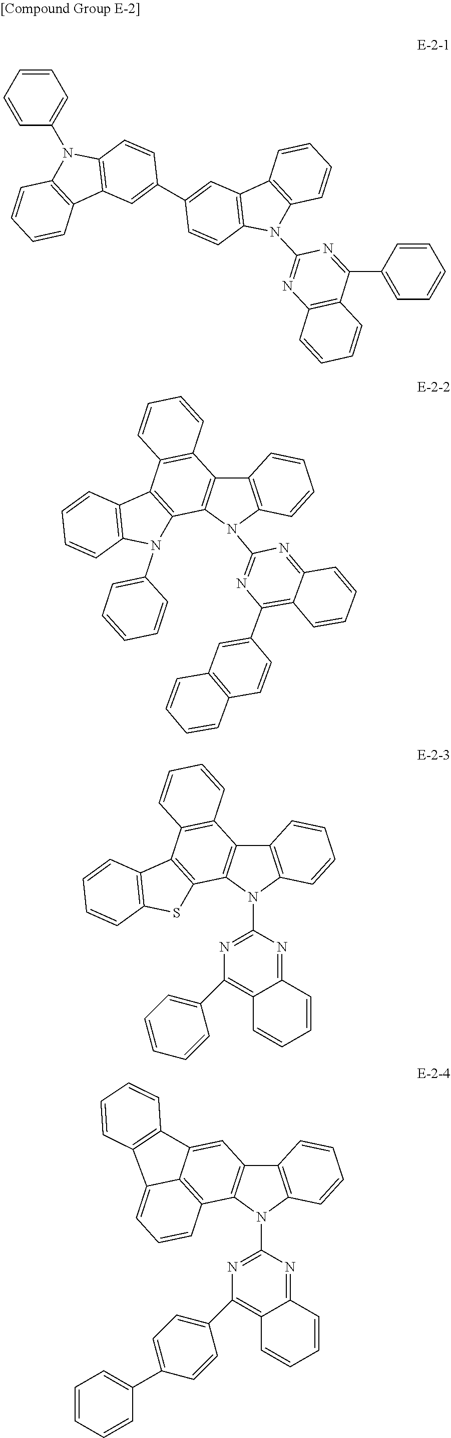

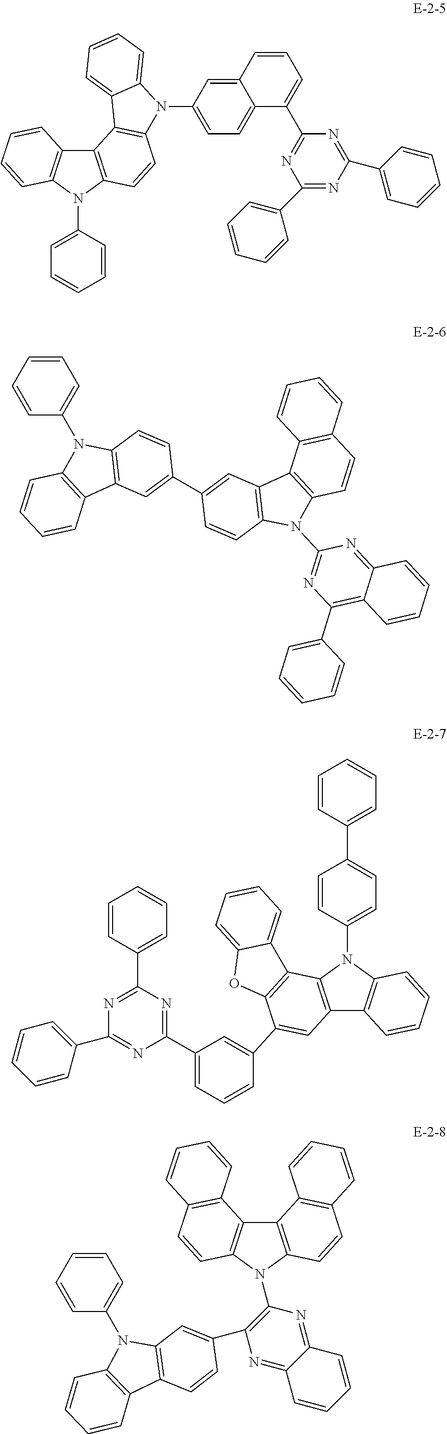

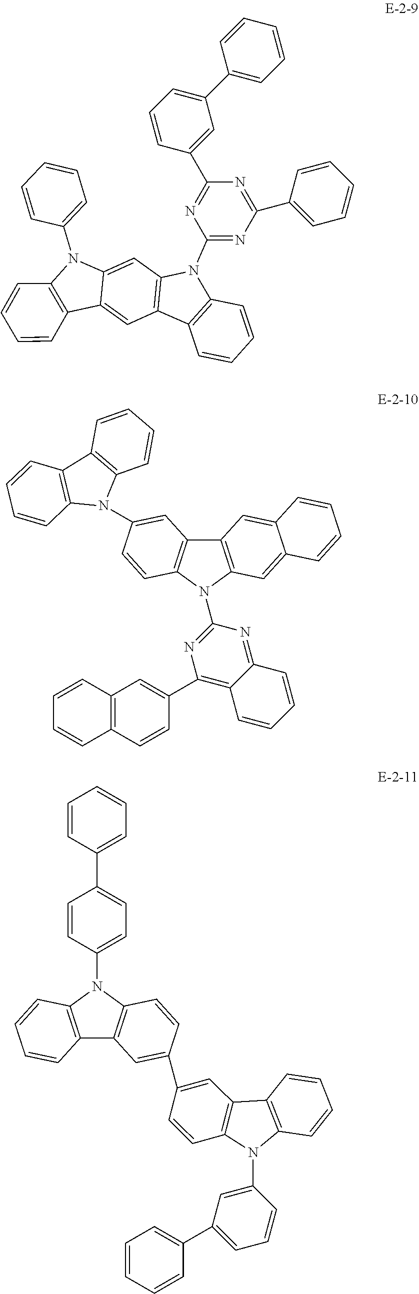

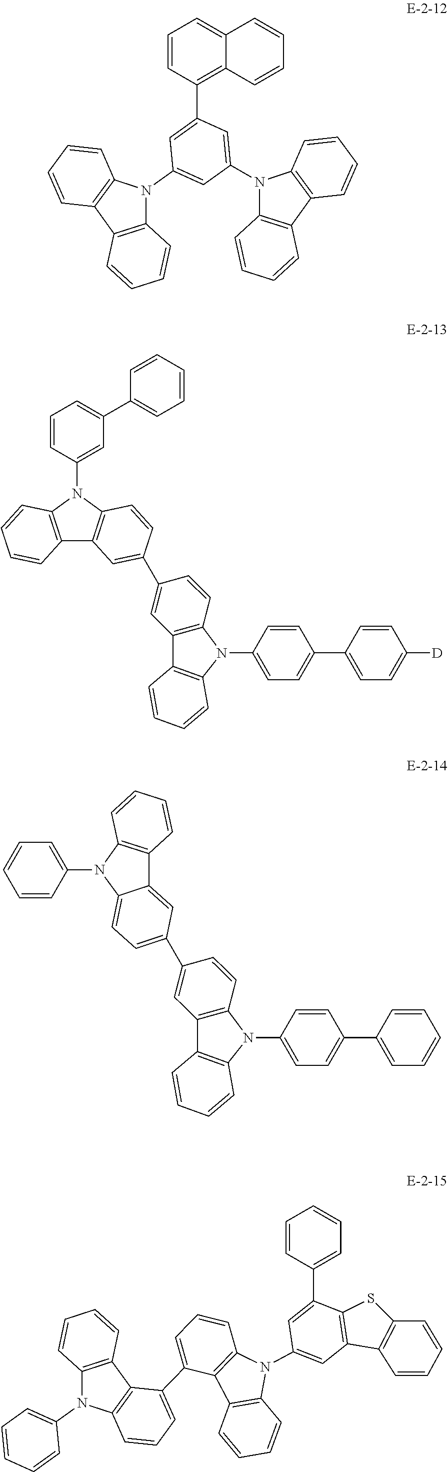 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

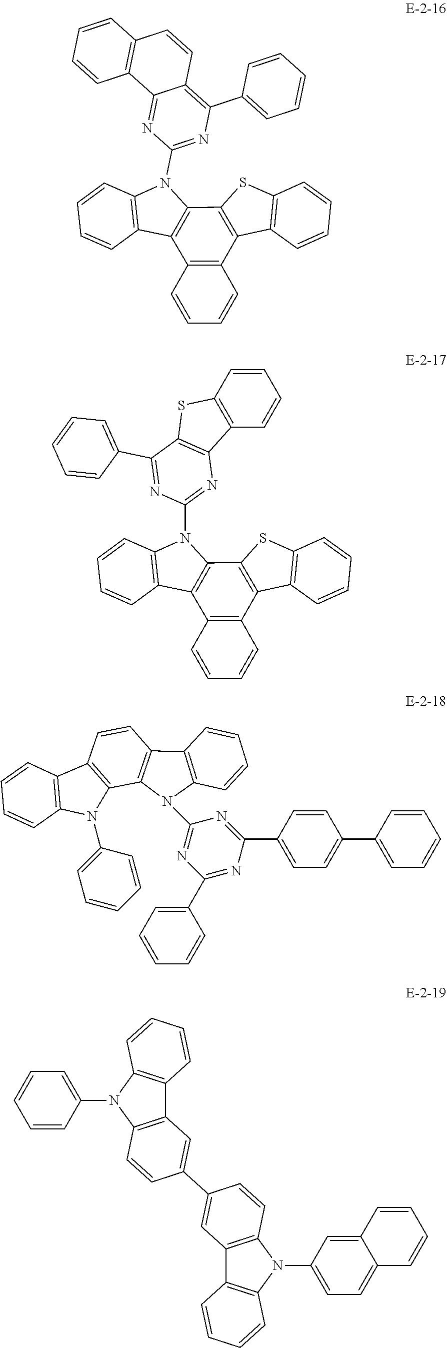 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

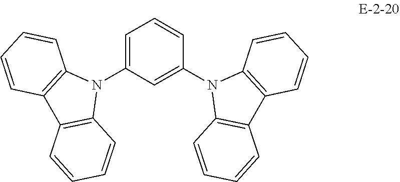 [SMILES: c1cc(-n2c3ccccc3c3ccccc32)cc(-n2c3ccccc3c3ccccc32)c1]

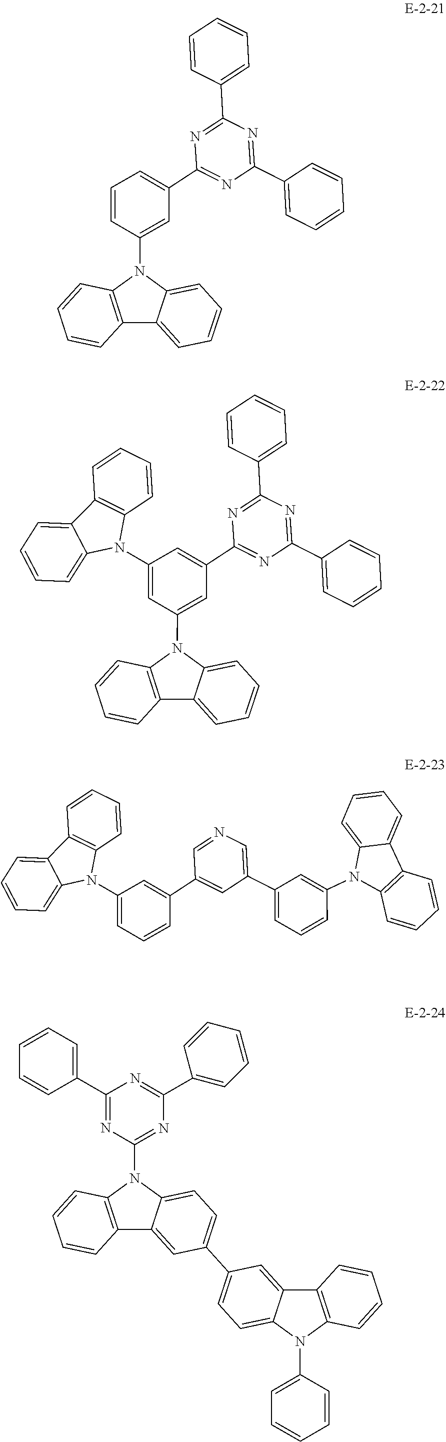 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. In an embodiment, the compound represented by Formula M-a may be used as a phosphorescent dopant material. In another embodiment, the compound represented by Formula M-a may be used as an auxiliary dopant material.

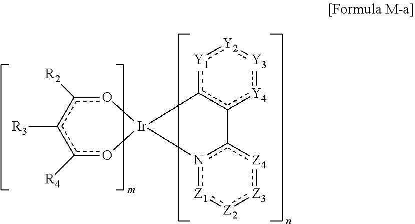

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25:

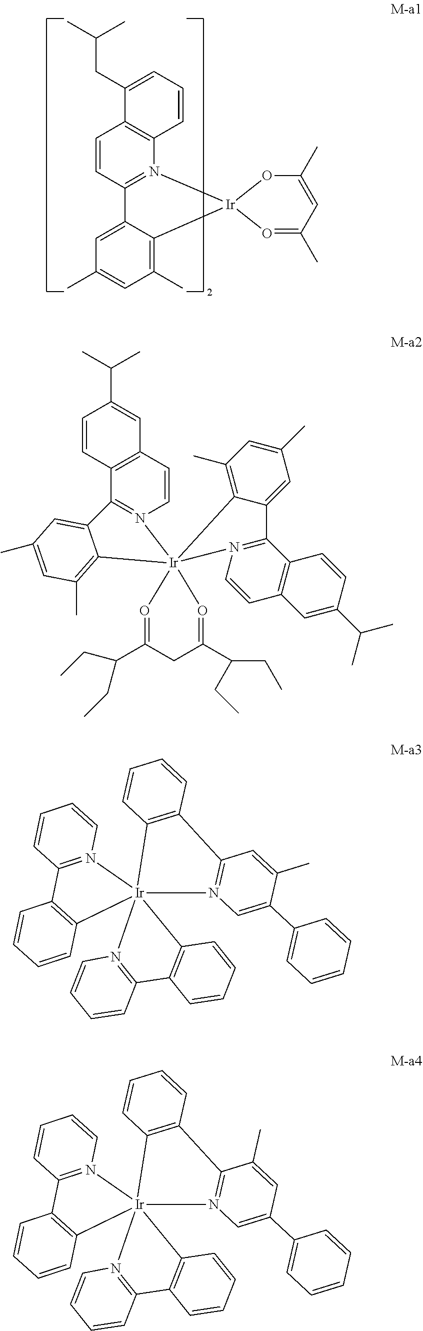

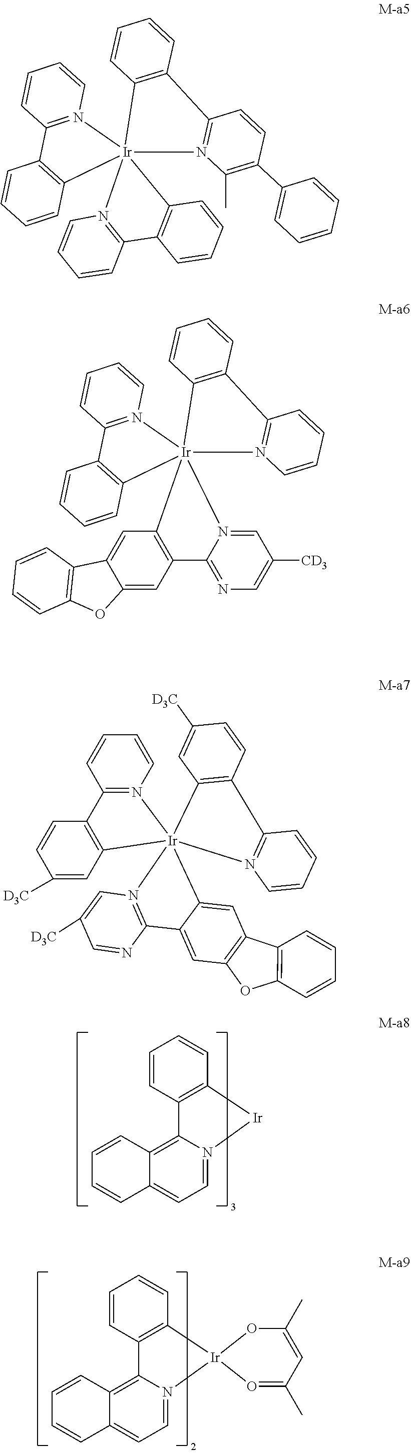

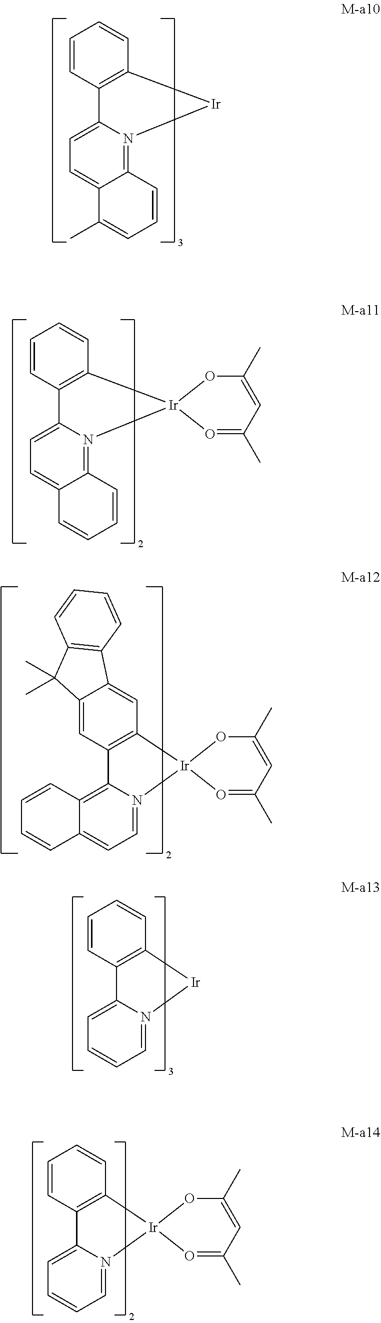

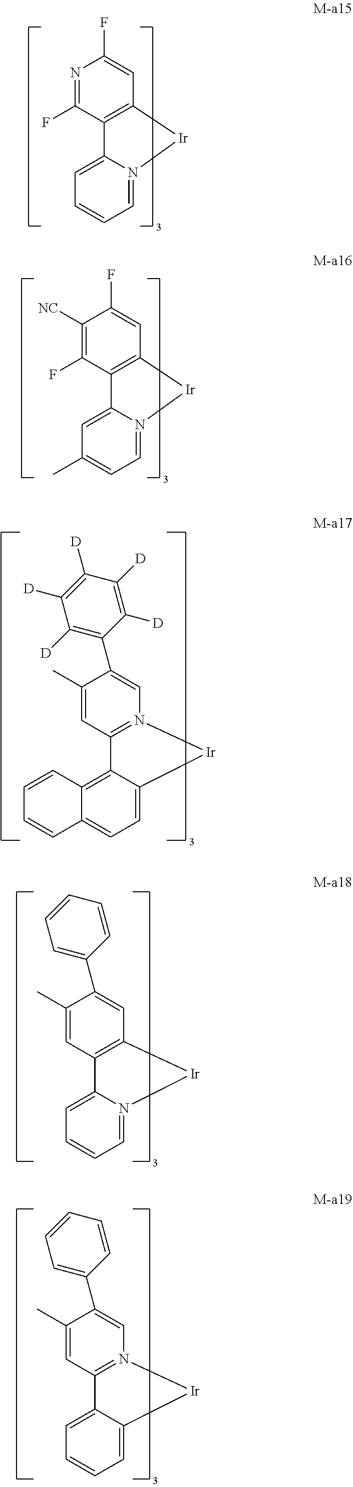

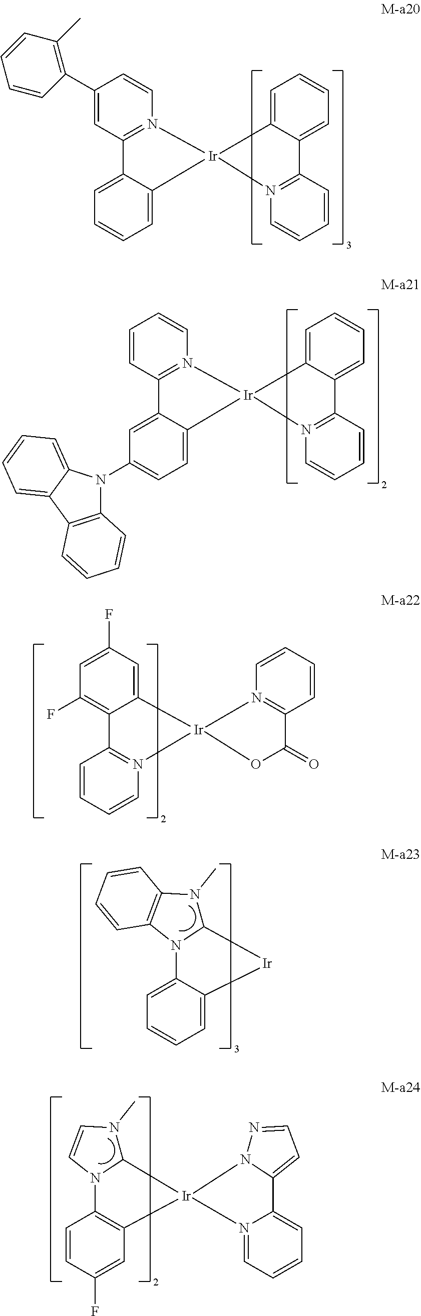

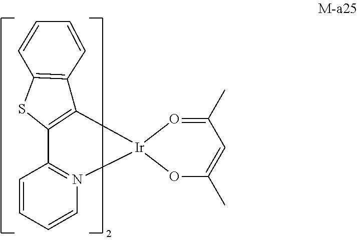

Compound M-a1 and Compound M-a2 may be used as a red dopant material, and Compound M-a3 to Compound M-a7 may be used as a green dopant material.

The emission layer EML may further include a compound represented by any one of Formula F-a to Formula F-c. The compound represented by any one of Formula F-a to Formula F-c may be used as a fluorescence dopant material.

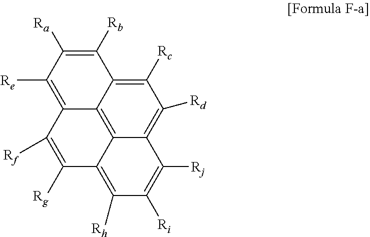

In Formula F-a, two of Rₐ to Rⱼ may each independently be substituted with a group represented by *—NAr₁Ar₂. In Formula F-a, the remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula F-a, in the group represented by *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

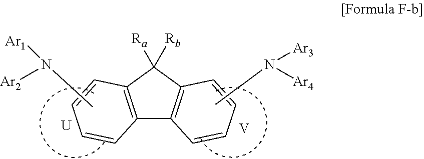

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at a portion indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

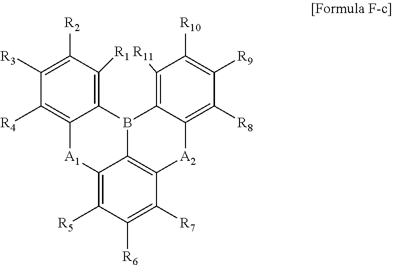

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to substituents of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

In an embodiment, when multiple emission layers EML are included, at least one emission layer EML may include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In embodiments, at least one emission layer EML may include a quantum dot. The quantum dot may be a Group II-VI compound, a Group III-VI compound, a Group 1-II-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

The Group III-VI compound may include: a binary compound such as In₂S₃ or In₂Se₃; a ternary compound such as InGaS₃ or InGaSe₃; or any combination thereof.

The Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, the Group III-V compound may further include a Group II metal. For example, InZnP, etc. may be selected as a Group III-II-V compound.

The Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. The Group IV element may include Si, Ge, or a mixture thereof. The Group IV compound may include a binary compound selected from the group consisting of SiC, SiGe, and a mixture thereof.

A binary compound, a ternary compound, or a quaternary compound may be present in a particle at a uniform concentration distribution, or may be present in a particle at a partially different concentration distribution. In an embodiment, the quantum dot may have a core/shell structure in which one quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoresis properties to the quantum dot. The shell may be a single layer or a multilayer.

Examples of the shell of the quantum dot may include a metal oxide, a non-metal oxide, a semiconductor compound, or any combination thereof.

For example, the metal oxide or the non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and NiO; a ternary compound such as MgAl₂O₄, CoFe₂O₄, NiFe₂O₄, and CoMn₂O₄; or any combination thereof, but embodiments are not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. When the quantum dot has a FWHM of an emission wavelength spectrum in any of the above ranges, color purity or color reproducibility may be improved. Light emitted through a quantum dot may be emitted in all directions, so that a wide viewing angle may be improved.

The form of a quantum dot is not particularly limited as long as it is any form that is used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoparticles, etc.

The quantum dot may control the color of emitted light according to a particle size thereof. Accordingly, the quantum dot may have various light emission colors such as blue, red, and green.

In the light emitting elements ED according to embodiments illustrated in FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer formed of a single material, a layer formed of different materials, or a structure including multiple layers formed of different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, a hole blocking layer HBL/electron transport layer ETL/electron injection layer EIL, or an electron transport layer ETL/buffer layer (not shown)/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2:

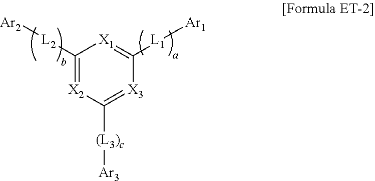

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

In embodiments, the electron transport region ETR may include at least one of Compound ET1 to Compound ET36:

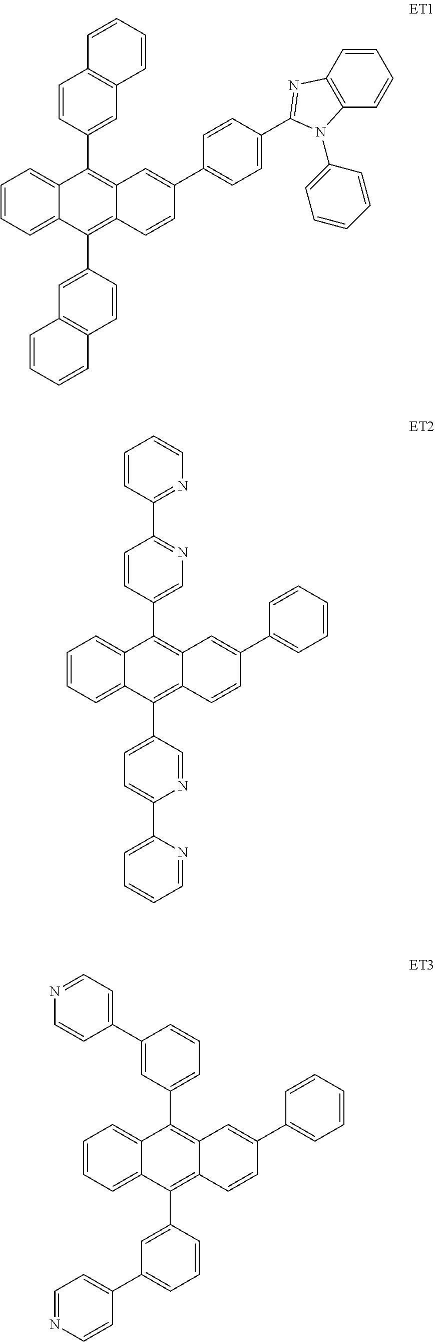 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

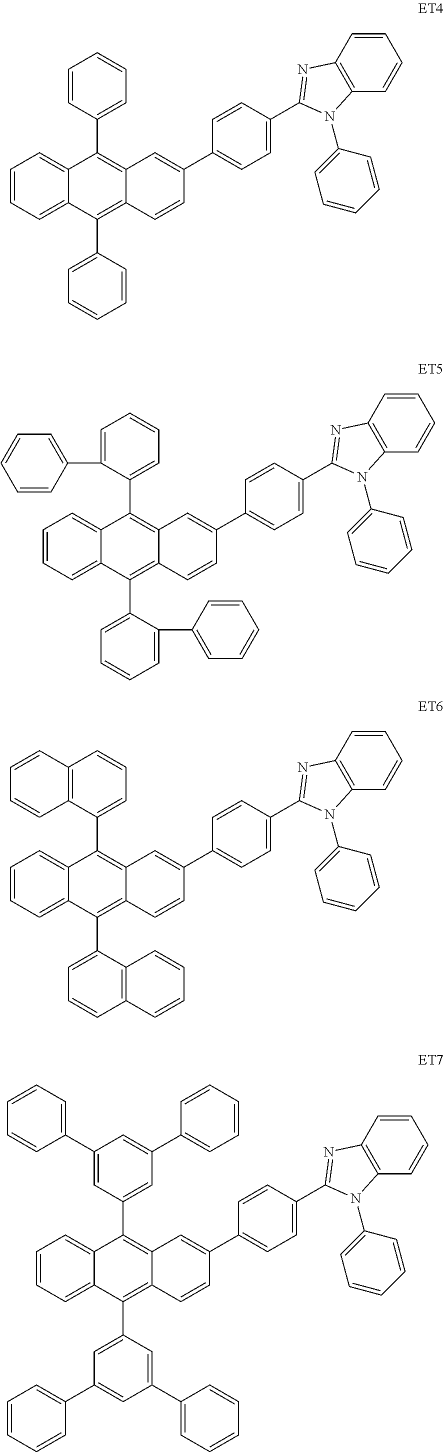 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

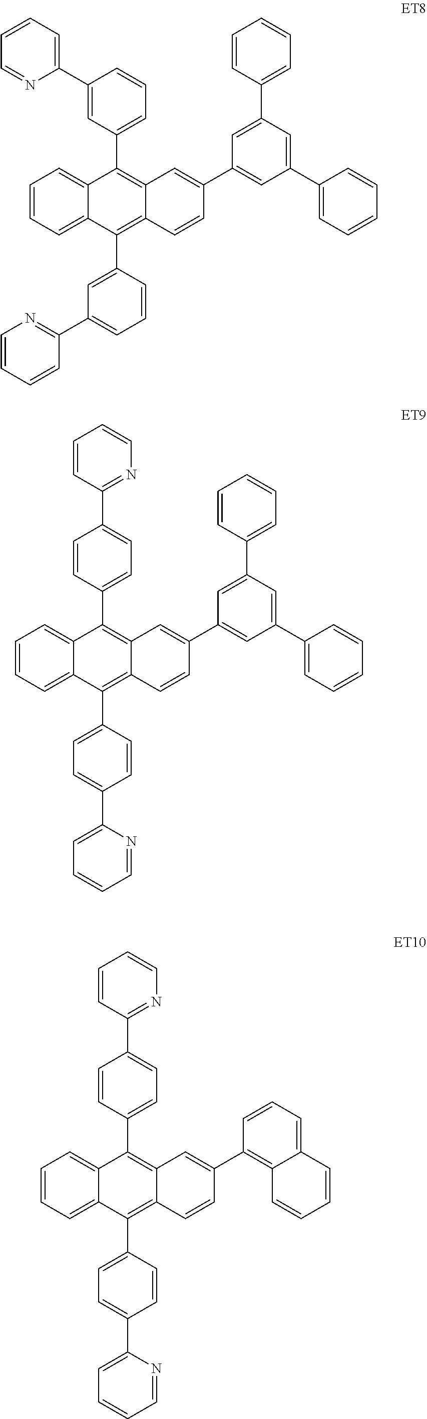 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

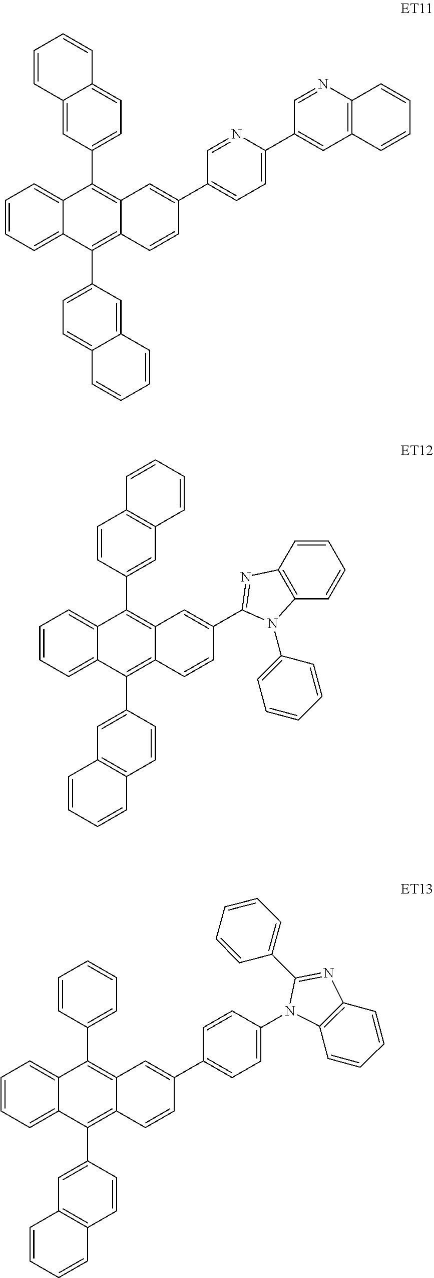 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

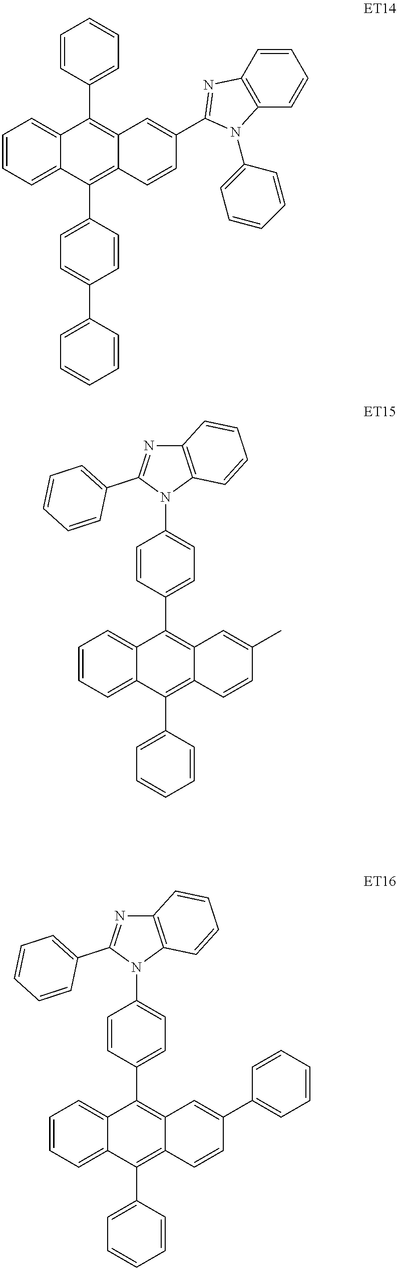

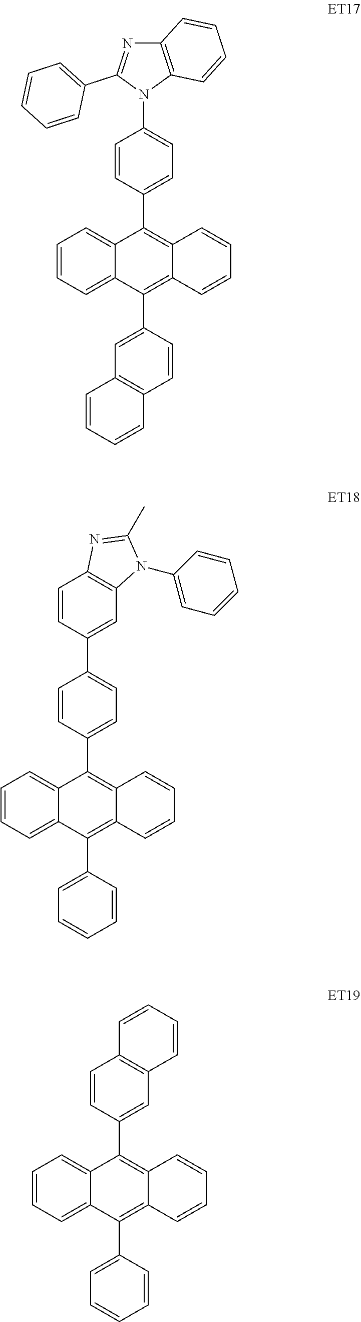

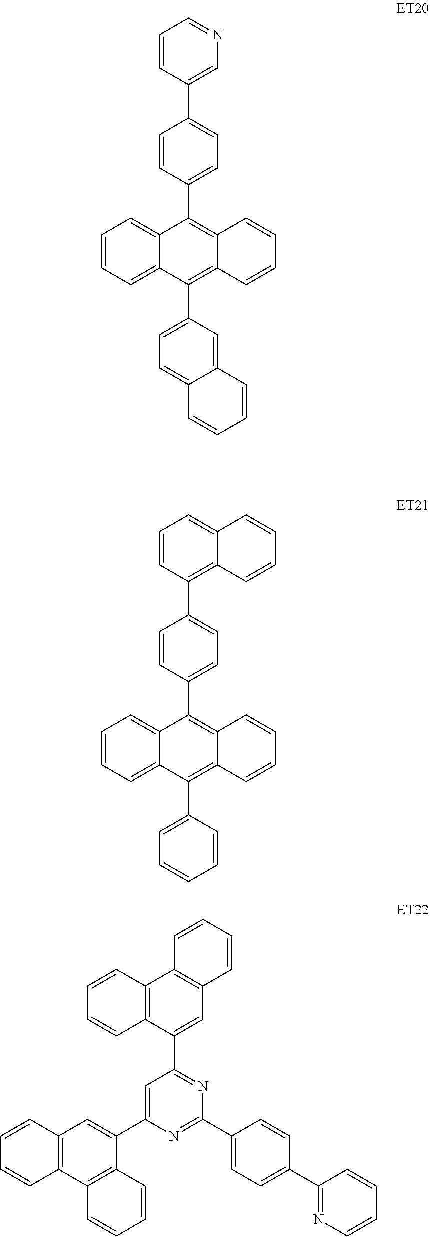

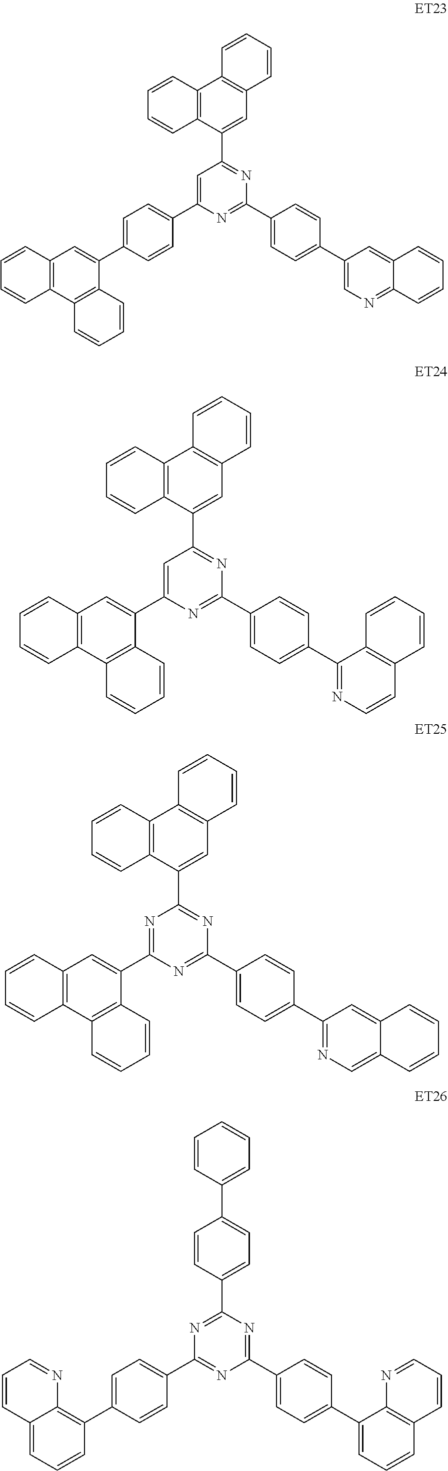 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)nc(-c5cc6ccccc6c6ccccc56)n4)cc3)ncc2c1 ; c1ccc(-c2ccc(-c3nc(-c4ccc(-c5cccc6cccnc56)cc4)nc(-c4ccc(-c5cccc6cccnc56)cc4)n3)cc2)cc1]

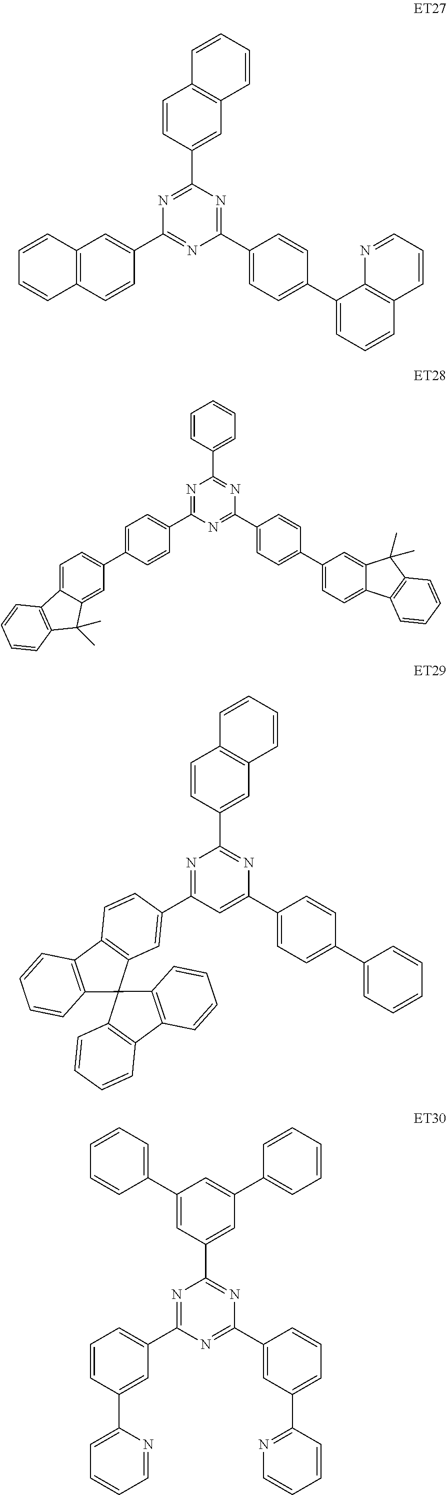

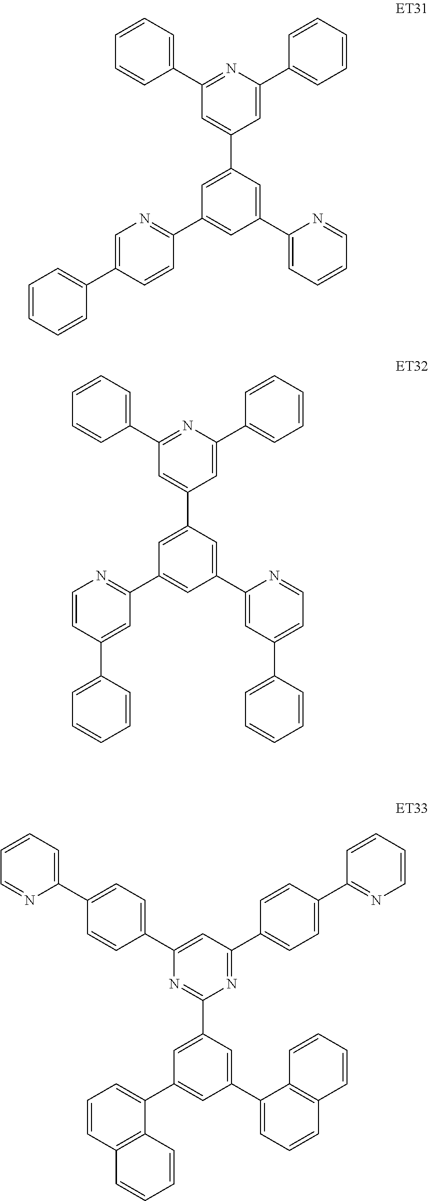 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

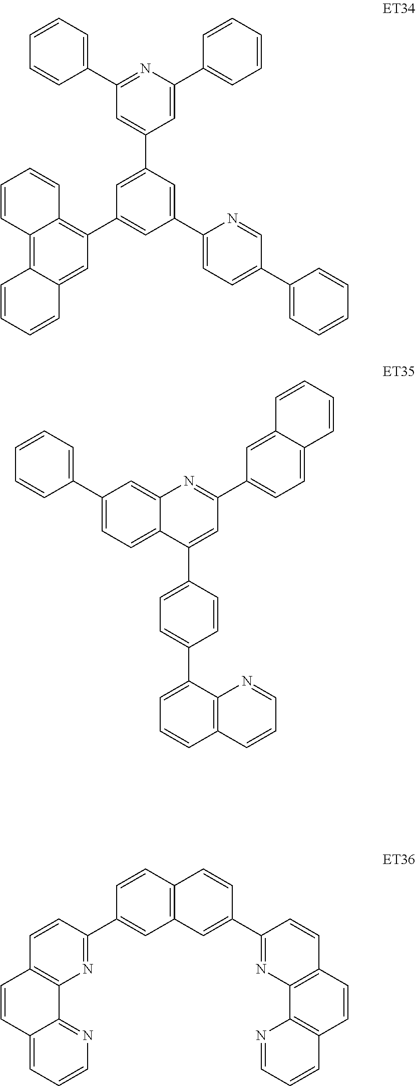 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport regions ETR may include a metal halide such as LiF, NaCl, CsF, RbCl, RbI, CuI, or KI; a lanthanide metal such as Yb; or a co-deposited material of a metal halide and a lanthanide metal. For example, the electron transport region ETR may include KI:Yb, RbI:Yb, LiF:Yb, etc. as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the hole transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, a compound thereof, or a mixture thereof (e.g., AgMg, AgYb, or MgYb). In another embodiment, the second electrode EL2 may have a multilayer structure including a reflective layer or a transflective layer formed of the above-described materials, and a transparent conductive layer formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (for example, LiF), an alkaline earth metal compound (for example, MgF₂), SiON, SiNₓ, SiO_{y}, etc.

For example, when the capping layer CPL contains an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as a methacrylate. However, embodiments are not limited thereto, and the capping layer CPL may include at least one of Compounds P1 to P5:

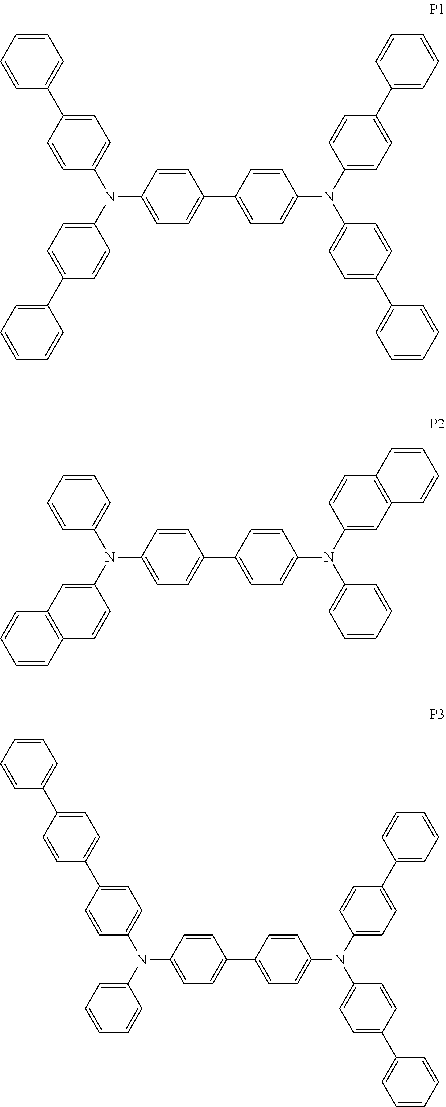 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

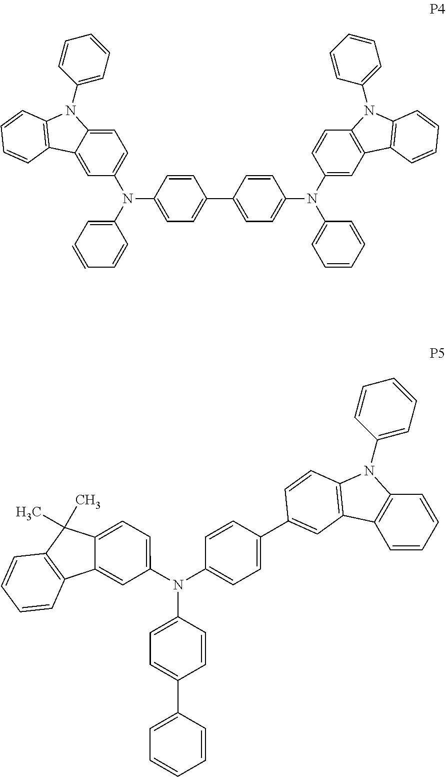 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6 with respect to light in a wavelength range of about 550 nm to about 660 nm.

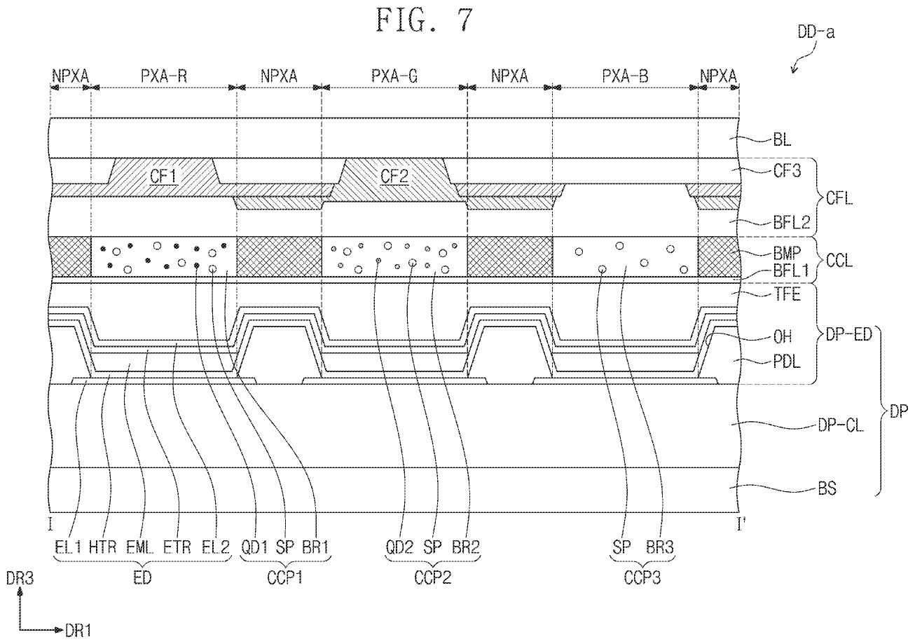

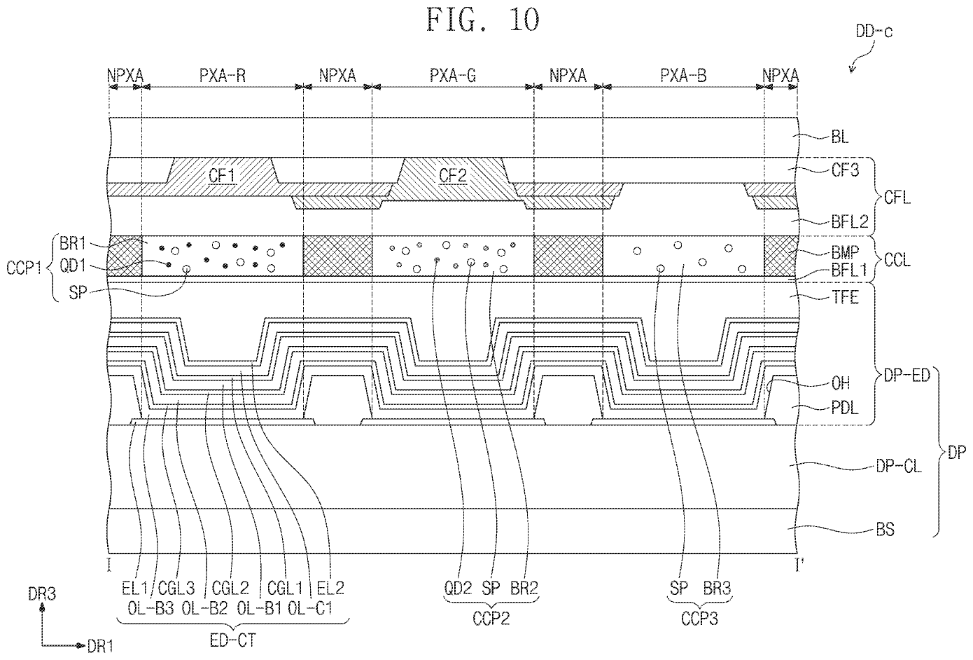

FIGS. 7 to 10 are each a schematic cross-sectional view of a display device according to embodiments. Hereinafter, in describing the display devices according to embodiments with reference to FIGS. 7 to 10, the features which have been described above with respect to FIGS. 1 to 6 will not be explained again, and the differing features will be described.

Referring to FIG. 7, a display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. A structure of the light emitting element ED shown in FIG. 7 may be the same as a structure of a light emitting element according to one of FIGS. 3 to 6 as described herein.

The emission layer EML of the light emitting element ED included in the display device DD according to an embodiment may include the above-described polycyclic compound according to an embodiment.

Referring to FIG. 7, the emission layer EML may be disposed in an opening OH defined in a pixel defining film PDL. For example, the emission layer EML which is separated by the pixel defining film PDL and provided corresponding to each of the light emitting regions PXA-R, PXA-G, and PXA-B may emit light in a same wavelength range. In the display device DD-a according to an embodiment, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be an inorganic particle. For example, the scatterer SP may include at least one of TiO₂, ZnO, Al₂O₃, SiO₂, or hollow silica. The scatterer SP may include any one of TiO₂, ZnO, Al₂O₃, SiO₂, or hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may each independently be formed of a single layer or of multiple layers.

In the display device DD-a according to an embodiment, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter. The first to third filters CF1, CF2, and CF3 may be disposed corresponding to the red light emitting region PXA-R, the green light emitting region PXA-G, and the blue light emitting region PXA-B, respectively.

The color filter layer CFL may include a light shielding part (not shown). The color filter layer CFL may include the light shielding part (not shown) disposed so that it overlaps the boundaries between neighboring filters CF1, CF2, and CF3. The light shielding part (not shown) may be a black matrix. The light shielding part (not shown) may include an organic light shielding material or an inorganic light shielding material containing a black pigment or dye. The light shielding part (not shown) may prevent light leakage, and may separate boundaries between adjacent filters CF1, CF2, and CF3. In an embodiment, the light shielding part (not shown) may be formed of a blue filter.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

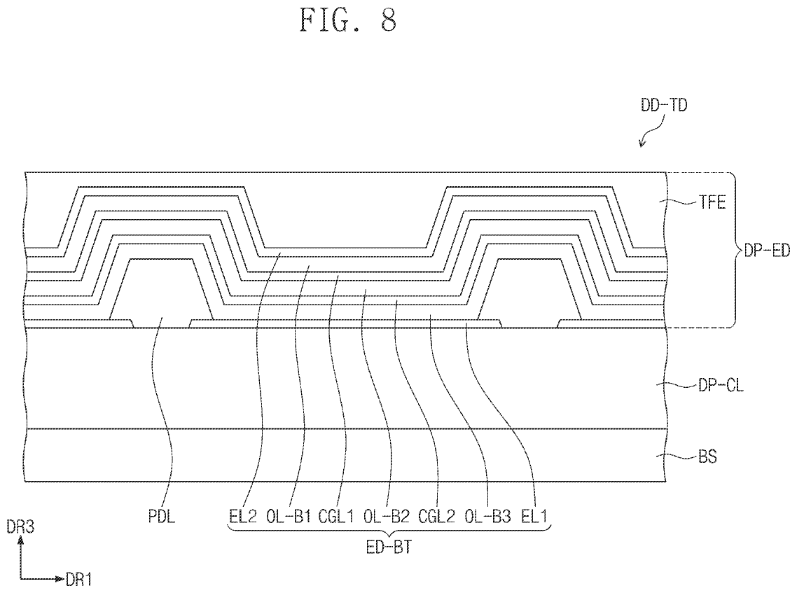

FIG. 8 is a schematic cross-sectional view illustrating a portion of the display device DD-a according to an embodiment. FIG. 8 is a schematic cross-sectional view that illustrates a part corresponding to the display panel DP of FIG. 7. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7), and a hole transport region HTR and an electron transport region ETR disposed with the emission layer EML (FIG. 7) located therebetween.

For example, the light emitting element ED-BT included in the display device DD-TD according to an embodiment may be a light emitting element having a tandem structure and including multiple emission layers.

In an embodiment illustrated in FIG. 8, light emitted from each of the light emitting structures OL-B1, OL-B2, and OL-B3 may all be blue light. However, embodiments are not limited thereto, and the light emitted from each of the light emitting structures OL-B1, OL-B2, and OL-B3 may have wavelength ranges that are different from each other. For example, the light emitting element ED-BT including the light emitting structures OL-B1, OL-B2, and OL-B3 which emit light having wavelength ranges different from each other may emit white light.

Charge generation layers CGL1 and CGL2 may be disposed between neighboring light emitting structures OL-B1, OL-B2, and OL-B3. Charge generation layers CGL1 and CGL2 may each independently include a p-type charge generation layer and/or an n-type charge generation layer.

At least one of the light emitting structures OL-B1, OL-B2, and OL-B3 included in the display device DD-TD according to an embodiment may include the polycyclic compound according to an embodiment, as described herein. For example, at least one of the emission layers included in the light emitting element ED-BT may include the polycyclic compound according to an embodiment.

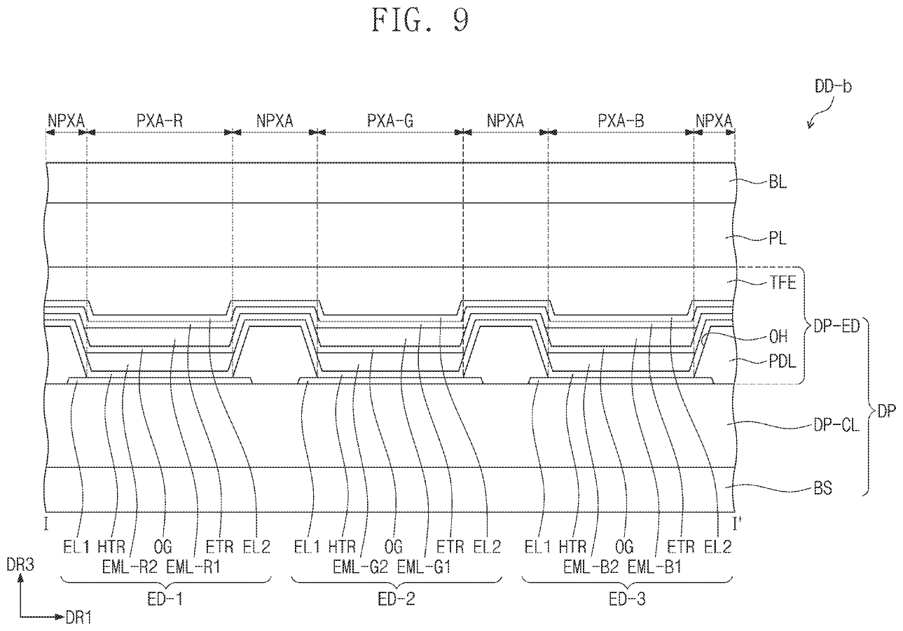

Referring to FIG. 9, the display device DD-b according to an embodiment may include light emitting elements ED-1, ED-2, and ED-3 which may each include two emission layers that are stacked. In comparison to the display device DD illustrated in FIG. 2, the embodiment illustrated in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2, stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, stacked in that order.

An optical auxiliary layer PL may be disposed on the display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device DD-b.

At least one emission layer included in the display device DD-b according to an embodiment illustrated in FIG. 9 may include the above-described polycyclic compound according to an embodiment. For example, in an embodiment, at least one of the first blue emission layer EML-B1 or the second blue emission layer EML-B2 may include the polycyclic compound according to an embodiment.

In contrast to FIGS. 8 and 9, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may each emit light in different wavelength regions.

The charge generation layers CGL1, CGL2, and CGL3 disposed between adjacent light emitting structures OL-B1, OL-B2, OL-B3, and OL-C1 may each independently include a p-type charge generation layer and/or an n-type charge generation layer.

In the display device DD-c according to an embodiment, at least one of the light emitting structures OL-B1, OL-B2, OL-B3, and OL-C1 may include the polycyclic compound according to embodiments. For example, in an embodiment, at least one of the first to third light emitting structures OL-B1, OL-B2, and OL-B3 may include the polycyclic compound according to embodiments.

The light emitting element ED according to an embodiment may include the above-described polycyclic compound according to an embodiment in at least one functional layer disposed between the first electrode EL1 and the second electrode EL2, thereby exhibiting excellent luminous efficiency and improved service life characteristics. For example, the polycyclic compound according to an embodiment may be included in the emission layer EML of the light emitting element ED according to an embodiment, and the light emitting element may exhibit high efficiency and long service life characteristics.

The polycyclic compound according to embodiments includes a spiro-bifluorene substituent, which is a bulky substituent, and the fused ring core moiety includes a boron atom, and thus may have high stability. The polycyclic compound according to an embodiment includes the fused ring core moiety including a boron atom and the spiro-bifluorene substituent, thereby implementing both short range charge transfer and long range charge transfer phenomena, and thus may be used as a thermally activated delayed fluorescence dopant material, thereby increasing luminous efficiency.

Hereinafter, a polycyclic compound according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### EXAMPLES

### 1. Synthesis of Polycyclic Compound of Example

A synthesis method of the polycyclic compound according to an embodiment will be explained in detail with reference to the synthesis methods of Compounds 3, 4, 11, 15, 32, 43, and 48. The synthesis methods of the polycyclic compounds are provided only as examples, but the synthesis methods of the polycyclic compound according to embodiments is not limited to the Examples below.

(1) Synthesis of Compound 3

Polycyclic Compound 3 according to an example may be synthesized by, for example, the steps shown in Reaction Scheme 1:

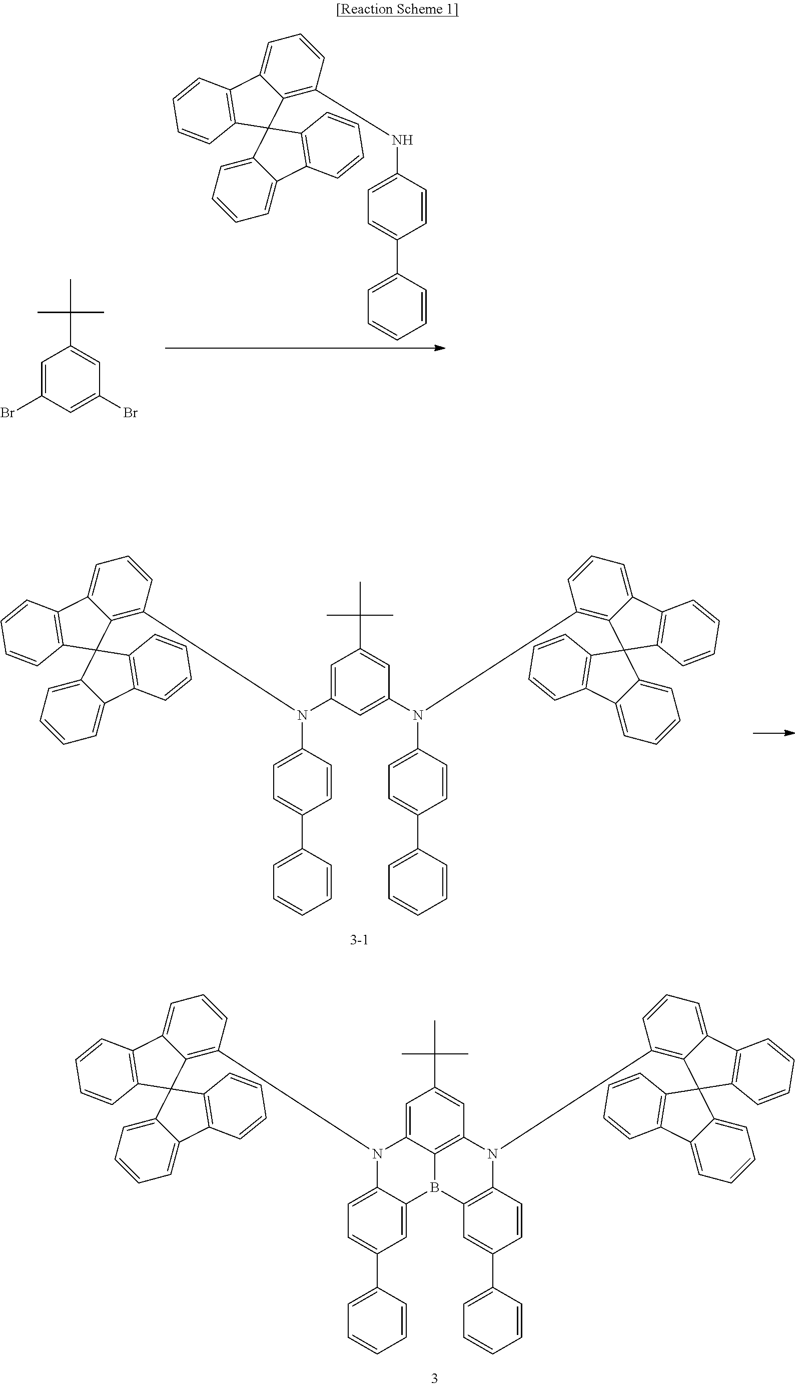 [SMILES: CC(C)(C)c1cc(Br)cc(Br)c1 ; c1ccc(-c2ccc(Nc3cccc4c3C3(c5ccccc5-c5ccccc53)c3ccccc3-4)cc2)cc1 ; CC(C)(C)c1cc(N(c2ccc(-c3ccccc3)cc2)c2cccc3c2C2(c4ccccc4-c4ccccc42)c2ccccc2-3)cc(N(c2ccc(-c3ccccc3)cc2)c2cccc3c2C2(c4ccccc4-c4ccccc42)c2ccccc2-3)c1 ; CC(C)(C)c1cc2c3c(c1)N(c1cccc4c1C1(c5ccccc5-c5ccccc51)c1ccccc1-4)c1ccc(-c4ccccc4)cc1B3c1cc(-c3ccccc3)ccc1N2c1cccc2c1C1(c3ccccc3-c3ccccc31)c1ccccc1-2]

1) Synthesis of Intermediate Compound 3-1

1,3-dibromo-5-(tert-butyl)benzene (1 eq), N-([1,1′-biphenyl]-4-yl)-9,9′-spirobi[fluoren]-1-amine (2.1 eq), tris(dibenzylideneacetone)dipalladium(0) (0.1 eq), tri-tert-butylphosphine (0.2 eq), and sodium tert-butoxide (3 eq) were dissolved in o-xylene, and the resultant mixture was stirred at about 150° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using methylene chloride (hereinafter, MC) and n-hexane to obtain Intermediate Compound 3-1. (yield: 67%)

2) Synthesis of Compound 3

Intermediate Compound 3-1 (1 eq) was dissolved in ortho dichlorobenezene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After the mixture was cooled, the reaction was terminated by dropping triethylamine slowly in the flask containing the reactant, and ethyl alcohol was added to the reactant and extracted and filtered to obtain solids. The obtained solids were purified by column chromatography using MC and n-hexane, and were subjected to recrystallization using toluene and acetone to obtain Compound 3. (yield: 21%)

(2) Synthesis of Compound 4

Polycyclic Compound 4 according to an example may be synthesized by, for example, the steps shown in Reaction Scheme 2:

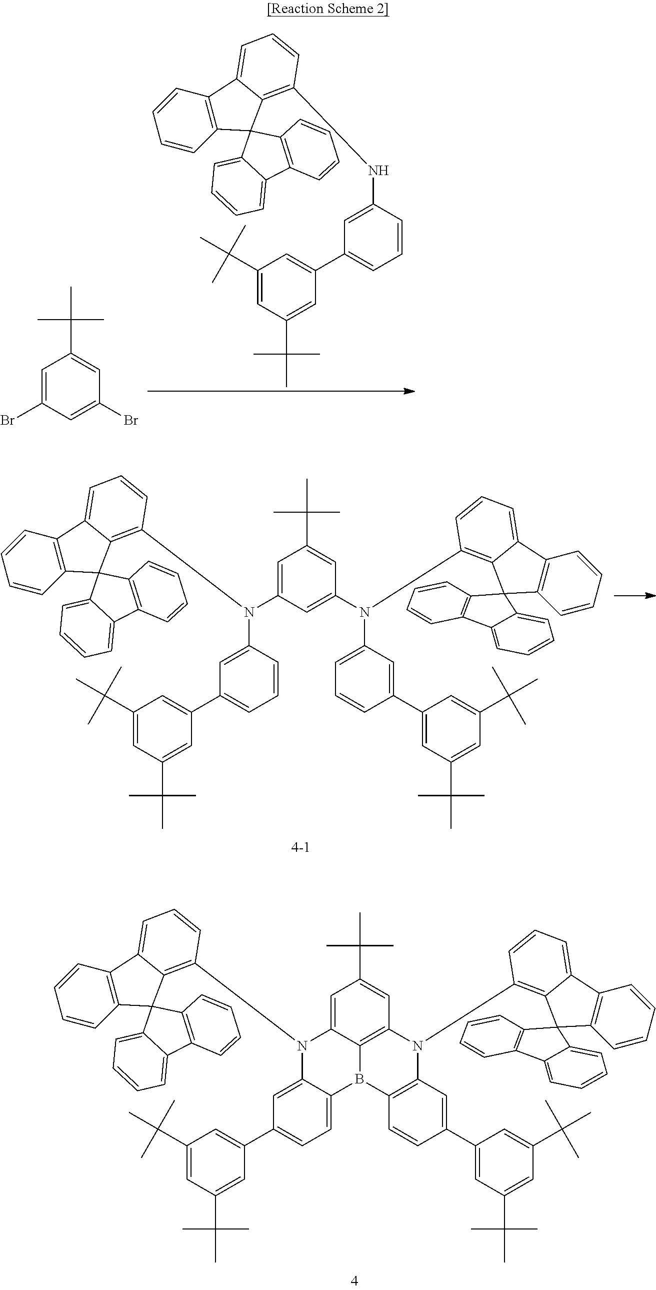 [SMILES: CC(C)(C)c1cc(Br)cc(Br)c1 ; CC(C)(C)c1cc(-c2cccc(Nc3cccc4c3C3(c5ccccc5-c5ccccc53)c3ccccc3-4)c2)cc(C(C)(C)C)c1 ; CC(C)(C)c1cc(N(c2cccc(-c3cc(C(C)(C)C)cc(C(C)(C)C)c3)c2)c2cccc3c2C2(c4ccccc4-c4ccccc42)c2ccccc2-3)cc(N(c2cccc(-c3cc(C(C)(C)C)cc(C(C)(C)C)c3)c2)c2cccc3c2C2(c4ccccc4-c4ccccc42)c2ccccc2-3)c1 ; CC(C)(C)c1cc(-c2ccc3c(c2)N(c2cccc4c2C2(c5ccccc5-c5ccccc52)c2ccccc2-4)c2cc(C(C)(C)C)cc4c2B3c2ccc(-c3cc(C(C)(C)C)cc(C(C)(C)C)c3)cc2N4c2cccc3c2C2(c4ccccc4-c4ccccc42)c2ccccc2-3)cc(C(C)(C)C)c1]

1) Synthesis of Intermediate Compound 4-1

1,3-dibromo-5-(tert-butyl)benzene (1 eq), N-(3′,5′-di-tert-butyl-[1,1′-biphenyl]-3-yl)-9,9′-spirobi[fluoren]-1-amine (2.1 eq), tris(dibenzylideneacetone)dipalladium(0) (0.1 eq), tri-tert-butylphosphine (0.2 eq), and sodium tert-butoxide (3 eq) were dissolved in o-xylene, and the resultant mixture was stirred at about 150° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate Compound 4-1. (yield: 53%)

2) Synthesis of Compound 4

Intermediate Compound 4-1 (1 eq) was dissolved in ortho dichlorobenezene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After the mixture was cooled, the reaction was terminated by dropping triethylamine slowly in the flask containing the reactant, and ethyl alcohol was added to the reactant and extracted and filtered to obtain solids. The obtained solids were purified by column chromatography using MC and n-hexane, and were subjected to recrystallization using toluene and acetone to obtain Compound 4. (yield: 20%)

(3) Synthesis of Compound 11

Polycyclic Compound 11 according to an example may be synthesized by, for example, the steps shown in Reaction Scheme 3:

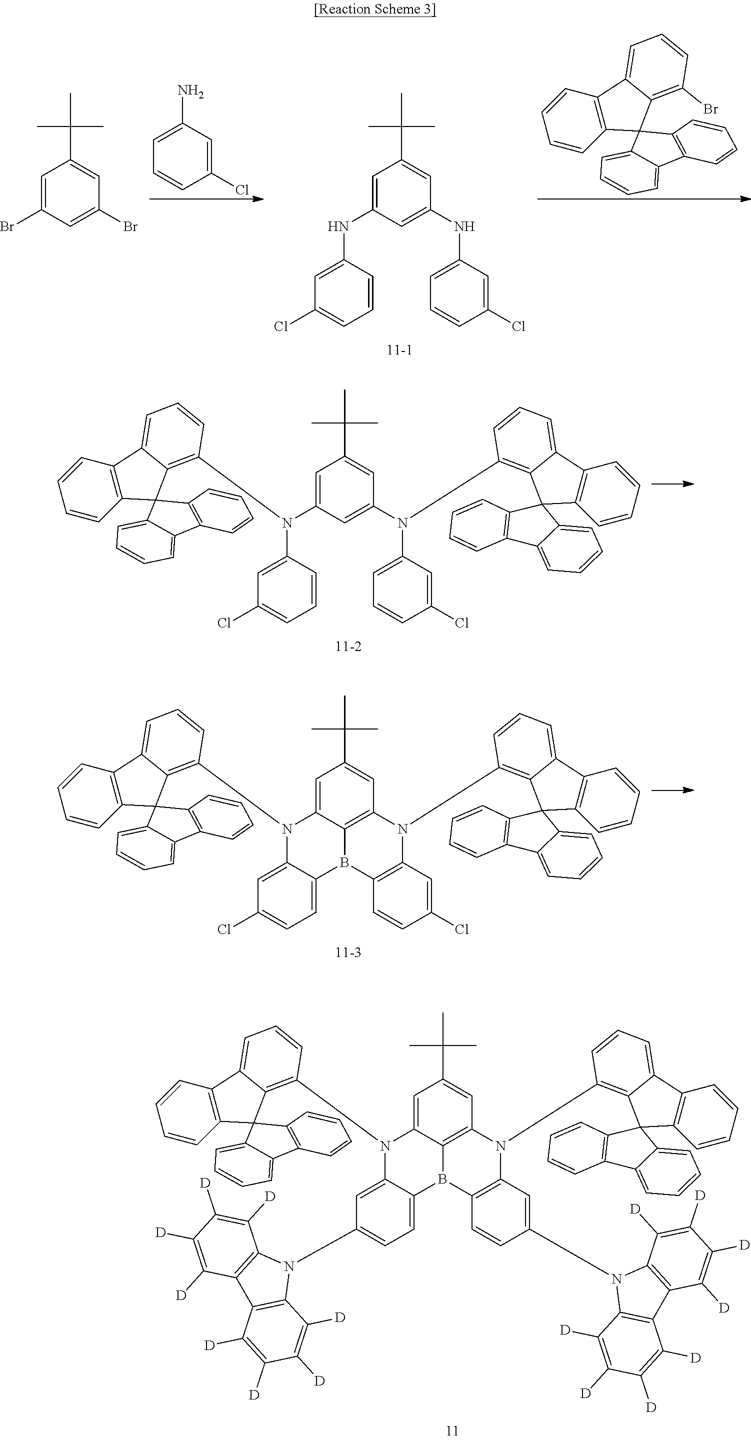

1) Synthesis of Intermediate Compound 11-1

1,3-dibromo-5-(tert-butyl)benzene (1 eq), 3-chloroaniline (2 eq), tris(dibenzylideneacetone)dipalladium(0) (0.05 eq), 1,1′-bis(diphenylphosphino)ferrocene (0.1 eq), and sodium tert-butoxide (3 eq) were dissolved in toluene and stirred at about 80° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate Compound 11-1. (yield: 75%)

2) Synthesis of Intermediate Compound 11-2

Intermediate Compound 11-1 (1 eq), 1-bromo-9,9′-spirobi[fluorene] (2.5 eq), tris(dibenzylideneacetone)dipalladium(0) (0.05 eq), 1,1′-bis(diphenylphosphino)ferrocene (0.1 eq), and sodium tert-butoxide (3 eq) were dissolved in toluene and stirred at about 80° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate Compound 11-2. (yield: 69%)

3) Synthesis of Intermediate Compound 11-3

Intermediate Compound 11-2 (1 eq) was dissolved in ortho dichlorobenezene, the mixture was cooled to about 0° C., and BBr₃ (5 eq) was slowly injected thereto in a nitrogen atmosphere. After dropping was completed, the temperature was elevated to 180° C., and the mixture was stirred for 24 hours. After the mixture was cooled, the reaction was terminated by dropping triethylamine slowly in the flask containing the reactant, and ethyl alcohol was added to the reactant and extracted and filtered to obtain solids. The obtained solids were purified by column chromatography using MC and n-hexane, and were subjected to recrystallization using toluene and acetone to obtain Intermediate Compound 11-3. (yield: 10%)

4) Synthesis of Compound 11

Intermediate Compound 11-3 (1 eq), carbazole-D8 (2.5 eq), tris(dibenzylideneacetone)dipalladium(0) (0.05 eq), tri-tert-butylphosphine (0.1 eq), and sodium tert-butoxide (3 eq) were dissolved in o-xylene, and the resultant mixture was stirred at about 150° C. for about 48 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Compound 11. (yield: 71%)

(4) Synthesis of Compound 15

Polycyclic Compound 15 according to an example may be synthesized by, for example, the steps shown in Reaction Scheme 4:

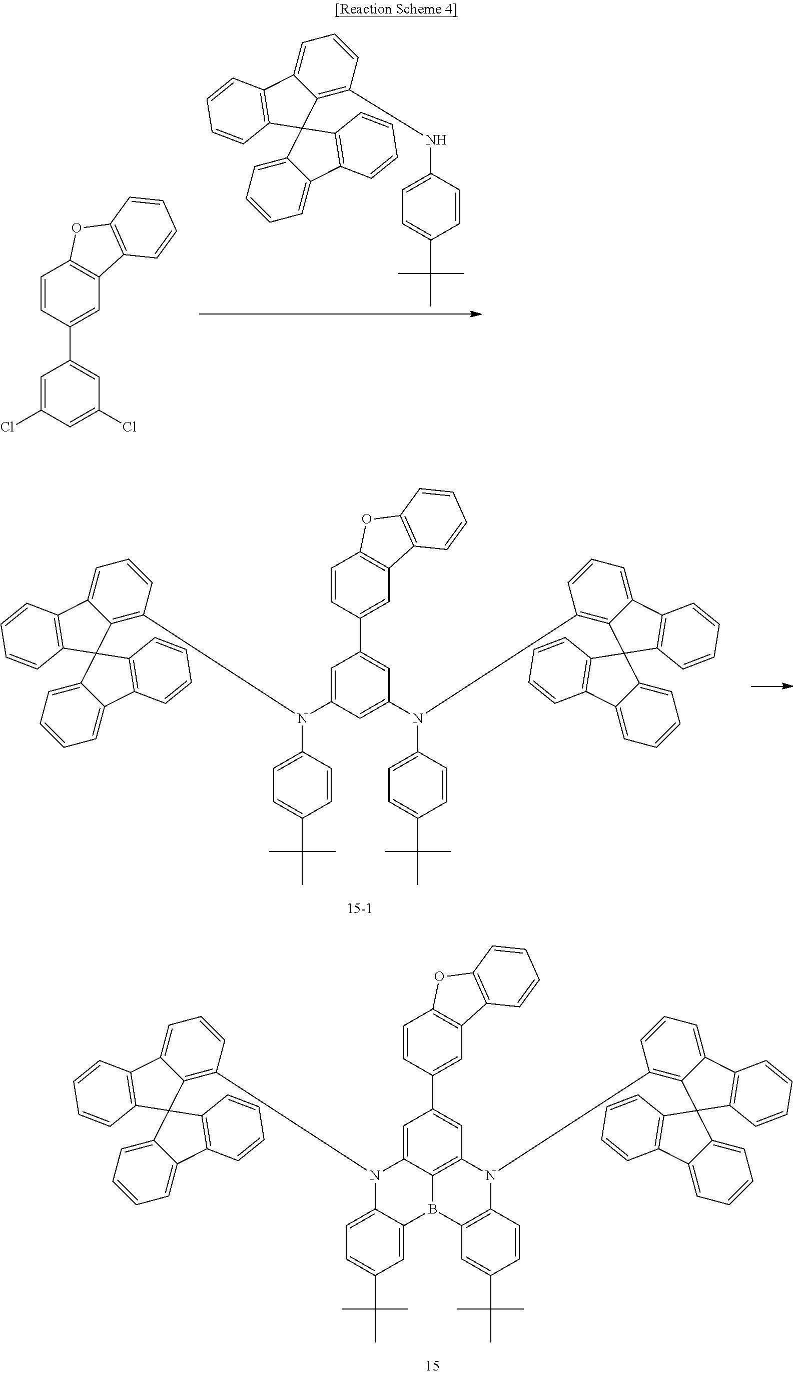 [SMILES: Clc1cc(Cl)cc(-c2ccc3oc4ccccc4c3c2)c1 ; CC(C)(C)c1ccc(Nc2cccc3c2C2(c4ccccc4-c4ccccc42)c2ccccc2-3)cc1 ; CC(C)(C)c1ccc(N(c2cc(-c3ccc4oc5ccccc5c4c3)cc(N(c3ccc(C(C)(C)C)cc3)c3cccc4c3C3(c5ccccc5-c5ccccc53)c3ccccc3-4)c2)c2cccc3c2C2(c4ccccc4-c4ccccc42)c2ccccc2-3)cc1 ; CC(C)(C)c1ccc2c(c1)B1c3cc(C(C)(C)C)ccc3N(c3cccc4c3C3(c5ccccc5-c5ccccc53)c3ccccc3-4)c3cc(-c4ccc5oc6ccccc6c5c4)cc(c31)N2c1cccc2c1C1(c3ccccc3-c3ccccc31)c1ccccc1-2]

1) Synthesis of Intermediate Compound 15-1

2-(3,5-dichlorophenyl)dibenzo[b,d]furan (1 eq), N-(4-(tert-butyl)phenyl)-9,9′-spirobi[fluoren]-1-amine (2 eq), tris(dibenzylideneacetone)dipalladium(0) (0.05 eq), tri-tert-butylphosphine (0.1 eq), and sodium tert-butoxide (3 eq) were dissolved in o-xylene, and the resultant mixture was stirred at about 140° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate Compound 15-1. (yield: 71%)

2) Synthesis of Compound 15

Intermediate Compound 15-1 (1 eq) was dissolved in ortho dichlorobenezene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After the mixture was cooled, the reaction was terminated by dropping triethylamine slowly in the flask containing the reactant, and ethyl alcohol was added to the reactant and extracted and filtered to obtain solids. The obtained solids were purified by column chromatography using MC and n-hexane, and were subjected to recrystallization using toluene and acetone to obtain Compound 15. (yield: 17%)

(5) Synthesis of Compound 32

Polycyclic Compound 32 according to an example may be synthesized by, for example, the steps shown in Reaction Scheme 5:

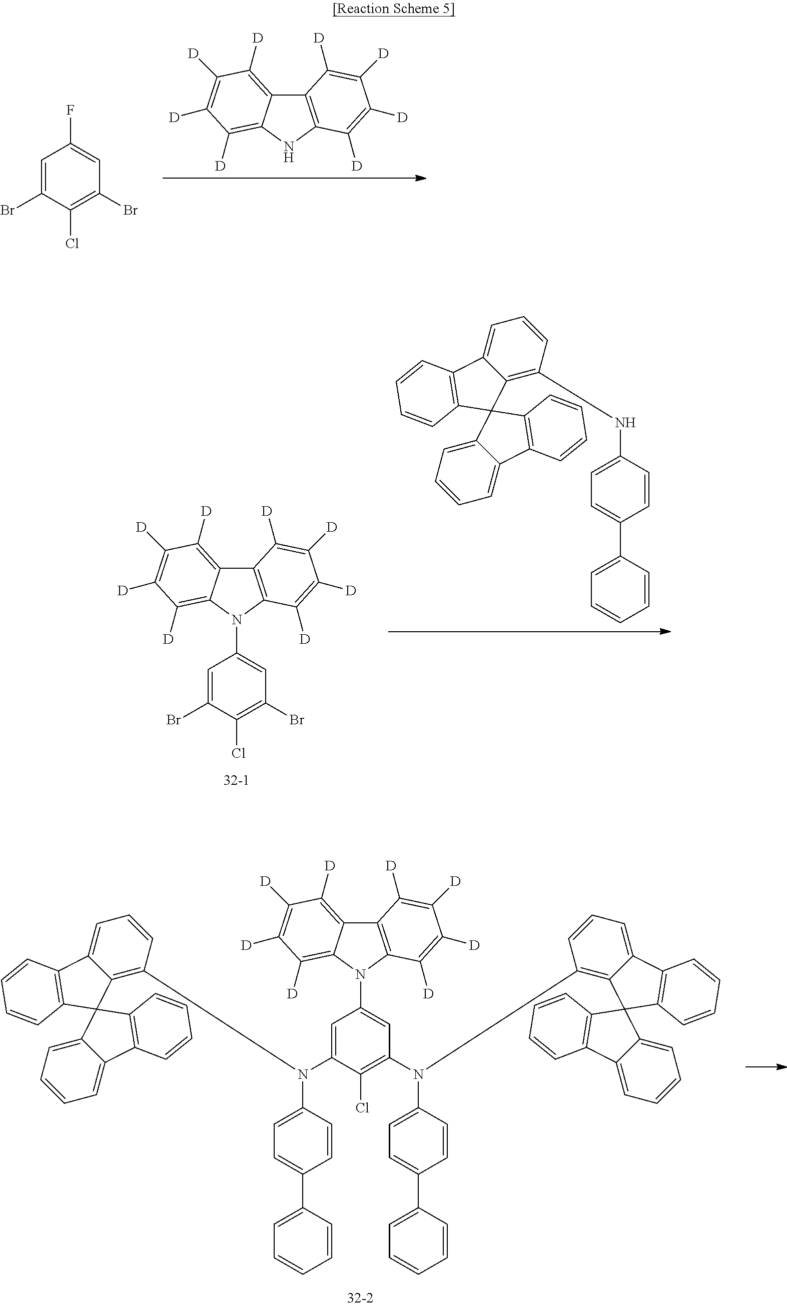 [SMILES: Fc1cc(Br)c(Cl)c(Br)c1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1cc(Br)c(Cl)c(Br)c1 ; c1ccc(-c2ccc(Nc3cccc4c3C3(c5ccccc5-c5ccccc53)c3ccccc3-4)cc2)cc1 ; [2H]c1c([2H])c([2H])c2c(c1[2H])c1c([2H])c([2H])c([2H])c([2H])c1n2-c1cc(N(c2ccc(-c3ccccc3)cc2)c2cccc3c2C2(c4ccccc4-c4ccccc42)c2ccccc2-3)c(Cl)c(N(c2ccc(-c3ccccc3)cc2)c2cccc3c2C2(c4ccccc4-c4ccccc42)c2ccccc2-3)c1]

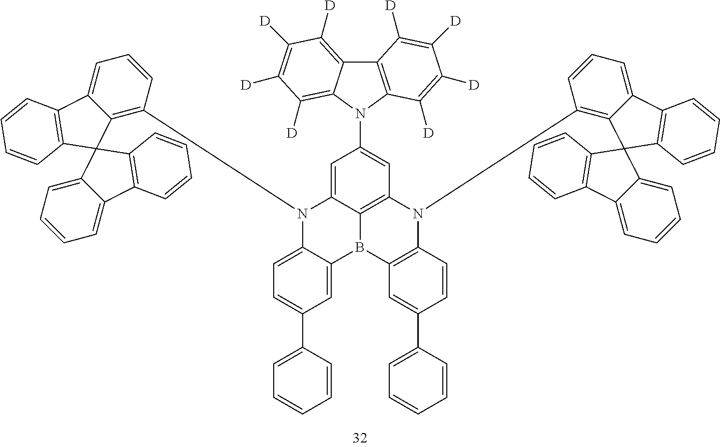 [SMILES: [2H]c1c([2H])c([2H])c2c(c1[2H])c1c([2H])c([2H])c([2H])c([2H])c1n2-c1cc2c3c(c1)N(c1cccc4c1C1(c5ccccc5-c5ccccc51)c1ccccc1-4)c1ccc(-c4ccccc4)cc1B3c1cc(-c3ccccc3)ccc1N2c1cccc2c1C1(c3ccccc3-c3ccccc31)c1ccccc1-2]

1) Synthesis of Intermediate Compound 32-1

1,3-dibromo-2-chloro-5-fluorobenzene (1 eq), carbazole-D8 (1.1 eq), and K₃PO₄ (2 eq) were dissolved in DMF and the resultant mixture was stirred at about 160° C. for about 16 hours. After the resultant mixture was cooled, the solvent was removed under reduced pressure, and the reactant was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate Compound 32-1. (yield: 85%)

2) Synthesis of Intermediate Compound 32-2

Intermediate Compound 32-1 (1 eq), N-([1,1′-biphenyl]-4-yl)-9,9′-spirobi[fluoren]-1-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate Compound 32-2. (yield: 41%)

3) Synthesis of Compound 32

Intermediate Compound 32-2 (1 eq) was dissolved in o-xylene, and cooled to about 0° C. in a nitrogen atmosphere. sec-BuLi (1.5 eq) was slowly injected thereto, the temperature was elevated to about 70° C., the resultant mixture was stirred for about 2 hours, and heated to about 120° C. and stirred for about 2 hours. The temperature of the reactor was cooled to about 0° C., and BBr₃ (2 eq) was slowly injected thereto. After dropping was completed, the mixture was stirred for about 1 hour. After the mixture was cooled to about 0° C., triethylamine (6 eq) was injected thereto, and the mixture was heated to about 140° C. and stirred for about 12 hours. After the mixture was cooled, the reaction was terminated by dropping triethylamine slowly in the flask containing the reactant, and ethyl alcohol was added to the reactant and extracted and filtered to obtain solids. The obtained solids were purified by column chromatography to obtain Compound 32. (yield: 14%)

(6) Synthesis of Compound 43

Polycyclic Compound 43 according to an example may be synthesized by, for example, the steps shown in Reaction Scheme 6:

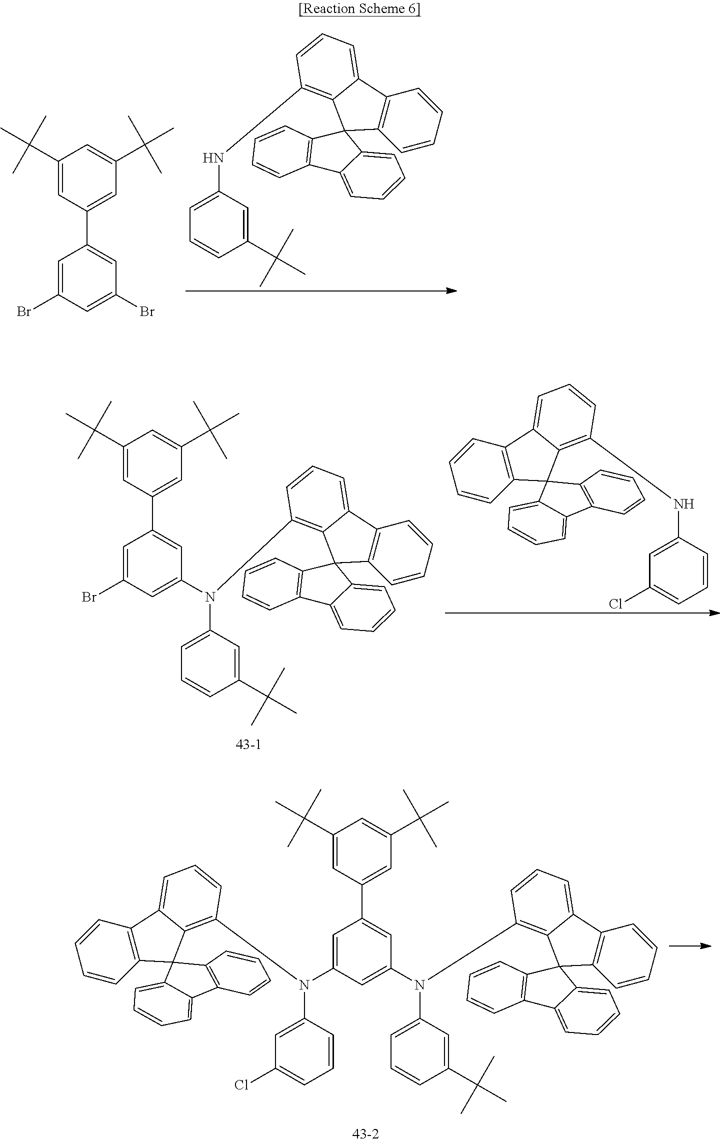

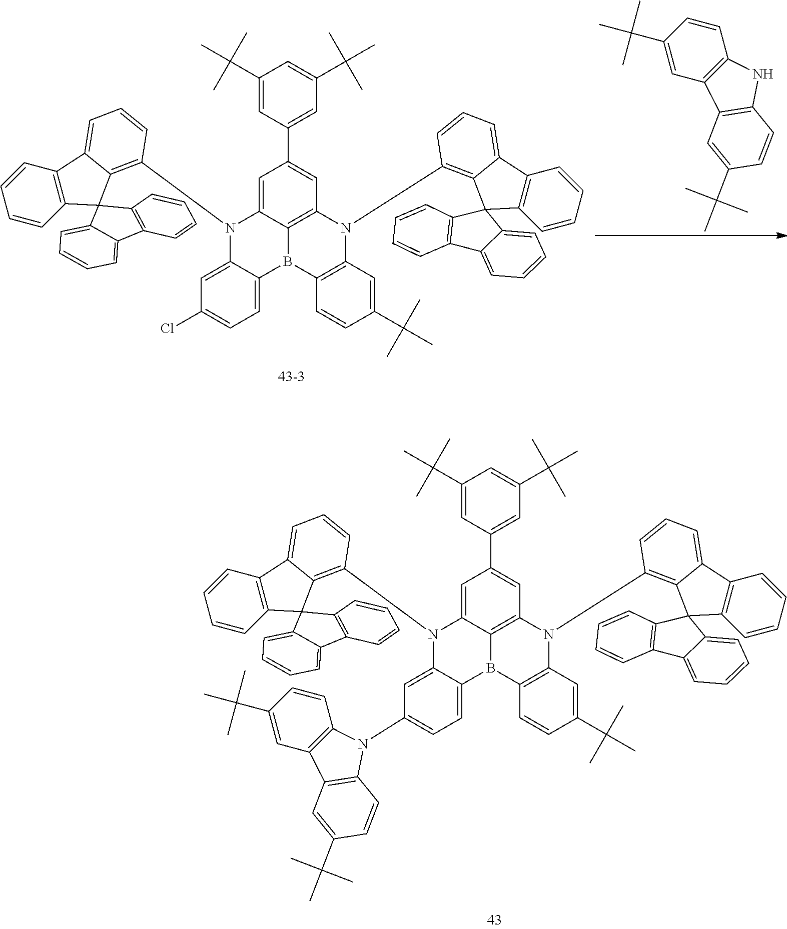 [SMILES: CC(C)(C)c1cc(-c2cc3c4c(c2)N(c2cccc5c2C2(c6ccccc6-c6ccccc62)c2ccccc2-5)c2cc(C(C)(C)C)ccc2B4c2ccc(Cl)cc2N3c2cccc3c2C2(c4ccccc4-c4ccccc42)c2ccccc2-3)cc(C(C)(C)C)c1 ; CC(C)(C)c1ccc2[nH]c3ccc(C(C)(C)C)cc3c2c1 ; CC(C)(C)c1cc(-c2cc3c4c(c2)N(c2cccc5c2C2(c6ccccc6-c6ccccc62)c2ccccc2-5)c2cc(C(C)(C)C)ccc2B4c2ccc(-n4c5ccc(C(C)(C)C)cc5c5cc(C(C)(C)C)ccc54)cc2N3c2cccc3c2C2(c4ccccc4-c4ccccc42)c2ccccc2-3)cc(C(C)(C)C)c1]

1) Synthesis of Intermediate Compound 43-1

3,5-dibromo-3′,5′-di-tert-butyl-1,1′-biphenyl (1 eq), N-(3-(tert-butyl)phenyl)-9,9′-spirobi[fluoren]-1-amine (1 eq), tris(dibenzylideneacetone)dipalladium(0) (0.05 eq), 1,1′-bis(diphenylphosphino)ferrocene (0.1 eq), and sodium tert-butoxide (3 eq) were dissolved in toluene, and the resultant mixture was stirred at about 80° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 43-1. (yield: 53%)

2) Synthesis of Intermediate Compound 43-2

Intermediate Compound 43-1 (1 eq), N-(3-chlorophenyl)-9,9′-spirobi[fluoren]-1-amine (1 eq), tris(dibenzylideneacetone)dipalladium(0) (0.05 eq), 1,1′-bis(diphenylphosphino)ferrocene (0.1 eq), and sodium tert-butoxide (3 eq) were dissolved in toluene and the resulting mixture was stirred at about 80° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate 43-2. (yield: 72%)

3) Synthesis of Intermediate Compound 43-3

Intermediate Compound 43-2 (1 eq) was dissolved in ortho dichlorobenezene, the mixture was cooled to about 0° C., and BBr₃ (5 eq) was slowly injected thereto in a nitrogen atmosphere. After dropping was completed, the temperature was elevated to 180° C., and the mixture was stirred for 24 hours. After the mixture was cooled, the reaction was terminated by dropping triethylamine slowly in the flask containing the reactant, and ethyl alcohol was added to the reactant and extracted and filtered to obtain solids. The obtained solids were purified by column chromatography using MC and n-hexane, and were subjected to recrystallization using toluene and acetone to obtain Intermediate Compound 43-3. (yield: 13%)

4) Synthesis of Compound 43

Intermediate Compound 43-3 (1 eq), 3,6-di-tert-butyl-9H-carbazole (1.5 eq), Tris(dibenzylideneacetone)dipalladium(0) (0.05 eq), tri-tert-butylphosphine (0.1 eq), and sodium tert-butoxide (3 eq) were dissolved in o-xylene, and the resultant mixture was stirred at about 150° C. for about 24 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Compound 43. (yield: 66%)

(7) Synthesis of Compound 48

Polycyclic Compound 48 according to an example may be synthesized by, for example, the steps shown in Reaction Scheme 7:

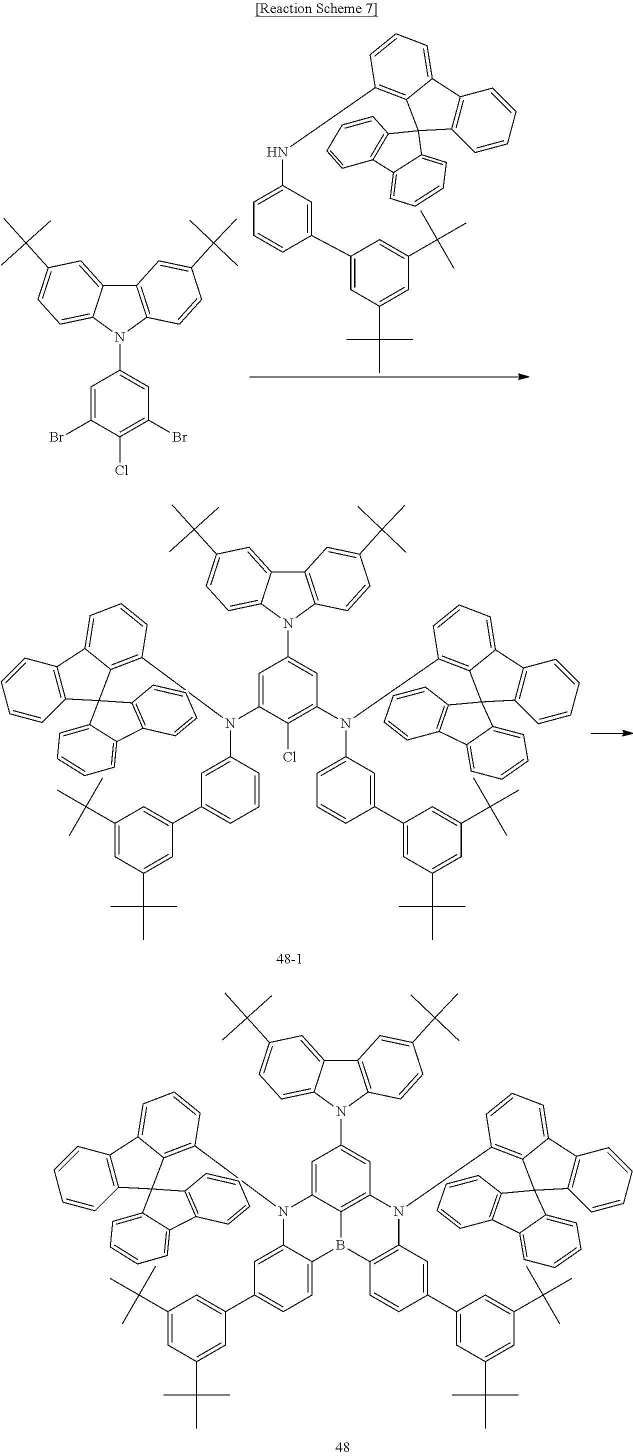

1) Synthesis of Intermediate Compound 48-1

3,6-di-tert-butyl-9-(3,5-dibromo-4-chlorophenyl)-9H-carbazole (1 eq), N-(3′,5′-di-tert-butyl-[1,1′-biphenyl]-3-yl)-9,9′-spirobi[fluoren]-1-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 12 hours. After the mixture was cooled, the reactant was washed three times with ethyl acetate and water, and separated to obtain an organic layer. The obtained organic layer was dried over MgSO₄, and dried under reduced pressure. The resulting product was purified by column chromatography using MC and n-hexane to obtain Intermediate Compound 48-1. (yield: 37%)

2) Synthesis of Compound 48

Intermediate Compound 48-1 (1 eq) was dissolved in o-xylene, and cooled to about 0° C. in a nitrogen atmosphere. sec-BuLi (1.5 eq) was slowly injected thereto, the temperature was elevated to about 70° C., the resultant mixture was stirred for about 2 hours, and heated to about 120° C. and stirred for about 2 hours. The temperature of the reactor was cooled to about 0° C., and BBr₃ (2 eq) was slowly injected thereto. After dropping was completed, the mixture was stirred for about 1 hour. After the mixture was cooled to about 0° C., triethylamine (3 eq) was injected thereto, and the mixture was heated to about 140° C. and stirred for about 12 hours. After the mixture was cooled, the reaction was terminated by dropping triethylamine slowly in the flask containing the reactant, and ethyl alcohol was added to the reactant and extracted and filtered to obtain solids. The obtained solids were purified by column chromatography to obtain Compound 48. (yield: 12%)

TABLE 1

| | | | MS |
|---|---|---|---|
| Compound | ¹H NMR chemical shift (500 MHz) | MS (Cal) | (Meas.) |
| 3 | 8.92-8.88 (2H, d), 8.00-7.86 (6H, d), 7.83-7.71 (14H, m), | 1105.176 | 1105.169 |
| | 7.40-7.35 (6H, d), 7.32-7.29 (8H, m), 7.27-7.23 (6H, m), | | |
| | 7.18-7.15 (2H, m), 7.04-7.01 (2H, m), 6.15-6.10 (2H, s), | | |
| | 1.53-1.50 (9H, s) | | |
| 4 | 8.98-8.94 (2H, d), 8.01-7.86 (6H, d) 7.82-7.78 (6H, | 1329.601 | 1329.588 |
| | m)7.52-7.42 (4H, m), 7.40-7.32 (14H, m), 7.28-7.25 | | |
| | (6H, m), | | |
| | 7.17-7.15 (2H, m), 7.07-7.03 (2H, m), 6.31-6.25 (2H, s) | | |
| | 1.55-1.52 (9H, s), 1.47-1.43 (36H, s) | | |
| 11 | 8.81-8.74 (2H, d), 7.99-7.92 (6H, d), 7.78-7.74 (2H, d) | 1299.464 | 1299.451 |
| | 7.42-7.35 (16H, m) 7.27-7.25 (6H, m), 7.17-7.15 (2H, m) | | |
| | 6.99-6.95 (2H, m), 6.19-6.15 (2H, s), 1.53-1.50 (9H, s) | | |
| 15 | 8.55-8.48 (2H, s), 7.98-7.93 (8H, d), 7.78-7.74 (2H, | 1175.266 | 1175.258 |
| | d)7.62-7.56 (2H, m), 7.53-7.47 (2H, m), 7.43-7.36 (7H, m) | | |
| | 7.34-7.32 (8H, m) 7.27-7.25 (6H, m), 7.17-7.10 (4H, m) | | |
| | 6.86-6.77 (2H, m), 6.64-6.56 (2H, s), 1.45-1.42 (18H, s) | | |
| 32 | 9.04-9.01 (2H, s) 8.05-7.98 (6H, d), 7.83-7.71 (14H, | 1222.309 | 1222.289 |
| | m)7.40-7.35 (6H, d), 7.34-7.32 (8H, m), 7.27-7.25 (6H, m), | | |
| | 7.17-7.15 (2H, m), 7.04-7.01 (2H, m), 6.55-6.51 (2H, s) | | |
| 43 | 8.94-8.88 (2H, d), 8.11-8.07 (2H, s) 8.00-7.86 (6H, d) | 1418.696 | 1418.688 |
| | 7.78-7.74 (2H, d), 7.55-7.44 (5H, m), 7.41-7.32 (8H, m) | | |
| | 7.34-7.31 (8H, m), 7.27-7.25 (6H, m), 7.17-7.15 (2H, m), | | |
| | 7.11-7.04 (2H, d), 6.64-6.57 (2H, m), 6.44-6.39 (2H, s) | | |
| | 1.58-1.52 (45H, m) | | |
| 48 | 9.01-8.97 (2H, s), 8.13-8.09 (2H, s), 8.01-7.76 (12H, d) | 1550.898 | 1550.882 |
| | 7.50-7.43 (6H, m), 7.40-7.32 (16H, m), 7.27-7.25 (6H, m), | | |
| | 7.17-7.15 (2H, m), 7.04-7.01 (2H, m), 6.55-6.51 (2H, s) | | |
| | 1.57-1.42 (54H, m) | | |

### 2. Example and Comparative Example Compounds

The Example Compounds and the Comparative Example Compounds which were used to manufacture light emitting elements of the Examples and the Comparative Examples are listed in Table 2:

TABLE 2

| | |
|---|---|
| Compound 3 | 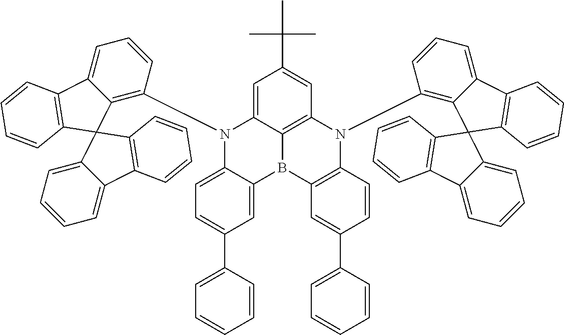 [SMILES: CC(C)(C)c1cc2c3c(c1)N(c1cccc4c1C1(c5ccccc5-c5ccccc51)c1ccccc1-4)c1ccc(-c4ccccc4)cc1B3c1cc(-c3ccccc3)ccc1N2c1cccc2c1C1(c3ccccc3-c3ccccc31)c1ccccc1-2] |
| | 3 |
| Compound 4 | 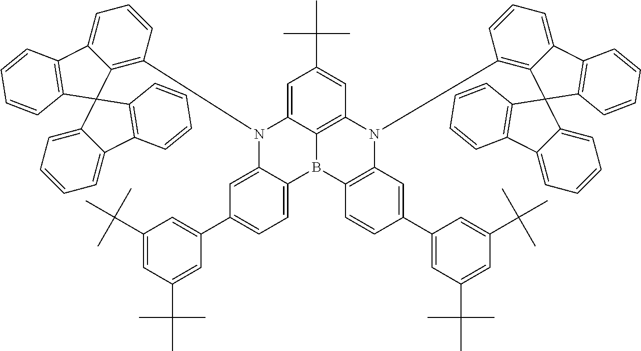 [SMILES: CC(C)(C)c1cc(-c2ccc3c(c2)N(c2cccc4c2C2(c5ccccc5-c5ccccc52)c2ccccc2-4)c2cc(C(C)(C)C)cc4c2B3c2ccc(-c3cc(C(C)(C)C)cc(C(C)(C)C)c3)cc2N4c2cccc3c2C2(c4ccccc4-c4ccccc42)c2ccccc2-3)cc(C(C)(C)C)c1] |
| | 4 |
| Compound 11 | 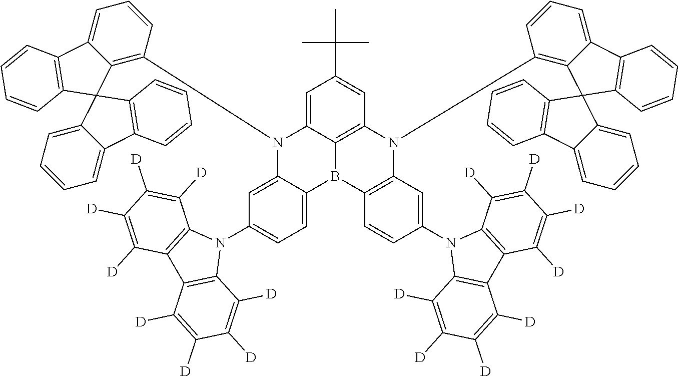 [SMILES: [2H]c1c([2H])c([2H])c2c(c1[2H])c1c([2H])c([2H])c([2H])c([2H])c1n2-c1ccc2c(c1)N(c1cccc3c1C1(c4ccccc4-c4ccccc41)c1ccccc1-3)c1cc(C(C)(C)C)cc3c1B2c1ccc(-n2c4c([2H])c([2H])c([2H])c([2H])c4c4c([2H])c([2H])c([2H])c([2H])c42)cc1N3c1cccc2c1C1(c3ccccc3-c3ccccc31)c1ccccc1-2] |
| | 11 |
| Compound 15 | 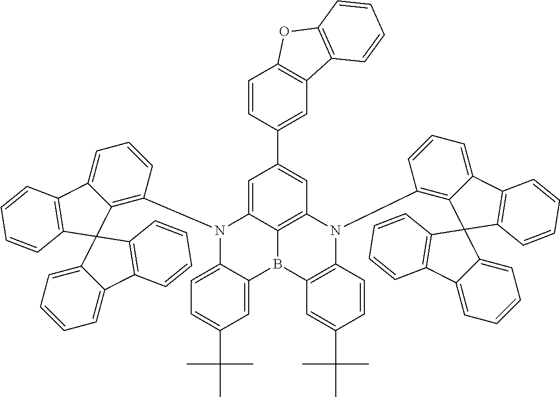 [SMILES: CC(C)(C)c1ccc2c(c1)B1c3cc(C(C)(C)C)ccc3N(c3cccc4c3C3(c5ccccc5-c5ccccc53)c3ccccc3-4)c3cc(-c4ccc5oc6ccccc6c5c4)cc(c31)N2c1cccc2c1C1(c3ccccc3-c3ccccc31)c1ccccc1-2] |
| | 15 |
| Compound 32 | 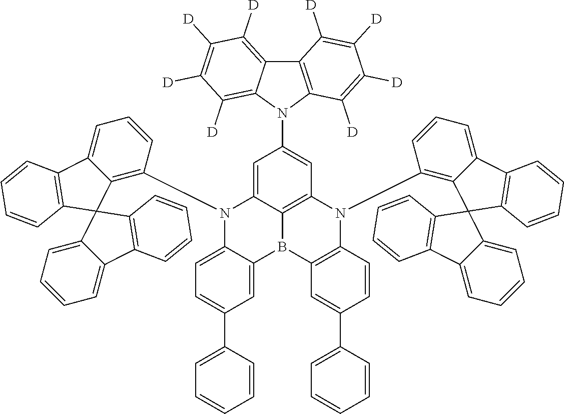 [SMILES: [2H]c1c([2H])c([2H])c2c(c1[2H])c1c([2H])c([2H])c([2H])c([2H])c1n2-c1cc2c3c(c1)N(c1cccc4c1C1(c5ccccc5-c5ccccc51)c1ccccc1-4)c1ccc(-c4ccccc4)cc1B3c1cc(-c3ccccc3)ccc1N2c1cccc2c1C1(c3ccccc3-c3ccccc31)c1ccccc1-2] |
| | 32 |
| Compound 43 | 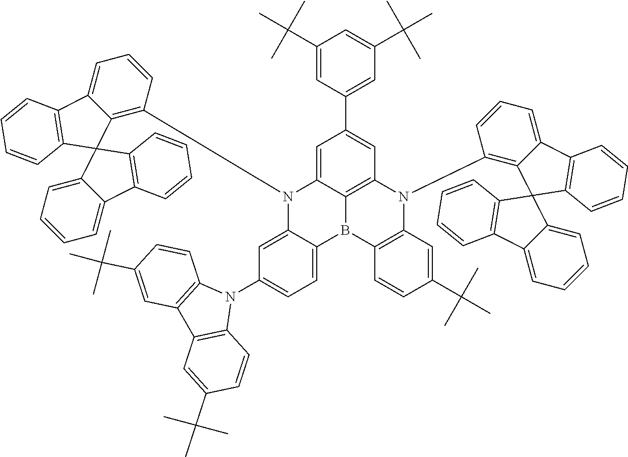 [SMILES: CC(C)(C)c1cc(-c2cc3c4c(c2)N(c2cccc5c2C2(c6ccccc6-c6ccccc62)c2ccccc2-5)c2cc(C(C)(C)C)ccc2B4c2ccc(-n4c5ccc(C(C)(C)C)cc5c5cc(C(C)(C)C)ccc54)cc2N3c2cccc3c2C2(c4ccccc4-c4ccccc42)c2ccccc2-3)cc(C(C)(C)C)c1] |
| | 43 |
| Compound 48 | 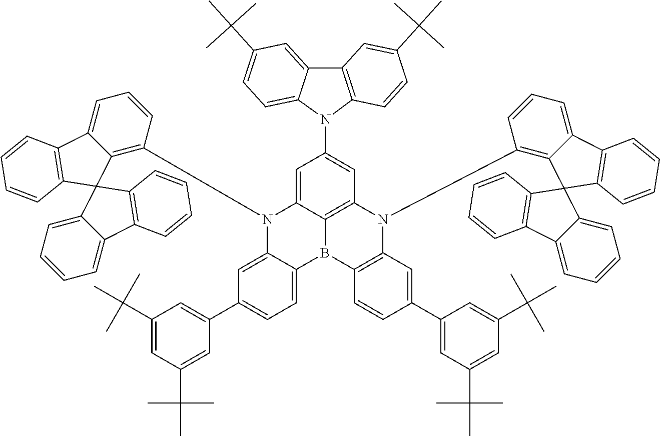 [SMILES: CC(C)(C)c1cc(-c2ccc3c(c2)N(c2cccc4c2C2(c5ccccc5-c5ccccc52)c2ccccc2-4)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2cccc3c2C2(c4ccccc4-c4ccccc42)c2ccccc2-3)cc(C(C)(C)C)c1] |
| | 48 |
| Comparative Example Compound C1 | 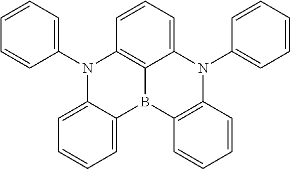 [SMILES: c1ccc(N2c3ccccc3B3c4ccccc4N(c4ccccc4)c4cccc2c43)cc1] |
| | C1 |
| Comparative Example Compound C2 | 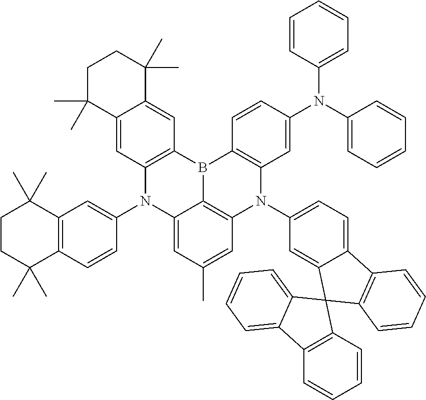 [SMILES: Cc1cc2c3c(c1)N(c1ccc4c(c1)C(C)(C)CCC4(C)C)c1cc4c(cc1B3c1ccc(N(c3ccccc3)c3ccccc3)cc1N2c1ccc2c(c1)C1(c3ccccc3-c3ccccc31)c1ccccc1-2)C(C)(C)CCC4(C)C] |
| | C2 |
| Comparative Example Compound C3 | 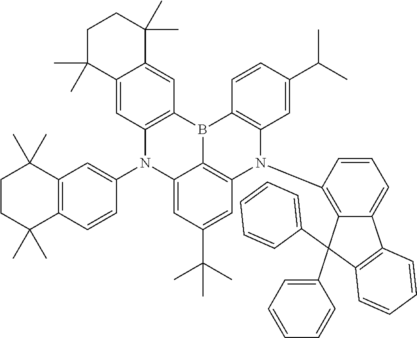 [SMILES: CC(C)c1ccc2c(c1)N(c1cccc3c1C(c1ccccc1)(c1ccccc1)c1ccccc1-3)c1cc(C(C)(C)C)cc3c1B2c1cc2c(cc1N3c1ccc3c(c1)C(C)(C)CCC3(C)C)C(C)(C)CCC2(C)C] |
| | C3 |

### 3. Manufacture and Evaluation of Light Emitting Elements

(1) Manufacture of Light Emitting Elements

The light emitting elements were manufactured using the Example Compounds and the Comparative Example Compounds as a dopant material for the emission layer.

A glass substrate (made by Corning Co.), on which an ITO electrode of about 15 Ω/cm² (about 1200 Å) is formed as an anode, was cut to a size of about 50 mm×50 mm×0.7 mm, cleansed by ultrasonic waves using isopropyl alcohol and pure water for about five minutes, and irradiated with ultraviolet rays for about 30 minutes and exposed to ozone and cleansed. The glass substrate was installed on a vacuum deposition apparatus.

NPD was deposited on the upper portion of the anode to form a 300 Å-thick hole injection layer, H-1-1 was deposited on the upper portion of the hole injection layer to form a 200 Å-thick hole transport layer, and CzSi was deposited on the upper portion of the hole transport layer to form a 100 Å-thick emission-auxiliary layer.

On the upper portion of the emission-auxiliary layer, a host mixture, a phosphorescent sensitizer, and a dopant of an Example Compound or a Comparative Example Compound were co-deposited at a weight ratio of 85:14:1 to form a 200 Å-thick emission layer. The host mixture was provided by mixing a first host (HT1, HT2, HT3, and HT4) and a second host (ET85, ET66, and ET86) at a weight ratio of 5:5 as shown in Table 3. PS1 or PS2 was used as the phosphorescent sensitizer as shown in Table 3.

TSP01 was deposited on the upper portion of the emission layer to form a 200 Å-thick hole blocking layer, TPBI was deposited on the upper portion of the hole blocking layer to form a 300 Å-thick electron transport layer, LiF was deposited on the upper portion of the electron transport layer to form a 10 Å-thick electron injection layer, and Al was deposited on the upper portion of the electron injection layer to form a 3,000 Å-thick cathode, thereby manufacturing a light emitting element.

The compounds used to manufacture the light emitting element are as follows:

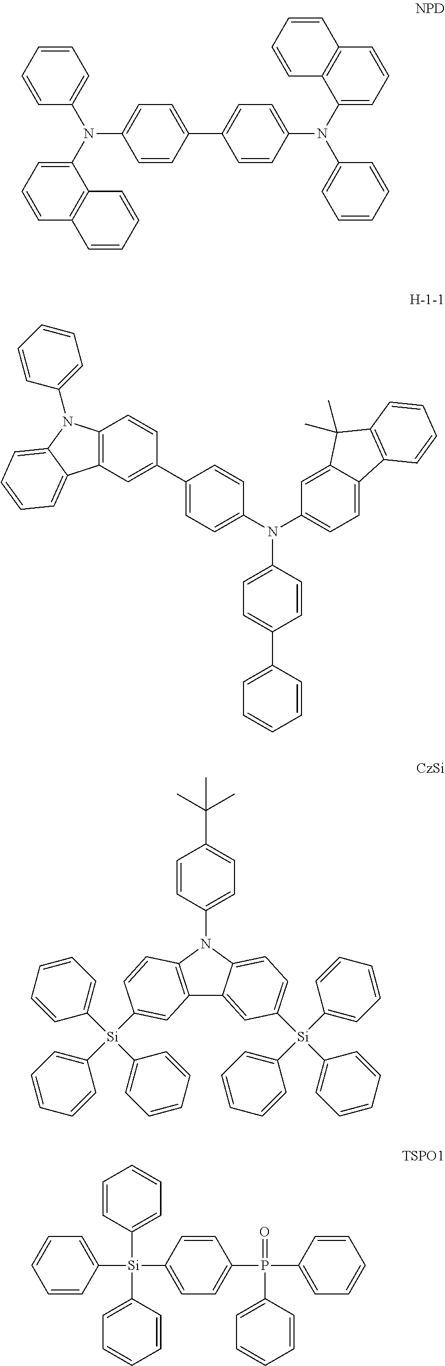 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; O=P(c1ccccc1)(c1ccccc1)c1ccc([Si](c2ccccc2)(c2ccccc2)c2ccccc2)cc1]

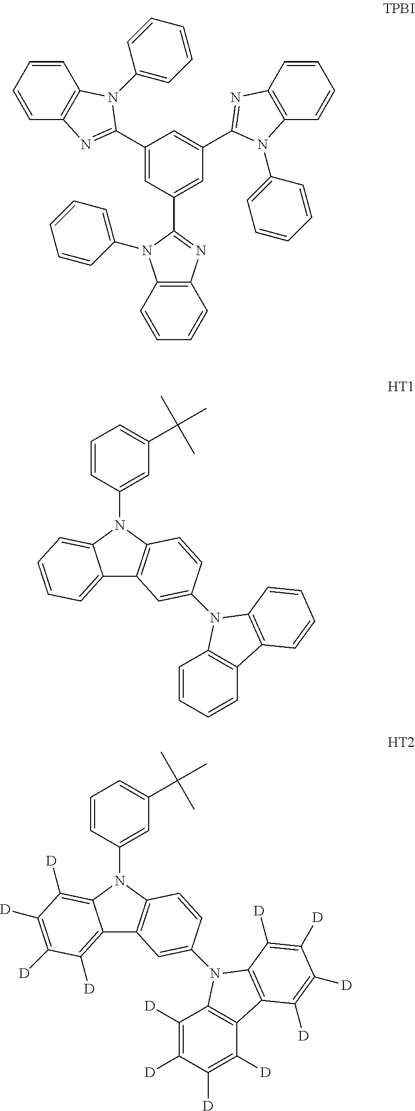 [SMILES: c1ccc(-n2c(-c3cc(-c4nc5ccccc5n4-c4ccccc4)cc(-c4nc5ccccc5n4-c4ccccc4)c3)nc3ccccc32)cc1 ; CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

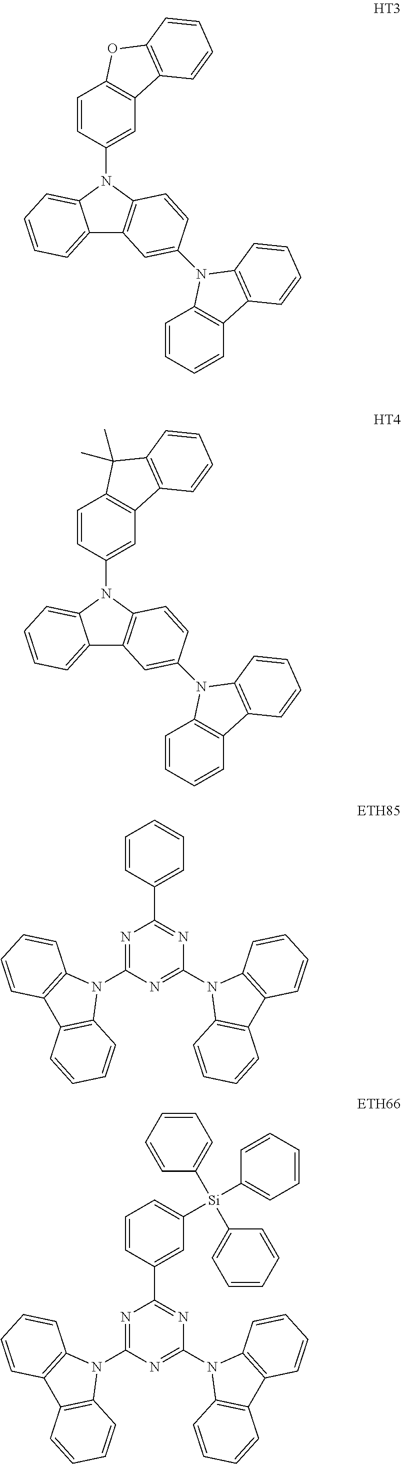

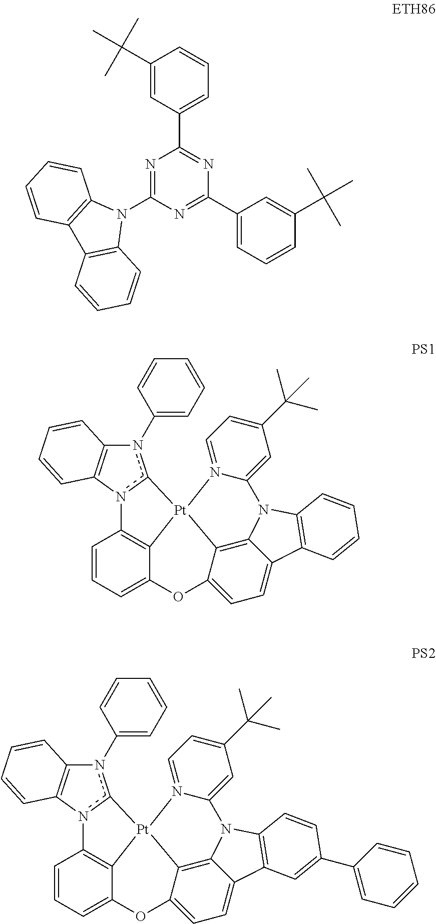

(2) Evaluation of Light Emitting Elements

Driving voltages (V), luminous efficiencies (cd/A), luminescence wavelengths (nm), and element service lives of the light emitting elements of Examples 1 to 13 and Comparative Examples 1 to 4 were evaluated, and the results are listed in Table 3. In the evaluation results of characteristics of the light emitting elements of Examples and Comparative Examples, the driving voltage (V), luminous efficiency (cd/A), and luminescence wavelength at a current density of 1,000 cd/m2 were each measured by using Keithley MU 236 and a luminance meter PR650. For the service life ratio (T₉₅), the time taken to reach 95% brightness relative to an initial brightness was measured, and a relative service life was calculated based on Comparative Example 2, and the results are listed in Table 3.

TABLE 3

| | | | | Driving | | Luminescence | Service |
|---|---|---|---|---|---|---|---|
| | Exciplex Host | Phosphorescent | | voltage | Efficiency | wavelength | life ratio |
| | (HT:ET = 5:5) | sensitizer | Dopant | (V) | (cd/A) | (nm) | (T⁹⁵) |
| Example 1 | HT2/ETH66 | PS2 | 3 | 4.4 | 26.5 | 462 | 5.8 |
| Example 2 | HT2/ETH66 | PS2 | 4 | 4.4 | 26.4 | 463 | 6.0 |
| Example 3 | HT2/ETH66 | PS2 | 11 | 4.3 | 27.3 | 458 | 6.9 |
| Example 4 | HT2/ETH66 | PS2 | 15 | 4.5 | 26.2 | 459 | 5.2 |
| Example 5 | HT2/ETH66 | PS2 | 32 | 4.5 | 26.6 | 458 | 5.8 |
| Example 6 | HT2/ETH66 | PS2 | 43 | 4.5 | 26.1 | 458 | 6.5 |
| Example 7 | HT2/ETH66 | PS2 | 48 | 4.6 | 25.8 | 460 | 6.3 |
| Example 8 | HT3/ETH86 | PS1 | 3 | 4.5 | 26.8 | 462 | 6.3 |
| Example 9 | HT3/ETH86 | PS1 | 11 | 4.3 | 27.4 | 460 | 6.9 |
| Example 10 | HT1/ETH86 | PS1 | 32 | 4.2 | 26.4 | 459 | 5.8 |
| Example 11 | HT1/ETH86 | PS1 | 43 | 4.3 | 26.7 | 460 | 6.6 |
| Example 12 | HT4/ETH85 | PS2 | 15 | 4.4 | 25.8 | 461 | 5.3 |
| Example 13 | HT4/ETH85 | PS2 | 48 | 4.5 | 25.9 | 460 | 6.2 |
| Comparative | HT2/ETH66 | x | C1 | 5.6 | 13.2 | 459 | — |
| Example 1 | | | | | | | |
| Comparative | HT2/ETH66 | PS2 | C1 | 5.5 | 14.8 | 464 | 1.0 |
| Example 2 | | | | | | | |
| Comparative | HT2/ETH66 | PS2 | C2 | 5.3 | 20.3 | 456 | 2.6 |
| Example 3 | | | | | | | |
| Comparative | HT2/ETH66 | PS2 | C3 | 5.2 | 21.2 | 459 | 3.3 |
| Example 4 | | | | | | | |

Referring to Table 3, it can be seen that Examples 1 to 13 all achieve long service life and high efficiency as compared with Comparative Examples 1 to 4. It can be seen that Examples 1 to 13 exhibit lower driving voltage characteristics than those of Comparative Examples 1 to 4.

The Comparative Compounds used in Comparative Examples 1 and 2 each have structures that do not include a spiro-bifluorene substituent having a high steric hindrance at two nitrogen atoms of the core moiety, unlike the Example Compounds. Accordingly, Comparative Examples 1 and 2 exhibit relatively higher driving voltage characteristics than those of Examples, and exhibit reduced luminous efficiency and service life characteristics. For example, Comparative Example 1 exhibits significantly reduced results so that the service life characteristic cannot be measured.

The Comparative Compounds used in Comparative Examples 3 and 4 have structures in which a spiro-bifluorene substituent having a high steric hindrance is bonded at only one nitrogen atom of the two nitrogen atoms of the core moiety, unlike the Example Compounds. Accordingly, Comparative Examples 3 and 4 exhibit reduced luminous efficiency and service life characteristics as compared with Examples, and also exhibit poor results in terms of driving voltage characteristics.

In the polycyclic compound according to an embodiment, the spiro-bifluorene substituents having a high steric hindrance are each bonded to two nitrogen atoms of the core moiety, and thus may protect the core moiety. The polycyclic compound according to an embodiment has a structure in which the core moiety and the two spiro-bifluorene substituents overlap on a same plane, and thus may exhibit an effect of additionally suppressing rotation, and have a great effect of shielding the p-orbital of the boron atom. Accordingly, the polycyclic compound according to an embodiment has a decrease in the structural degree of freedom, and thus may prevent the deterioration of optical characteristics (Stokes shift, FWHM, etc.), and contribute to the improvement of luminous efficiency and service life.

The light emitting element according to an embodiment may include the polycyclic compound according to an embodiment, thereby exhibiting high efficiency and long service life characteristics.

The polycyclic compound according to an embodiment may include a boron-containing core moiety and a spiro-bifluorene substituent, thereby contributing to service life improvement and luminous efficiency increase of the light emitting element.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein the emission layer comprises:
a first compound represented by Formula 1; and
at least one of a second compound represented by Formula HT-1, a third compound represented by Formula ET-1, or a fourth compound represented by Formula M-b: 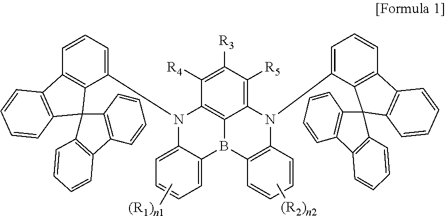
wherein in Formula 1,
R₁ and R₂ are each independently a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₃ is a substituted or unsubstituted amine group, a substituted or unsubstituted silyl group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
R₄ and R₅ are each independently a hydrogen atom or a deuterium atom, and
n1 and n2 are each independently an integer from 0 to 4; 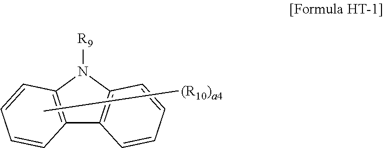
wherein in Formula HT-1,
a4 is an integer from 0 to 8, and
R₉ and R₁₀ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms; 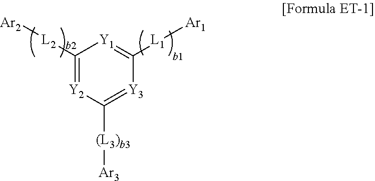
wherein in Formula ET-1,
at least one of Y₁ to Y₃ is each N,
the remainder of Y₁ to Y₃ are each independently C(Rₐ),
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and 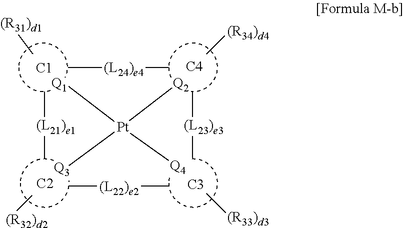
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heterocyclic group having 2 to 30 ring-forming carbon atoms,
e1 to e4 are each independently 0 or 1,
L₂₁ to L₂₄ are each independently a direct linkage, 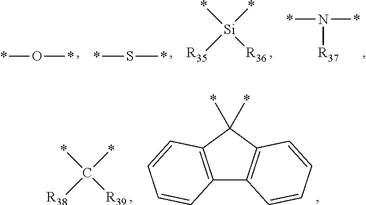
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

2. The light emitting element of claim 1, wherein the first compound represented by Formula 1 is represented by one of Formula 1-1 to Formula 1-3: 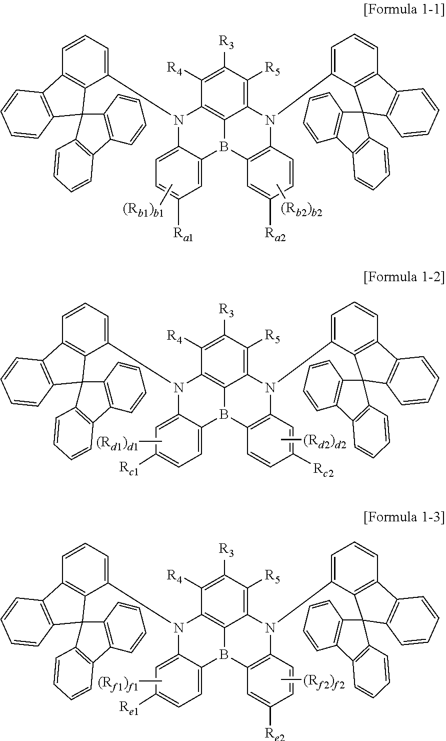
wherein in Formula 1-1 to Formula 1-3,
Rₐ₁, Rₐ₂, R_{c1}, R_{c2}, Rₑ₁, and Rₑ₂ are each independently a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a substituted or unsubstituted heterocycle,
R_{b1}, R_{b2}, Rₐ₁, Rₐ₂, R_{f1}, and R_{f2} are each independently a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a substituted or unsubstituted heterocycle,
b1, b2, d1, d2, f1, and f2 are each independently an integer from 0 to 3, and
R₃ to R₅ are each the same as defined in Formula 1.

3. The light emitting element of claim 2, wherein the first compound represented by Formula 1 is represented by one of Formula 2-1 to Formula 2-7: 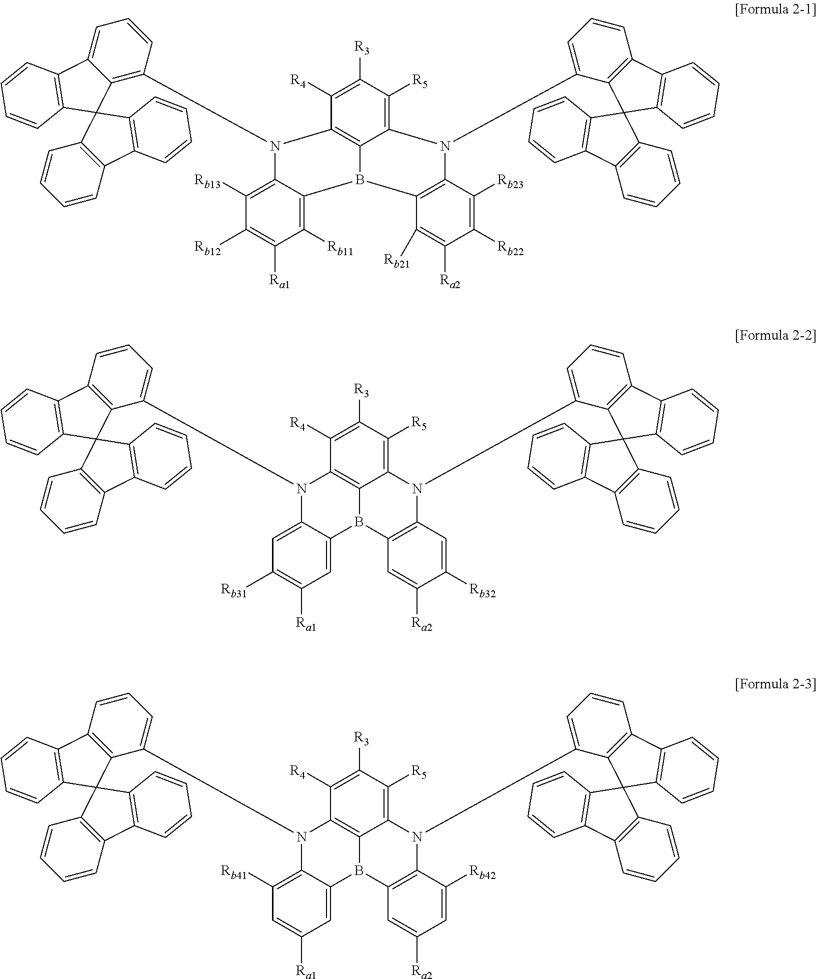 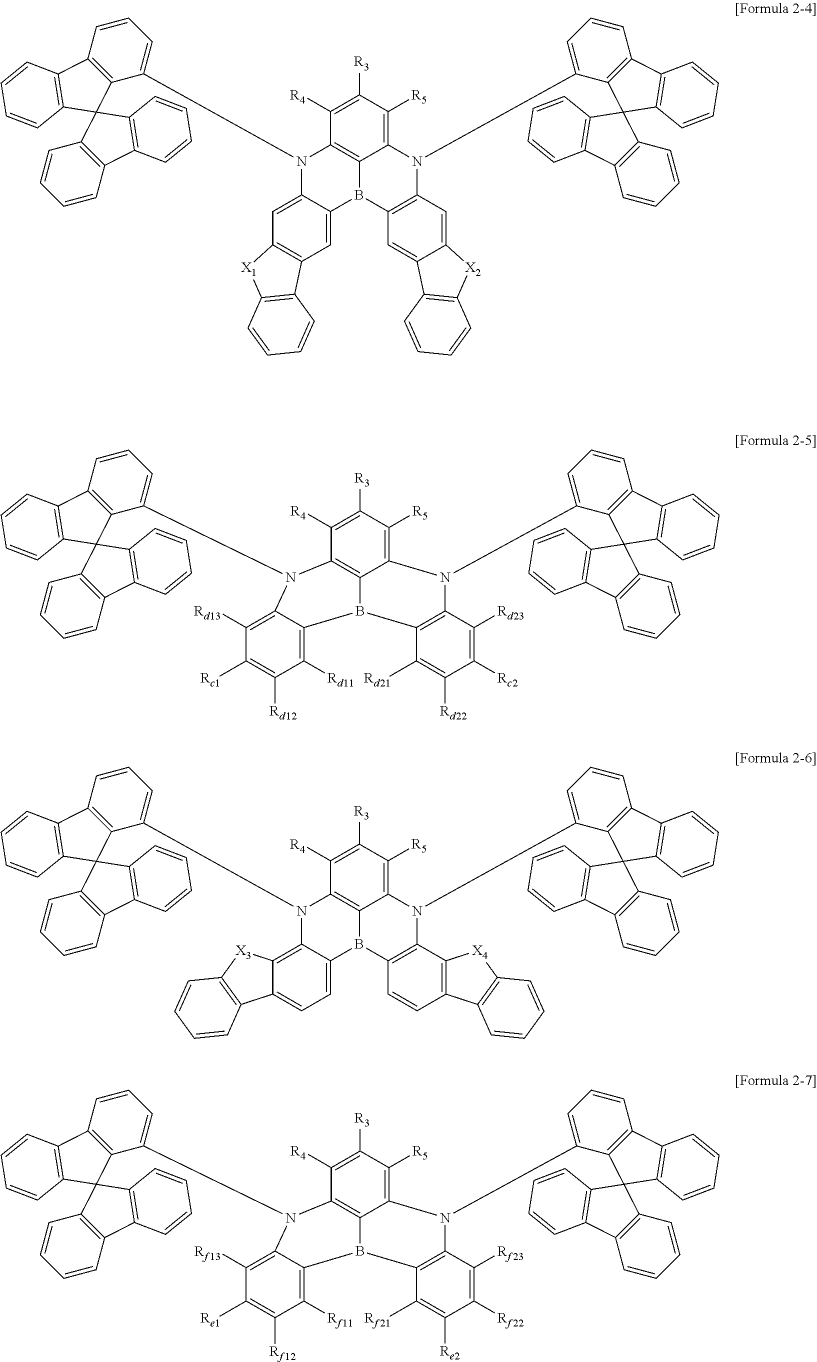
wherein in Formula 2-1 to Formula 2-7,
R_{b11} to R_{b13}, R_{b21} to R_{b23}, R_{d11} to R_{d13}, R_{d21} to R_{d23}, R_{f11} to R_{f13}, and R_{f21} to R_{f23} are each independently a hydrogen atom or a deuterium atom,
R_{b31}, R_{b32}, R_{b41}, and R_{b42} are each independently a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
X₁ to X₄ are each independently O, S, or N(Rₓ₁),
Rₓ₁ is a substituted or unsubstituted aryl group having 6 to 20 ring-forming carbon atoms, and
Rₐ₁, Rₐ₂, R_{c1}, R_{c2}, Rₑ₁, Rₑ₂, and R₃ to R₅ are each the same as defined in Formula 1 and Formula 1-1 to Formula 1-3.

4. The light emitting element of claim 1, wherein the first compound represented by Formula 1 is represented by Formula 3: 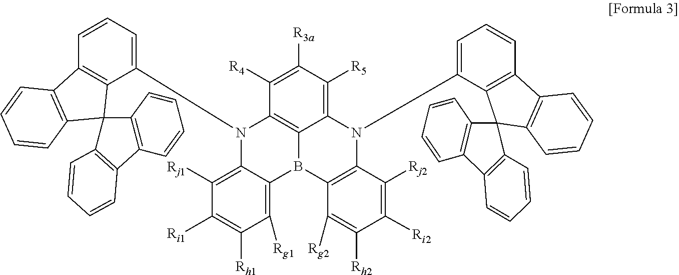
wherein in Formula 3,
R_{g1}, R_{g2}, Rₕ₁, Rₕ₂, Rᵢ₁, Rᵢ₂, Rⱼ₁, and Rⱼ₂ are each independently a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, or are bonded to an adjacent group to form a substituted or unsubstituted heterocycle,
R₃ₐ is a substituted or unsubstituted alkyl group having 1 to 10 carbon atoms, a substituted or unsubstituted carbazole group, a substituted or unsubstituted indolocarbazole group, a substituted or unsubstituted phenyl group, a substituted or unsubstituted fluorenyl group, a substituted or unsubstituted dibenzofuran group, a substituted or unsubstituted diphenylamine group, or a substituted or unsubstituted triphenylsilyl group, and
R₄ and R₅ are each the same as defined in Formula 1.

5. The light emitting element of claim 4, wherein the first compound represented by Formula 3 is represented by one of Formula 3-1 to Formula 3-3: 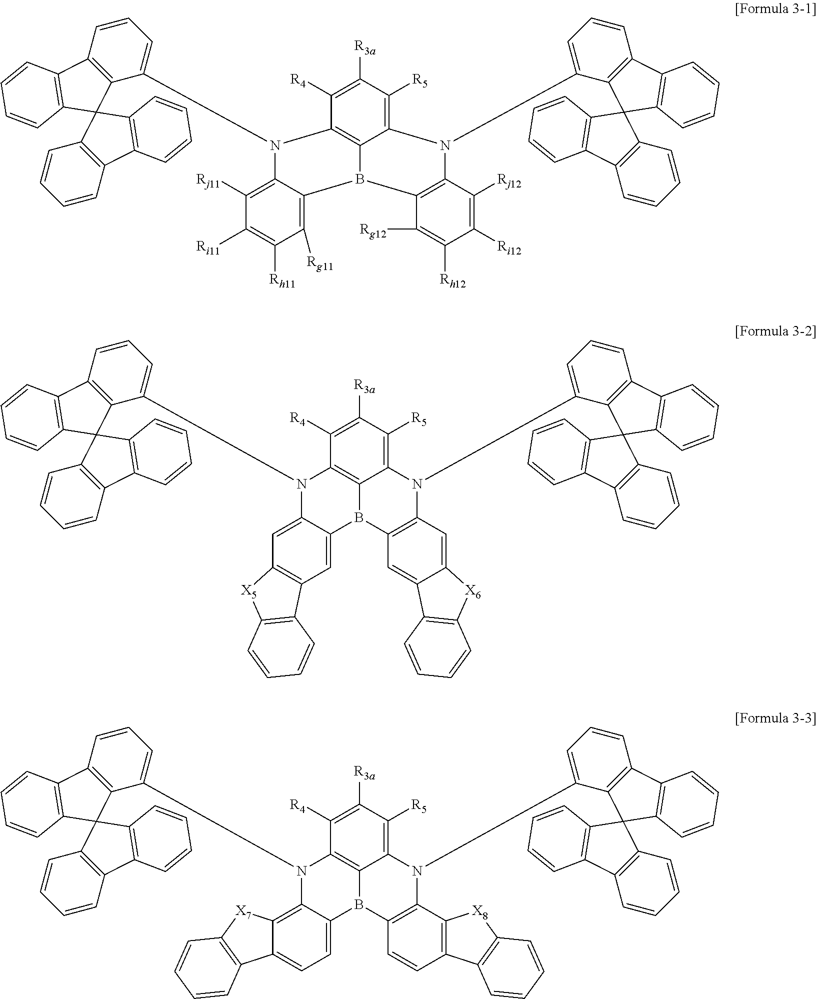
wherein in Formula 3-1,
R_{g11}, Rₕ₁₁, Rᵢ₁₁, Rⱼ₁₁, R_{g12}, Rₕ₁₂, Rᵢ₁₂, and Rⱼ₁₂ are each independently a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, and
at least one of R_{g11}, Rₕ₁₁, Rᵢ₁₁, or Rⱼ₁₁ and at least one of R_{g12}, Rₕ₁₂, Rᵢ₁₂, or Rⱼ₁₂ are each independently a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms,
wherein in Formula 3-2 and Formula 3-3,
X₅ to X₈ are each independently O, S, or N(Rₓ₂), and
Rₓ₂ is a substituted or unsubstituted aryl group having 6 to 20 ring-forming carbon atoms, and
wherein in Formula 3-1 to Formula 3-3,
R₃ₐ, R₄, and R₅ are each the same as defined in Formula 1 and Formula 3.

6. The light emitting element of claim 1, wherein R₃ is a group represented by one of R3-1 to R3-8: 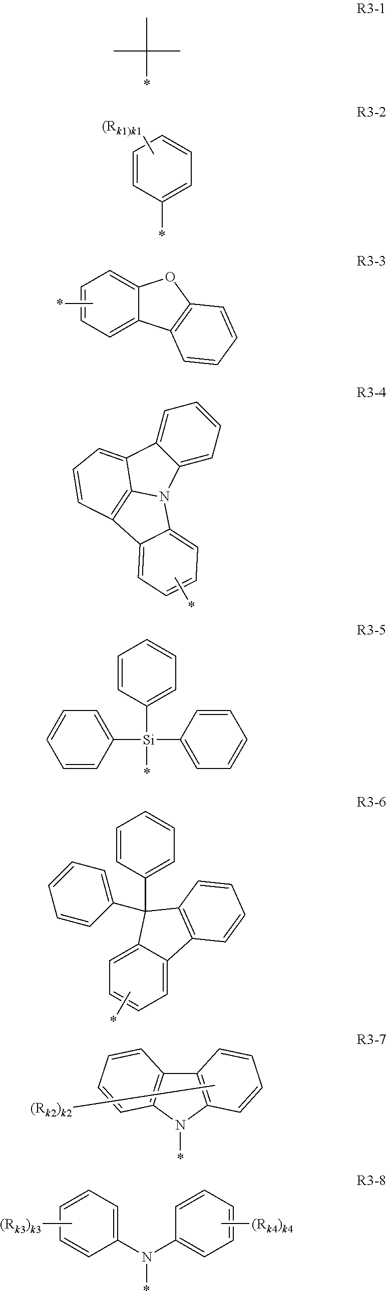
wherein in R3-1 to R3-8,
Rₖ₁, Rₖ₂, Rₖ₃, and Rₖ₄ are each independently a hydrogen atom, a deuterium atom, a substituted or unsubstituted alkyl group having 1 to 10 carbon atoms, or a substituted or unsubstituted aryl group having 6 to 10 ring-forming carbon atoms,
k1, k3, and k4 are each independently an integer from 0 to 5, and
k2 is an integer from 0 to 8.

7. The light emitting element of claim 1, wherein the emission layer comprises the first compound, the second compound, and the third compound.

8. The light emitting element of claim 1, wherein the emission layer comprises the first compound, the second compound, the third compound, and the fourth compound.

9. The light emitting element of claim 1, wherein the emission layer emits delayed fluorescence.

10. The light emitting element of claim 1, wherein the emission layer emits light having a central wavelength in a range of about 430 nm to about 490 nm.

11. The light emitting element of claim 7, wherein a weight ratio of the second compound to the third compound is in a range of about 3:7 to about 7:3.

12. The light emitting element of claim 1, further comprising a hole transport region disposed between the first electrode and the emission layer, wherein
the hole transport region comprises a compound represented by Formula H-1: 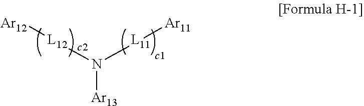
wherein in Formula H-1,
c1 and c2 are each independently an integer from 0 to 10,
L₁₁ and L₁₂ are each independently a direct linkage, a substituted or unsubstituted arylene group having 6 to 30 ring-forming carbon atoms, or a substituted or unsubstituted heteroarylene group having 2 to 30 ring-forming carbon atoms,
Ar₁₁ and Ar₁₂ are each independently a substituted or unsubstituted aryl group having 6 to 30 ring-forming carbon atoms, or a substituted or unsubstituted heteroaryl group having 2 to 30 ring-forming carbon atoms, and
Ar₁₃ is a substituted or unsubstituted aryl group having 6 to 30 ring-forming carbon atoms.

13. The light emitting element of claim 1, wherein the first compound is selected from Compound Group 1: 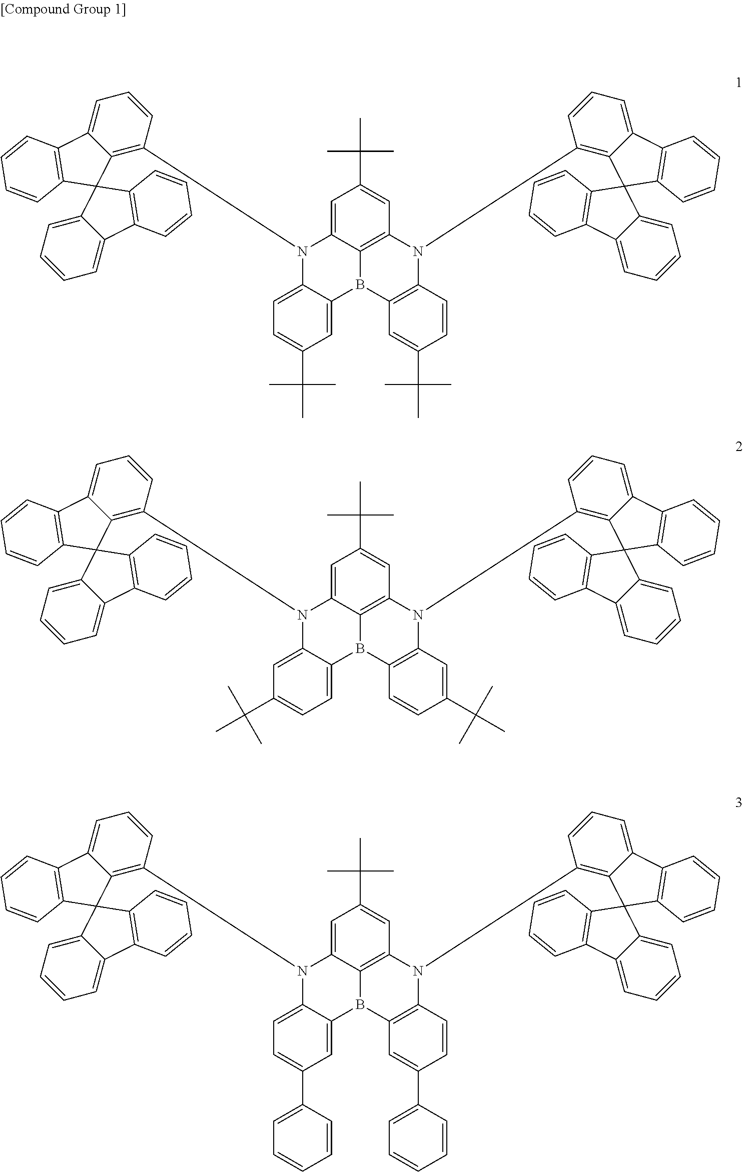 [SMILES: CC(C)(C)c1ccc2c(c1)B1c3cc(C(C)(C)C)ccc3N(c3cccc4c3C3(c5ccccc5-c5ccccc53)c3ccccc3-4)c3cc(C(C)(C)C)cc(c31)N2c1cccc2c1C1(c3ccccc3-c3ccccc31)c1ccccc1-2 ; CC(C)(C)c1ccc2c(c1)N(c1cccc3c1C1(c4ccccc4-c4ccccc41)c1ccccc1-3)c1cc(C(C)(C)C)cc3c1B2c1ccc(C(C)(C)C)cc1N3c1cccc2c1C1(c3ccccc3-c3ccccc31)c1ccccc1-2 ; CC(C)(C)c1cc2c3c(c1)N(c1cccc4c1C1(c5ccccc5-c5ccccc51)c1ccccc1-4)c1ccc(-c4ccccc4)cc1B3c1cc(-c3ccccc3)ccc1N2c1cccc2c1C1(c3ccccc3-c3ccccc31)c1ccccc1-2] 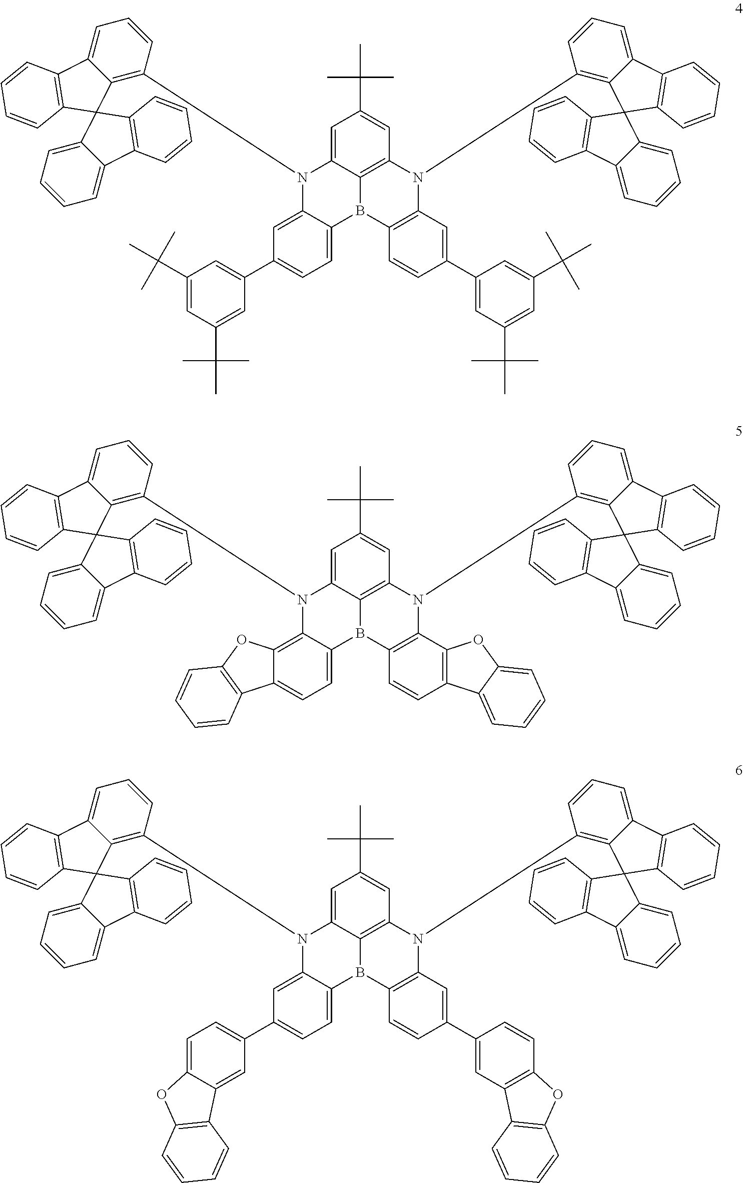 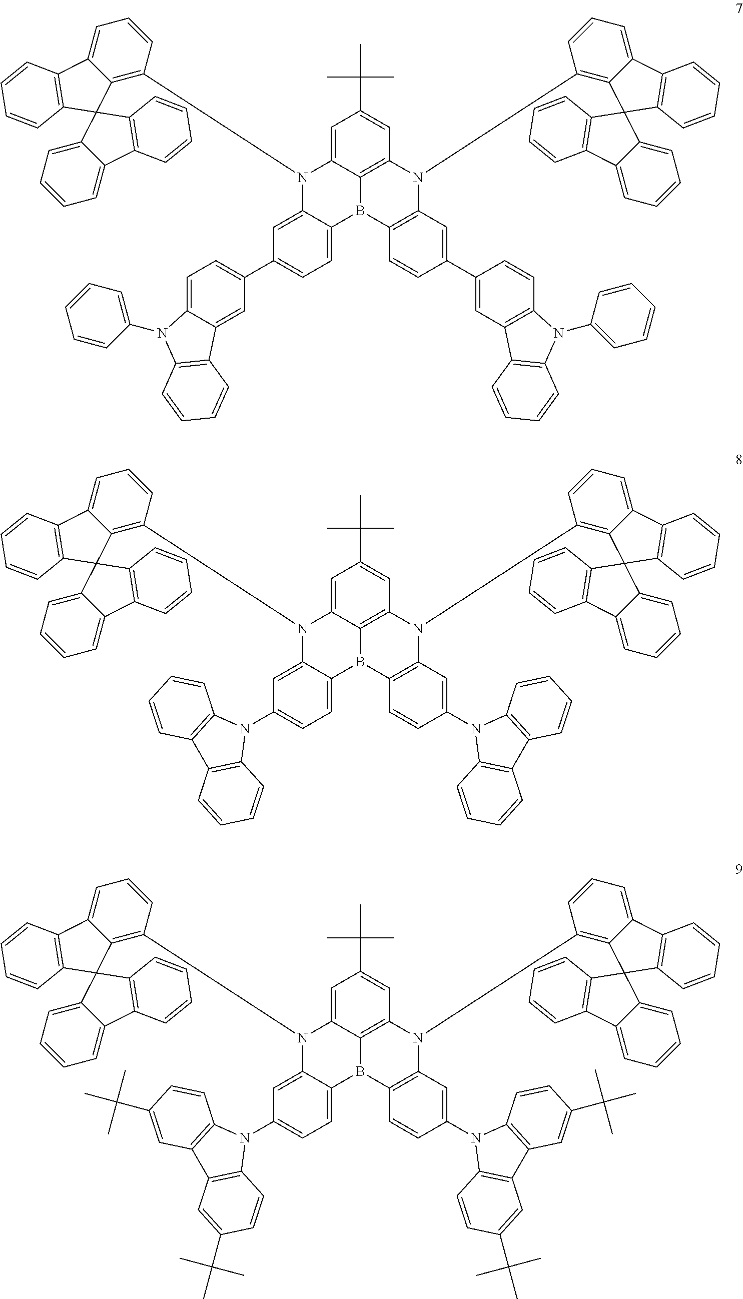 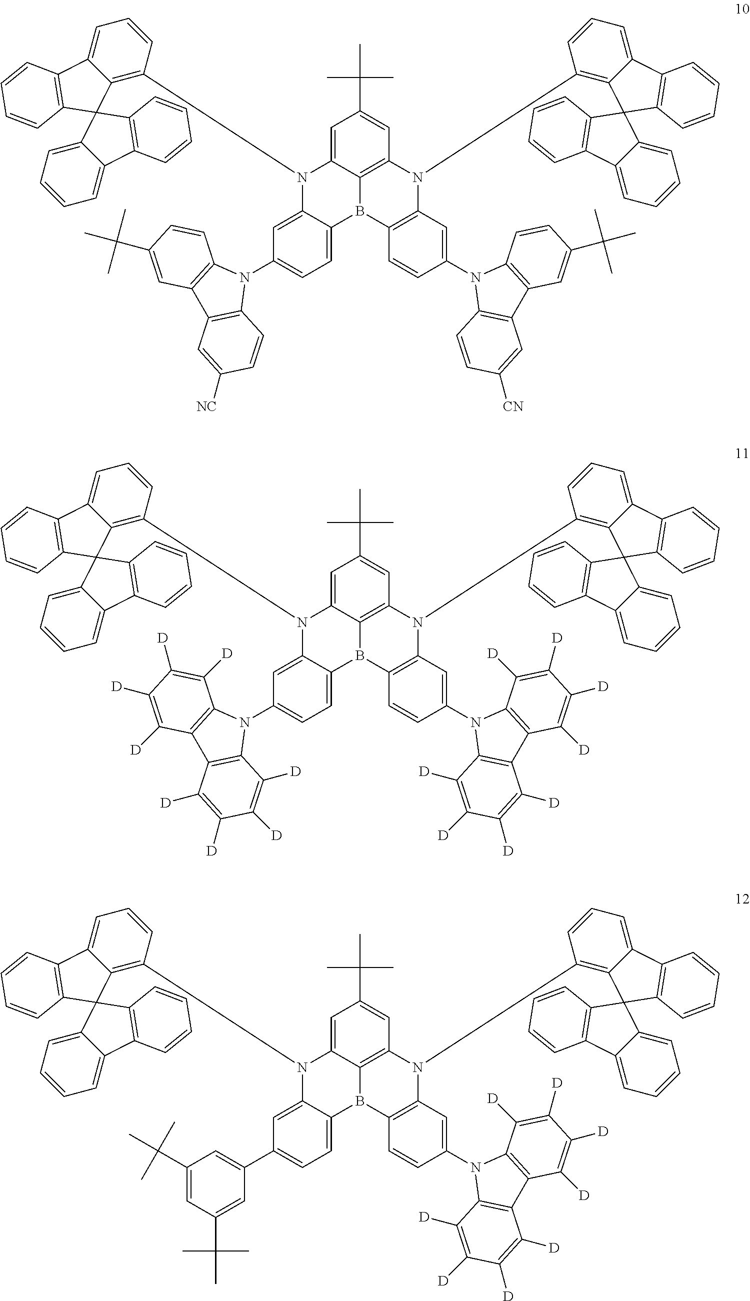 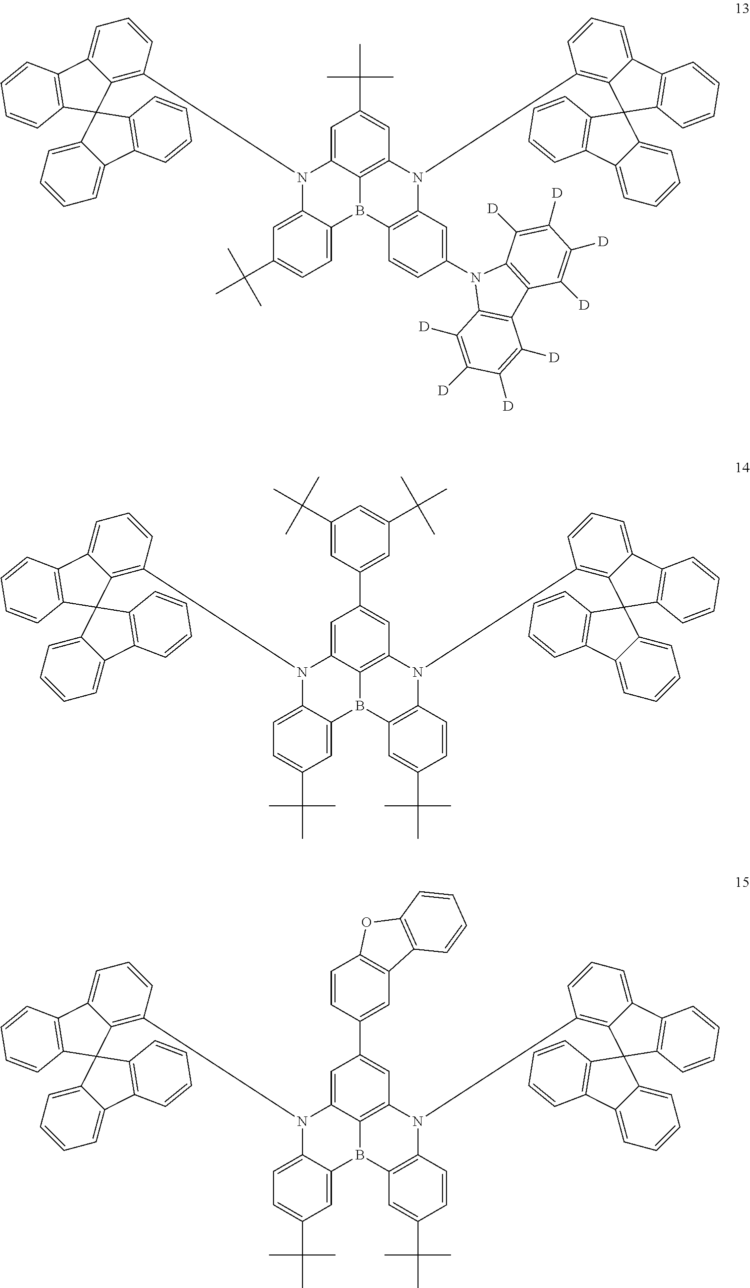 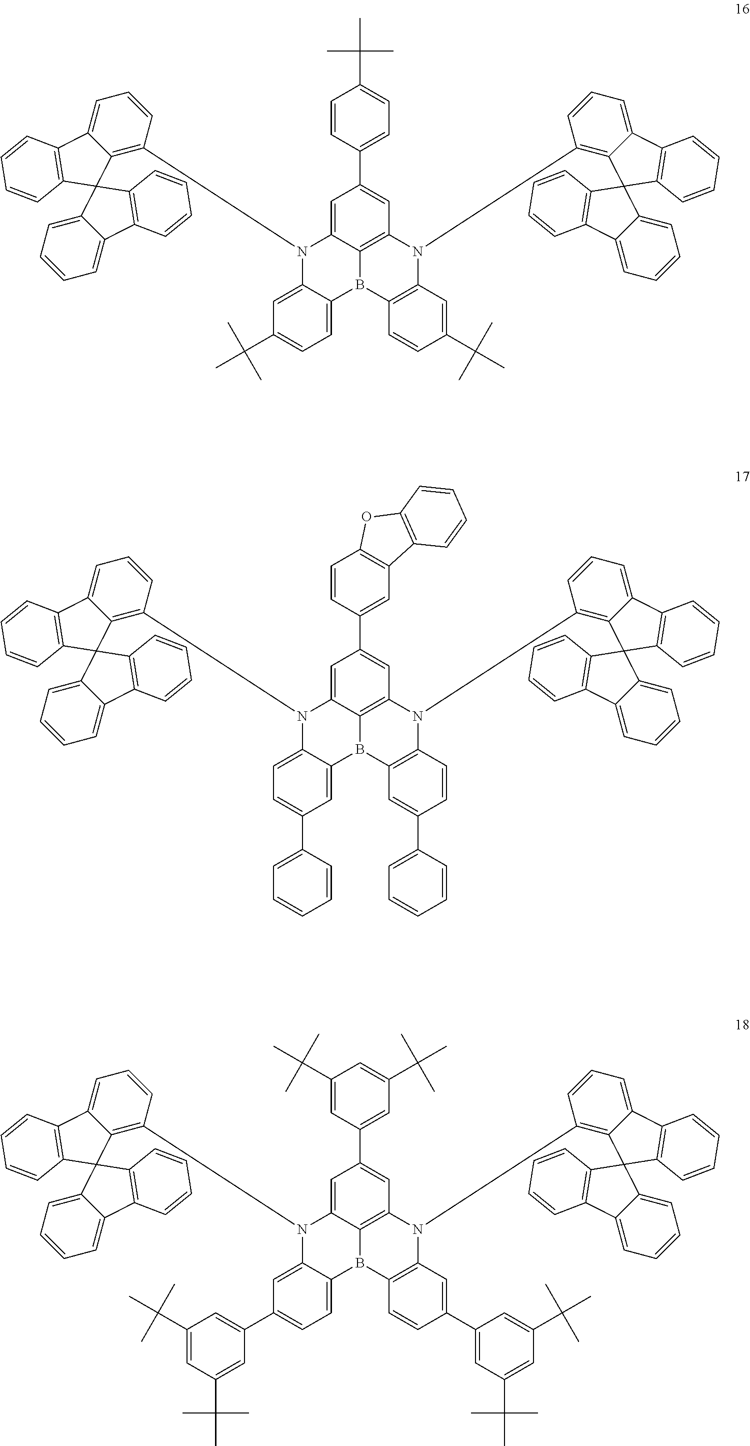 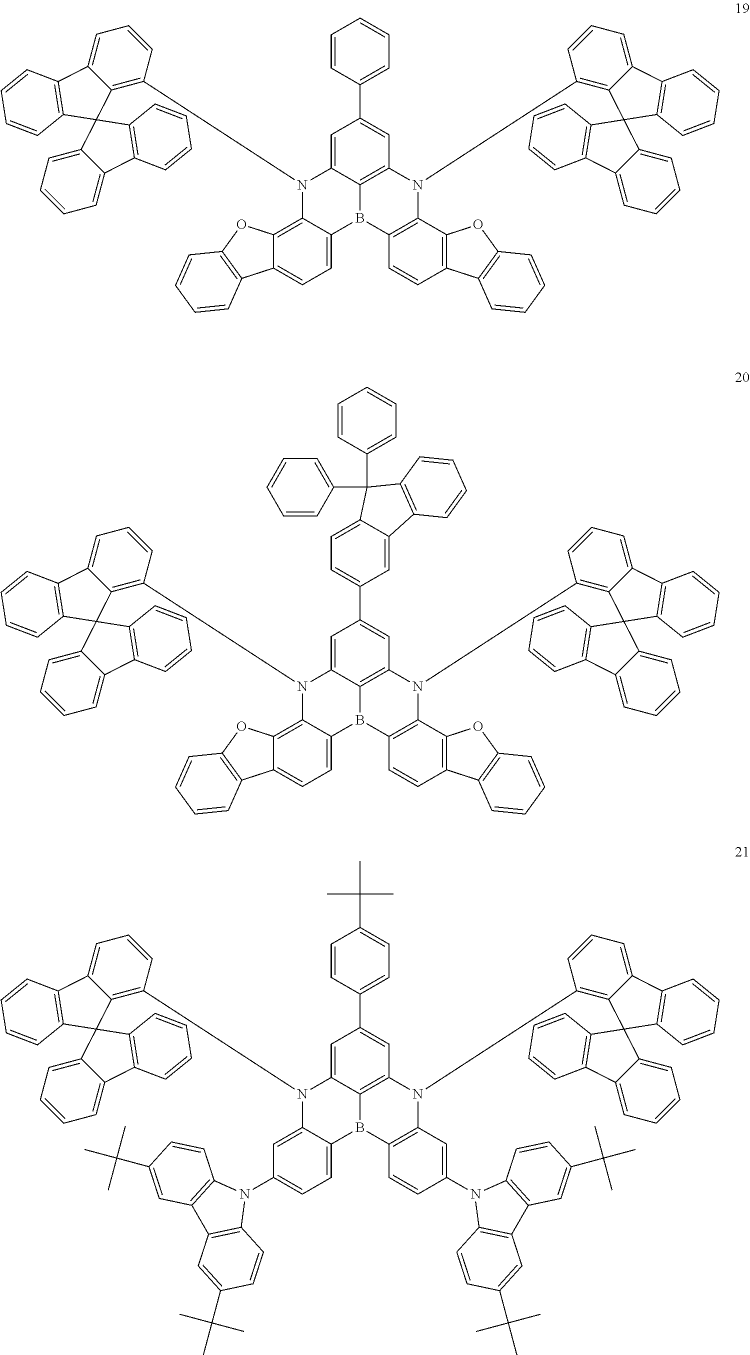 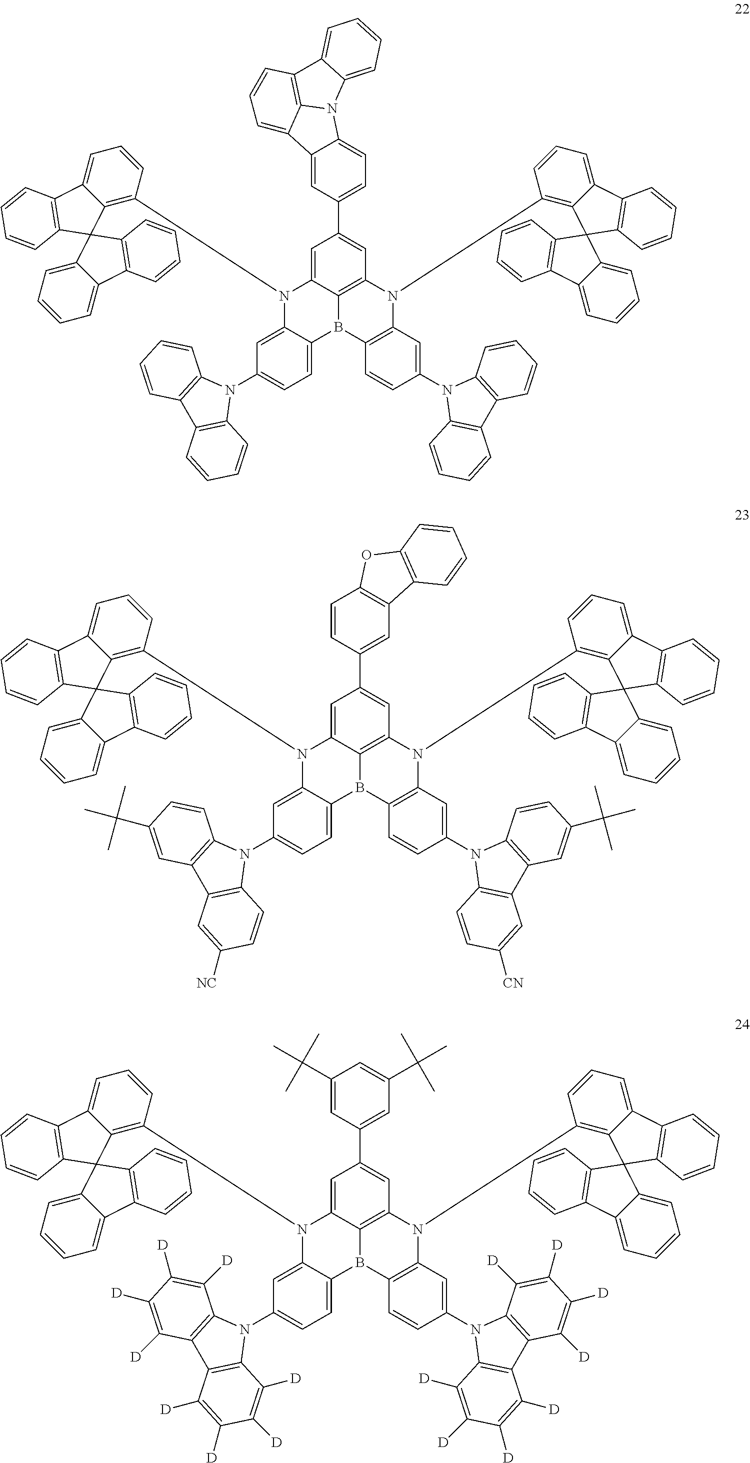 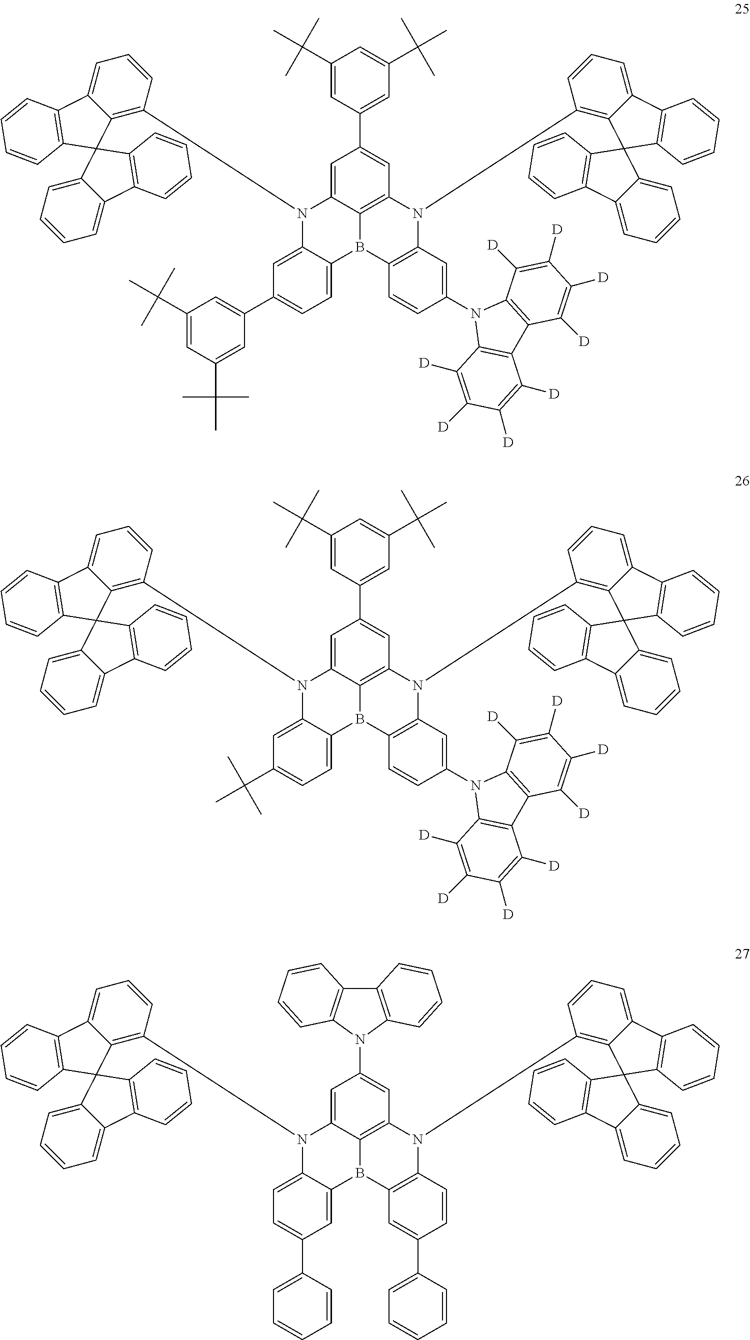 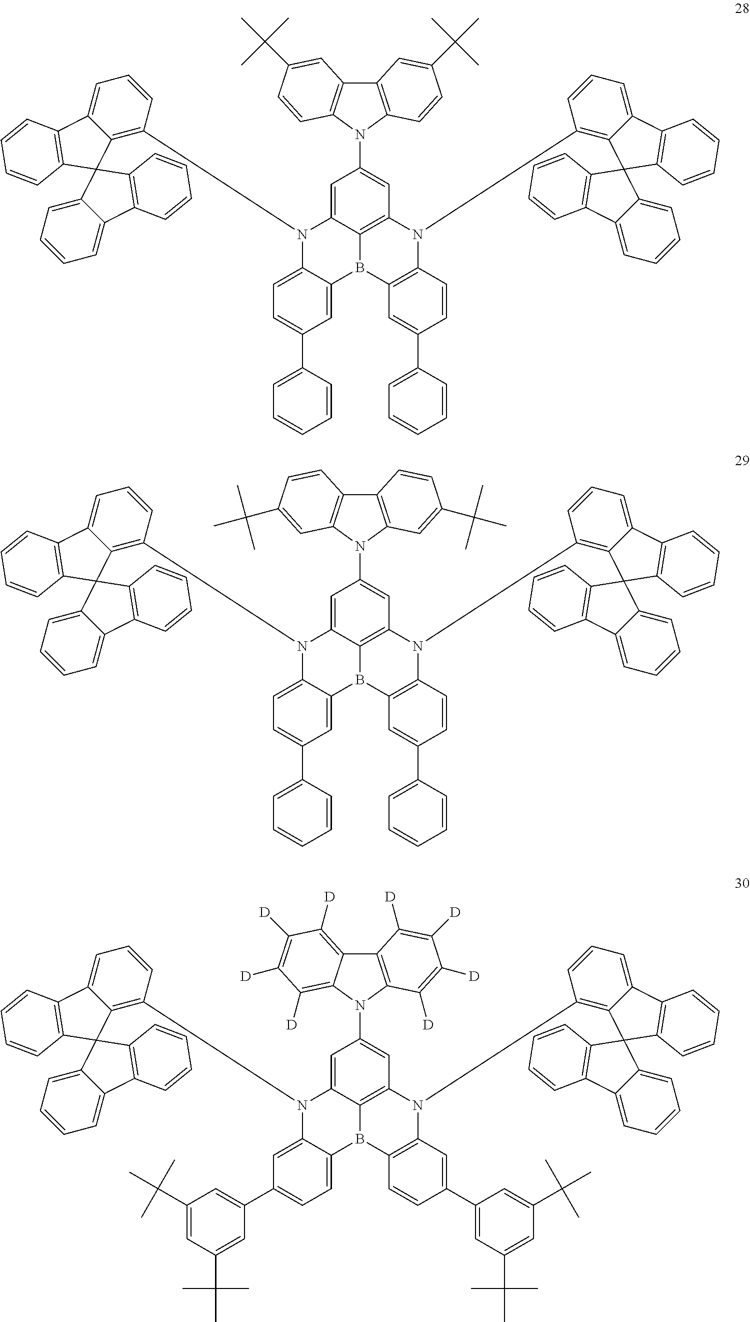 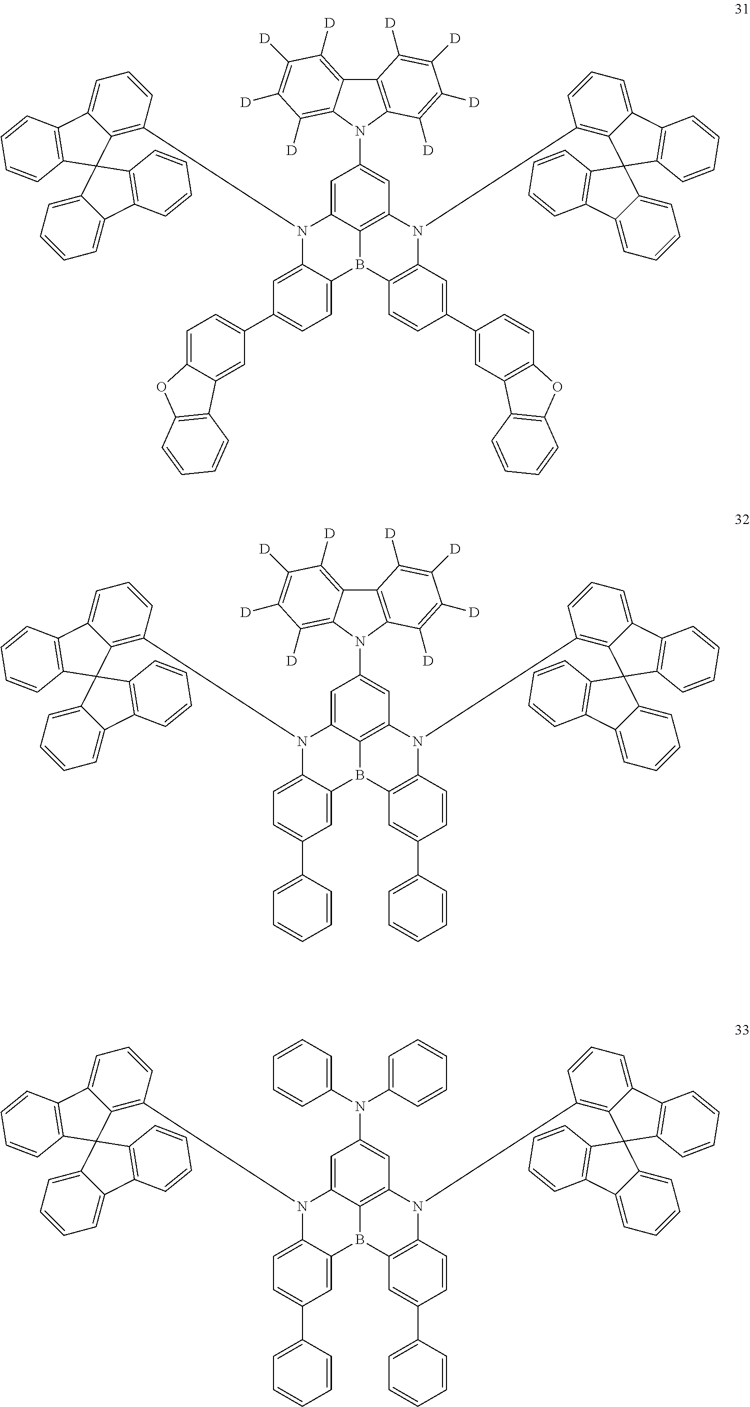 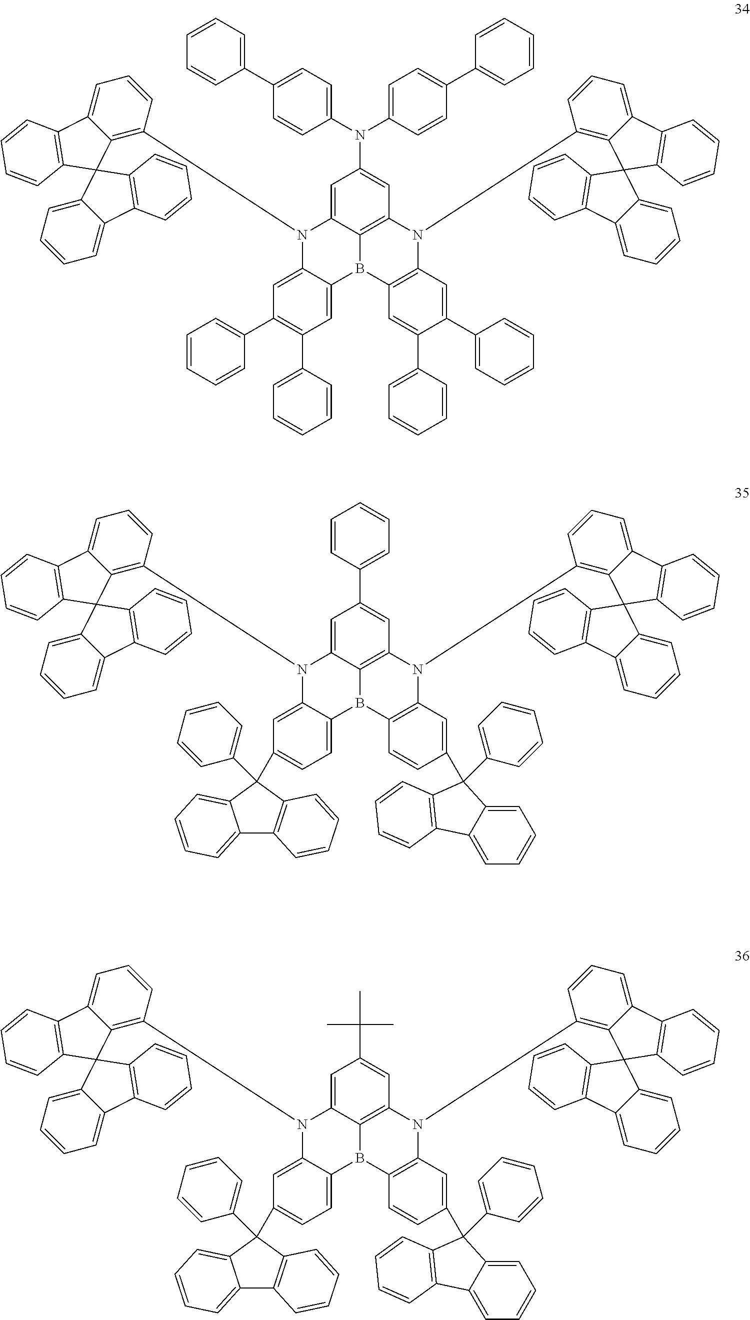 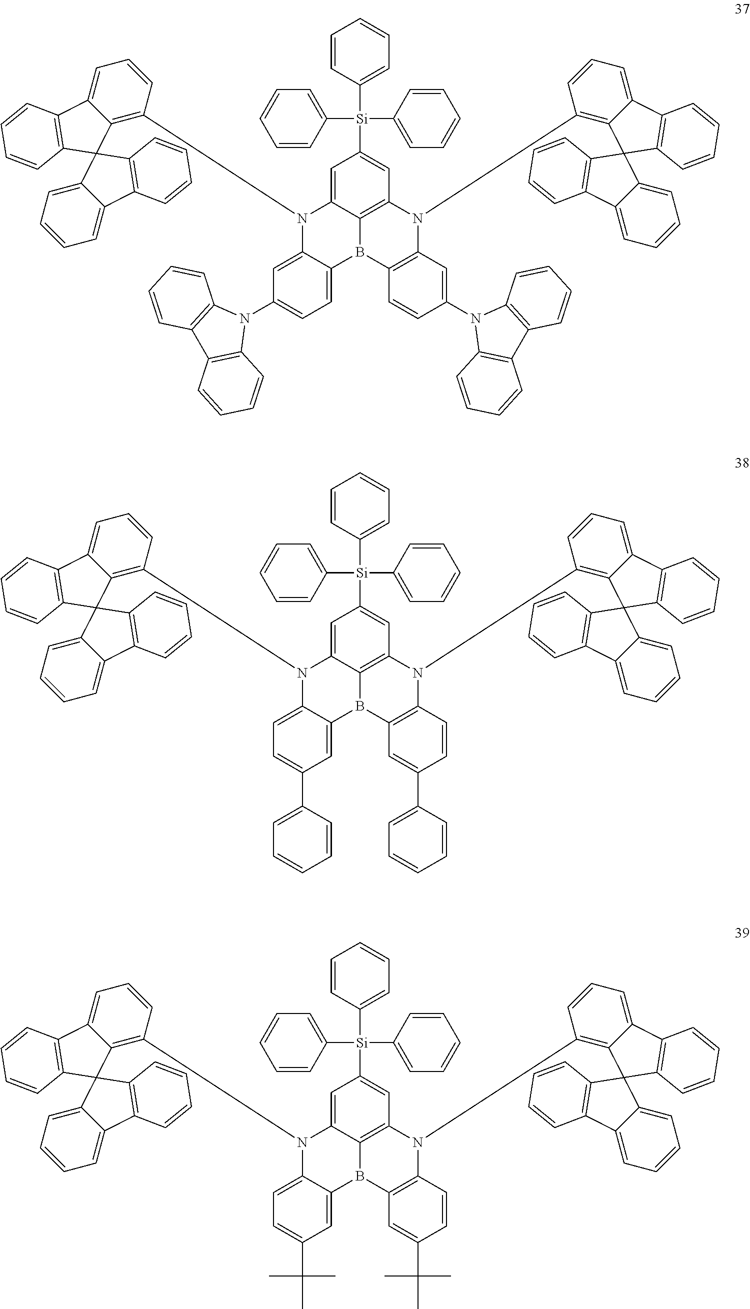 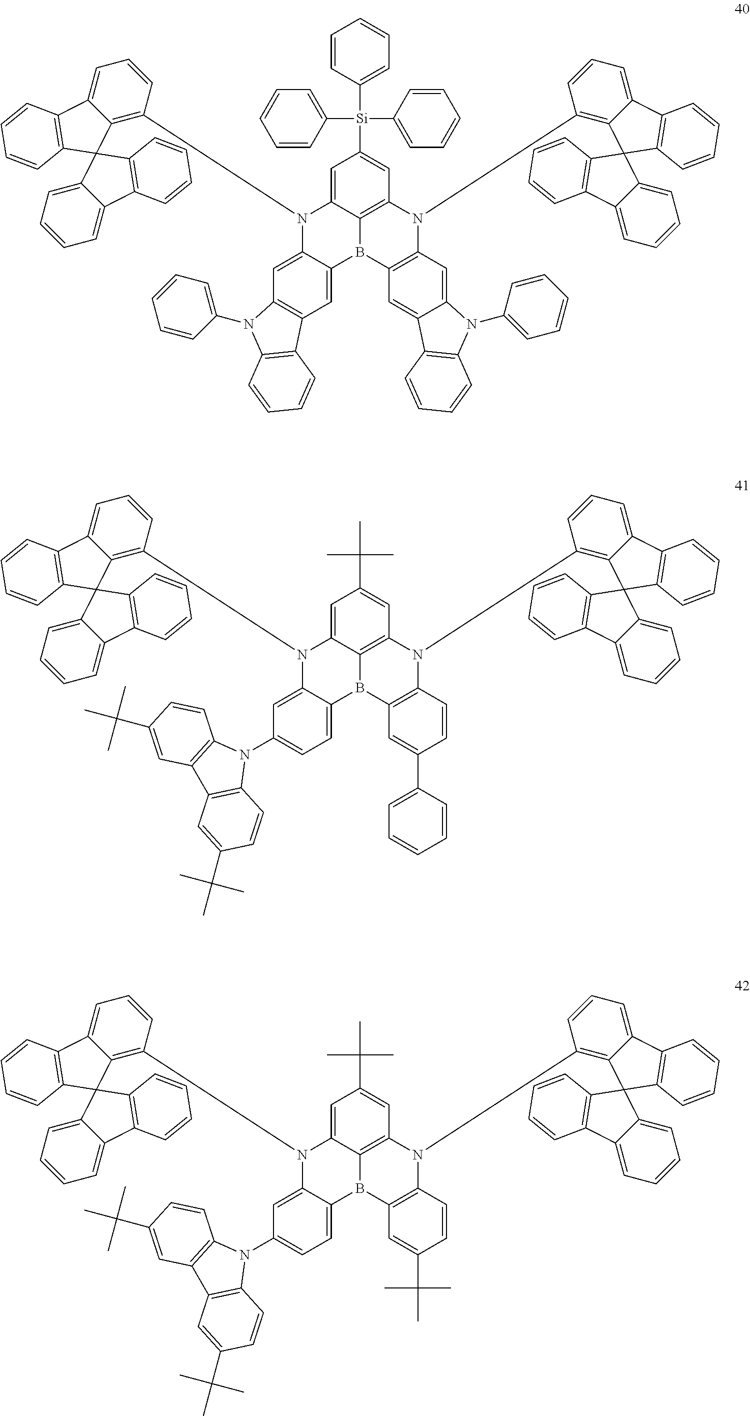 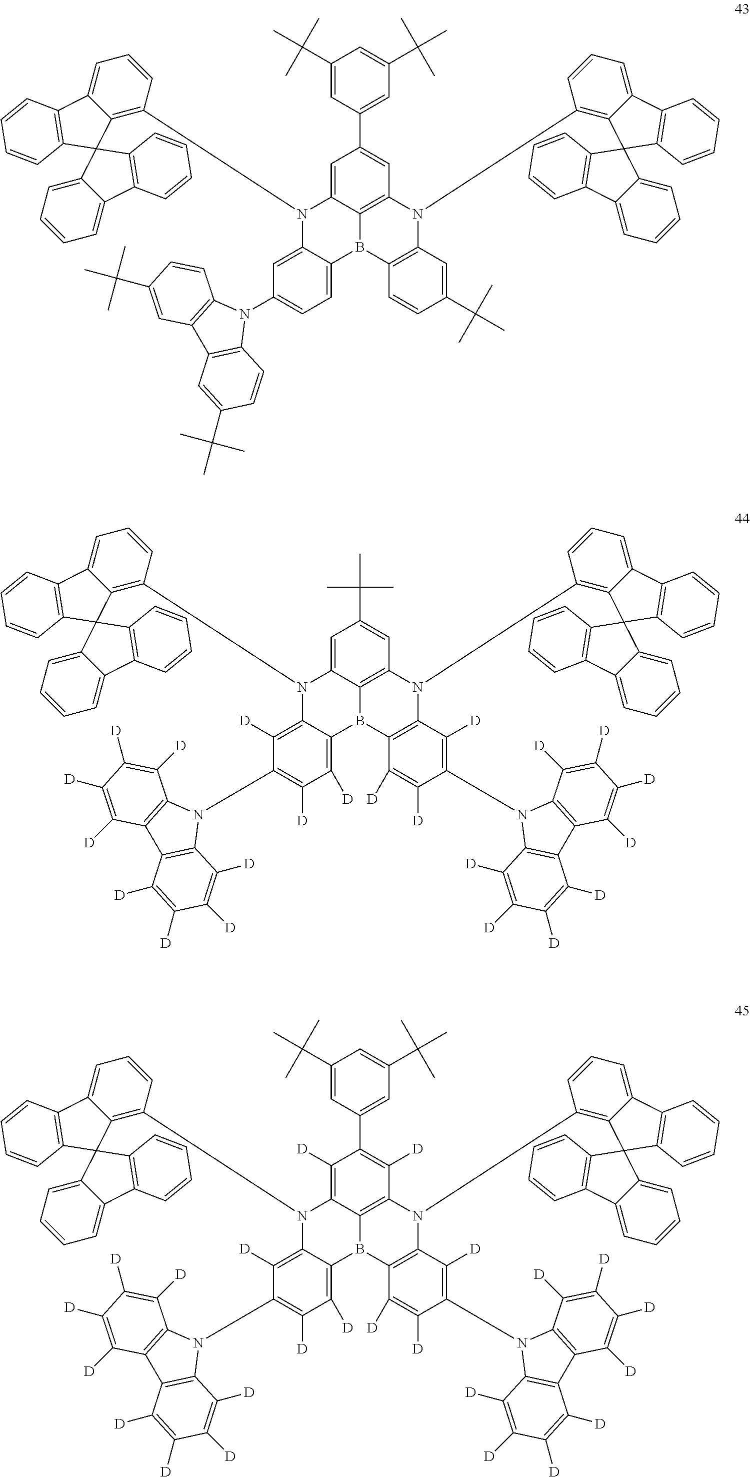 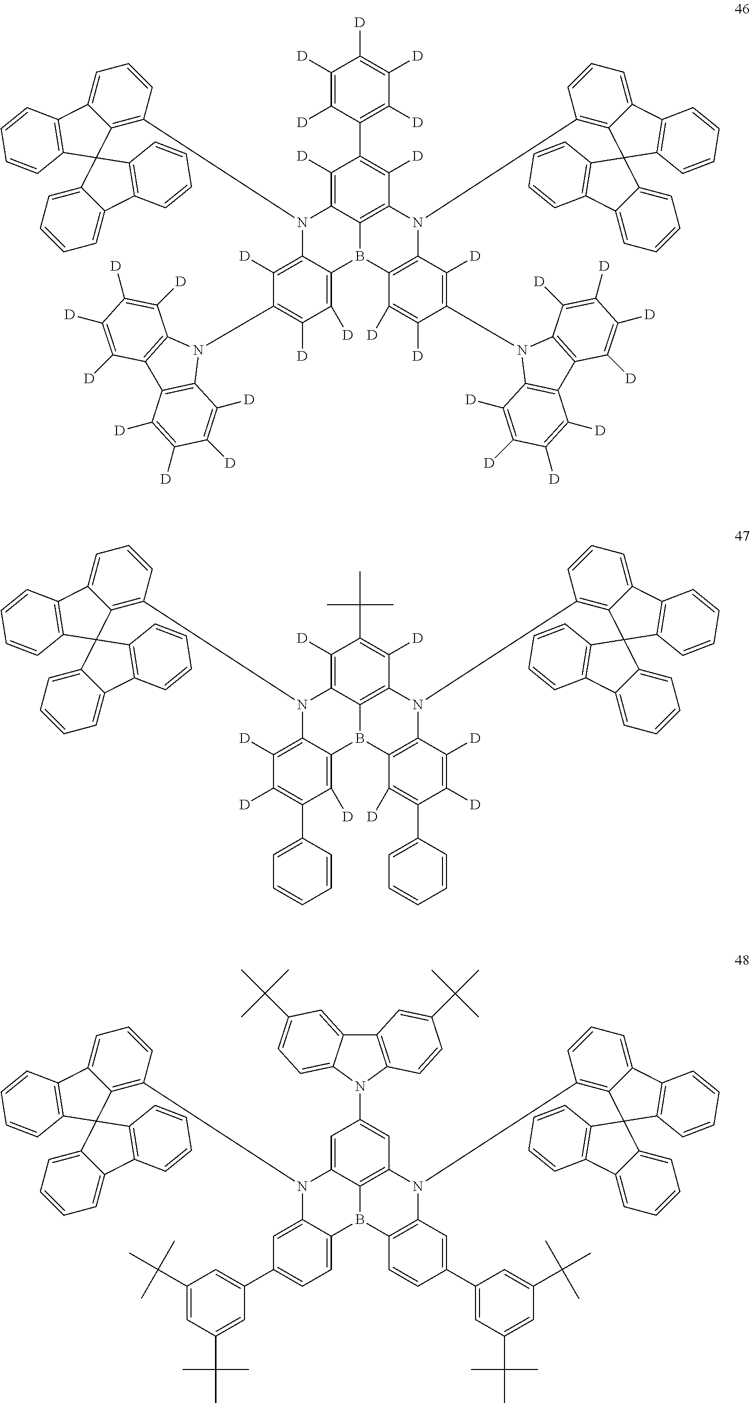
wherein in Compound Group 1,
D represents a deuterium atom.

14. A polycyclic compound represented by Formula 1 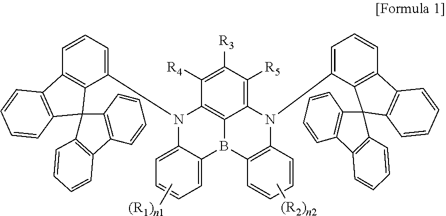
wherein in Formula 1,
R₁ and R₂ are each independently a hydrogen atom, a deuterium atom, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₃ is a substituted or unsubstituted amine group, a substituted or unsubstituted silyl group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
R₄ and R₅ are each independently a hydrogen atom or a deuterium atom, and
n1 and n2 are each independently an integer from 0 to 4.

15. The polycyclic compound of claim 14, wherein the polycyclic compound represented by Formula 1 is represented by one of Formula 1-1 to Formula 1-3: 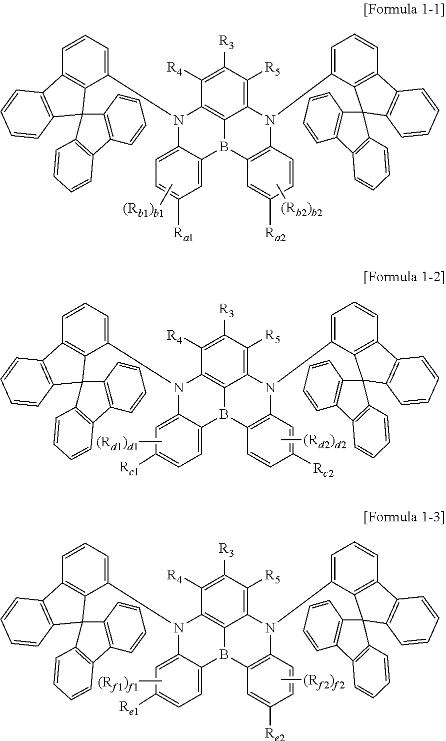
wherein in Formula 1-1 to Formula 1-3,
Rₐ₁, Rₐ₂, R_{c1}, R_{c2}, Rₑ₁, and Rₑ₂ are each independently a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a substituted or unsubstituted heterocycle,
R_{b1}, R_{b2}, Rₐ₁, Rₐ₂, R_{f1}, and R_{f2} are each independently a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a substituted or unsubstituted heterocycle,
b1, b2, d1, d2, f1, and f2 are each independently an integer from 0 to 3, and
R₃ to R₅ are each the same as defined in Formula 1.

16. The polycyclic compound of claim 15, wherein the polycyclic compound represented by Formula 1 is represented by one of Formula 2-1 to Formula 2-7: 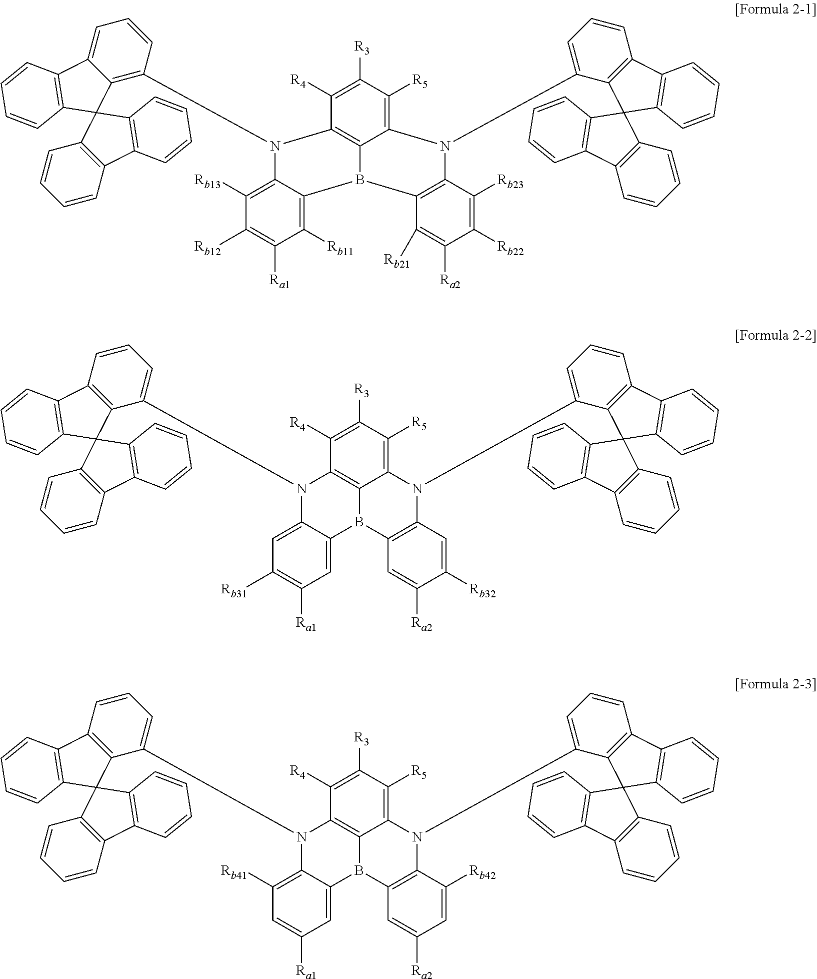 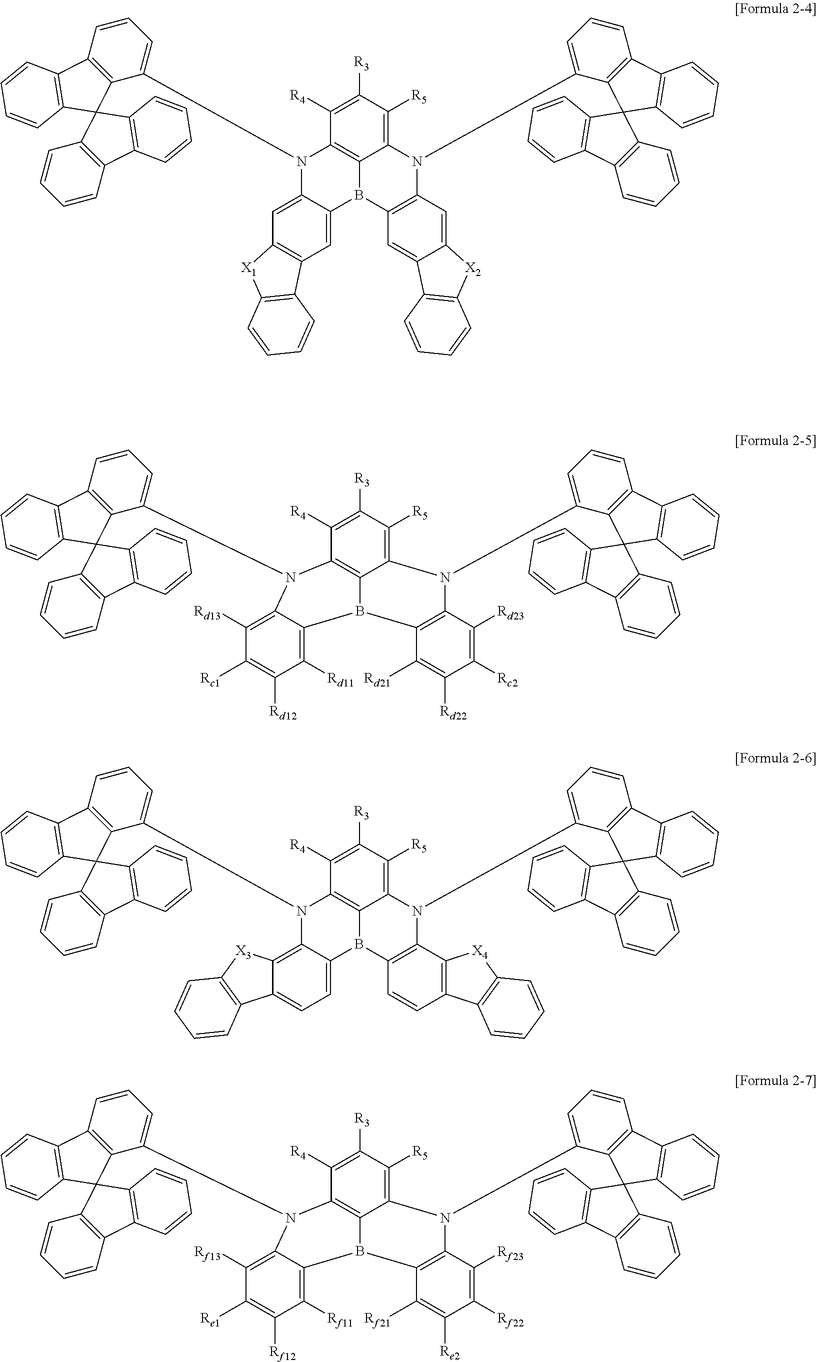
wherein in Formula 2-1 to Formula 2-7,
R_{b11} to R_{b13}, R_{b21} to R_{b23}, Rₐ₁₁ to Rₐ₁₃, Rₐ₂₁ to Rₐ₂₃, R_{f11} to R_{f13}, and R_{f21} to R_{f23} are each independently a hydrogen atom or a deuterium atom,
R_{b31}, R_{b32}, R_{b41}, and R_{b42} are each independently a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
X₁ to X₄ are each independently O, S, or N(Rₓ₁),
Rₓ₁ is a substituted or unsubstituted aryl group having 6 to 20 ring-forming carbon atoms, and
Rₐ₁, Rₐ₂, R_{c1}, R_{c2}, Rₑ₁, Rₑ₂, and R₃ to R₅ are each the same as defined in Formula 1 and Formula 1-1 to Formula 1-3.

17. The polycyclic compound of claim 14, wherein the polycyclic compound represented by Formula 1 is represented by Formula 3: 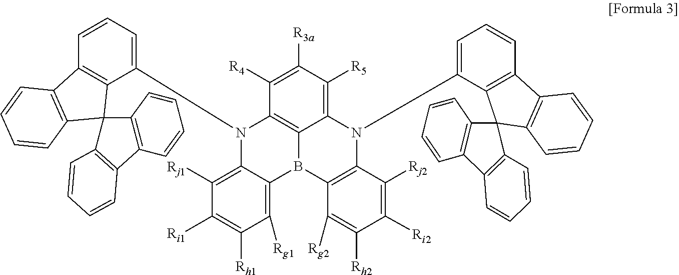
wherein in Formula 3,
R_{g1}, R_{g2}, Rₕ₁, Rₕ₂, Rᵢ₁, Rᵢ₂, Rⱼ₁, and Rⱼ₂ are each independently a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, or are bonded to an adjacent group to form a substituted or unsubstituted heterocycle,
R₃ₐ is a substituted or unsubstituted alkyl group having 1 to 10 carbon atoms, a substituted or unsubstituted carbazole group, a substituted or unsubstituted indolocarbazole group, a substituted or unsubstituted phenyl group, a substituted or unsubstituted fluorenyl group, a substituted or unsubstituted dibenzofuran group, a substituted or unsubstituted diphenylamine group, or a substituted or unsubstituted triphenylsilyl group, and
R₄ and R₅ are each the same as defined in Formula 1.

18. The polycyclic compound of claim 17, wherein the polycyclic compound represented by Formula 3 is represented by one of Formula 3-1 to Formula 3-3: 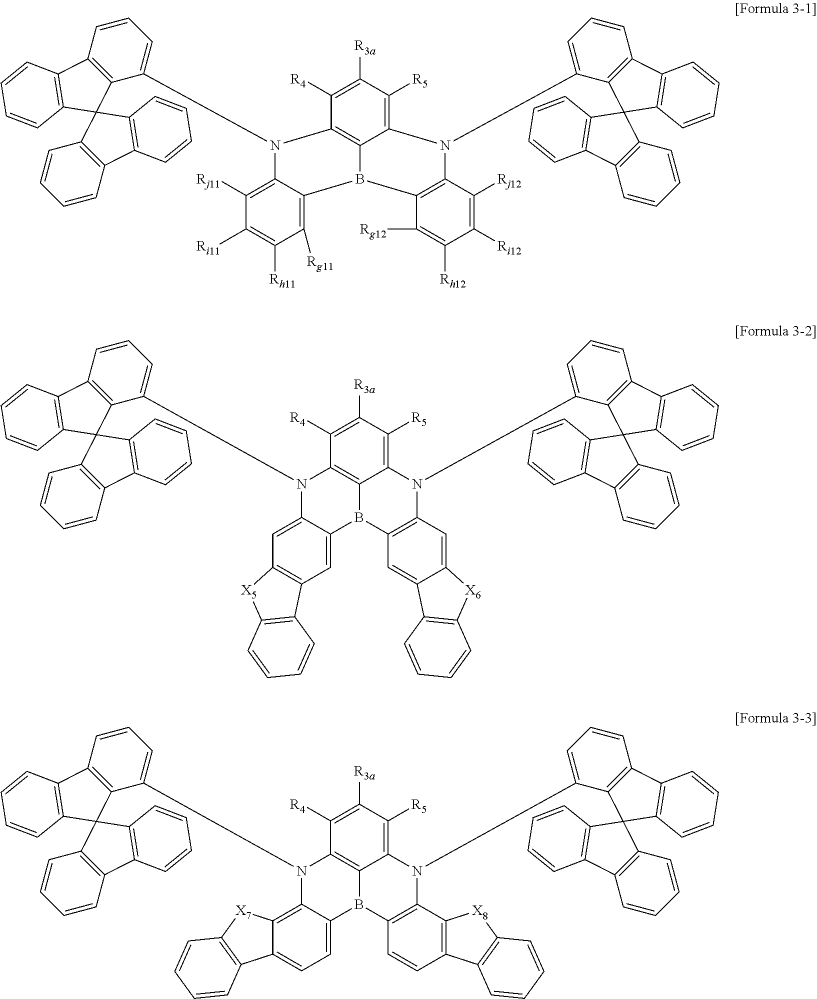
wherein in Formula 3-1,
R_{g11}, Rₕ₁₁, Rᵢ₁₁, Rⱼ₁₁, R_{g12}, Rₕ₁₂, Rᵢ₁₂, and Rⱼ₁₂ are each independently a hydrogen atom, a deuterium atom, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, and
at least one of R_{g11}, Rₕ₁₁, Rᵢ₁₁, or Rⱼ₁₁ and at least one of R_{g12}, Rₕ₁₂, Rᵢ₁₂, or Rⱼ₁₂ are each independently a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms,
wherein in Formula 3-2 and Formula 3-3,
X₅ to X₈ are each independently O, S, or N(Rₓ₂), and
Rₓ₂ is a substituted or unsubstituted aryl group having 6 to 20 ring-forming carbon atoms, and
wherein in Formula 3-1 to Formula 3-3,
R₃ₐ, R₄, and R₅ are each the same as defined in Formula 1 and Formula 3.

19. The polycyclic compound of claim 14, wherein R₃ is a group represented by one of R3-1 to R3-8: 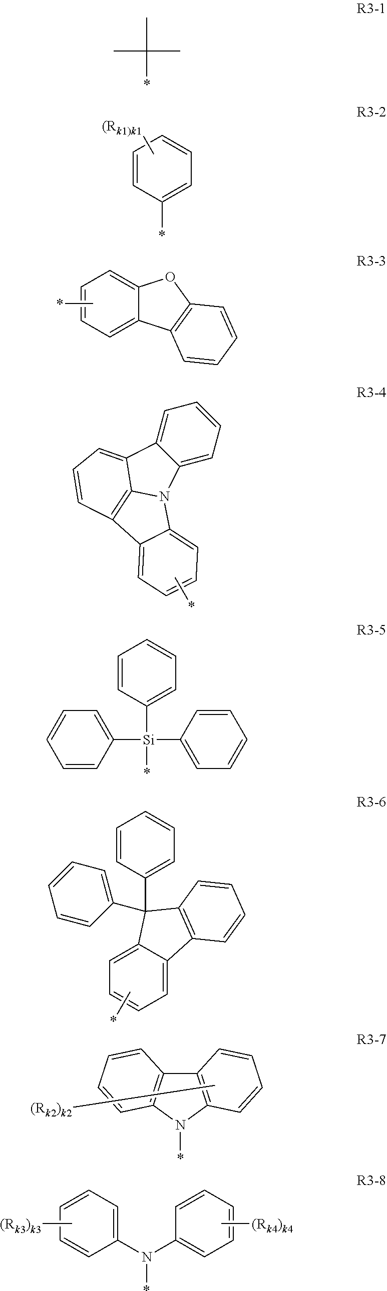
wherein in R3-1 to R3-8,
Rₖ₁, Rₖ₂, Rₖ₃, and Rₖ₄ are each independently a hydrogen atom, a deuterium atom, a substituted or unsubstituted alkyl group having 1 to 10 carbon atoms, or a substituted or unsubstituted aryl group having 6 to 10 ring-forming carbon atoms,
k1, k3, and k4 are each independently an integer from 0 to 5, and
k2 is an integer 0 to 8.

20. The polycyclic compound of claim 14, wherein the polycyclic compound is selected from Compound Group 1: 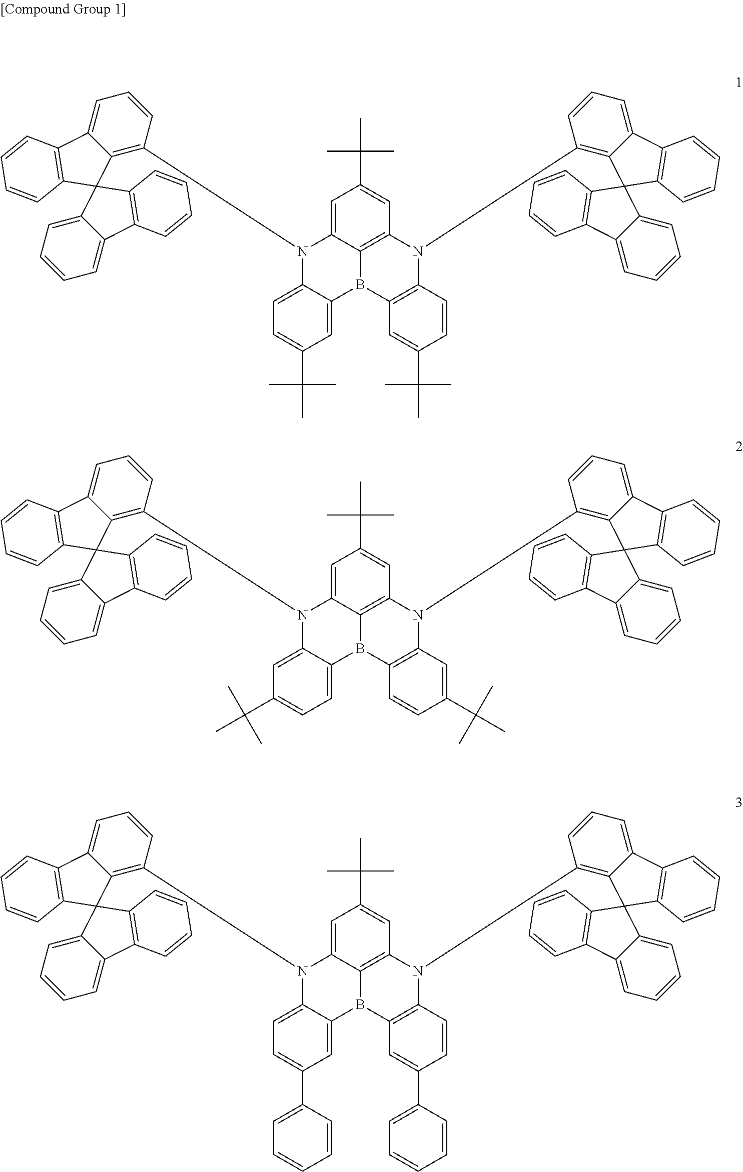 [SMILES: CC(C)(C)c1ccc2c(c1)B1c3cc(C(C)(C)C)ccc3N(c3cccc4c3C3(c5ccccc5-c5ccccc53)c3ccccc3-4)c3cc(C(C)(C)C)cc(c31)N2c1cccc2c1C1(c3ccccc3-c3ccccc31)c1ccccc1-2 ; CC(C)(C)c1ccc2c(c1)N(c1cccc3c1C1(c4ccccc4-c4ccccc41)c1ccccc1-3)c1cc(C(C)(C)C)cc3c1B2c1ccc(C(C)(C)C)cc1N3c1cccc2c1C1(c3ccccc3-c3ccccc31)c1ccccc1-2 ; CC(C)(C)c1cc2c3c(c1)N(c1cccc4c1C1(c5ccccc5-c5ccccc51)c1ccccc1-4)c1ccc(-c4ccccc4)cc1B3c1cc(-c3ccccc3)ccc1N2c1cccc2c1C1(c3ccccc3-c3ccccc31)c1ccccc1-2] 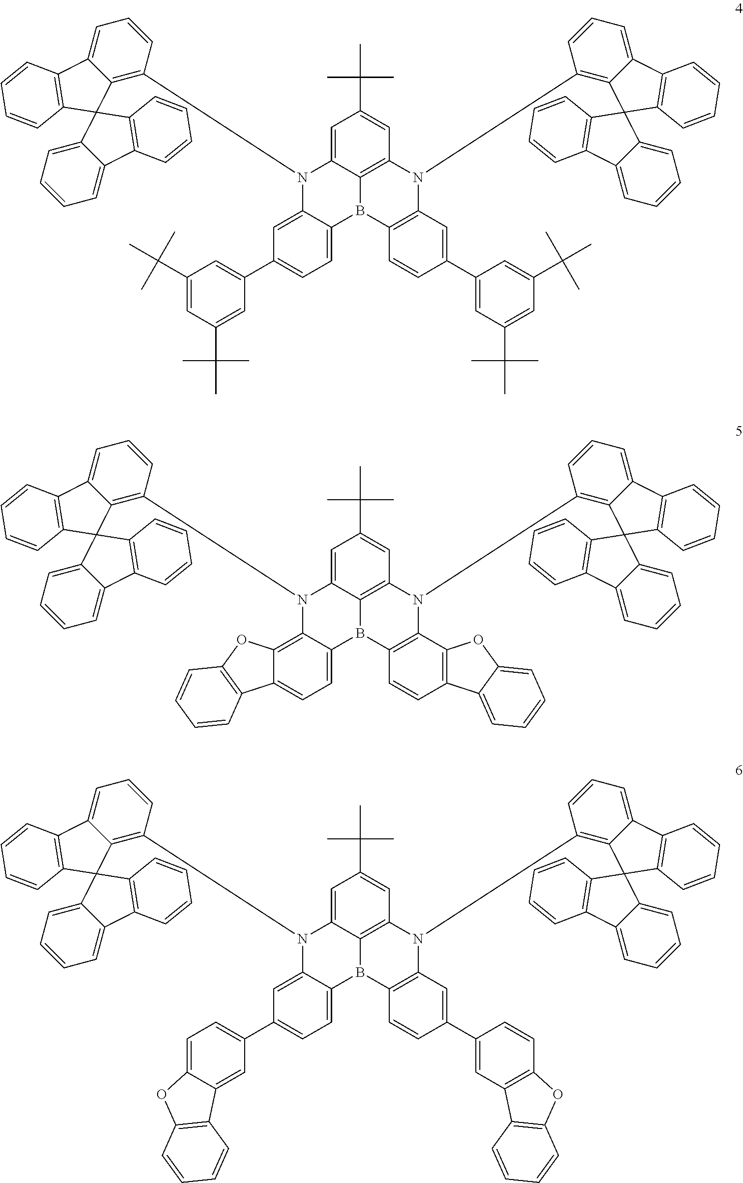 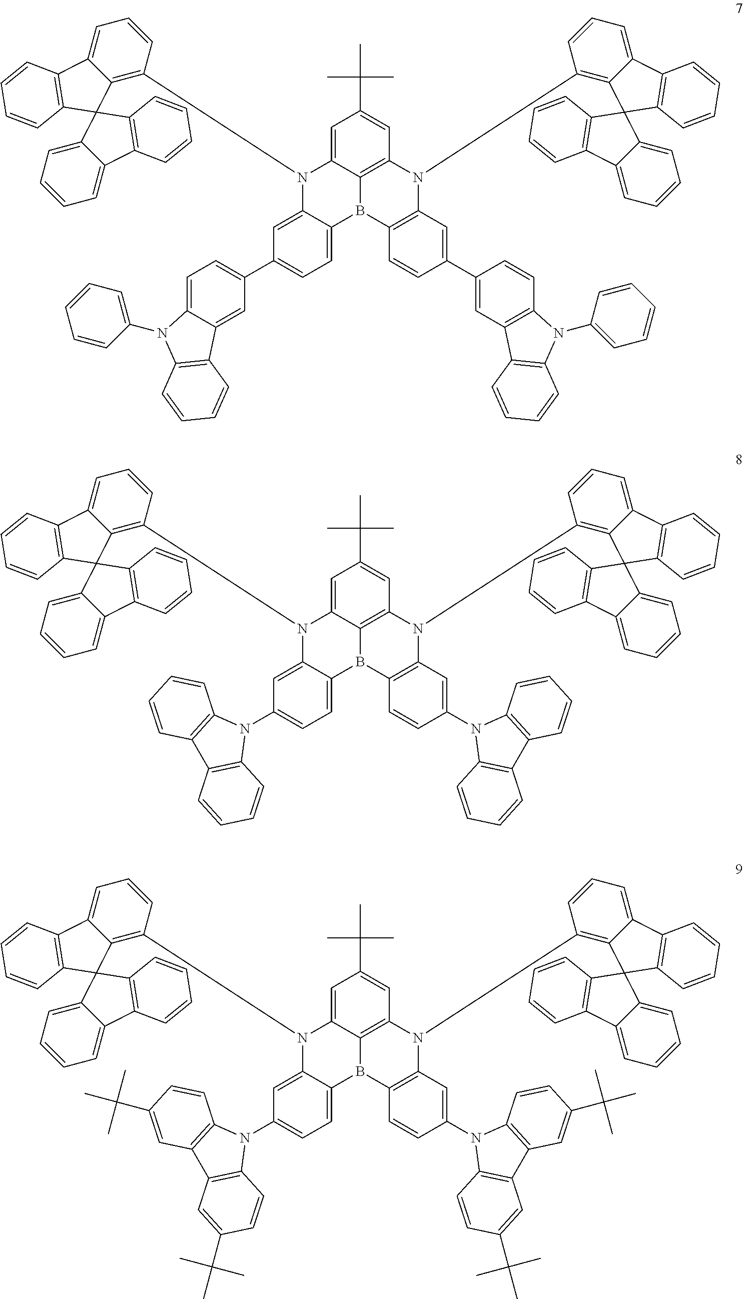 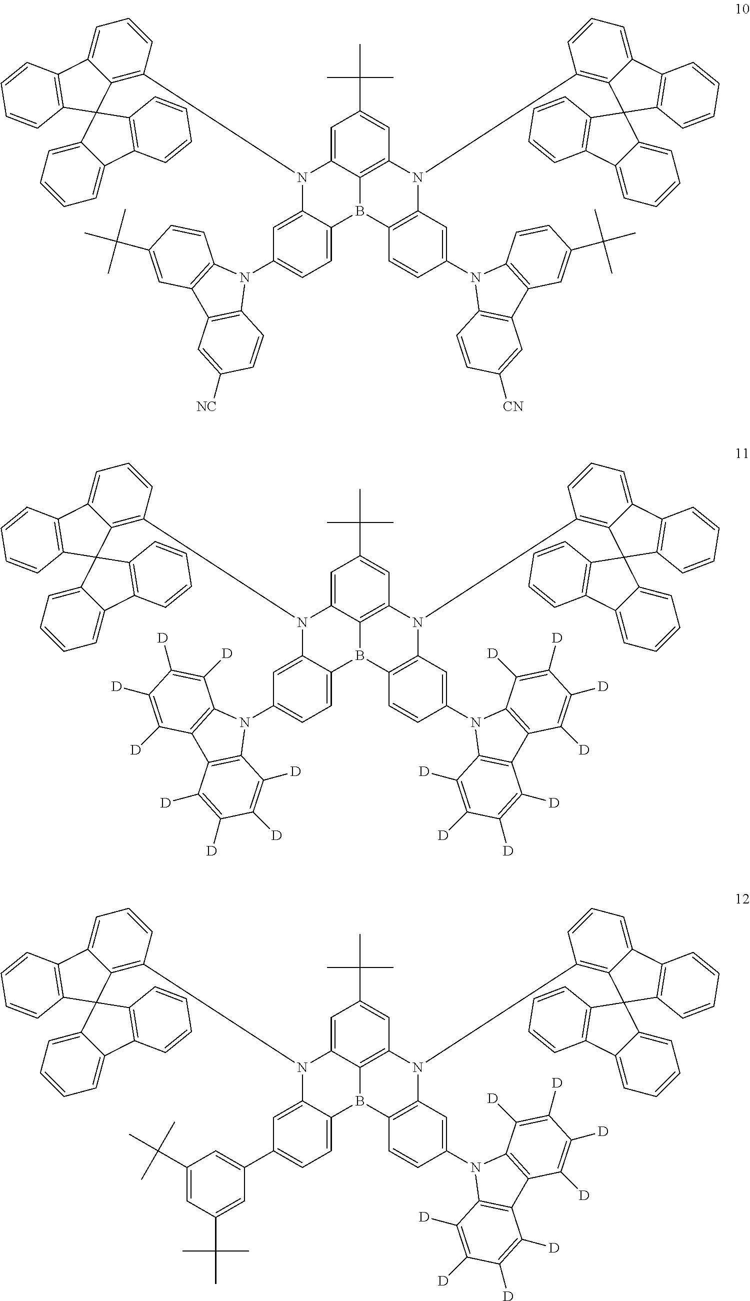 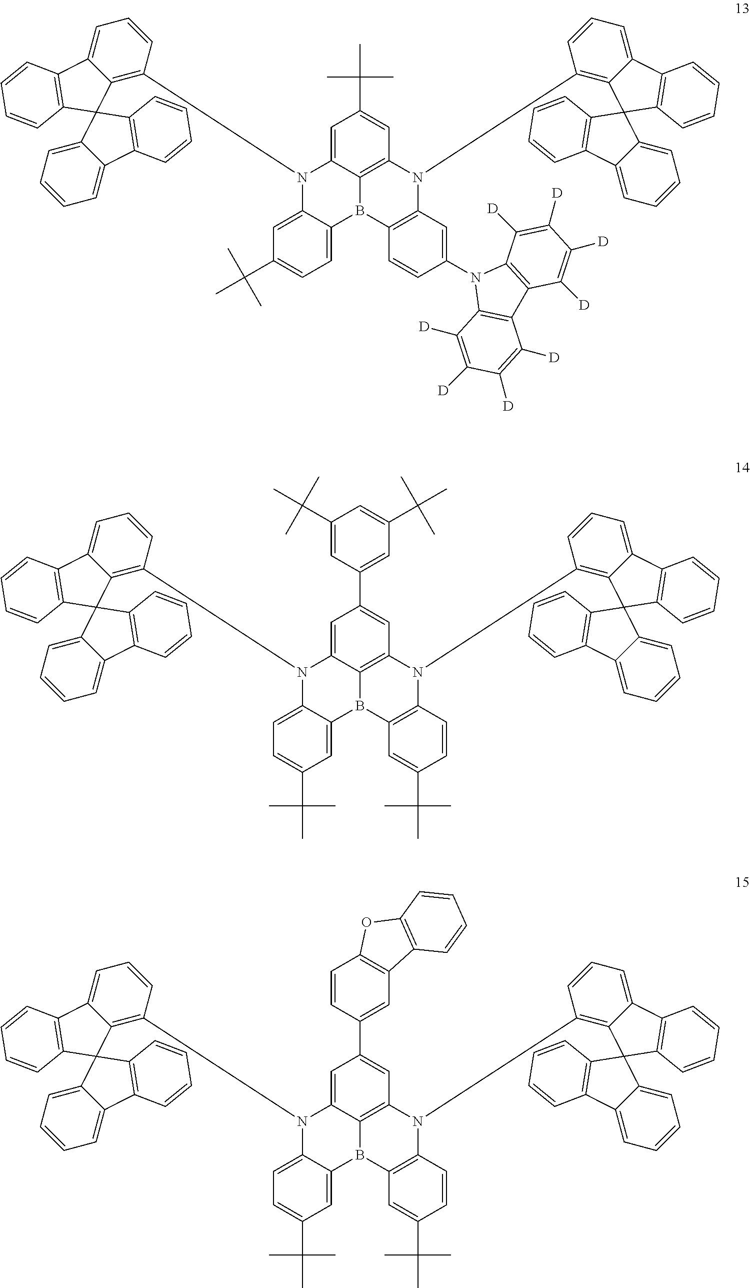 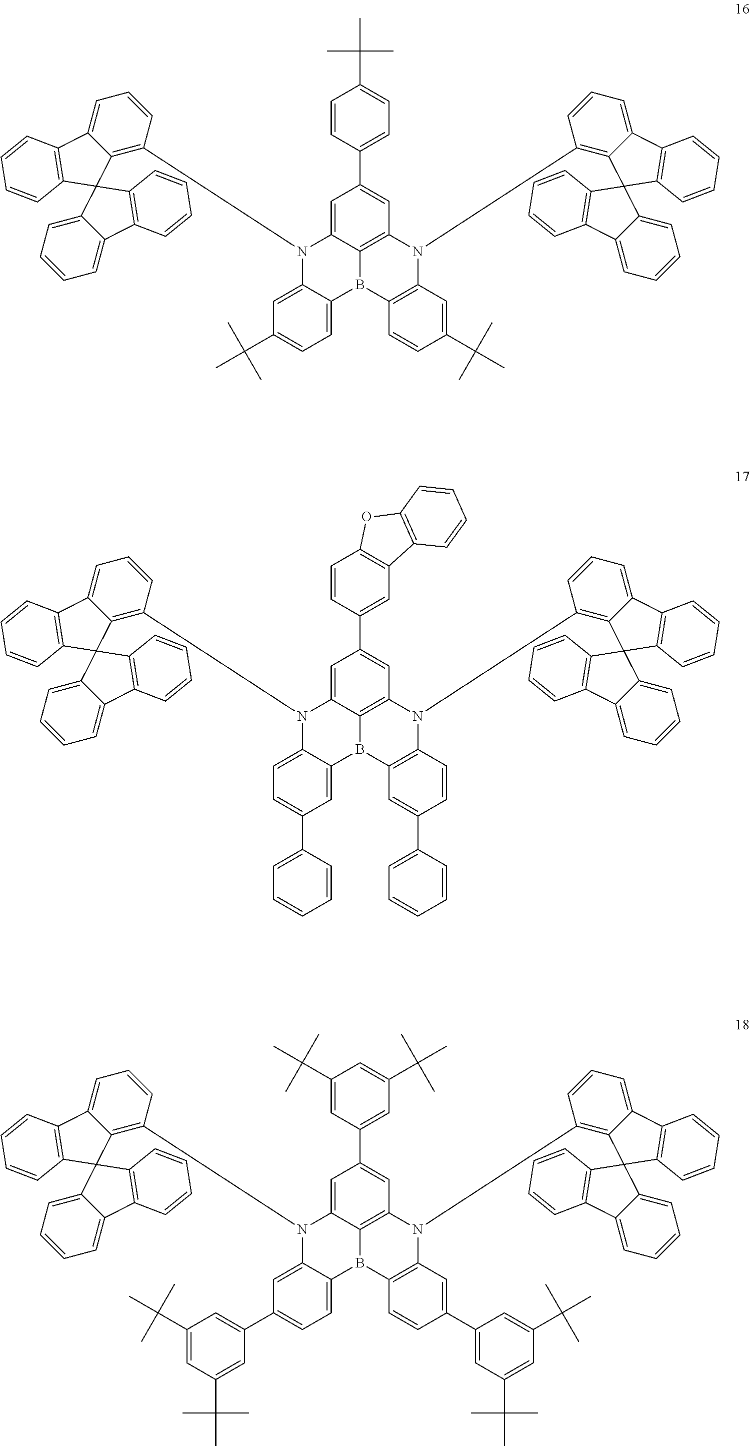 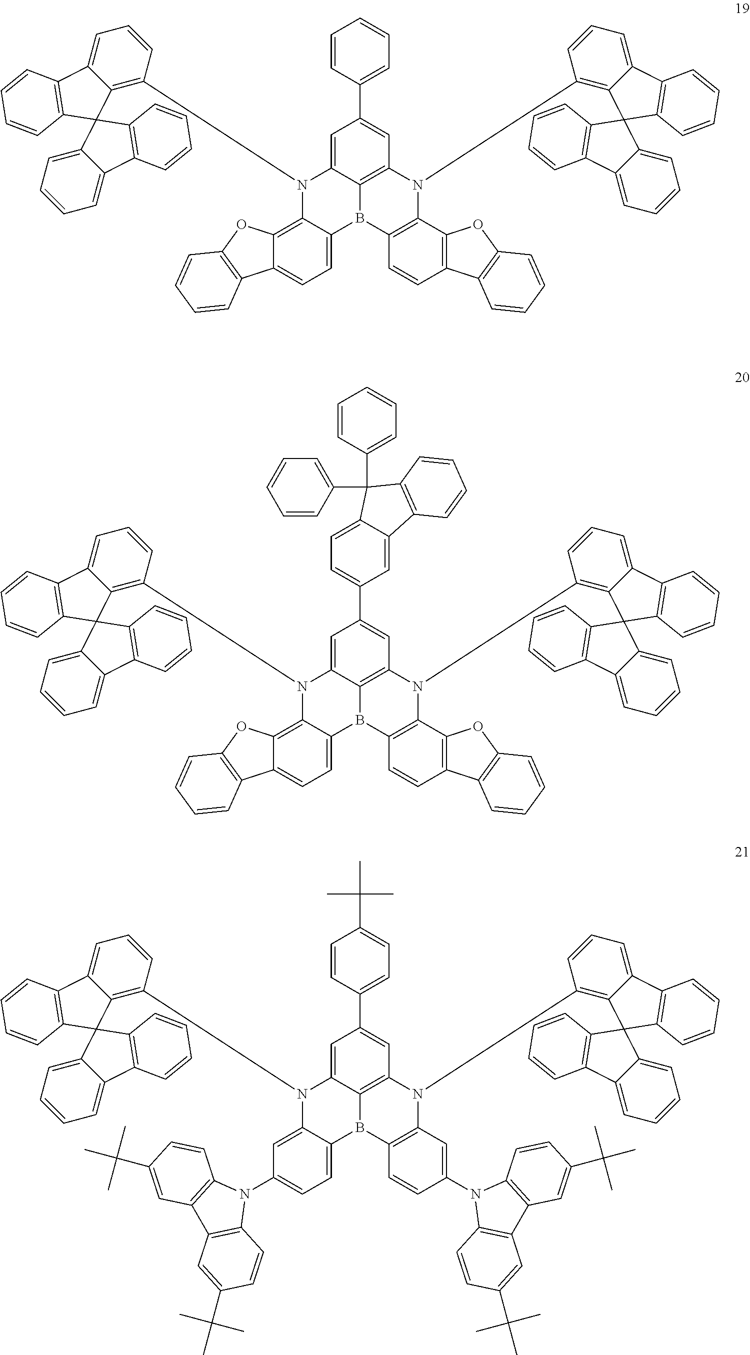 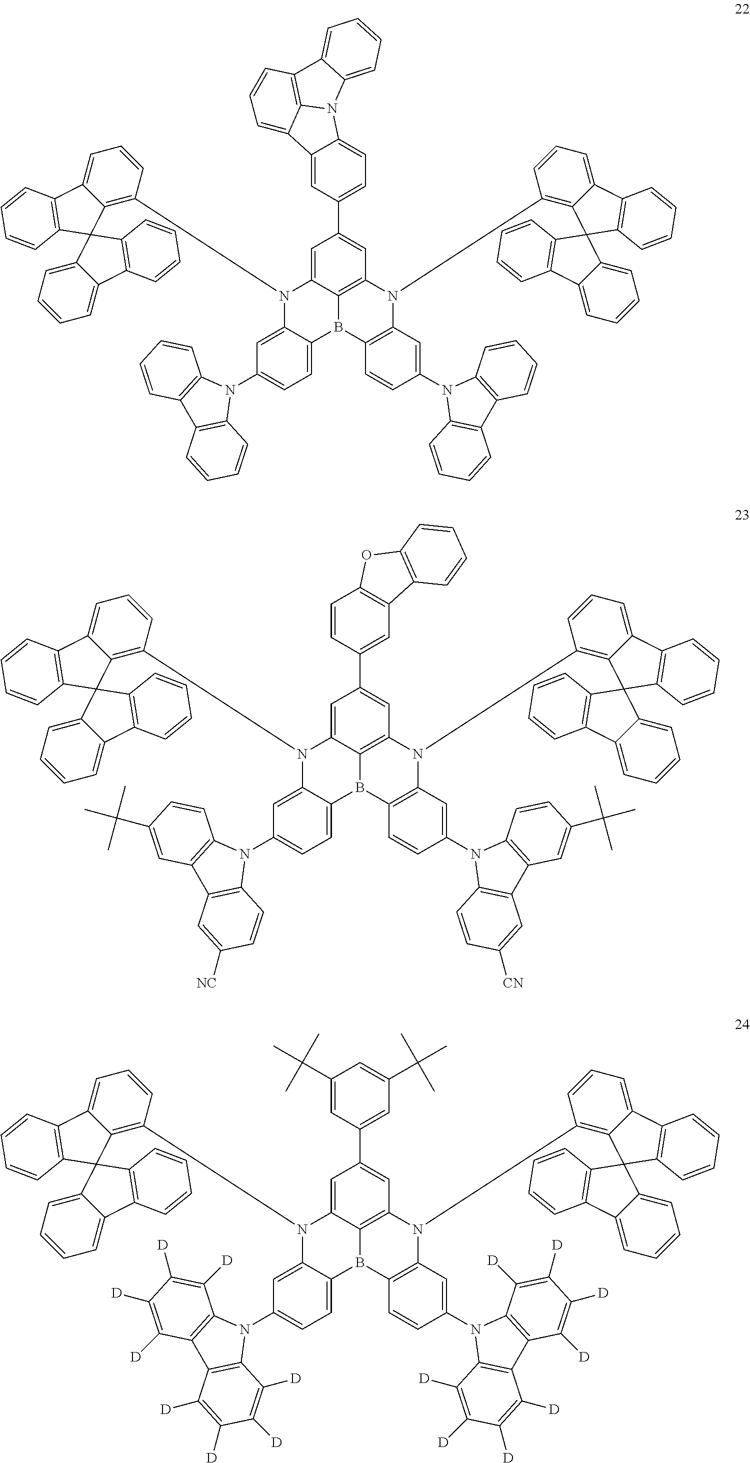 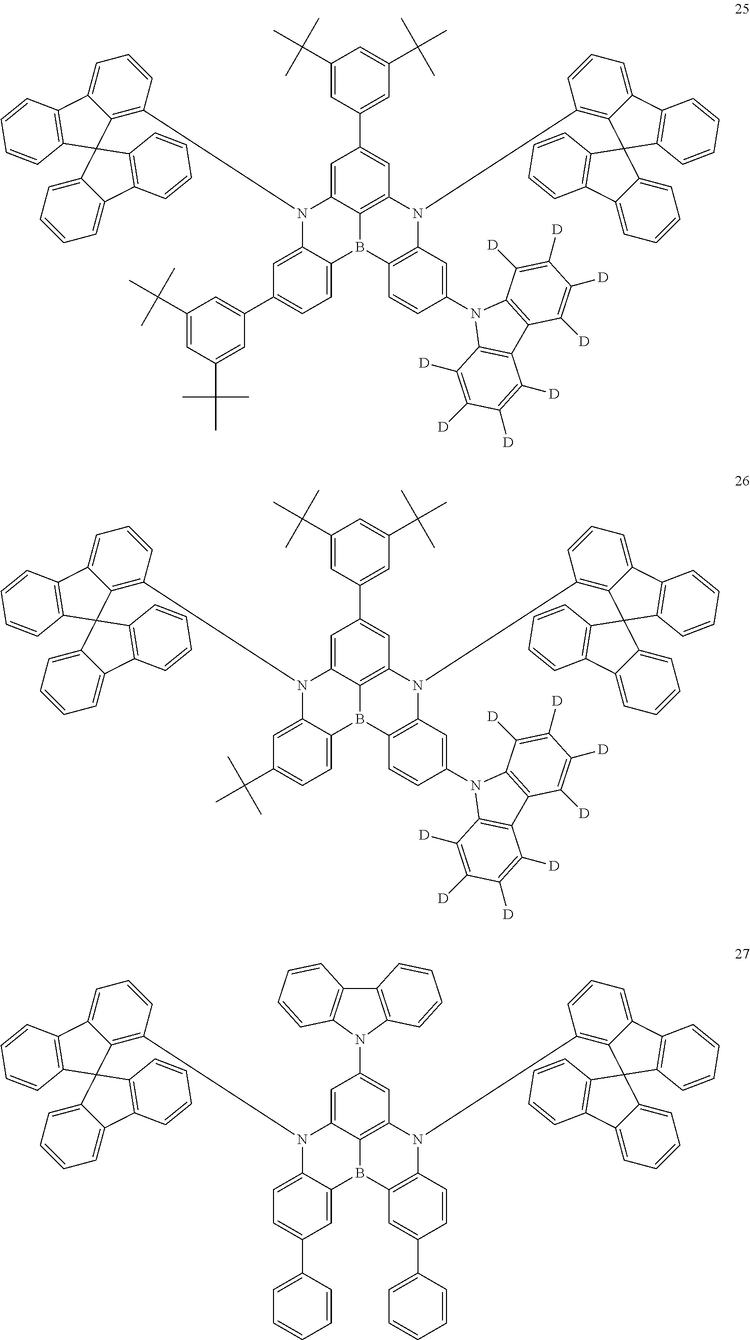 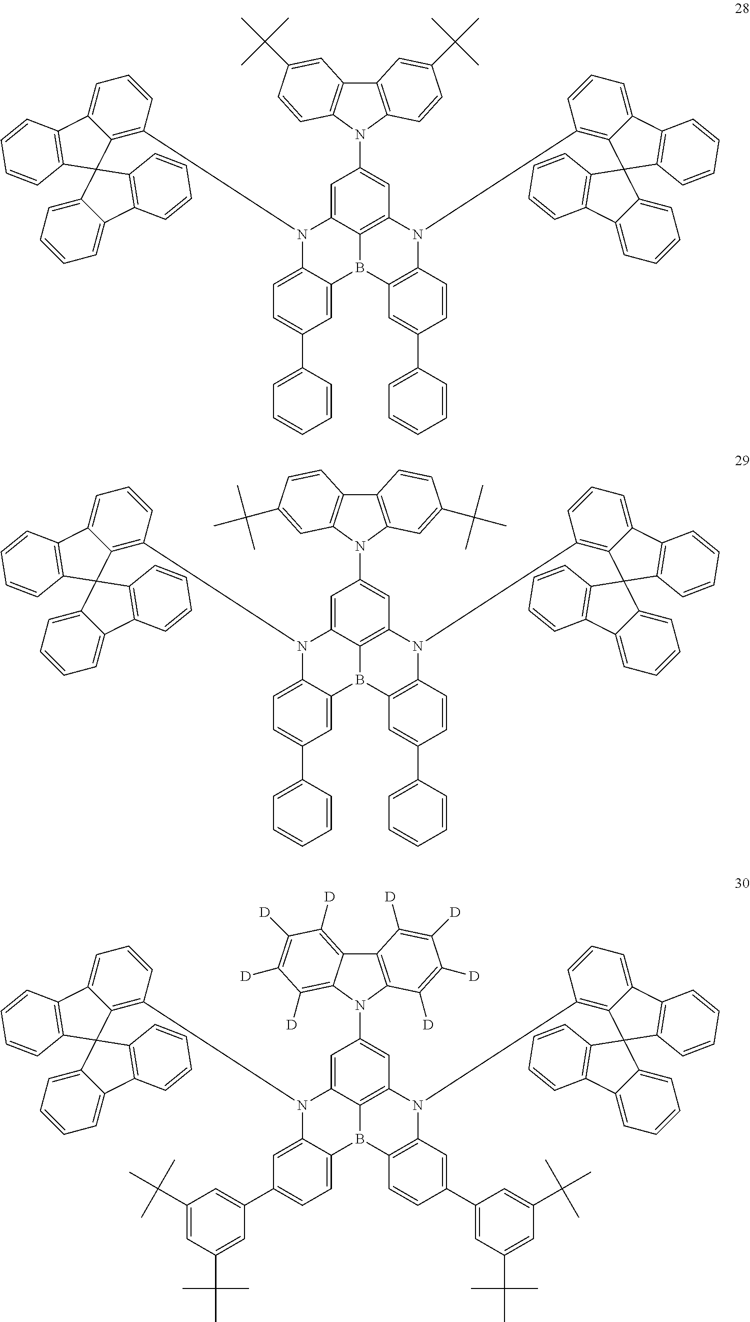 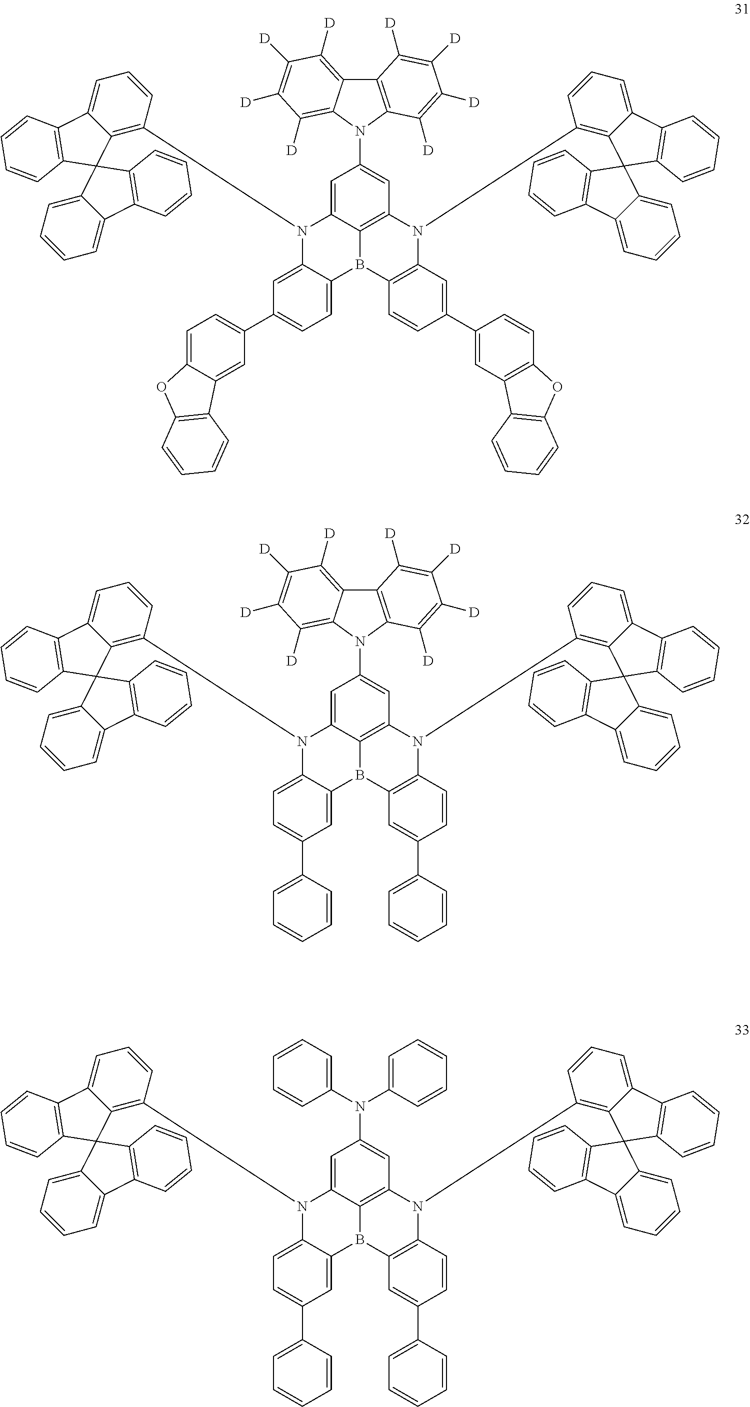 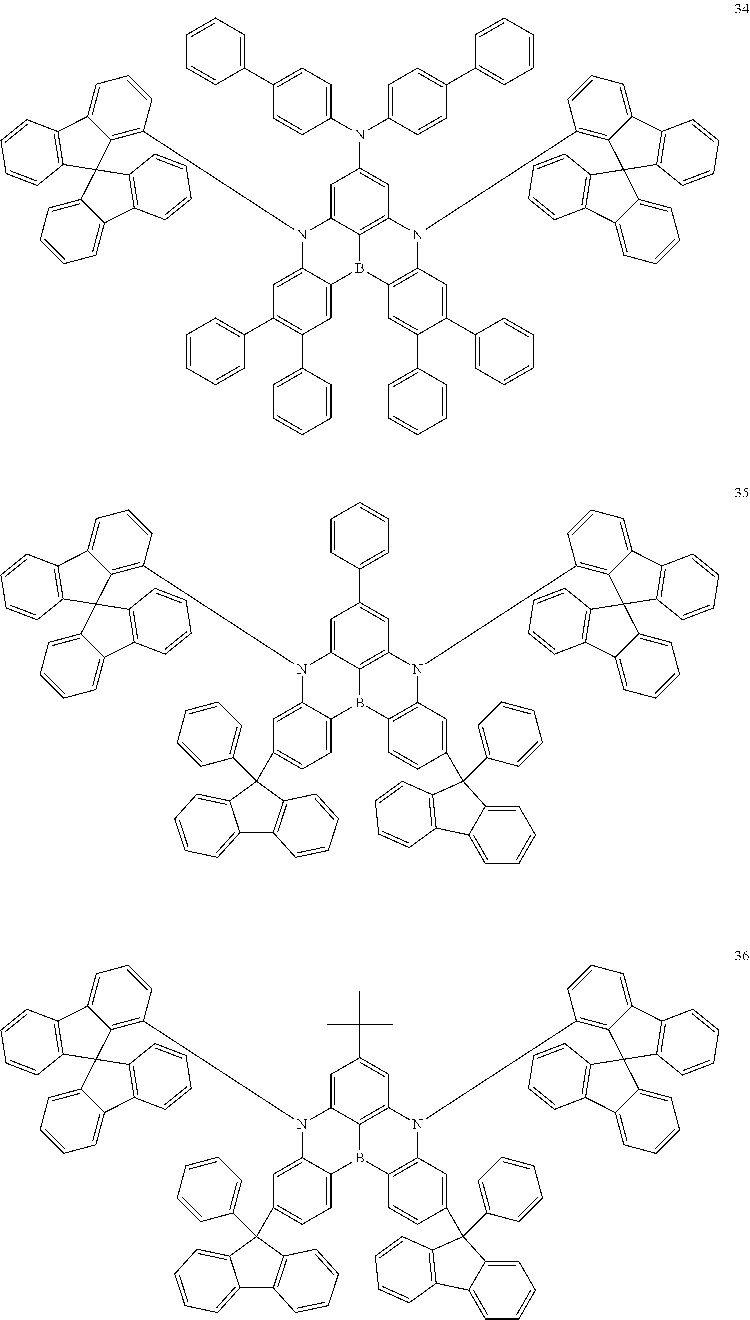 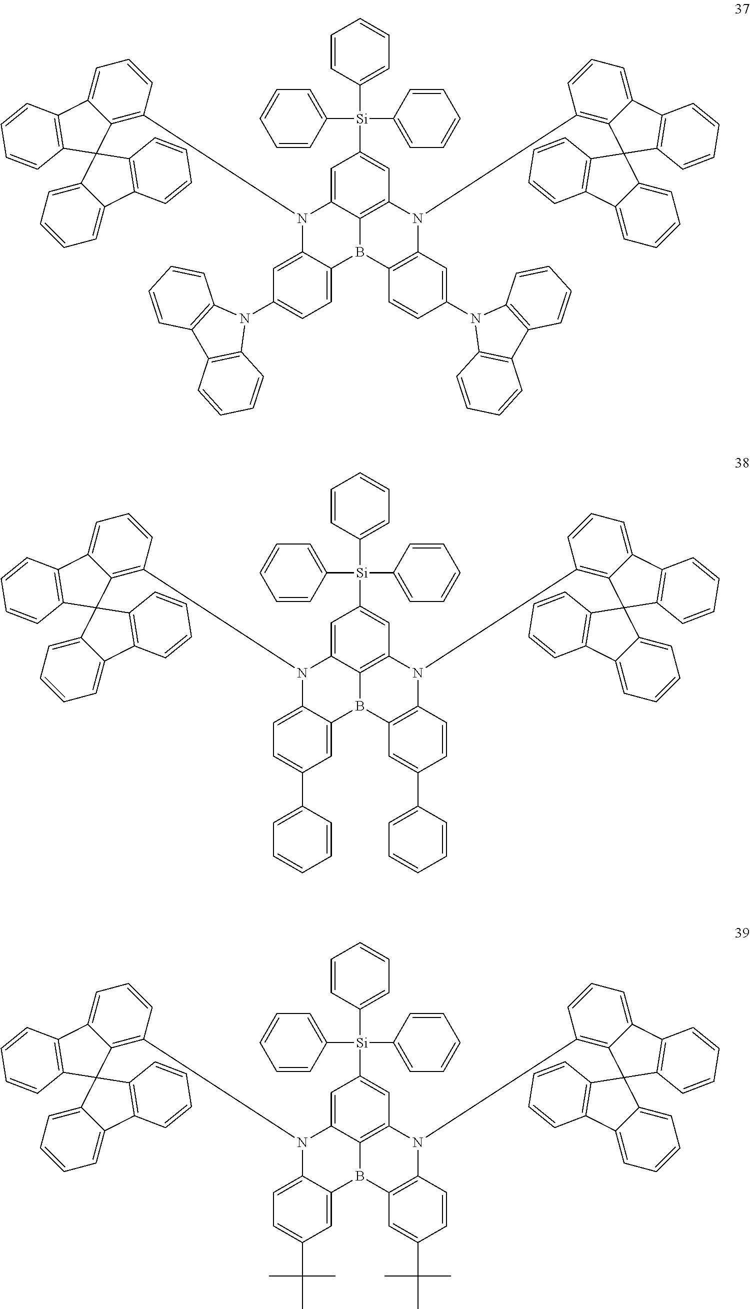 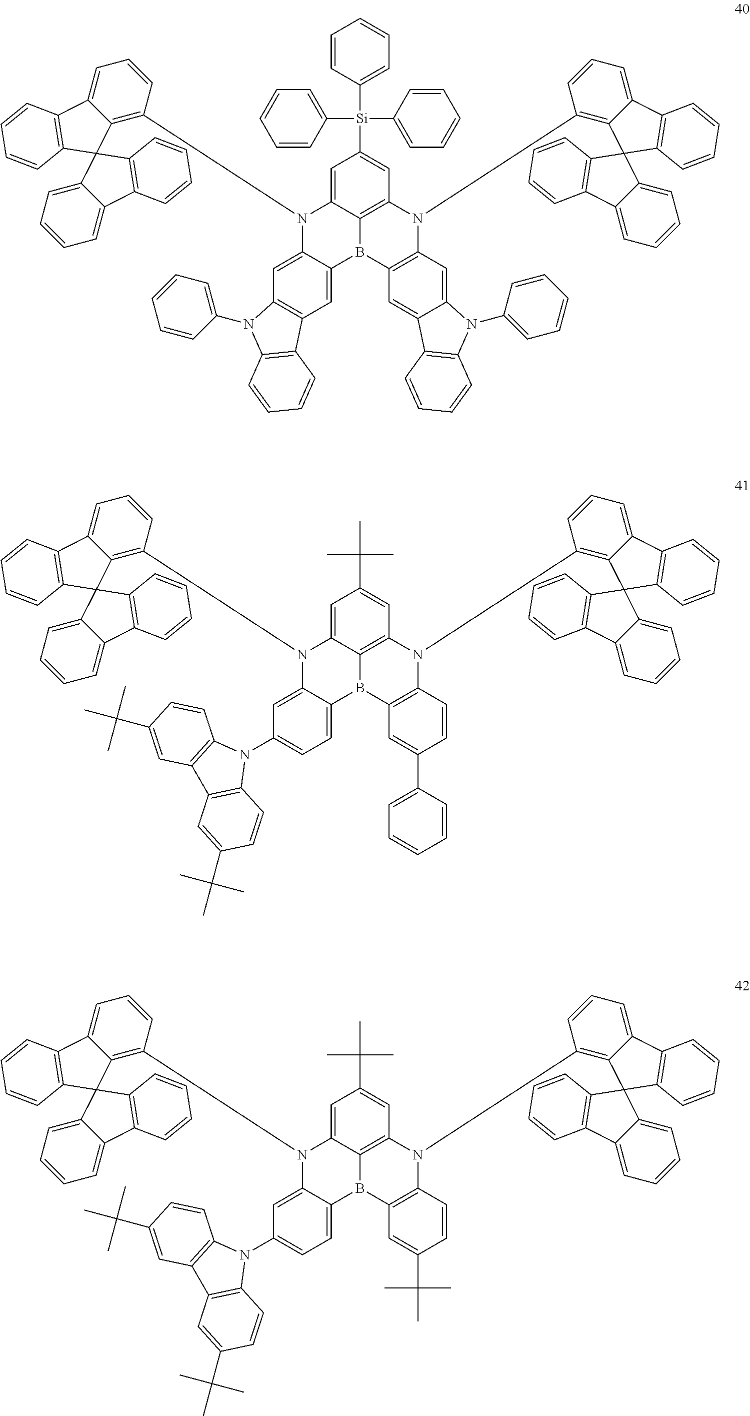 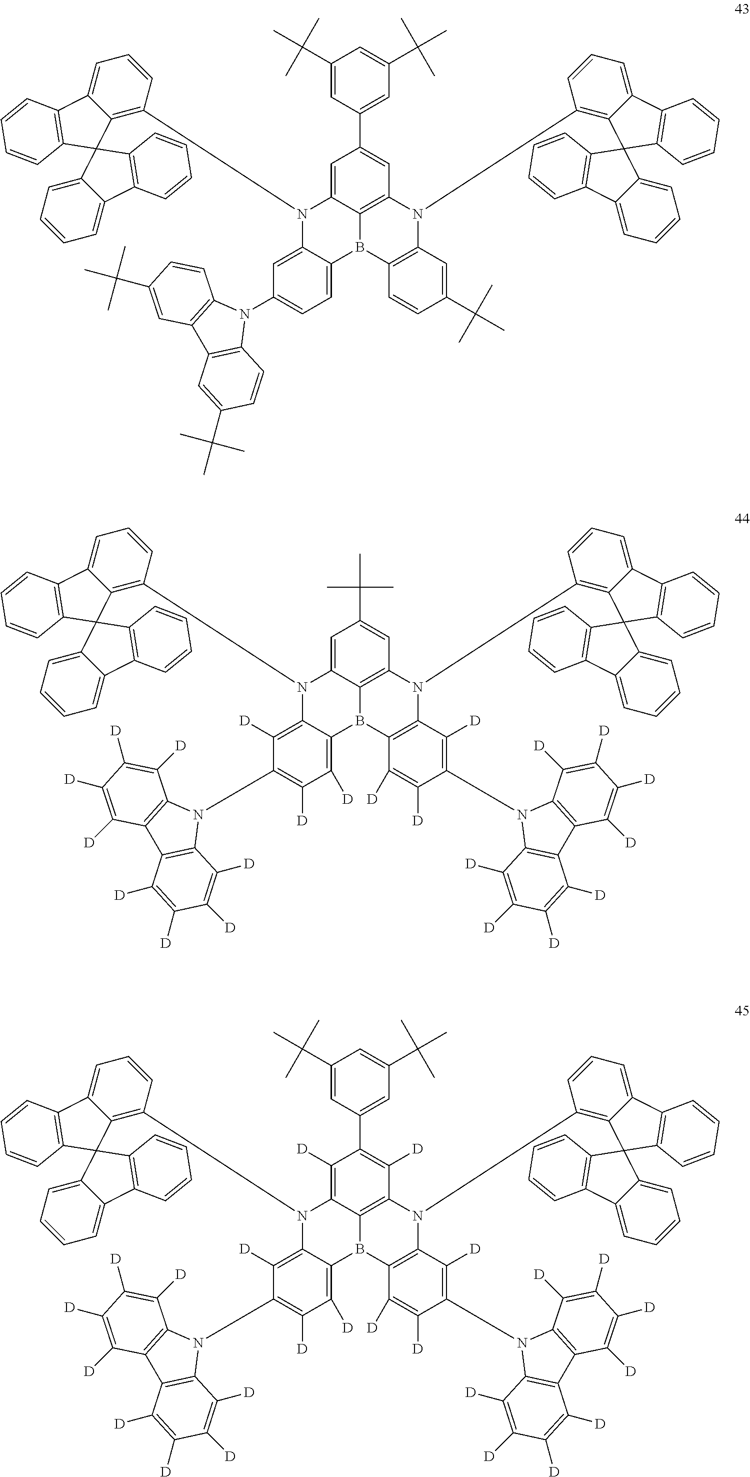 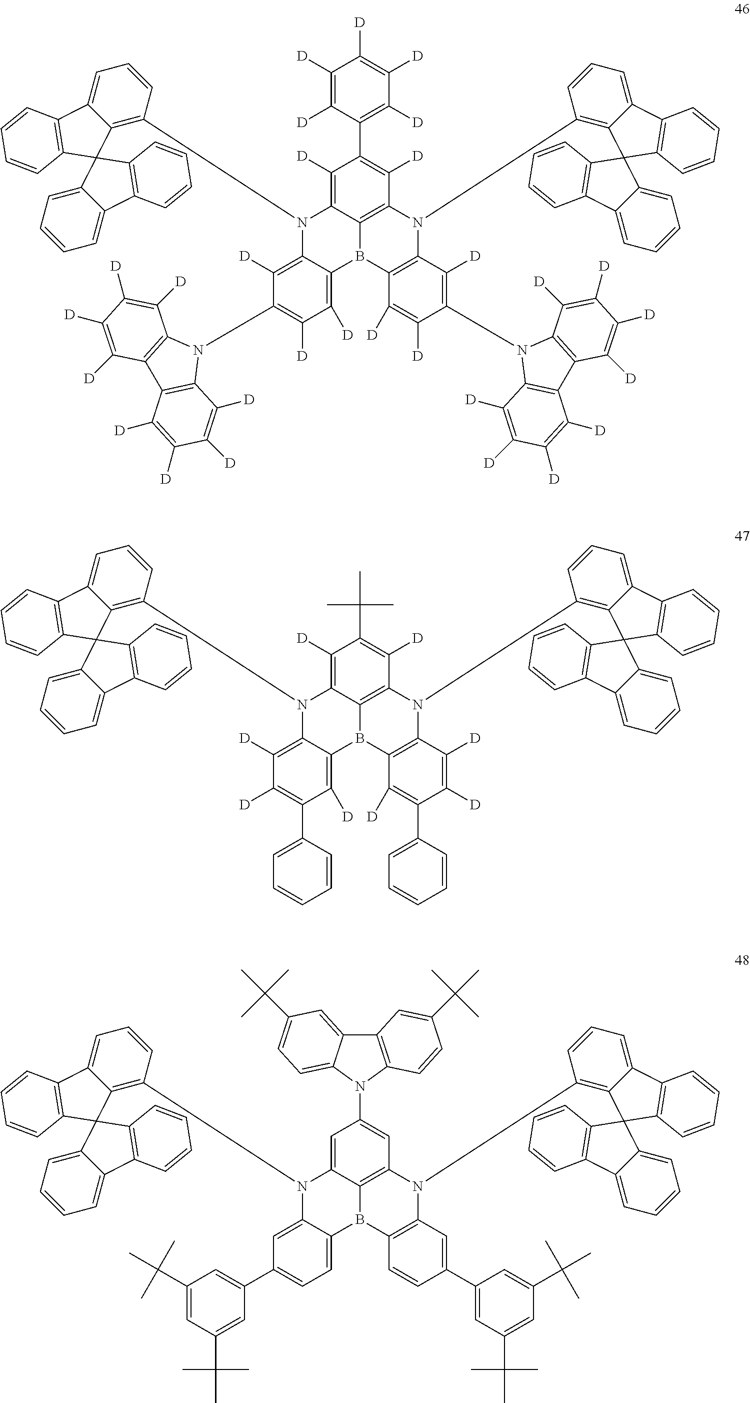
wherein in Compound Group 1,
D represents a deuterium atom.
